(19) United States
(12) Patent Application Publication
(10) Pub. No.: US 2024/0224780 A1
(43) Pub. Date: Jul. 4, 2024

(54) Organic Compound, Light-Emitting Element, and Display Panel

(71) Applicant: Shenzhen China Star Optoelectronics Semiconductor Display Technology Co., Ltd., Shenzhen (CN)

(72) Inventors: Xinlong SONG, Shenzhen (CN); Zhihua XIAO, Shenzhen (CN); Ruifeng HE, Shenzhen (CN); Jingyao SONG, Shenzhen (CN)

(73) Assignee: Shenzhen China Star Optoelectronics Semiconductor Display Technology Co., Ltd., Shenzhen (CN)

(21) Appl. No.: 18/079,490

(22) Filed: Dec. 12, 2022

(30) Foreign Application Priority Data
Nov. 15, 2022 (CN) 202211429281.3

(51) Int. Cl. H10K 85/30; C07F 5/02; C09K 11/06

(52) U.S. Cl. CPC H01L 51/008; C07F 5/027; C09K 11/06; H01L 51/5012

(57) ABSTRACT

The present application discloses an organic compound, a light-emitting element, and a display panel. The organic compound is represented by Formula (1):

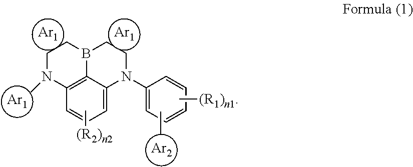

Each of Ar₁ groups is independently selected from structures represented by formula (A-1) to formula (A-5):

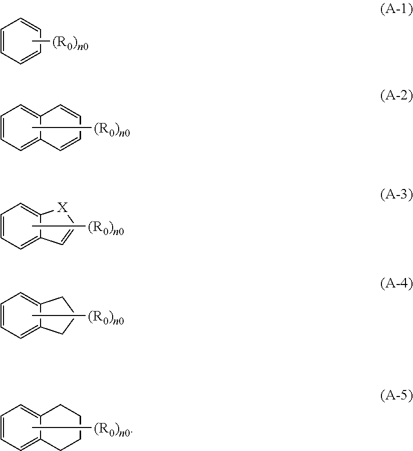

Ar₂ is selected from —H and structures represented by formula (B-1) to formula (B-4):

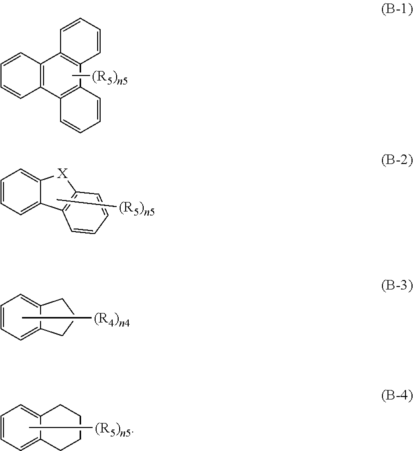

X is independently selected from O, S, N—CH₃, N-Ph, and C(CH₃)₂. Each of n₀, n₁, n₂, and n₅ is independently selected from 0 to 11. Each of R₀, R₁, R₂, and R₅ is independently selected from —H, -D, a C₁-C₂₀ linear alkyl group, a C₃-C₂₀ branched alkyl group, a substituted or unsubstituted aromatic group containing 6 to 30 ring atoms, and a substituted or unsubstituted heteroaromatic group containing 5 to 30 ring atoms.

### TECHNICAL FIELD

The present application relates to a field of display technologies, and particularly to an organic compound, a light-emitting element, and a display panel.

### BACKGROUND

In prior art, organic electroluminescent elements generally include positive electrodes, negative electrodes, and organic layers located between the positive electrodes and the negative electrodes. Organic substances in the organic layers are configured to convert electric energy into light energy to achieve organic electroluminescence. The organic layers are generally configured to be multi-layers, so as to improve light-emitting efficiency and service life of organic electroluminescent elements. The organic substances in each of the multi-layers are different. In detail, each of the organic layers mainly includes a hole injection layer, a hole transport layer, a light-emitting layer, an electron transport layer, an electron injection layer, etc. Voltages are applied on the positive electrodes and the negative electrodes of the organic electroluminescent element. Holes are injected into the organic layer from the positive electrodes. Electrons are injected into the organic layer from the negative electrodes. The injected holes meet the injected electrons in the organic layer to form excitons. The excitons emit light when transiting back to ground states, thereby realizing light emission of the organic electroluminescent element. The organic electroluminescent elements have characteristics of self-emission, high brightness, great efficiency, low driving voltages, wide viewing angles, high contrast ratios, good responsiveness, etc. Therefore, organic electroluminescent devices have broad application prospects.

In order to improve light-emitting efficiency of the organic electroluminescent elements, various light-emitting material systems based on fluorescence and phosphorescence have been developed. Among them, organic electroluminescent elements adopting fluorescent materials have a characteristic of high reliability. However, under electrical excitation, since a branch ratio of a single excited state and a triple excited state of an exciton is 1:3, internal electro electroluminescent quantum efficiency is limited to 25%. Organic electro electroluminescent elements adopting phosphorescent materials have achieved almost 100% internal electroluminescent quantum efficiency. However, the phosphorescent materials are generally metal complexes containing iridium and platinum, the above-mentioned materials are expensive and complex to synthesize. In addition, phosphorescent organic electroluminescent elements further produce a roll-off effect, that is, the light-emitting efficiency of the phosphorescent organic electroluminescent elements decreases rapidly with an increase of current or brightness, which limits their application in high brightness.

Light-emitting material systems in the prior art are generally combinations of various materials based on organic compounds, such as composite excited materials, thermally activated delayed fluorescence (TADF) materials, etc., so as to overcome the above-mentioned problems. Reverse internal conversion is adopted in electroluminescent elements to achieve high efficiency comparable to the phosphorescent organic electroluminescent elements. However, Improvement of performances such as light-emitting efficiency and life of traditional TADF organic compounds is limited, which makes it difficult to improve light-emitting efficiency and life of the organic electroluminescent elements adopting the TADF organic compounds.

Therefore, an organic compound, a light-emitting element, and a display panel are urgently needed to solve the above-mentioned technical problems.

### SUMMARY

An organic compound, a light-emitting element, and a display panel are provided in the present application, which can relieve technical problems that light-emitting efficiency and life of organic electroluminescent elements adopting TADF organic compounds are difficult to improve.

The organic compound provided in the present application is represented by Formula (1):

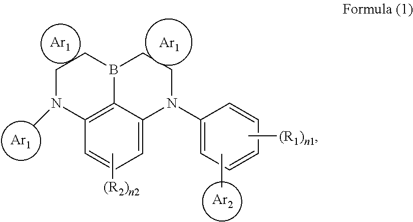

wherein each of Ar₁ groups is independently selected from structures represented by formula (A-1) to formula (A-5):

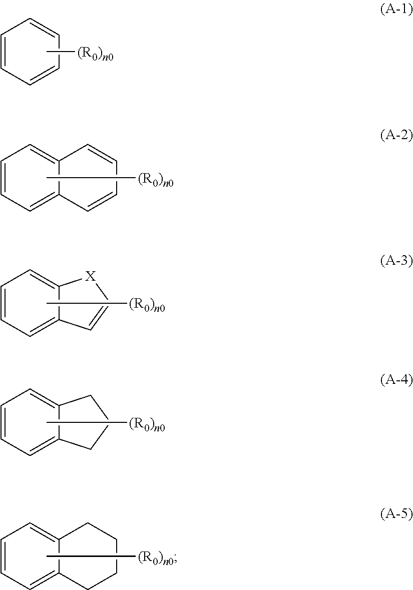

Ar₂ is selected from —H and structures represented by formula (B-1) to formula (B-4):

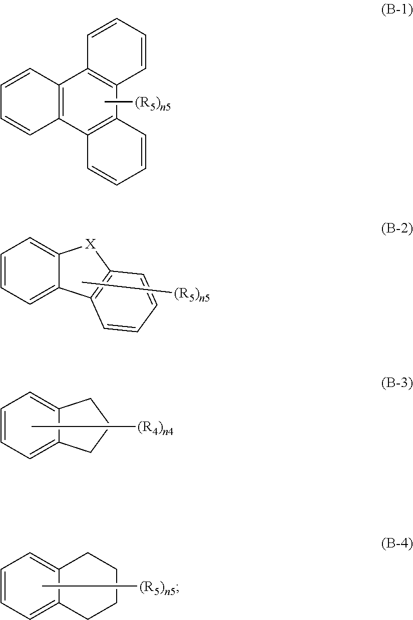

X is independently selected from O, S, N—CH₃, N-Ph, and C(CH₃)₂;
each of n₀, n₁, n₂, and n₅ is independently selected from 0 to 11;
each of R₀, R₁, R₂, and R₅ is independently selected from —H, -D, a C₁-C₂₀ linear alkyl group, a C₃-C₂₀ branched alkyl group, a substituted or unsubstituted aromatic group containing 6 to 30 ring atoms, and a substituted or unsubstituted heteroaromatic group containing 5 to 30 ring atoms; and
when n₀ is greater than or equal to 2, a ring is formed or no ring is formed between two adjacent R₀ groups; when n₁ is greater than or equal to 2, a ring is formed or no ring is formed between two adjacent R₁ groups; when n₂ is greater than or equal to 2, a ring is formed or no ring is formed between two adjacent R₂ groups; and when n₅ is greater than or equal to 2, a ring is formed or no ring is formed between two adjacent R₅ groups.

In an embodiment, the organic compound is represented by any one of formula (2-1) to formula (2-18):

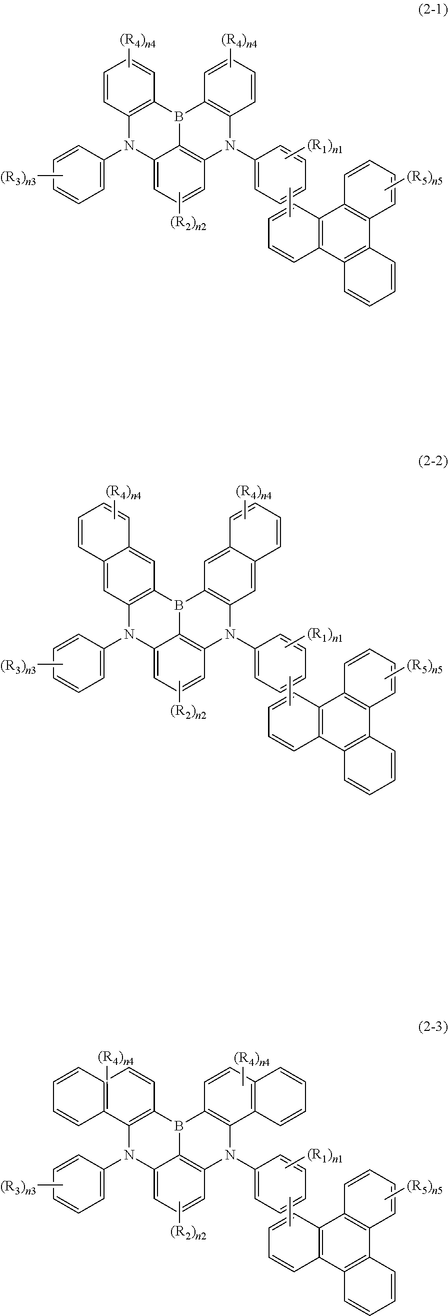

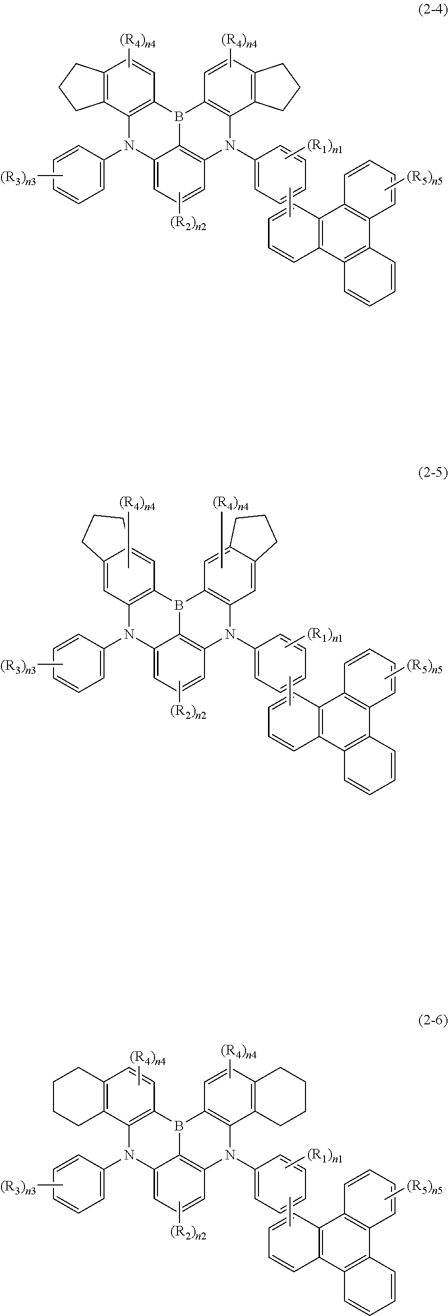

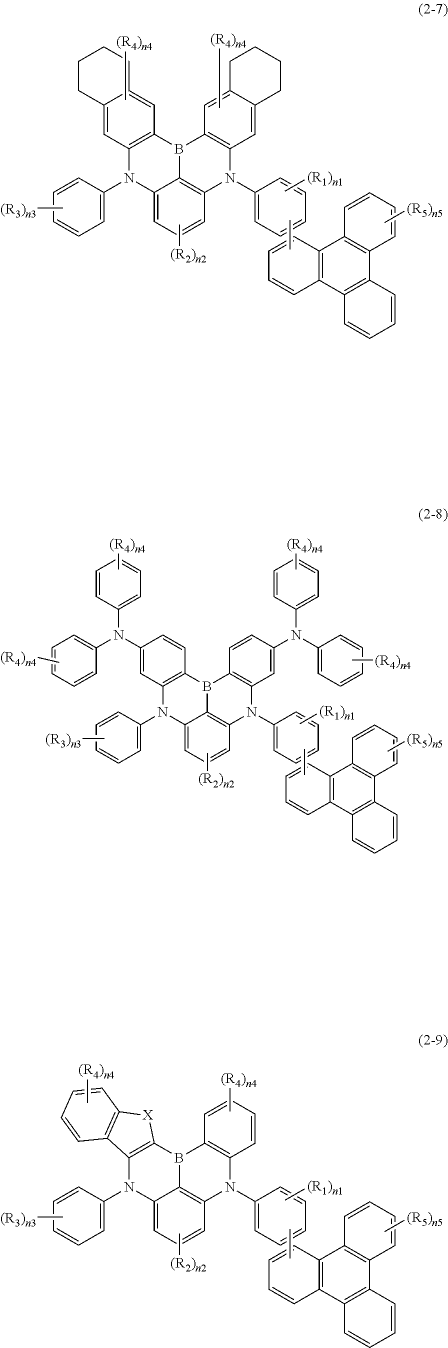

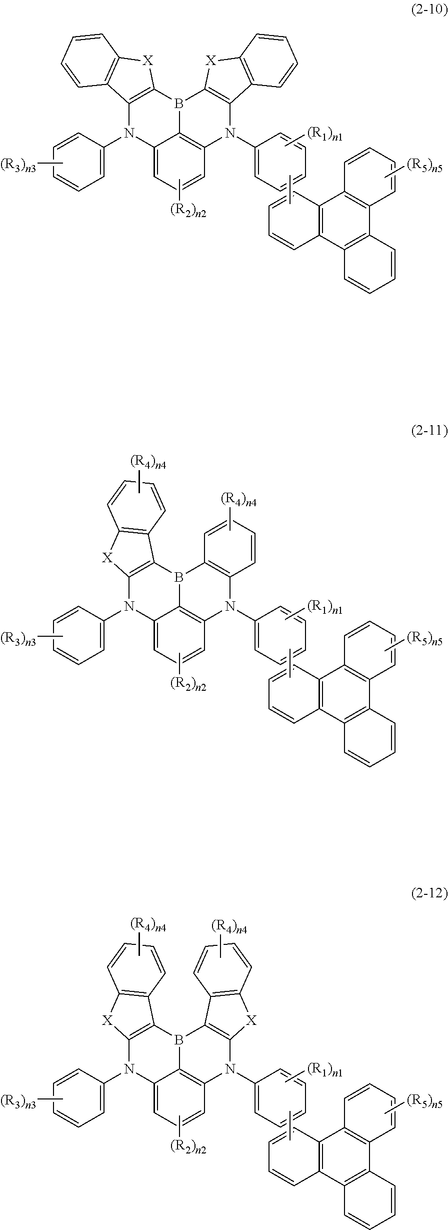

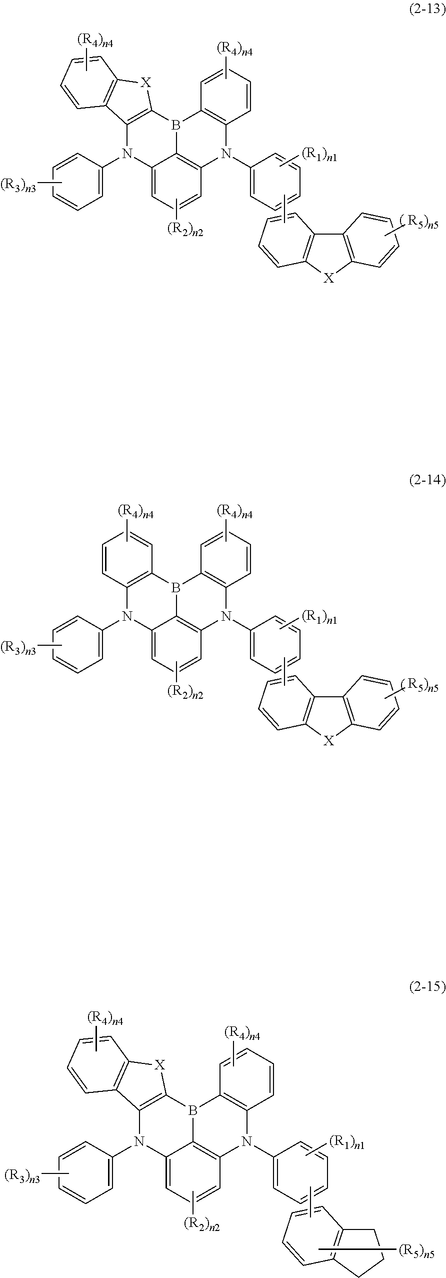

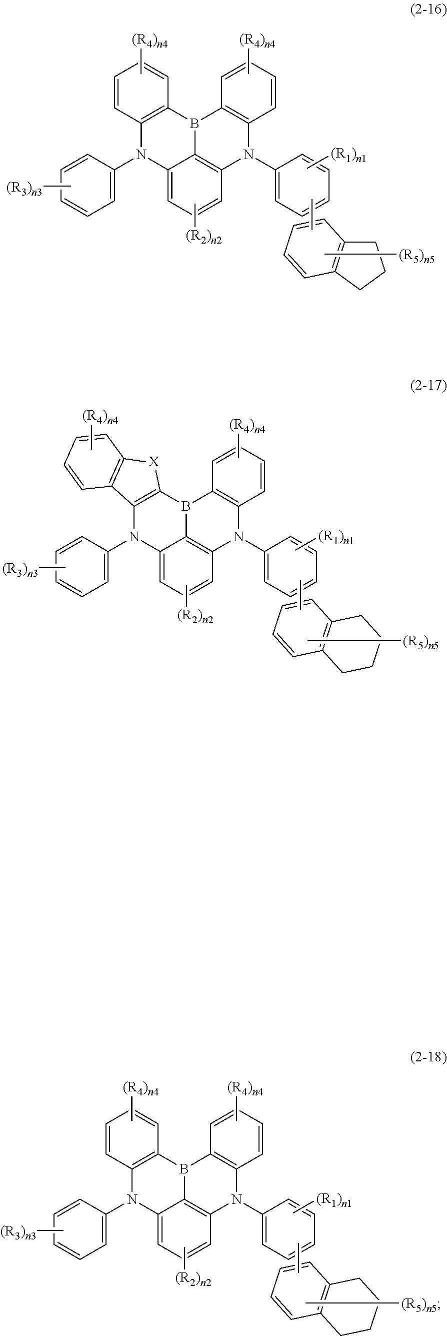

wherein each of R₃ and R₄ is independently selected from —H, -D, a C₁-C₂₀ linear alkyl group, a C₃-C₂₀ branched alkyl group, a substituted or unsubstituted aromatic group containing 6 to 30 ring atoms, and a substituted or unsubstituted heteroaromatic group containing 5 to 30 ring atoms;
each of n₃ and n₄ is independently selected from 0 to 11; and
when n₃ is greater than or equal to 2, a ring is formed or no ring is formed between two adjacent R₃ groups; and when n₄ is greater than or equal to 2, a ring is formed or no ring is formed between two adjacent R₄ groups.

In an embodiment, each of R₁, R₂, R₃, R₄, and R₅ is independently selected from —H, -D, a C₁-C₁₀ linear alkyl group, and a C₃-C₁₀ branched alkyl group.

In an embodiment, each of R₁, R₂, R₃, R₄, and R₅ is independently selected from —H, -D, a C₁-C₄ linear alkyl group, and a C₃-C₅ branched alkyl group.

In an embodiment, a structure represented by the formula (A-3) is

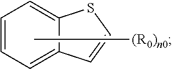

and
a structure represented by the formula (B-2) is

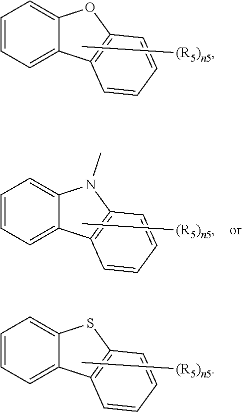

In an embodiment, the organic compound is selected from compounds as following:

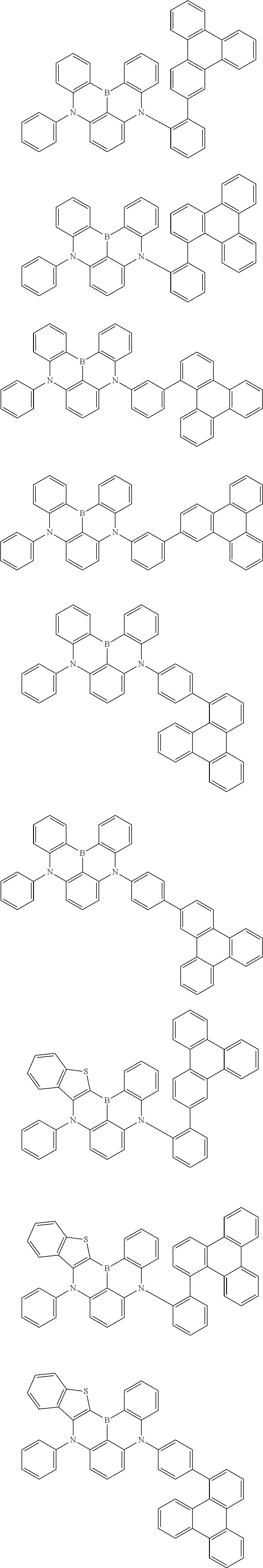

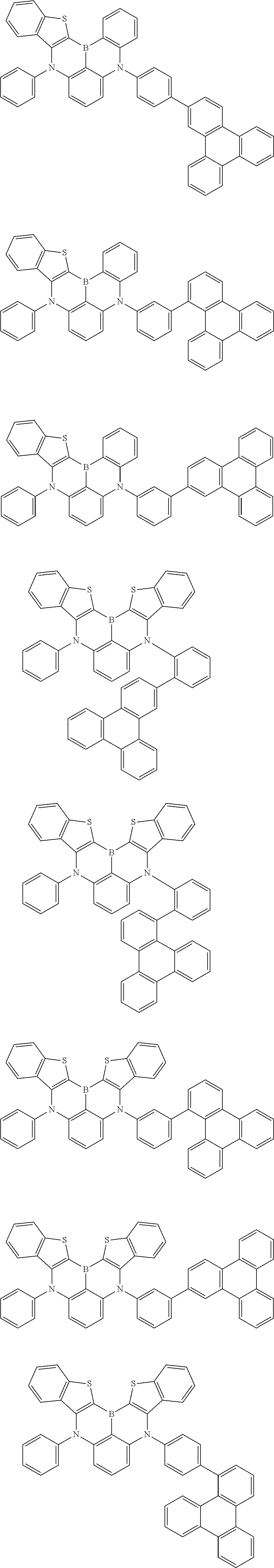

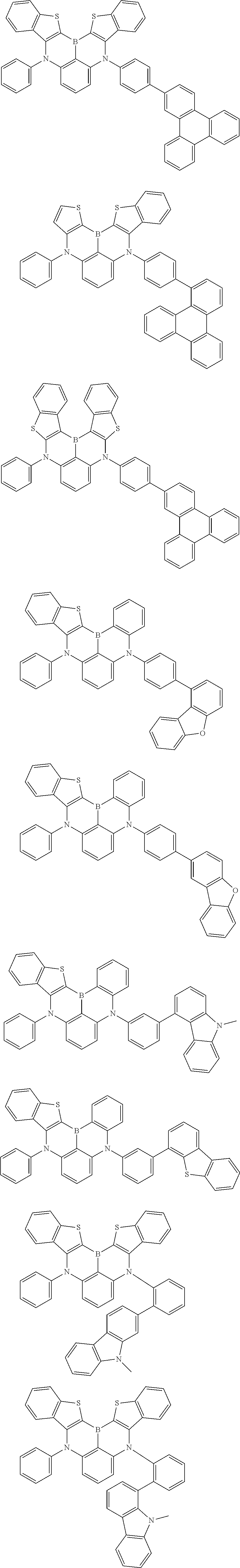

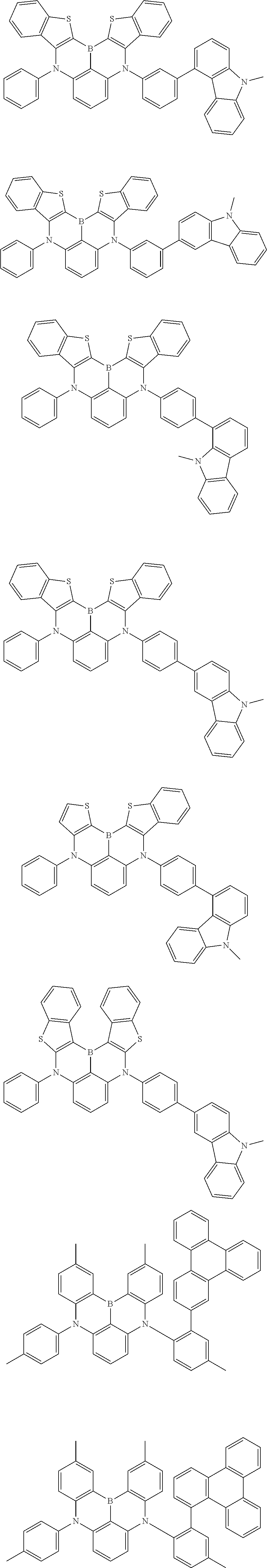

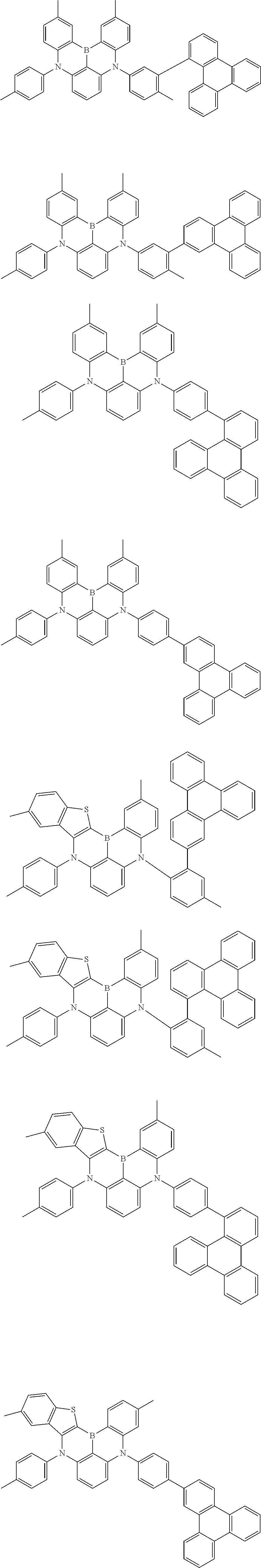

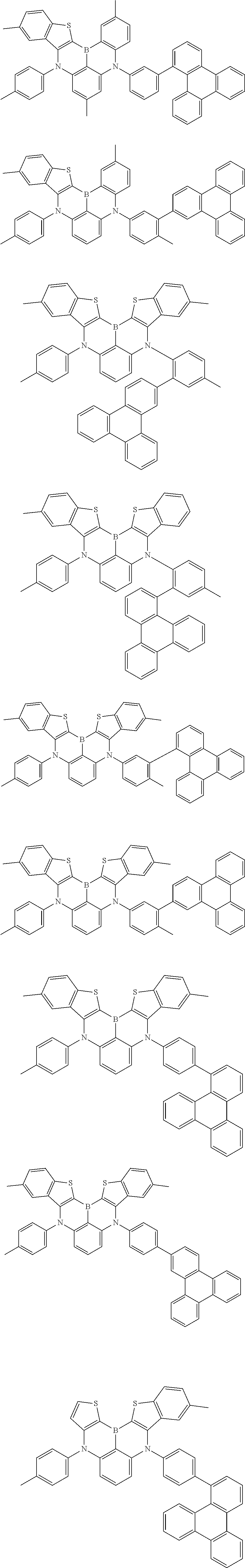

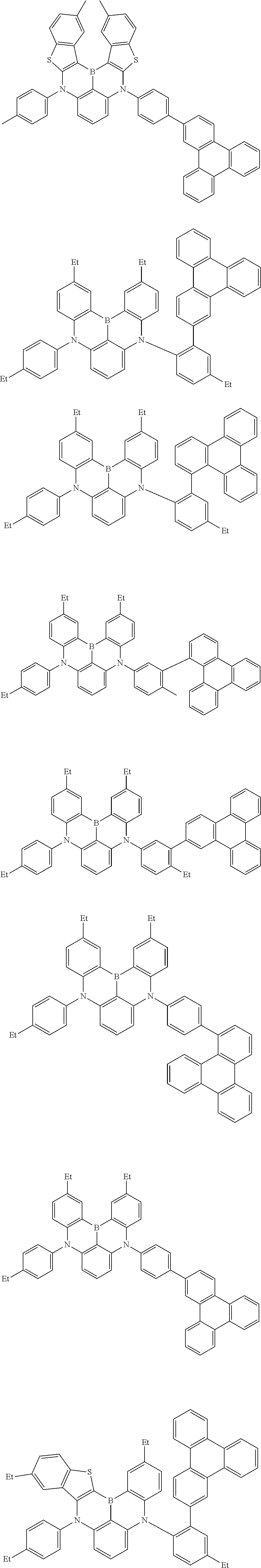

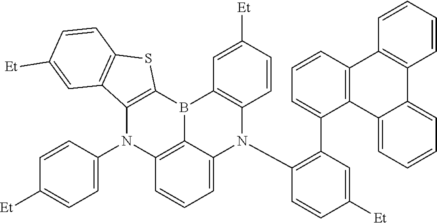 [SMILES: CCc1ccc(N2c3cccc4c3B(c3cc(CC)ccc3N4c3ccc(CC)cc3-c3cccc4c5ccccc5c5ccccc5c34)c3sc4ccc(CC)cc4c32)cc1]

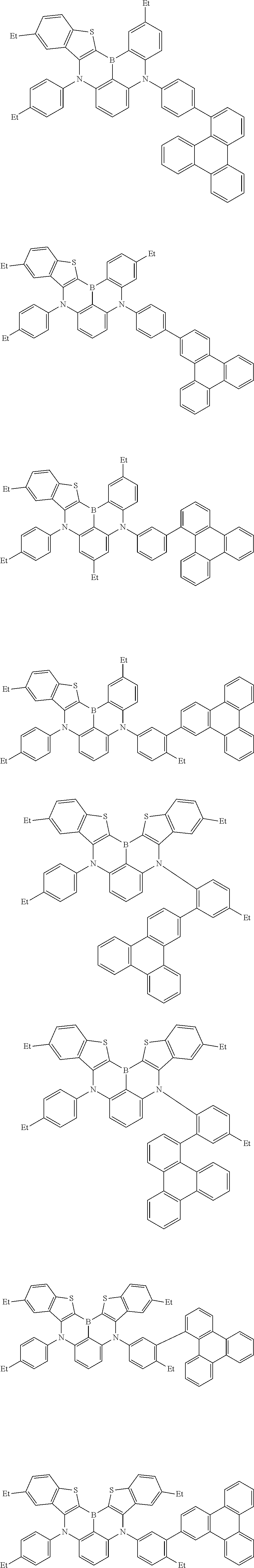

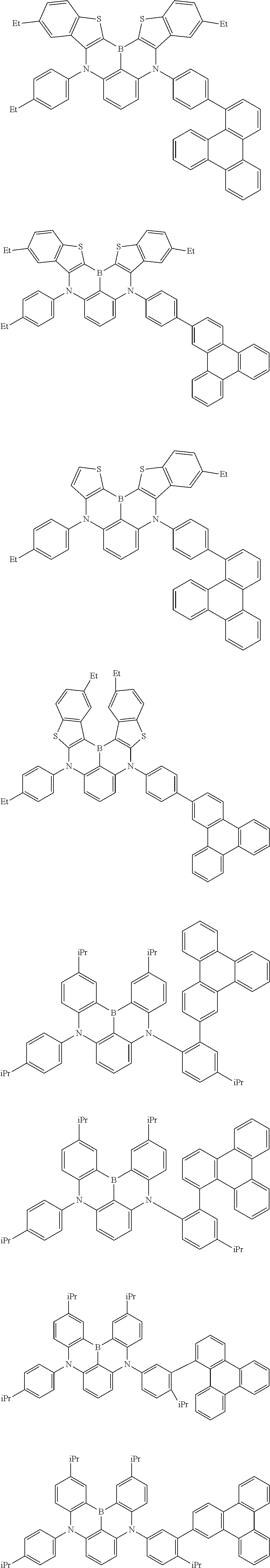

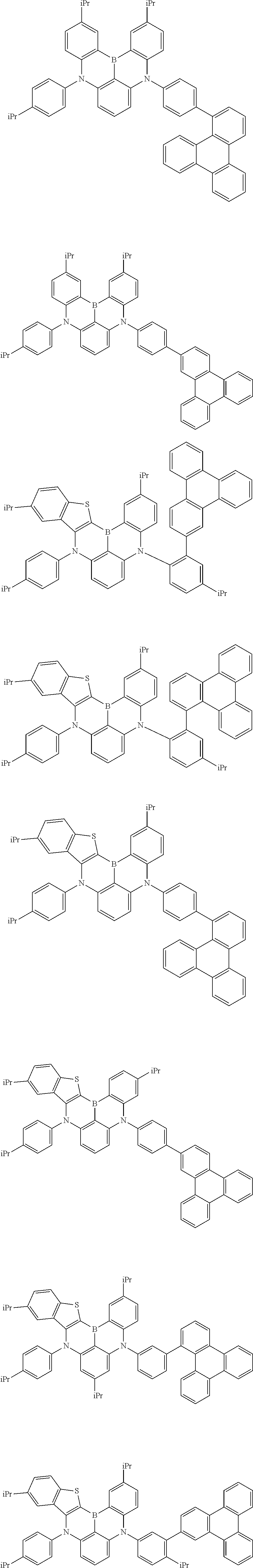

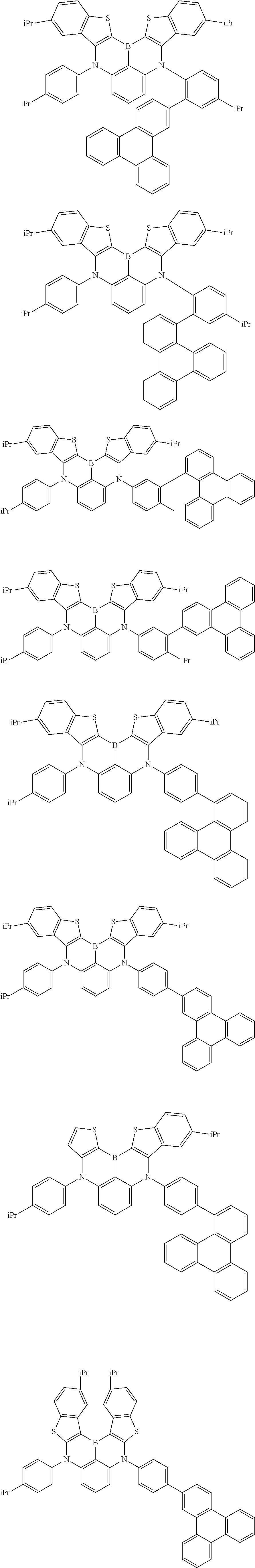

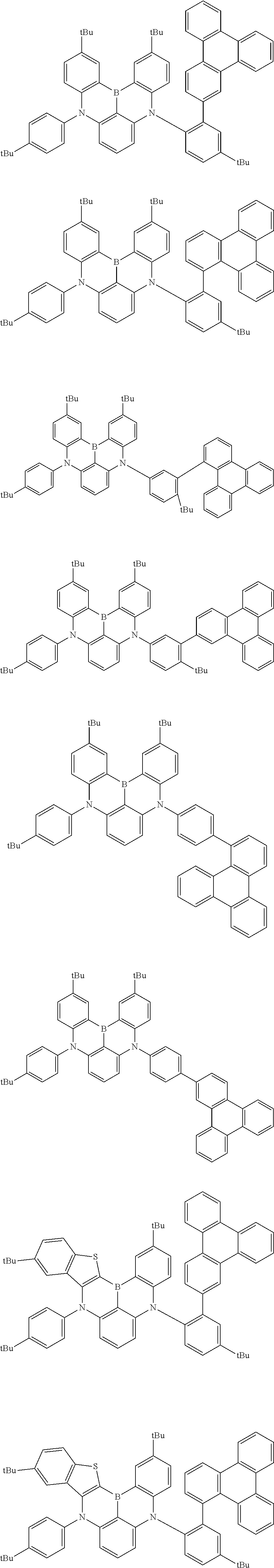

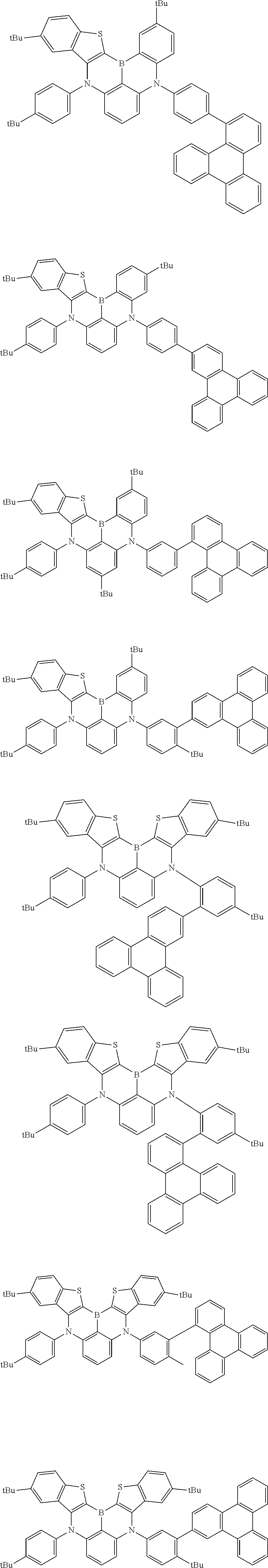

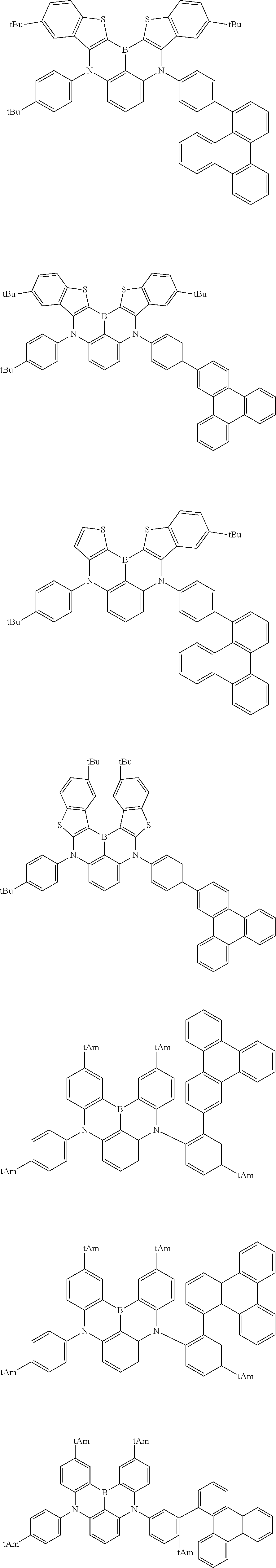

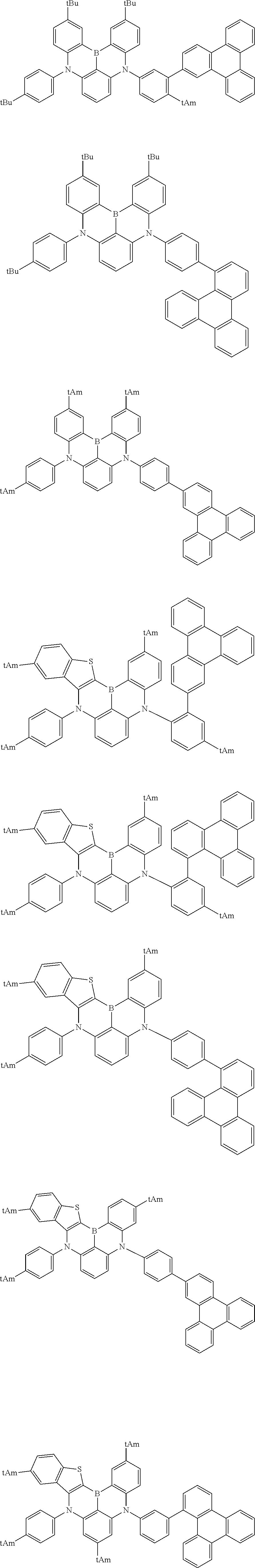

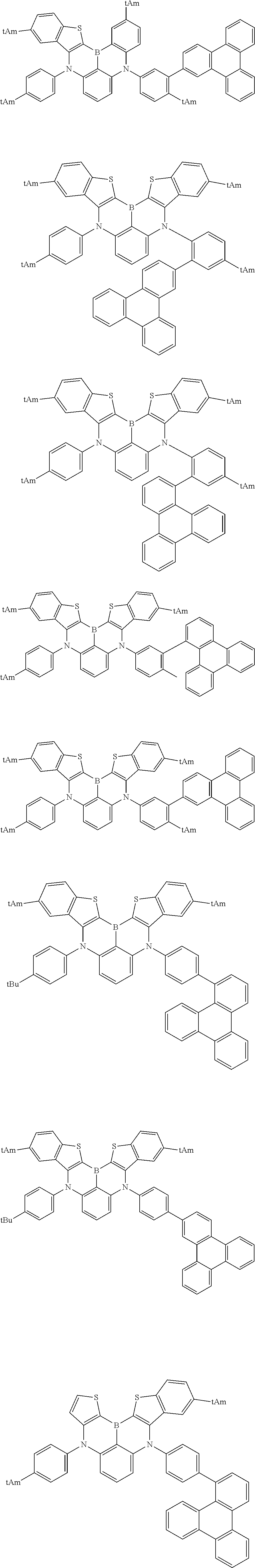

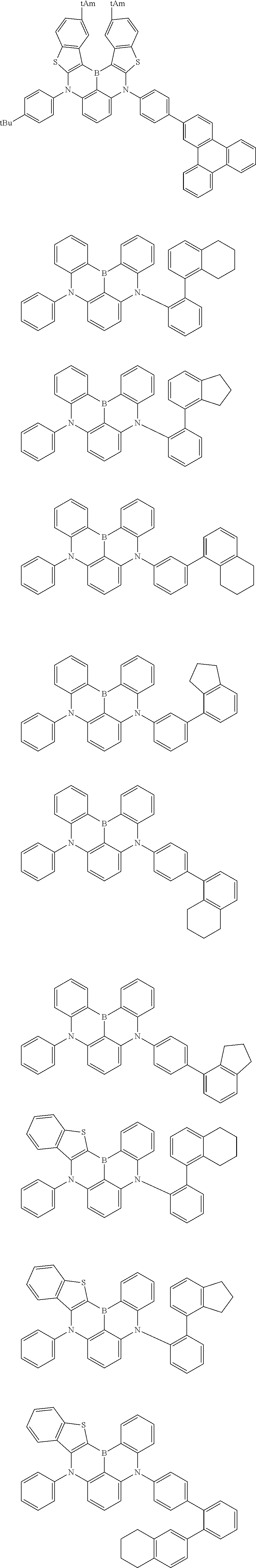

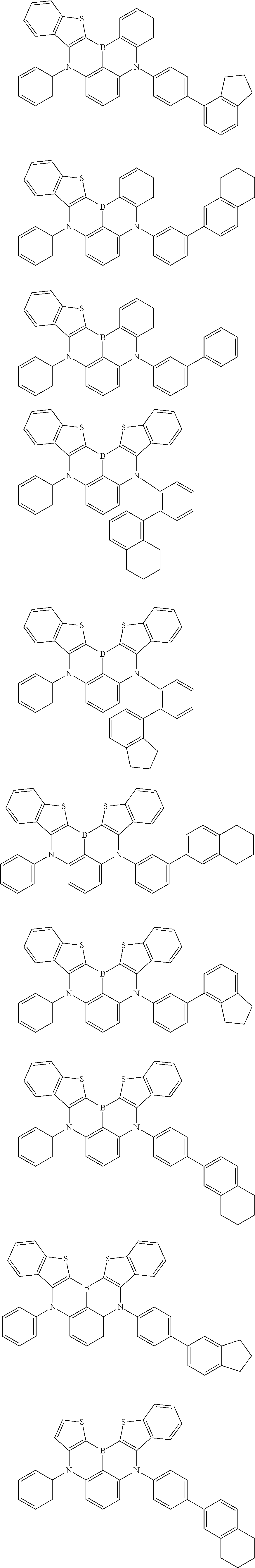

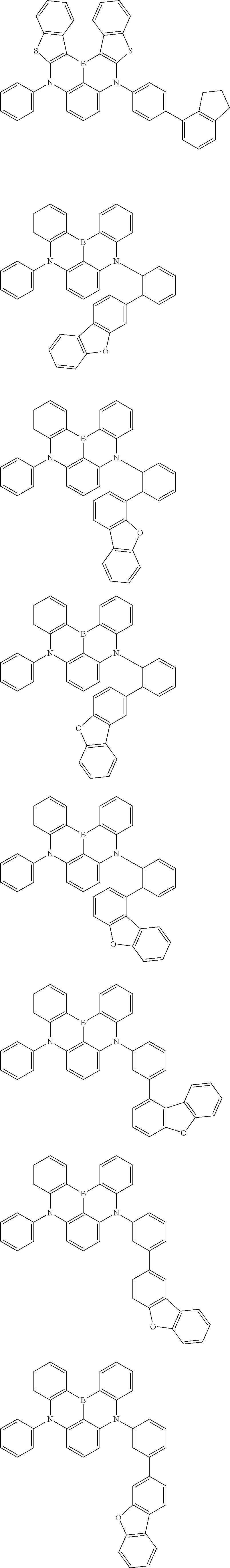

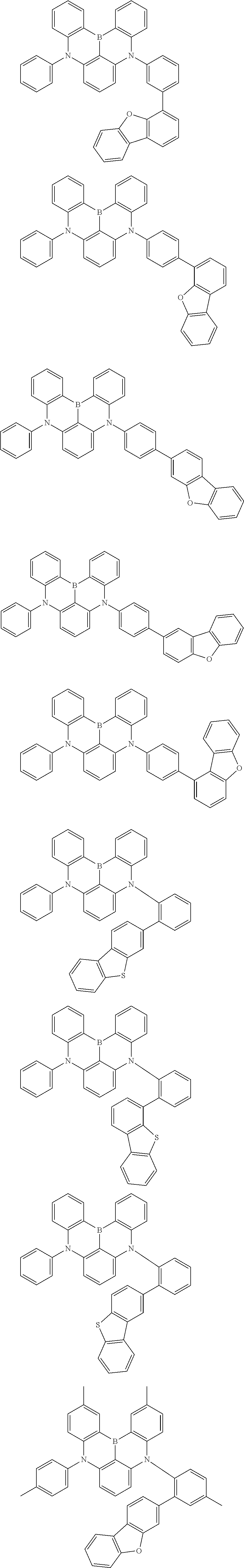

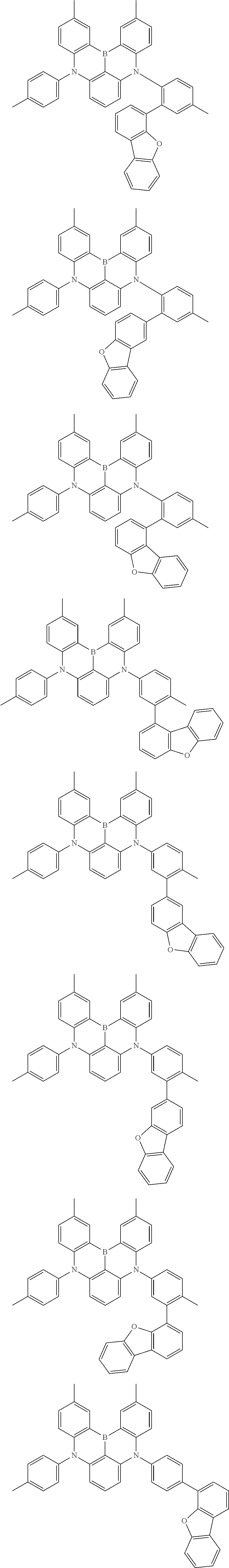

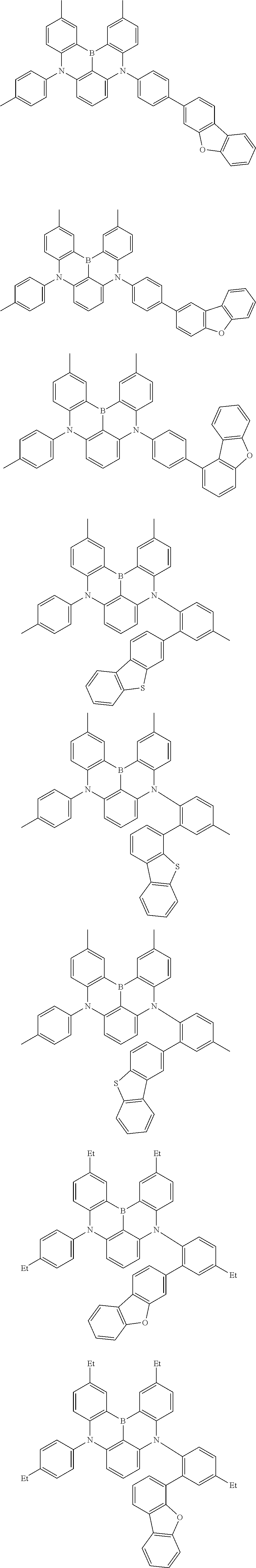

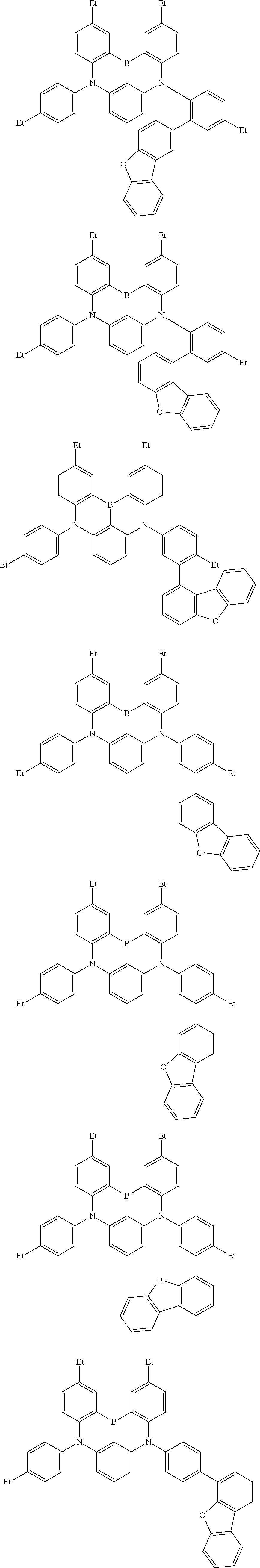

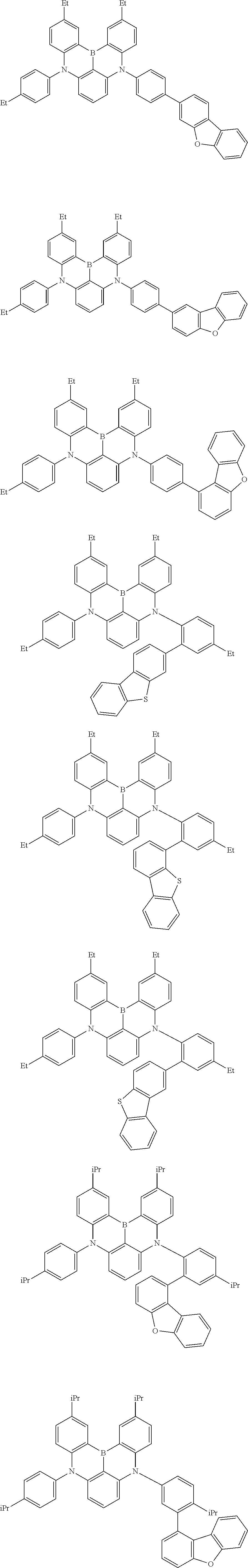

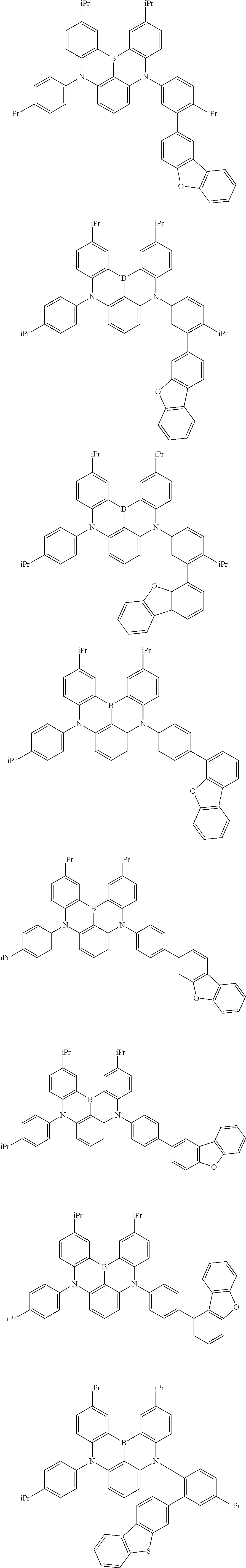

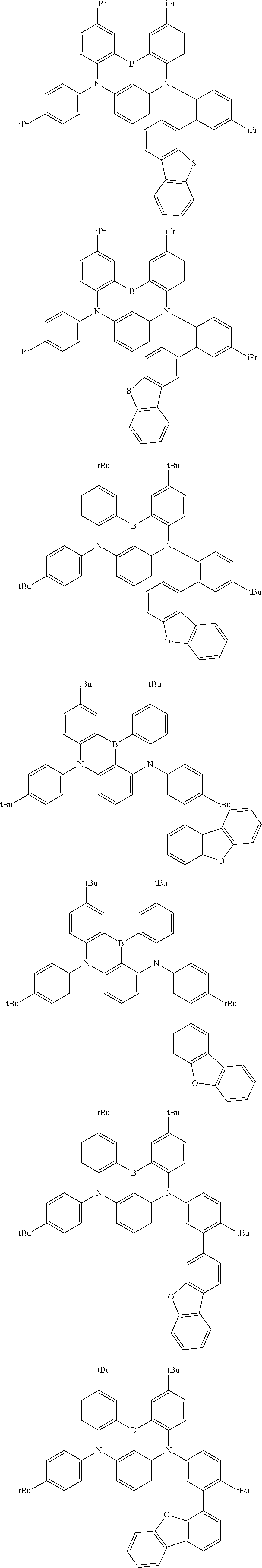

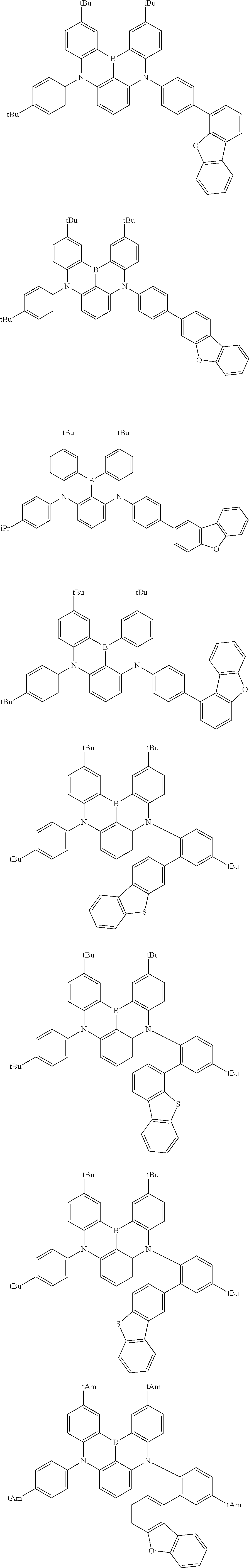

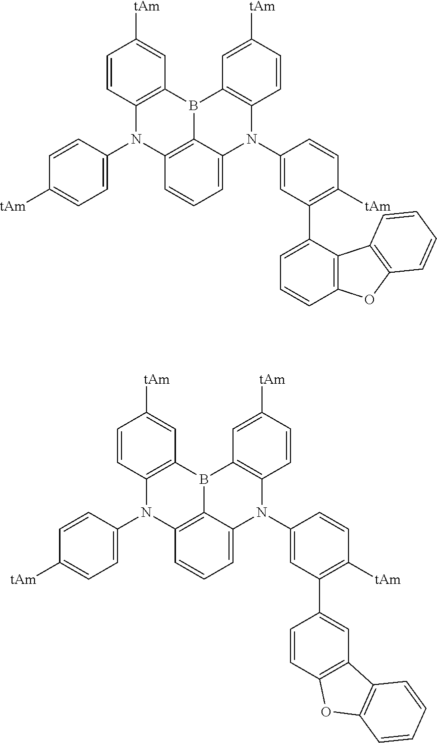

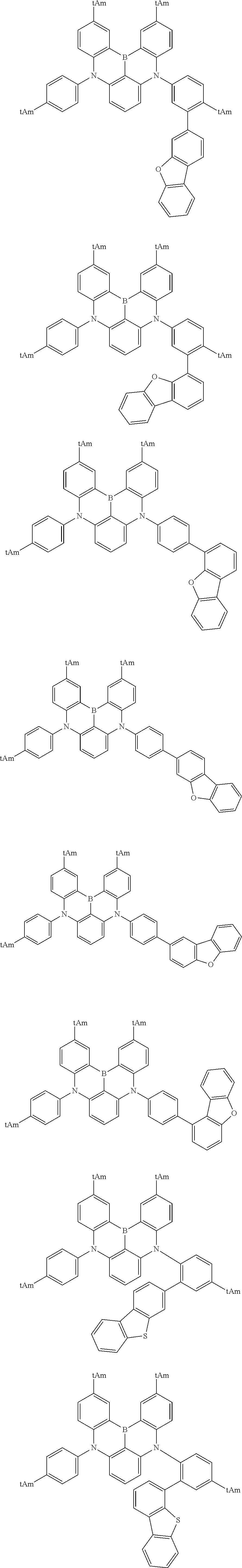

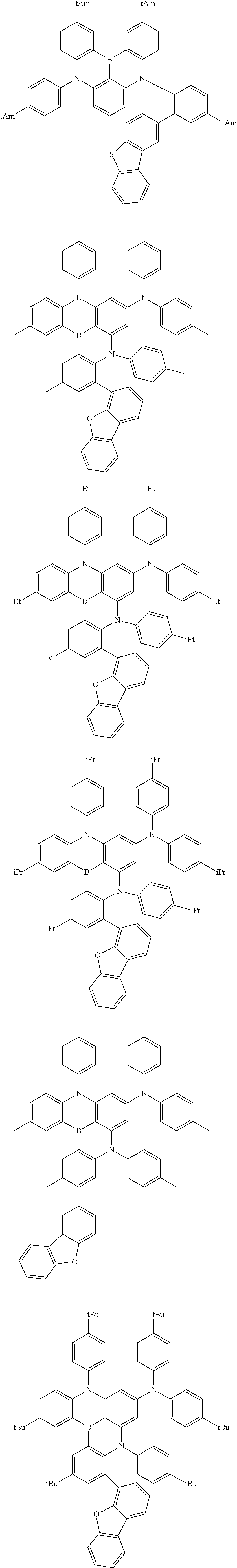

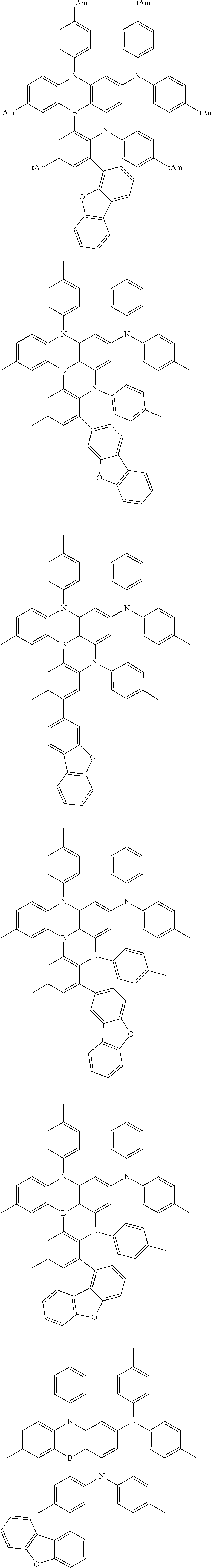

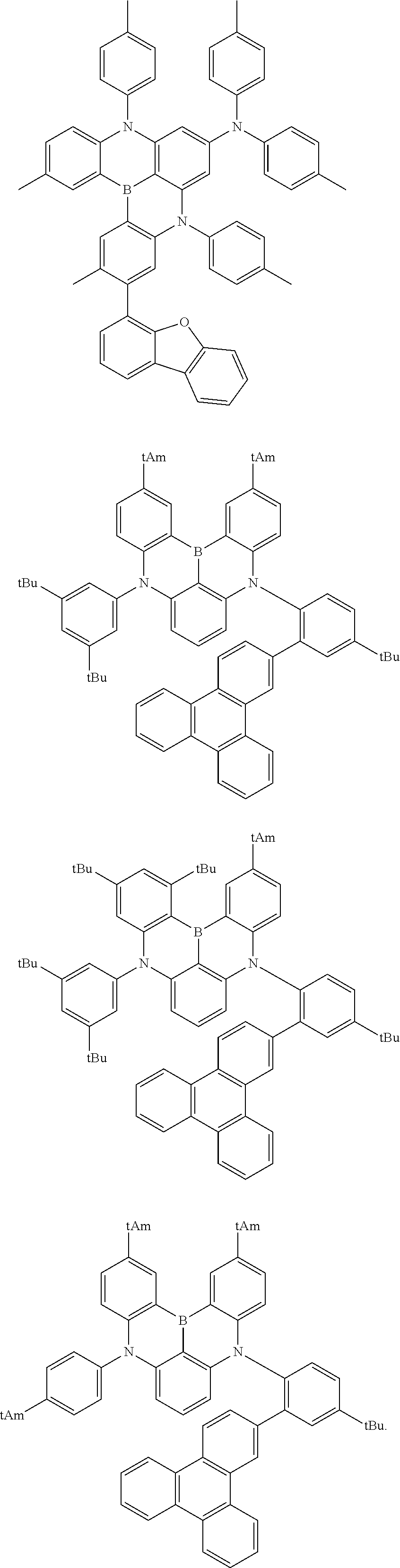

The light-emitting element is further provided in the present application, including: a pair of electrodes, the electrodes including a first electrode and a second electrode; and
an organic functional layer located between the first electrode and the second electrode;
wherein materials of the organic functional layer include at least one of the above-mentioned organic compounds.

In an embodiment, the organic functional layer includes at least a light-emitting layer, the light-emitting layer includes a host material and a guest material, the guest material is the organic compound, and the host material includes a fused aromatic derivative or a heteroaromatic compound.

In an embodiment, the host material includes at least one of an anthracene derivative, a pyrene derivative, a naphthalene derivative, a pentacene derivative, a phenanthrene compound, a fluoranthene compound, a carbazole derivative, a dibenzofuran derivative, a ladder type furan compound, and a pyrimidine derivative.

The display panel is further provided in the present application, including any of the above-mentioned light-emitting elements.

In the present application, by introducing groups that makes an overall conjugation of a boron-nitrogen-based compound greater in the boron-nitrogen-based compound, performances of materials adopting the boron-nitrogen-based compound can be improved, which improves light-emitting efficiency of the light-emitting element and prolongs life of the light-emitting element.

### DESCRIPTION OF DRAWINGS

In order to illustrate technical solutions in embodiments of the present application more clearly, the following briefly introduces drawings needed to be used in description of the embodiments. Obviously, the drawings in the following description are only some embodiments of the present application. For those skilled in the art, other drawings can be obtained from these drawings without paying creative effort.

FIG. 1 is a first schematic structural diagram of a light-emitting element provided by an embodiment of the present application.

FIG. 2 is a second schematic structural diagram of the light-emitting element provided by the embodiment of the present application.

FIG. 3 is a nuclear magnetic resonance hydrogen spectrum diagram of an organic compound M13 provided by an embodiment of the present application.

### DETAILED DESCRIPTION

Technical solutions in the present application will be illustrated clearly and completely below in combination drawings in the embodiments of the present application. Obviously, the described embodiments are only a part of the embodiments of the present application, not all of them. Based on the embodiments in the present application, all other embodiments obtained by those skilled in the art without pay creative effort belong to a scope of the present application. In addition, it should be understood that specific embodiments described herein are only used to explain the present application, not to define the present application. In the present application, location terms described, such as “up” and “down”, generally refer to up and down in actual use or working state of devices, in particular drawing directions in the drawings, unless otherwise described. Terms “inside” and “outside” refer to outlines of the devices. In the present application, “optional” and “optionally” refer to that either of two parallel schemes is “yes” or “no”. Each “optional” is independent, if there are multiple “optional” in a technical scheme, and there is no special description, contradiction, or mutual restriction. In the present application, technical features described in open forms include both closed technical solutions composed of listed features and open technical solutions containing listed features.

In the present application, an aromatic group and an aromatic ring system have a same meaning and may be interchanged.

In the present application, a heteroaromatic group and a heteroaromatic ring system have a same meaning and may be interchanged.

In the present application, “substituted” means that one or more hydrogen atoms in one substituted group are substituted by a substituent group.

In the present application, a same substituent group at different substituent site may be independently selected from different groups. If a formula includes a plurality of R, each R can be independently selected from different groups.

In the present application, “substituted or unsubstituted” means that a defined group may be substituted or not be substituted. When the defined group is substituted, it should be understood that the defined group may be substituted by at least one substituent R. The substituent R is selected from, but not limited thereto: -D, a cyano group, an isocyano group, a nitro group, a halogen group, a C₁-C₂₀ alkyl group, a heterocyclic group containing 3-20 ring atoms, an aromatic group containing 6-20 ring atoms, a heteroaromatic group containing 5-20 ring atoms, —NR′R″, a silane group, a carbonyl group, an alkoxycarbonyl group, an aryloxycarbonyl group, a carbamoyl group, a haloformyl group, a formyl group, an isocyanate group, a thiocyanate group, an isothiocyanate group, a hydroxyl group, and a trifluoromethyl group. The above-mentioned groups may further be substituted by acceptable substituent groups in the art. Understandably, R′ and R″ in the —NR′R″ are both independently selected from, but not limited thereto: —H, -D, a cyanogen group, an isocyano group, a nitro group, a halogen group, a C₁-C₁₀ alkyl group, a heterocyclic group containing 3-20 ring atoms, an aromatic group containing 6-20 ring atoms, and a heteroaromatic group containing 5-20 ring atoms. In some embodiments, the R is selected from, but not limited thereto: -D, a cyano group, an isocyano group, a nitro group, a halogen group, a C₁-C₁₀ alkyl group, a heterocyclic group containing 3-10 ring atoms, an aromatic group containing 6-20 ring atoms, a heteroaromatic group containing 5-20 ring atoms, a silane group, a carbonyl group, an alkoxycarbonyl group, an aryloxycarbonyl group, a carbamoyl group, a haloformyl group, a formyl group, an isocyanate group, a thiocyanate group, an isothiocyanate group, a hydroxyl group, and a trifluoromethyl group, and the above-mentioned groups may further be substituted by acceptable substituent groups in the art.

In the present application, “a ring atom number” refers to a number of atoms constituting a ring of structural compounds (such as a monocyclic compound, a fused ring compound, a cross-linked compound, a carbon ring compound, and a heterocyclic compound) obtained by atomic bonding. In a ring substituted by a substituent group, atoms contained in the substituent group is not included in the atoms forming the ring. The same applies to the “number of ring atoms” described below unless otherwise specified. For example, a ring atom number of a benzene ring is 6, a ring atom number of a naphthalene ring is 10, and a ring atom number of a thiophene group is 5.

In the present application, “an aryl group or an aromatic group” refers to an aromatic hydrocarbon group derived from a basis of an aromatic ring compound removing an H. The aromatic ring compound may be a single ring aromatic group, a fused ring aromatic group, or a polycyclic aromatic group. For a polycyclic ring type, at least one ring is an aromatic ring system. For example, in some embodiments, “a substituted or unsubstituted aryl group containing 6 to 40 ring atoms” refers to an aryl group containing 6 to 40 ring atoms. In some embodiments, “the substituted or unsubstituted aryl group containing 6 to 30 ring atoms” refers to a substituted or unsubstituted aryl group containing 6 to 30 ring atoms. In some embodiments, “the substituted or unsubstituted aryl group containing 6 to 18 ring atoms” refers to a substituted or unsubstituted aryl group containing 6 to 18 ring atoms. In some embodiments, “the substituted or unsubstituted aryl group containing 6 to 14 ring atoms” refers to a substituted or unsubstituted aryl group containing 6 to 14 ring atoms, and the aryl group is optionally further substituted. Suitable examples include, but are not limited thereto: a phenyl group, a biphenyl group, a triphenyl group, a naphthyl group, an anthracyl group, a phenanthryl group, a fluoranthenyl group, a triphenylene group, a pyrenyl group, a perylene group, a tetraphenyl group, a fluorenyl group, a diphenyl group, an acenaphthenyl group, and derivatives of these groups. Understandably, multiple aryl groups may further be disconnected by short non-aromatic units (for example, a non hydrogenium atoms contenting less than 10%, such as C, N, or O). In detail, an acenaphthene group, a fluorene group, a 9,9-diarylfluorene group, a triarylamine group, and a diaryl ether system should be further included in a definition of the aryl groups.

In the present application, “a heteroaryl group or a heteroaromatic group” refers a basis of an aryl group with at least one carbon atom substituted by a non-carbon atom, and the non-carbon atom may be N, O, S, etc. For example, in some embodiments, “a substituted or unsubstituted heteroaryl group containing 5 to 40 ring atoms” refers to a heteroaryl group containing 5 to 40 ring atoms. In some embodiments, “the substituted or unsubstituted heteroaryl group containing 5 to 30 ring atoms” refers to a substituted or unsubstituted heteroaryl group containing 5 to 30 ring atoms. In some embodiments, “the substituted or unsubstituted heteroaryl group containing 5 to 18 ring atoms” refers to a substituted or unsubstituted heteroaryl group containing 5 to 18 ring atoms. In some embodiments, “the substituted or unsubstituted heteroaryl group containing 5 to 14 ring atoms” refers to a substituted or unsubstituted heteroaryl group containing 5 to 14 ring atoms, and the heteroaryl group are optionally further substituted. Suitable examples include but are not limited thereto: a thiophene group, a furan group, a pyrrolyl group, a diazo group, a triazole group, an imidazolyl group, a pyridinyl group, a bipyridyl group, a pyrimidinyl group, a triazinyl group, an acridine group, a pyridazinyl group, a pyrazinyl group, a quinolinyl group, an isoquinolinyl group, a quinazolinyl group, a quinoxalinyl group, a phthalazinyl group, a pyridino pyrimidinyl group, a pyridino pyrazinyl group, a benzo thienyl group, a benzofuranyl group, an indolyl group, a pyrrolo imidazolyl group, a pyrrolo pyrrolyl group, a thiophenopyrrolyl group, a thiophenothiophenyl group, a furanopyrrolyl group, a furanofuranyl group, a thiophenofuranyl group, a benzoisoxazolyl group, a benzoisothiazolyl group, a benzimidazolyl group, an o-diaznaphthyl group, a phenanthryl group, a pyridinyl group, a quinazolinketone group, a dibenzothiophenyl group, a dibenzofuranyl group, a carbazolyl group, and derivatives of these groups.

In the present application, “an alkyl group” may mean a linear alkyl group, a branched alkyl group, and/or a cyclic alkyl group. A number of carbon atoms in the alkyl group may ranges from 1 to 50, 1 to 30, 1 to 20, 1 to 10, or, 1 to 6. A phrase containing the above-mentioned terms, for example, “a C₁-C₉ alkyl group” refers to an alkyl group containing 1 to 9 carbon atoms. The C₁-C₉ alkyl group may be a C₁ alkyl group, a C₂ alkyl group, a C₃ alkyl group, a C₄ alkyl group, a C₅ alkyl group, a C₆ alkyl group, a C₇ alkyl group, a C₈ alkyl group, or a C₉ alkyl group. Non limited examples of the alkyl group include a methyl group, an ethyl group, a n-propyl group, an isopropyl group, a n-butyl group, a sec butyl group, a tert butyl group, an isobutyl group, a 2-ethylbutyl group, a 3,3-dimethylbutyl group, a n-amyl group, an isopentyl group, a neopentyl group, a tert amyl group, a cyclopentyl group, a 1-methylamyl group, a 3-methylamyl group, a 2-ethylamyl group, a 4-methyl-2-amyl group, a n-hexyl group, a 1-methylhexyl group, a 2-ethylhexyl group, a 2-butylhexyl group, a cyclohexyl group, a 4-m ethylcyclohexyl 4-tert-butylcyclohexyl group, a n-heptyl group, a 1-methylheptyl group, a 2,2-dimethylheptyl group, a 2-ethylheptyl group, a 2-butyl-heptyl group, a n-octyl group, a t-octyl group, a 2-ethyloctyl group, a 2-butyl-octyl group, a 2-hexyloctyl group, a 3,7-dimethyloctyl group, a cyclooctyl group, a n-nonyl group, a n-decyl group, an adamantane group, a 2-ethyldecyl group, a 2-butyl-decyl group, a 2-hexyldecyl group, a 2-octyldecyl group, a n-undecyl group, a n-dodecyl group, a 2-ethyldodecyl 2-butyl dodecyl group, a 2-hexyl dodecyl group, a 2-octyl dodecyl group, a n-tridecyl group, a n-tetradecyl group, a n-pentadecyl group, a n-hexadecyl group, a 2-ethyl hexadecyl group, a 2-butyl hexadecyl group, a 2-hexyl hexadecyl group, a 2-octyl hexadecyl group, a n-heptadecyl group, a n-octadecyl group, a n-octadecyl group, a n-eicosyl group, a 2-ethyl eicosyl group, a 2-butyl eicosyl group, a 2-hexyl eicosyl group, a 2-octyl eicosyl group, a n-twenty one alkyl group, a n-twenty two alkyl group, a n-twenty three alkyl group, a n-twenty four alkyl group, a n-twenty five alkyl group, a n-twenty six alkyl group, a n-twenty seven alkyl group, a n-twenty eight alkyl group, a n-twenty nine alkyl group, or a n-thirty alkyl group.

In the present application, substituent groups and corresponding abbreviations are as following: n corresponds to a normal carbon, sec corresponds to a secondary carbon, i corresponds to an iso carbon, t corresponds to a tertiary carbon, o corresponds to an ortho-position, m corresponds to a meta-position, p corresponds to a para-position, Me corresponds to a methyl group, Et corresponds to an ethyl group, Pr corresponds to a propyl group, Bu corresponds to a butyl group, Am corresponds to a n-amyl group, Hx corresponds to a hexyl group, and Cy corresponds to a cyclohexyl group.

In the present application, “an amino group” refers to a derivative of an amine, has a feature of a group represented by formula —N(X)₂. Each “X” is independently selected from —H, a substituted or unsubstituted alkyl group, a substituted or unsubstituted cycloalkyl group, and a substituted or unsubstituted heterocyclic group, etc. Non-limited types of the amino group include —NH₂, —N(an alkyl group)₂, —NH(an alkyl group), —N(a cycloalkyl group)₂, —NH(a cycloalkyl group), —N(a heterocyclyl group)₂, —NH(a heterocyclyl group), —N(an aryl group)₂, —NH(an aryl group), —N(an alkyl group) (an aryl group), —N(an alkyl group)(a heterocyclyl group), —N(a cycloalkyl group)(a heterocyclyl group), —N(an aryl group)(a heteroaryl group), and —N(an alkyl group)(a heteroaryl group), etc.

In the present application, if not specifically defined, a hydroxyl group refers to —OH, a carboxyl group refers to —COOH, a carbonyl group refers to —C(═O)—, an amino group refers to —NH₂, a formyl group refers to —C(═O)H, a haloformyl group refers to —C(═O)Z (the Z represents a halogen group), a carbamoyl group refers to —C(═O)NH₂, an isocyanate group refers to —NCO, and an isothiocyanate group refers to —NC S.

In the present application, terms “an alkoxy group” refers to a group containing “—O-an alkyl group”, that is, the alkyl group as defined above is connected to other groups via an oxygen atom. Suitable examples include, but are not limited thereto, a methoxy group (—O—CH₃ or —OMe), an ethoxy group (—O—CH₂CH₃ or -OEt), and a tert butoxy group (—O—C(CH₃)₃ or -OtBu).

In the present application, the “*” connected to a single bond indicates a binding site or a fused site.

In the present application, when a binding site of a group is not specified, it means that any of connectable sites in the group may be selected as the binding site.

In the present application, when a fused site of a group is not specified, it means that any of fusible sites in the group may be selected as the fused site. In some embodiments, two or more sites located at ortho-positions of the group may be selected as fused sites.

In the present application, when a same group contains a plurality of substituent groups having a same symbol, the substituent groups may be the same or be different, such as

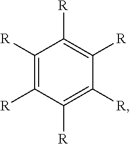

six R groups of a benzene ring may be the same or different.

In the present application, a single bond connected to a substituent group and penetrated a corresponding ring indicates that the substituent group may be connected to any site of the ring. For example,

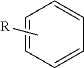

means that R is connected to any substituent site of the benzene ring; and

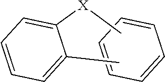

means that

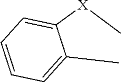

may be connected to any substituent site of

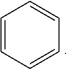

In the present application, “adjacent groups” means that there is no substitutable site between two substituent groups.

In the present application, “a ring is formed between two adjacent R₁, R₃, or R₅” represents a ring system formed by an interconnection of two adjacent R₁, R₃, or R₅. The ring system may be selected from an aliphatic hydrocarbon ring, an aliphatic heterocycle, an aromatic hydrocarbon ring, and an aromatic heterocycle. In some embodiments, the ring system may be

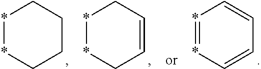

At present, due to limited improvements of efficiency and life of traditional TADF organic compounds, it is difficult to improve light-emitting efficiency and life of organic electroluminescent elements.

An organic compound is provided in an embodiment of the present application, the organic compound is represented by Formula (1):

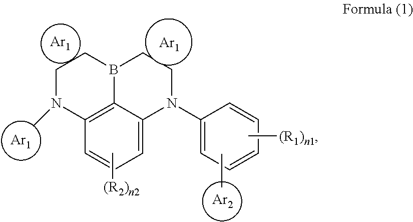

each of Ar₁ groups is independently selected from structures represented by formula (A-1) to formula (A-5):

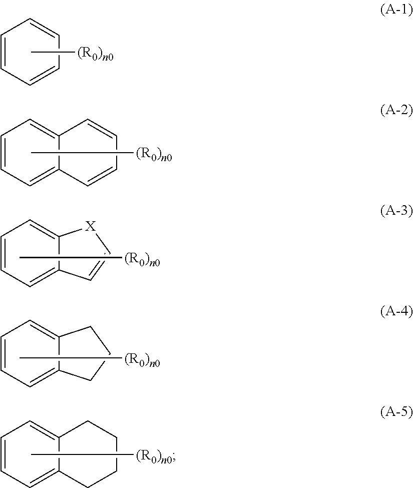

Ar₂ is selected from —H and structures represented by formula (B-1) to formula (B-4):

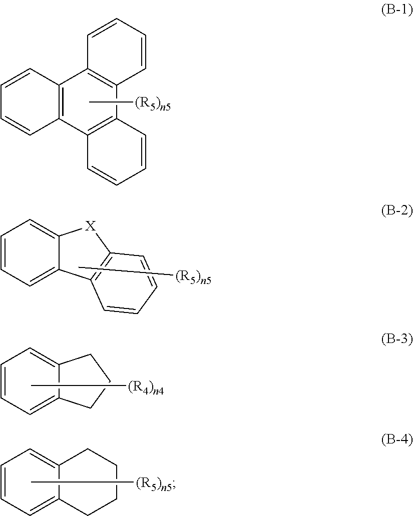

X is independently selected from O, S, N—CH₃, N-Ph, and C(CH₃)₂;
each of R₀, R₁, R₂, and R₅ is independently selected from —H, -D, a C₁-C₂₀ linear alkyl group, a C₁-C₂₀ linear alkoxy group, a C₁-C₂₀ linear thioalkoxy group, a C₃-C₂₀ branched alkyl group, a C₃-C₂₀ cyclic alkyl group, a C₃-C₂₀ branched alkoxy group, a C₃-C₂₀ branched thioalkoxy group, a C₃-C₂₀ cyclic thioalkoxy group, a silyl group, a C₁-C₂₀ ketone group, a C₂-C₂₀ alkoxycarbonyl group, a C₇-C₂₀ aryloxycarbonyl group, a C₁-C₂₀ alkenyl group, —CN, a carbamoyl group, a haloformyl group, a formyl group, an isocyano group, an isocyanate group, a thiocyanate group, an isothiocyanate ester group, a hydroxy group, a nitro group, —CF₃, —Cl, —Br, —F, a substituted or unsubstituted aromatic group containing 6 to 30 ring atoms, a substituted or unsubstituted heteroaromatic group containing 5 to 30 ring atoms, a substituted or unsubstituted aryloxy group containing 6 to 30 ring atoms, and a substituted or unsubstituted heteroaromatic oxygen group containing 5 to 30 ring atoms;
each of n₀, n₁, n₂, and n₅ is independently selected from 0 to 11; and
when n₀ is greater than or equal to 2, a ring is formed or no ring is formed between two adjacent R₀ groups; when n₁ is greater than or equal to 2, a ring is formed or no ring is formed between two adjacent R₁ groups; when n₂ is greater than or equal to 2, a ring is formed or no ring is formed between two adjacent R₂ groups; and when n₅ is greater than or equal to 2, a ring is formed or no ring is formed between two adjacent R₅ groups.

In the present application, by introducing groups that makes an overall conjugation of a boron-nitrogen-based compound greater in the boron-nitrogen-based compound, performances of materials adopting the boron-nitrogen-based compound can be improved, which improves light-emitting efficiency of the light-emitting element and prolongs life of the light-emitting element.

In some embodiments, the organic compound is represented by any one of formula (2-1) to formula (2-18):

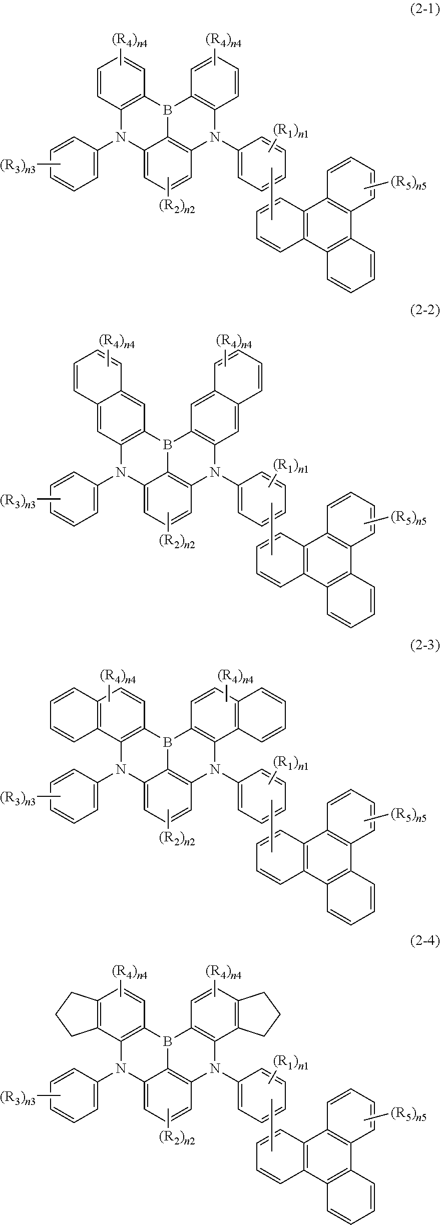

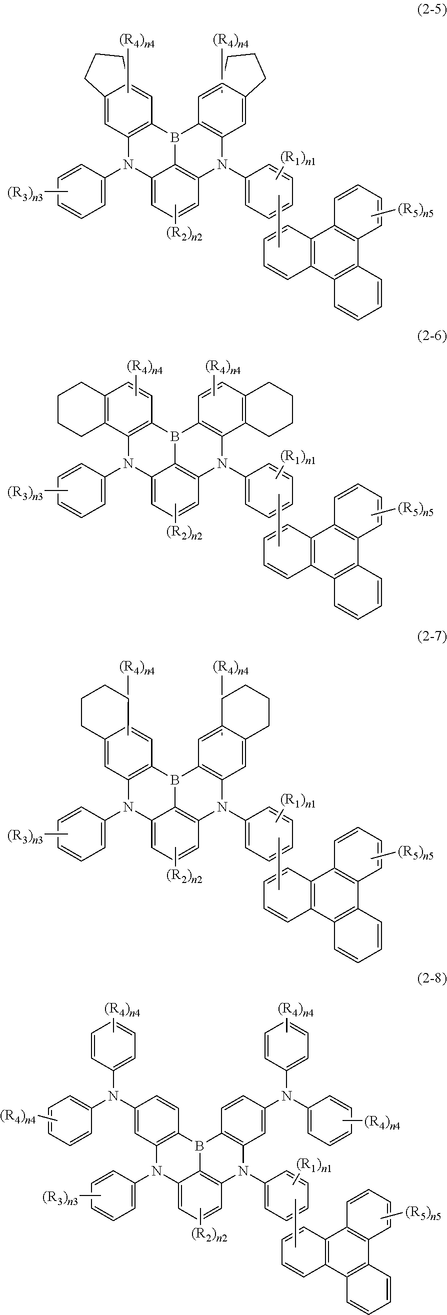

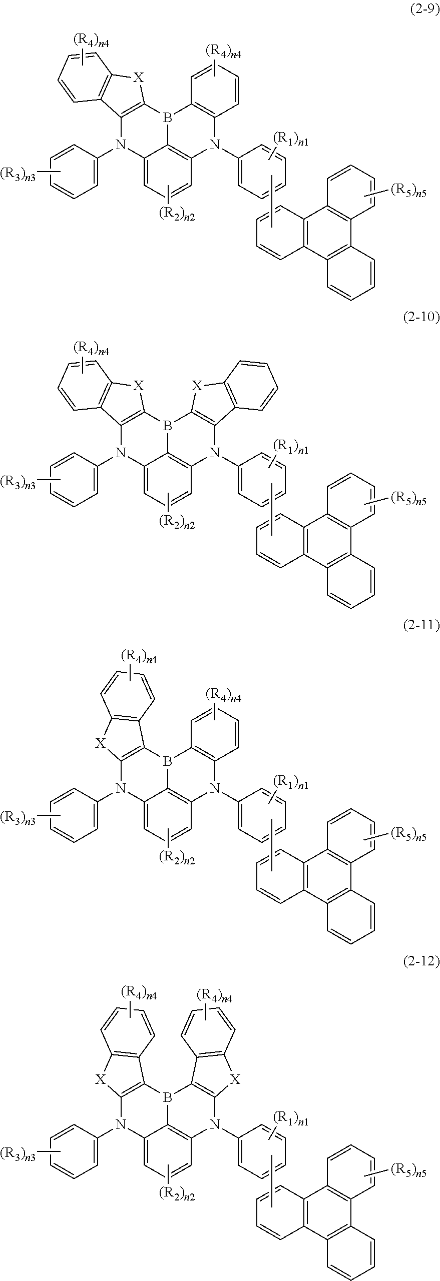

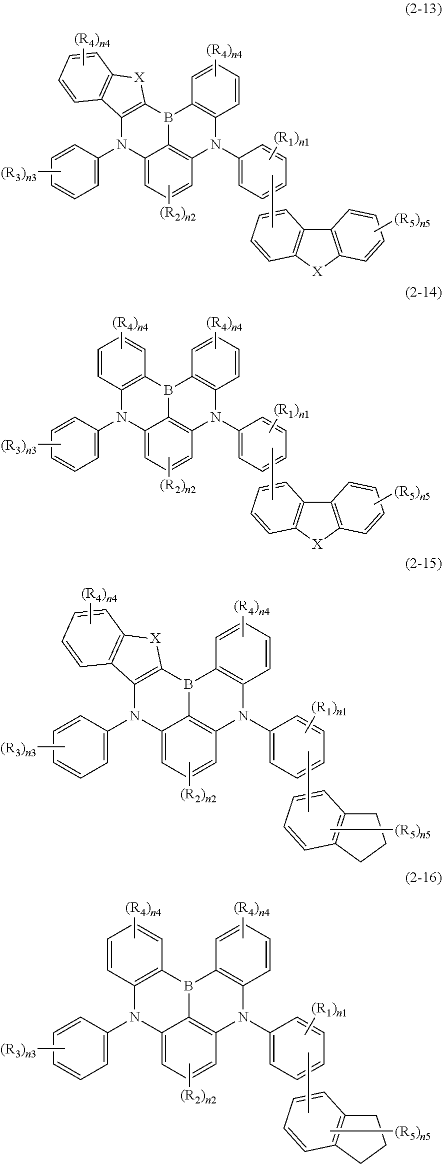

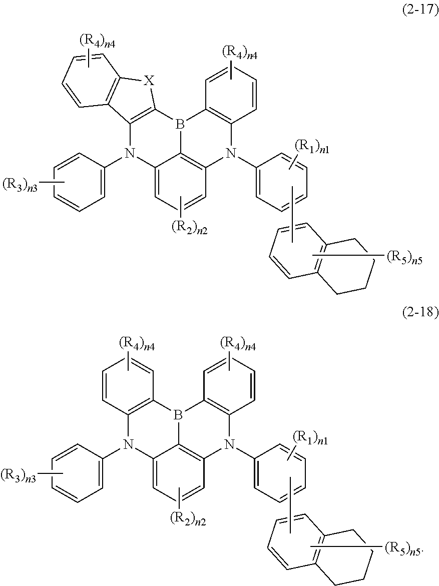

each of R₃ and R₄ is independently selected from —H, -D, a C₁-C₂₀ linear alkyl group, a C₁-C₂₀ linear alkoxy group, a C₁-C₂₀ linear thioalkoxy group, a C₃-C₂₀ branched alkyl group, a C₃-C₂₀ cyclic alkyl group, a C₃-C₂₀ branched alkoxy group, a C₃-C₂₀ branched thioalkoxy group, a C₃-C₂₀ cyclic thioalkoxy group, a silyl group, a C₁-C₂₀ ketone group, a C₂-C₂₀ alkoxycarbonyl group, a C₇-C₂₀ aryloxycarbonyl group, a C₁-C₂₀ alkenyl group, —CN, a carbamoyl group, a haloformyl group, a formyl group, an isocyano group, an isocyanate group, a thiocyanate group, an isothiocyanate ester group, a hydroxy group, a nitro group, —CF₃, —Cl, —Br, —F, a substituted or unsubstituted aromatic group containing 6 to 30 ring atoms, a substituted or unsubstituted heteroaromatic group containing 5 to 30 ring atoms, a substituted or unsubstituted aryloxy group containing 6 to 30 ring atoms, and a substituted or unsubstituted heteroaromatic oxygen group containing 5 to 30 ring atoms;
each of n₃ and n₄ is independently selected from 0 to 11; and
when n₃ is greater than or equal to 2, a ring is formed or no ring is formed between two adjacent R₃ groups; and when n₄ is greater than or equal to 2, a ring is formed or no ring is formed between two adjacent R₄ groups.

In some embodiments, a phenyl group is represented by Ph.

In the above-mentioned embodiment, each of R₁, R₂, R₃, R₄, and R₅ is independently selected from —H, -D, a C₁-C₁₀ linear alkyl group, a C₃-C₁₀ branched alkyl group, and a C₃-C₁₀ cyclic alkyl group.

In some embodiments, each of R₁, R₂, R₃, R₄, and R₅ is independently selected from —H, -D, a C₁-C₄ linear alkyl group and a C₃-C₅ branched alkyl group.

In some embodiments, at least one substituent group of R₁, R₂, R₃, R₄, and R₅ is selected from a C₁-C₄ linear alkyl group and a C₃-C₅ branched alkyl group.

An introduction of the alkyl group into the organic compound is conducive to improving solubility of the organic compound in a process such as ink-jet printing, and improving quality of the light-emitting element adopting the organic compound.

In some embodiments, a ring is formed between two adjacent R₁ groups. In some embodiments, a 6-membered aromatic ring or an aliphatic ring is formed between two adjacent R₁ groups. In some embodiments,

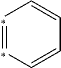 [SMILES: *1:*cccc1]

is formed between two adjacent R₁ groups. Wherein represents a binding site.

In some embodiments, a ring is formed between two adjacent R₂ groups. In some embodiments, a 6-membered aromatic ring or an aliphatic ring is formed between two adjacent R₂ groups. In some embodiments,

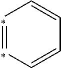 [SMILES: *1:*cccc1]

is formed between two adjacent R₂ groups. Wherein * represents a binding site.

In some embodiments, a ring is formed between two adjacent R₃ groups. In some embodiments, a 6-membered aromatic ring or an aliphatic ring is formed between two adjacent R₃ groups. In some embodiments,

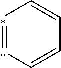 [SMILES: *1:*cccc1]

is formed between two adjacent R₃ groups. Wherein represents a binding site.

In some embodiments, a ring is formed between two adjacent R₄ groups. In some embodiments, a 6-membered aromatic ring or an aliphatic ring is formed between two adjacent R₄ groups. In some embodiments,

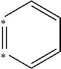 [SMILES: *1:*cccc1]

is formed between two adjacent R₄ groups. Wherein * represents a binding site.

In some embodiments, a ring is formed between two adjacent R₅ groups. In some embodiments, a 6-membered aromatic ring or an aliphatic ring is formed between two adjacent R₅ groups. In some embodiments,

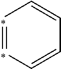 [SMILES: *1:*cccc1]

is formed between two adjacent R₅ groups. Wherein * represents a binding site.

In some embodiments, when Ar₁ is represented by formula (A-3), Ar₁ may be represented by

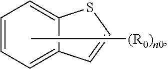

which is conducive to improving the light-emitting efficiency and the life of the light-emitting element adopting the above-mentioned organic compound.

In some embodiments, when Ar₂ is represented by formula (B-3), Ar₂ may be represented by formulas selected from

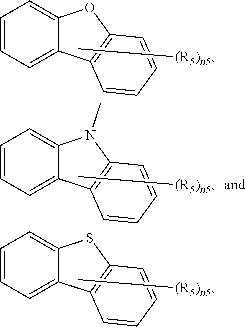

which is conducive to improving the light-emitting efficiency and the life of the light-emitting element adopting the above-mentioned organic compound.

In some embodiments, the organic compound is a blue light-emitting material.

In some embodiments, the organic compound is selected from compounds as following:

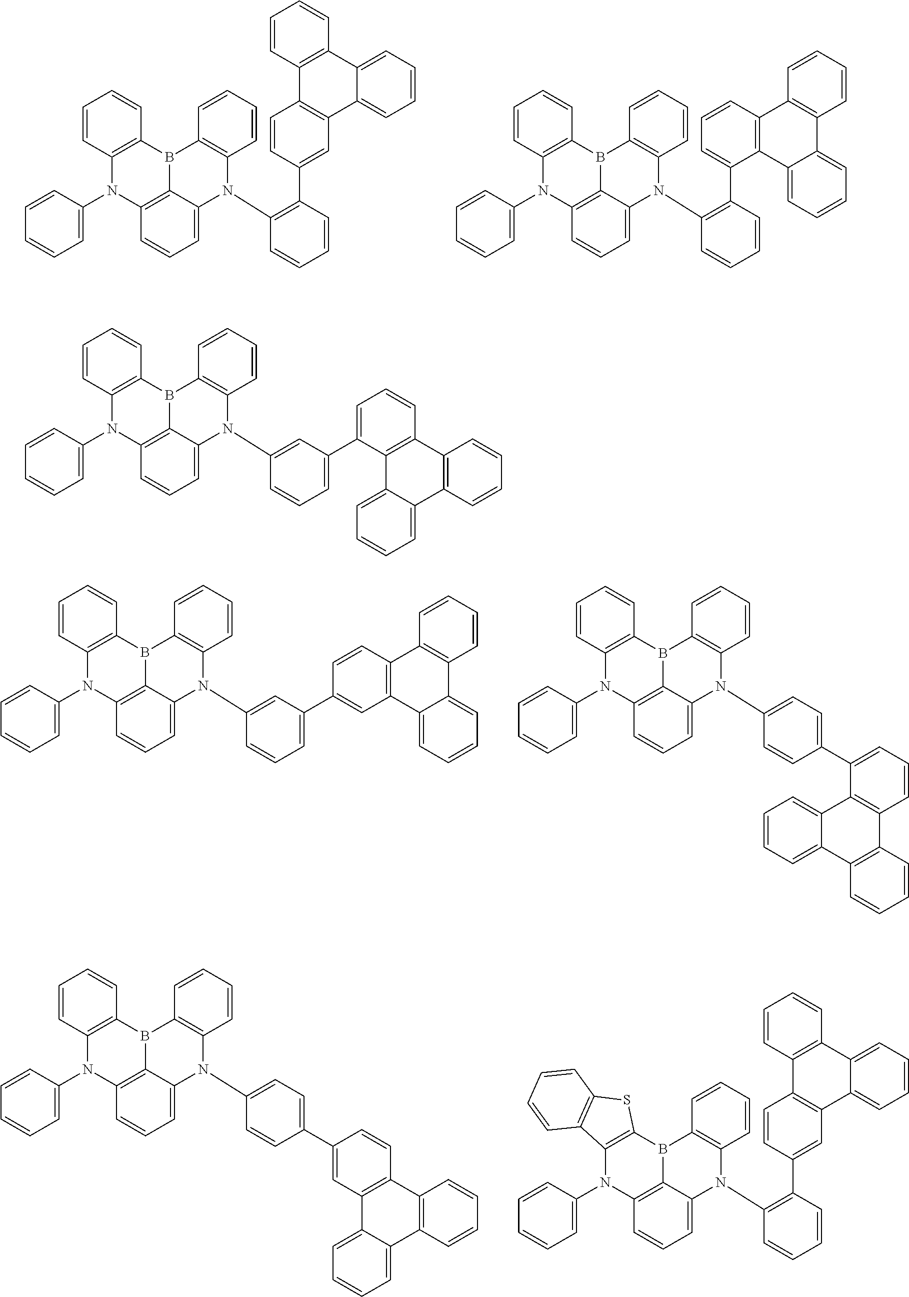

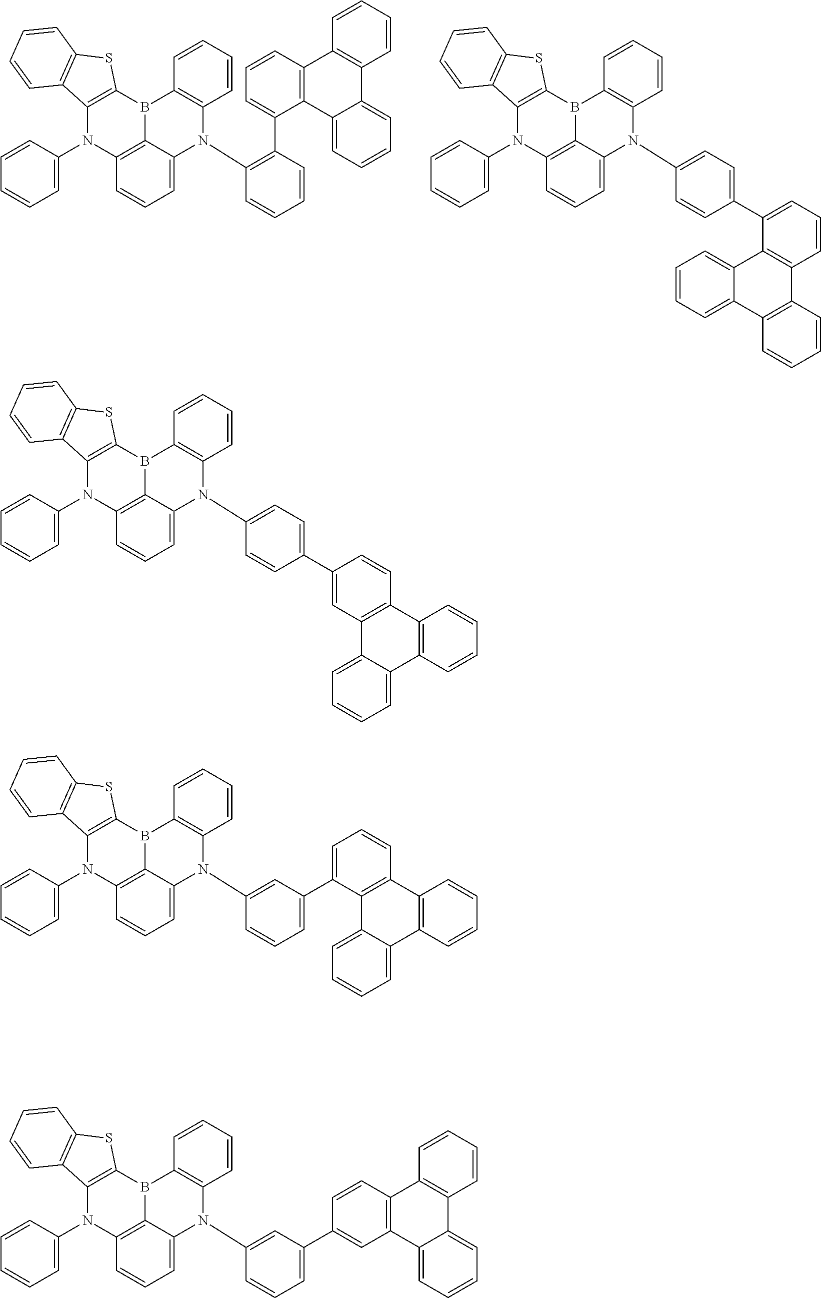

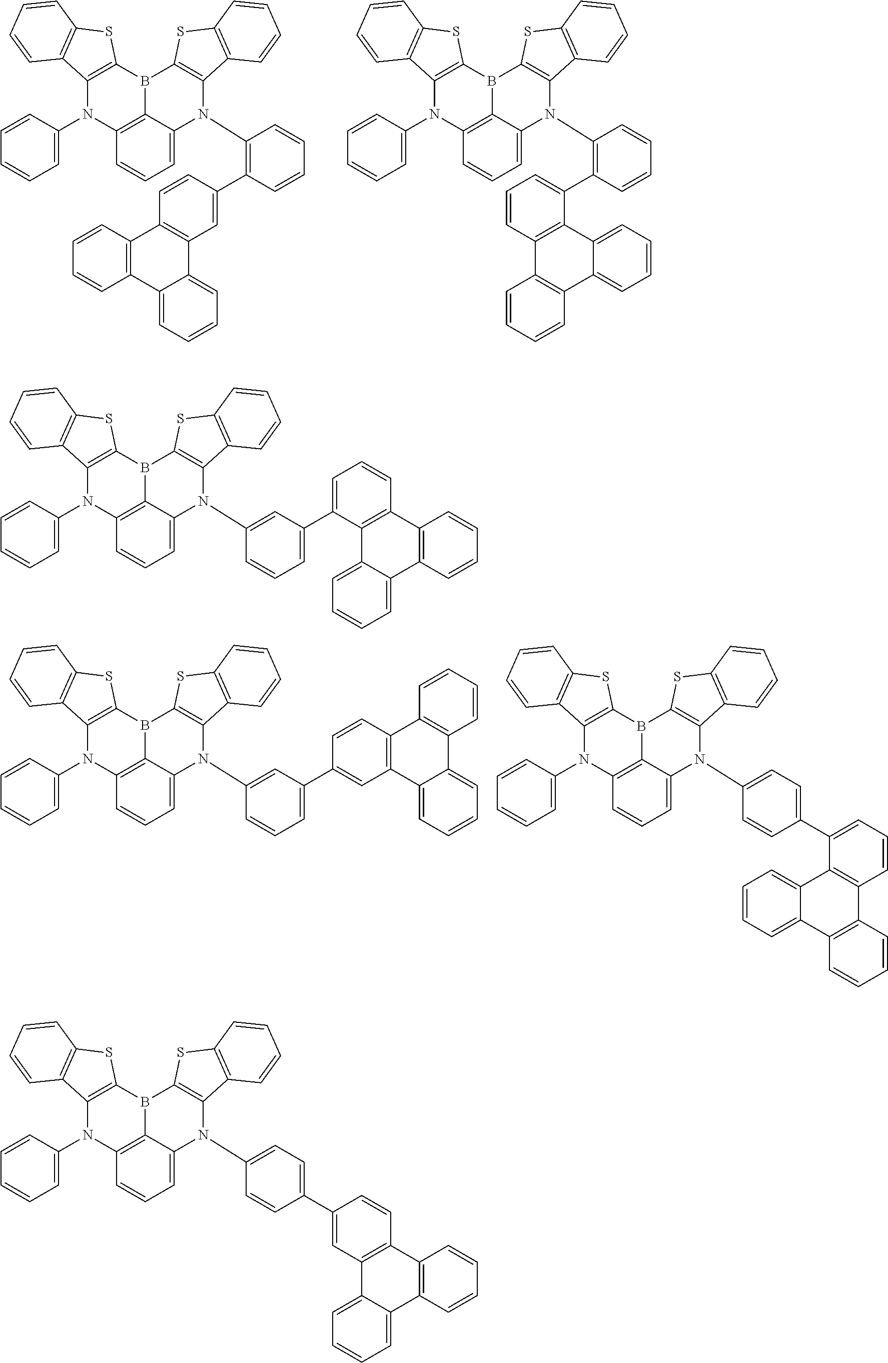

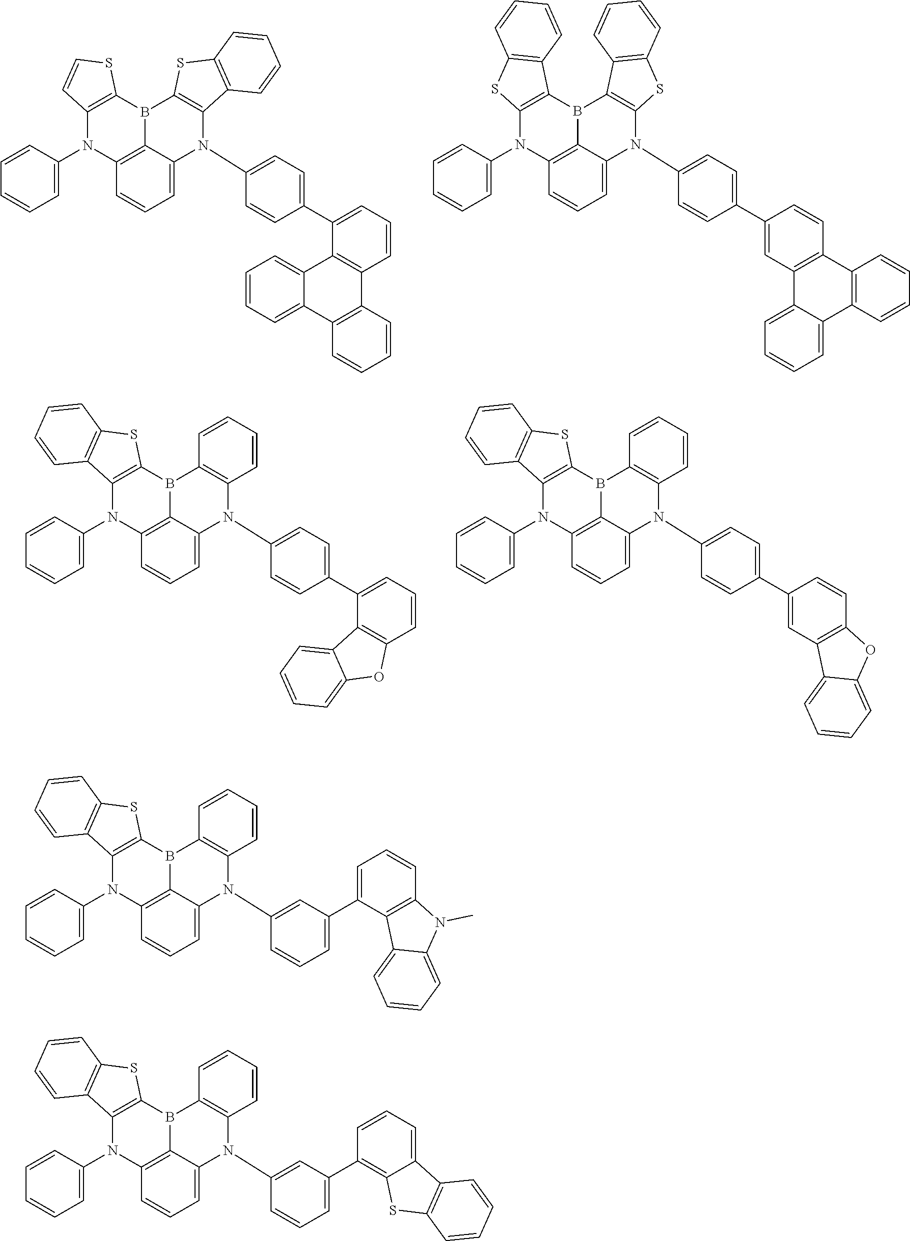

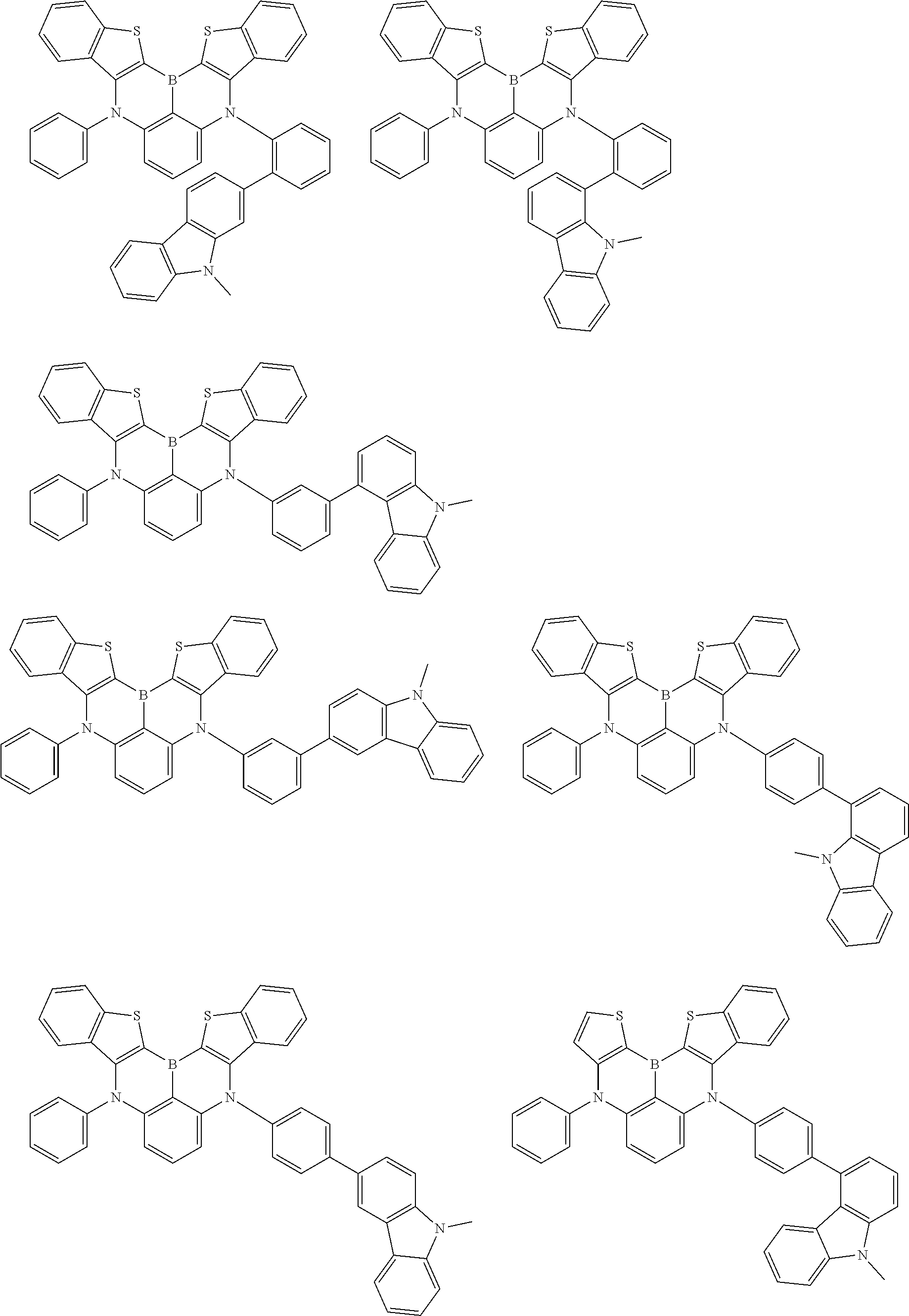

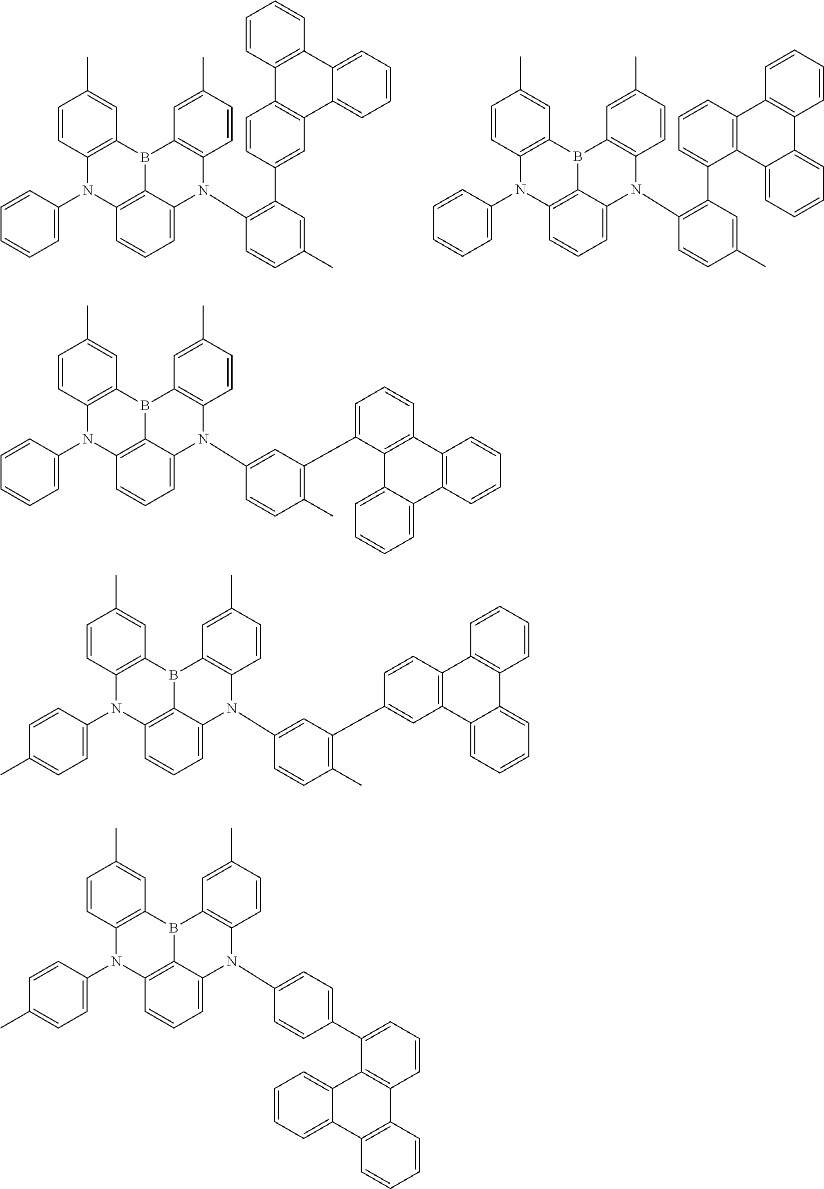 [SMILES: Cc1ccc2c(c1)B1c3cc(C)ccc3N(c3ccc(C)cc3-c3ccc4c5ccccc5c5ccccc5c4c3)c3cccc(c31)N2c1ccccc1 ; Cc1ccc2c(c1)B1c3cc(C)ccc3N(c3ccc(C)cc3-c3cccc4c5ccccc5c5ccccc5c34)c3cccc(c31)N2c1ccccc1 ; Cc1ccc2c(c1)B1c3cc(C)ccc3N(c3ccc(C)c(-c4cccc5c6ccccc6c6ccccc6c45)c3)c3cccc(c31)N2c1ccccc1 ; Cc1ccc(N2c3ccc(C)cc3B3c4cc(C)ccc4N(c4ccc(C)c(-c5ccc6c7ccccc7c7ccccc7c6c5)c4)c4cccc2c43)cc1 ; Cc1ccc(N2c3ccc(C)cc3B3c4cc(C)ccc4N(c4ccc(-c5cccc6c7ccccc7c7ccccc7c56)cc4)c4cccc2c43)cc1]

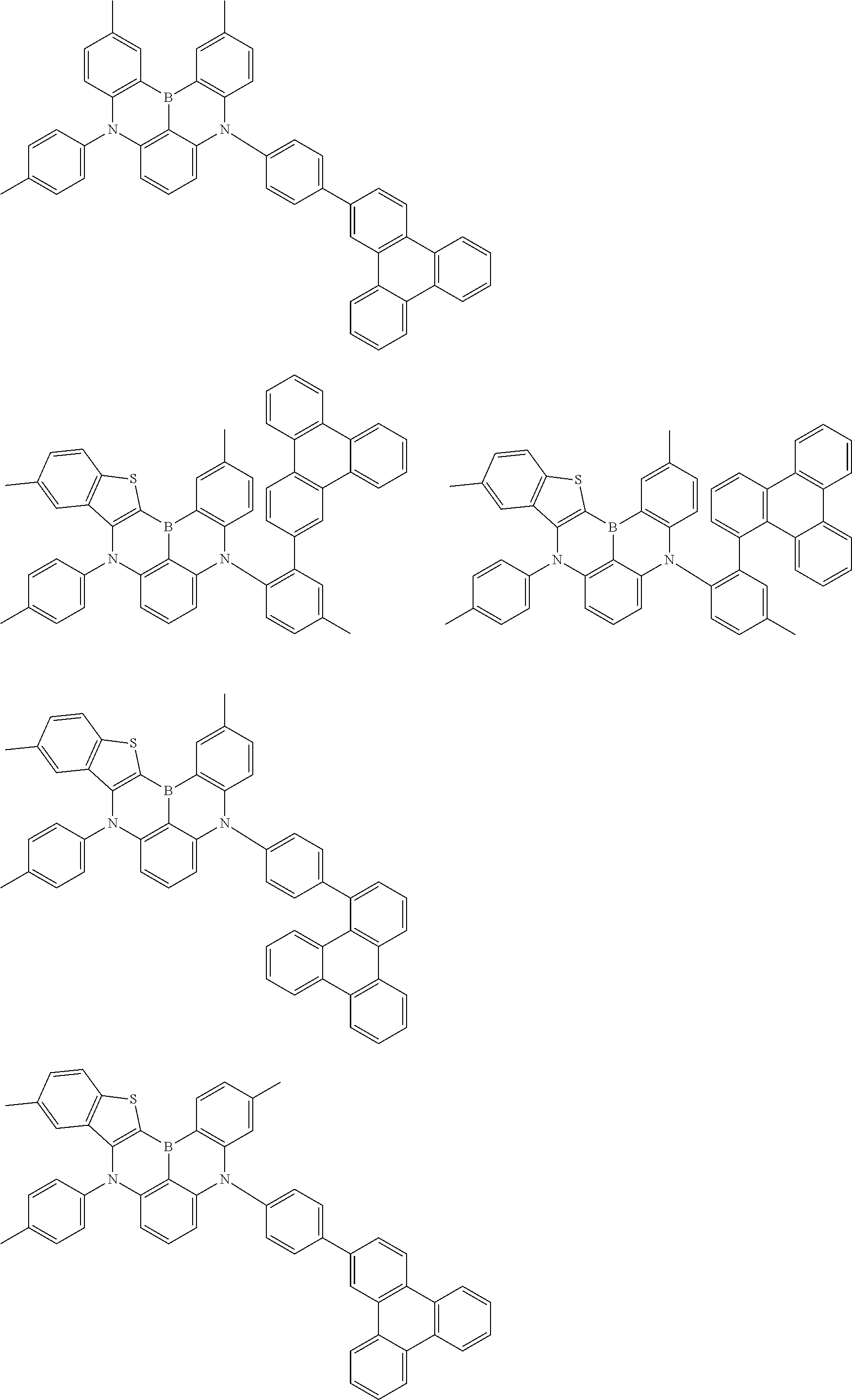 [SMILES: Cc1ccc(N2c3ccc(C)cc3B3c4cc(C)ccc4N(c4ccc(-c5ccc6c7ccccc7c7ccccc7c6c5)cc4)c4cccc2c43)cc1 ; Cc1ccc(N2c3cccc4c3B(c3cc(C)ccc3N4c3ccc(C)cc3-c3ccc4c5ccccc5c5ccccc5c4c3)c3sc4ccc(C)cc4c32)cc1 ; Cc1ccc(N2c3cccc4c3B(c3cc(C)ccc3N4c3ccc(C)cc3-c3cccc4c5ccccc5c5ccccc5c34)c3sc4ccc(C)cc4c32)cc1 ; Cc1ccc(N2c3cccc4c3B(c3cc(C)ccc3N4c3ccc(-c4cccc5c6ccccc6c6ccccc6c45)cc3)c3sc4ccc(C)cc4c32)cc1 ; Cc1ccc(N2c3cccc4c3B(c3ccc(C)cc3N4c3ccc(-c4ccc5c6ccccc6c6ccccc6c5c4)cc3)c3sc4ccc(C)cc4c32)cc1]

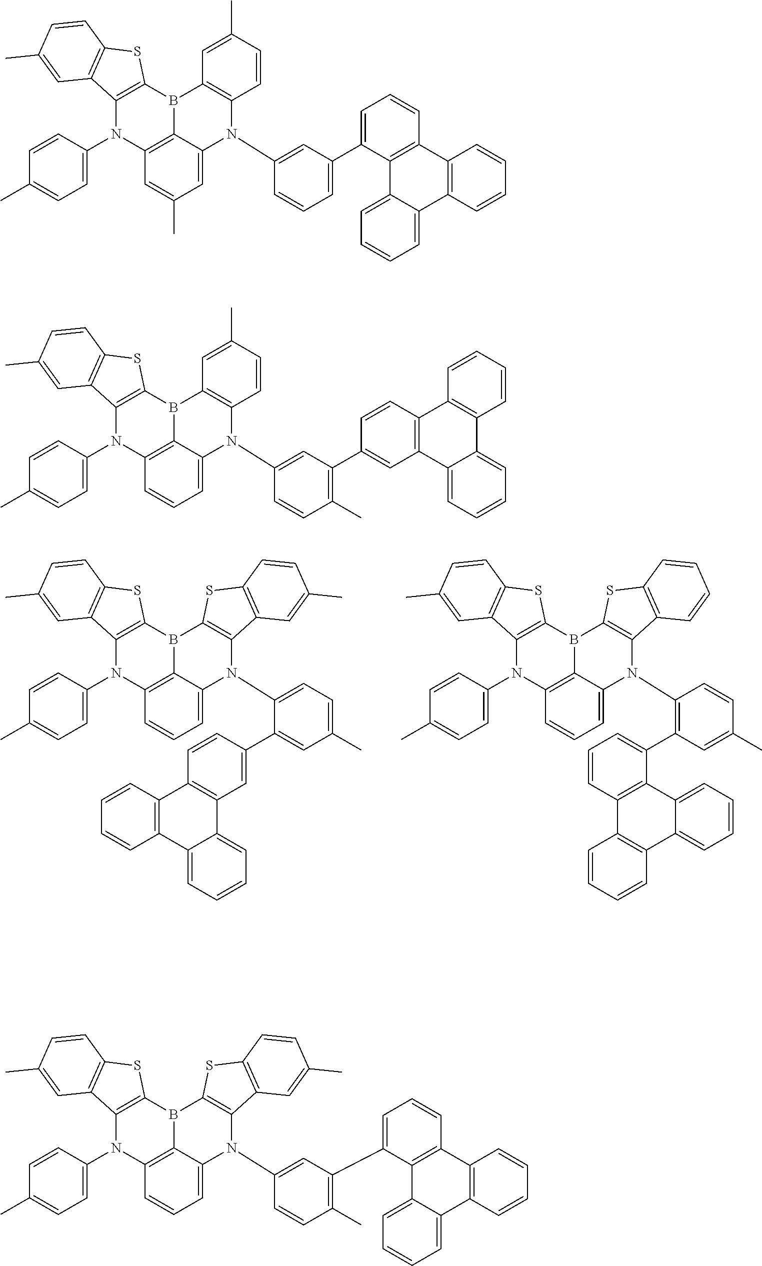

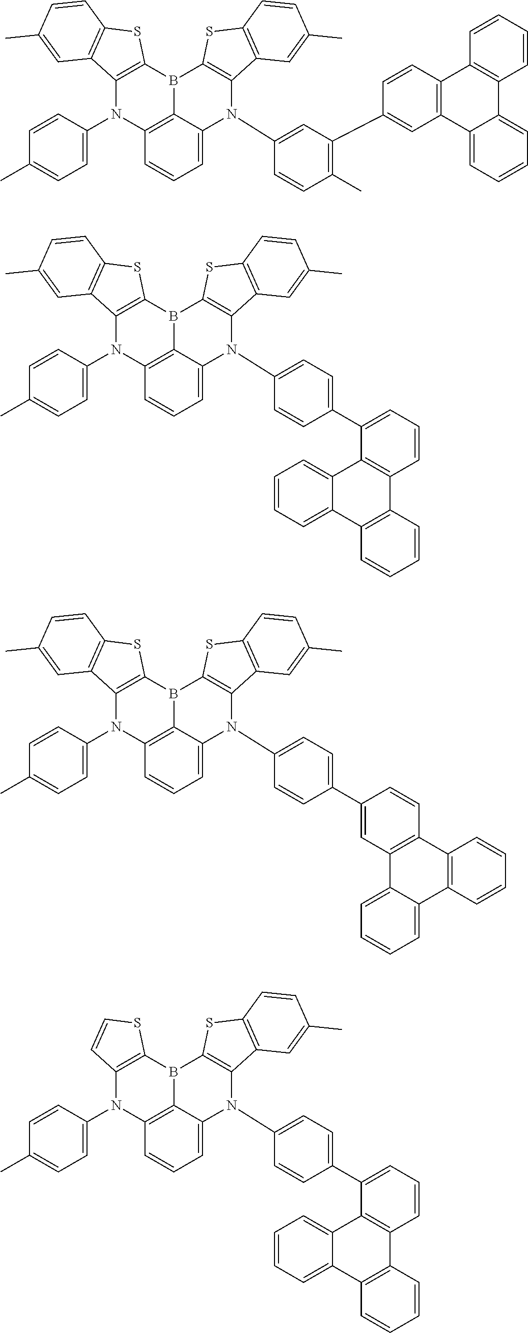 [SMILES: Cc1ccc(N2c3cccc4c3B(c3sc5ccc(C)cc5c32)c2sc3ccc(C)cc3c2N4c2ccc(C)c(-c3ccc4c5ccccc5c5ccccc5c4c3)c2)cc1 ; Cc1ccc(N2c3cccc4c3B(c3sc5ccc(C)cc5c32)c2sc3ccc(C)cc3c2N4c2ccc(-c3cccc4c5ccccc5c5ccccc5c34)cc2)cc1 ; Cc1ccc(N2c3cccc4c3B(c3sc5ccc(C)cc5c32)c2sc3ccc(C)cc3c2N4c2ccc(-c3ccc4c5ccccc5c5ccccc5c4c3)cc2)cc1 ; Cc1ccc(N2c3ccsc3B3c4sc5ccc(C)cc5c4N(c4ccc(-c5cccc6c7ccccc7c7ccccc7c56)cc4)c4cccc2c43)cc1]

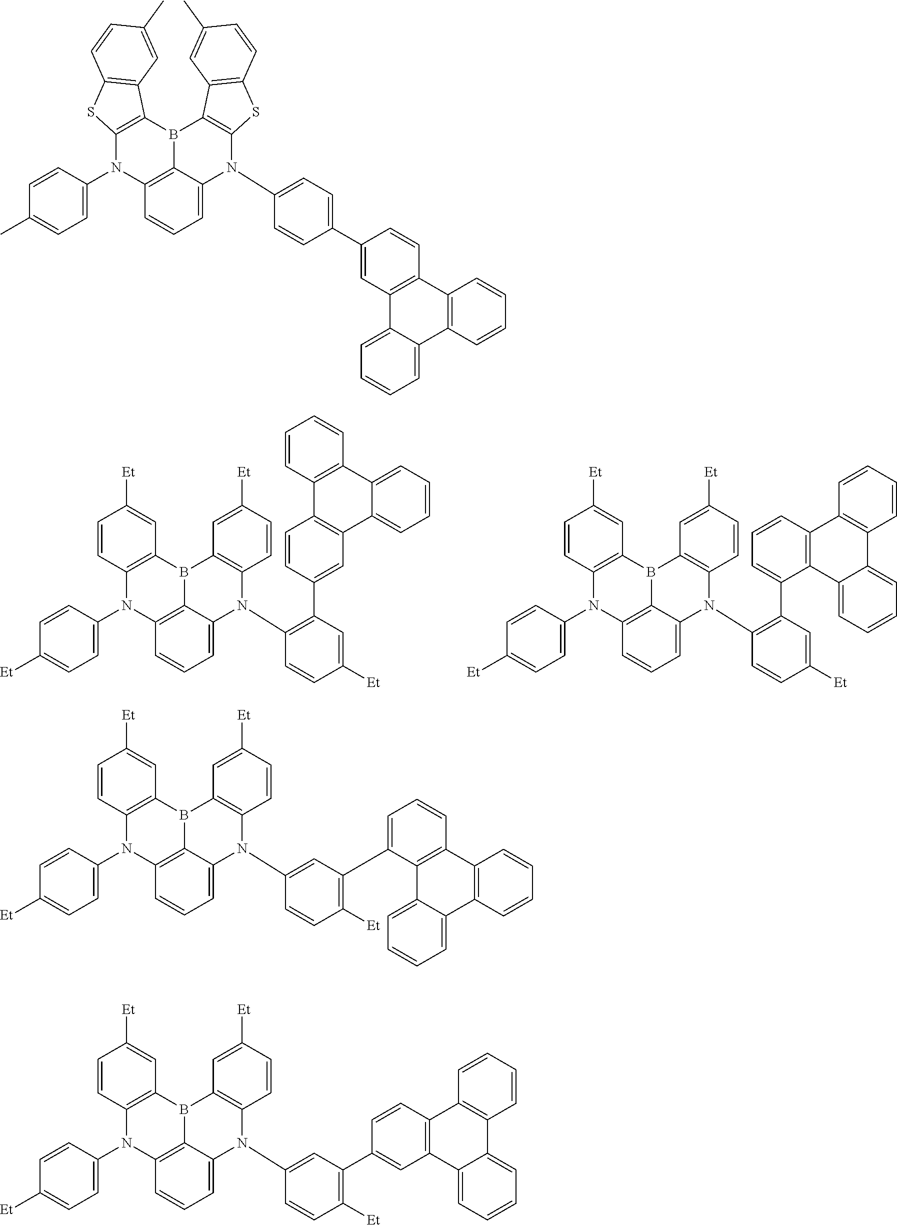 [SMILES: Cc1ccc(N2c3cccc4c3B(c3c2sc2ccc(C)cc32)c2c(sc3ccc(C)cc23)N4c2ccc(-c3ccc4c5ccccc5c5ccccc5c4c3)cc2)cc1 ; CCc1ccc(N2c3ccc(CC)cc3B3c4cc(CC)ccc4N(c4ccc(CC)cc4-c4ccc5c6ccccc6c6ccccc6c5c4)c4cccc2c43)cc1 ; CCc1ccc(N2c3ccc(CC)cc3B3c4cc(CC)ccc4N(c4ccc(CC)cc4-c4cccc5c6ccccc6c6ccccc6c45)c4cccc2c43)cc1 ; CCc1ccc(N2c3ccc(CC)cc3B3c4cc(CC)ccc4N(c4ccc(CC)c(-c5cccc6c7ccccc7c7ccccc7c56)c4)c4cccc2c43)cc1 ; CCc1ccc(N2c3ccc(CC)cc3B3c4cc(CC)ccc4N(c4ccc(CC)c(-c5ccc6c7ccccc7c7ccccc7c6c5)c4)c4cccc2c43)cc1]

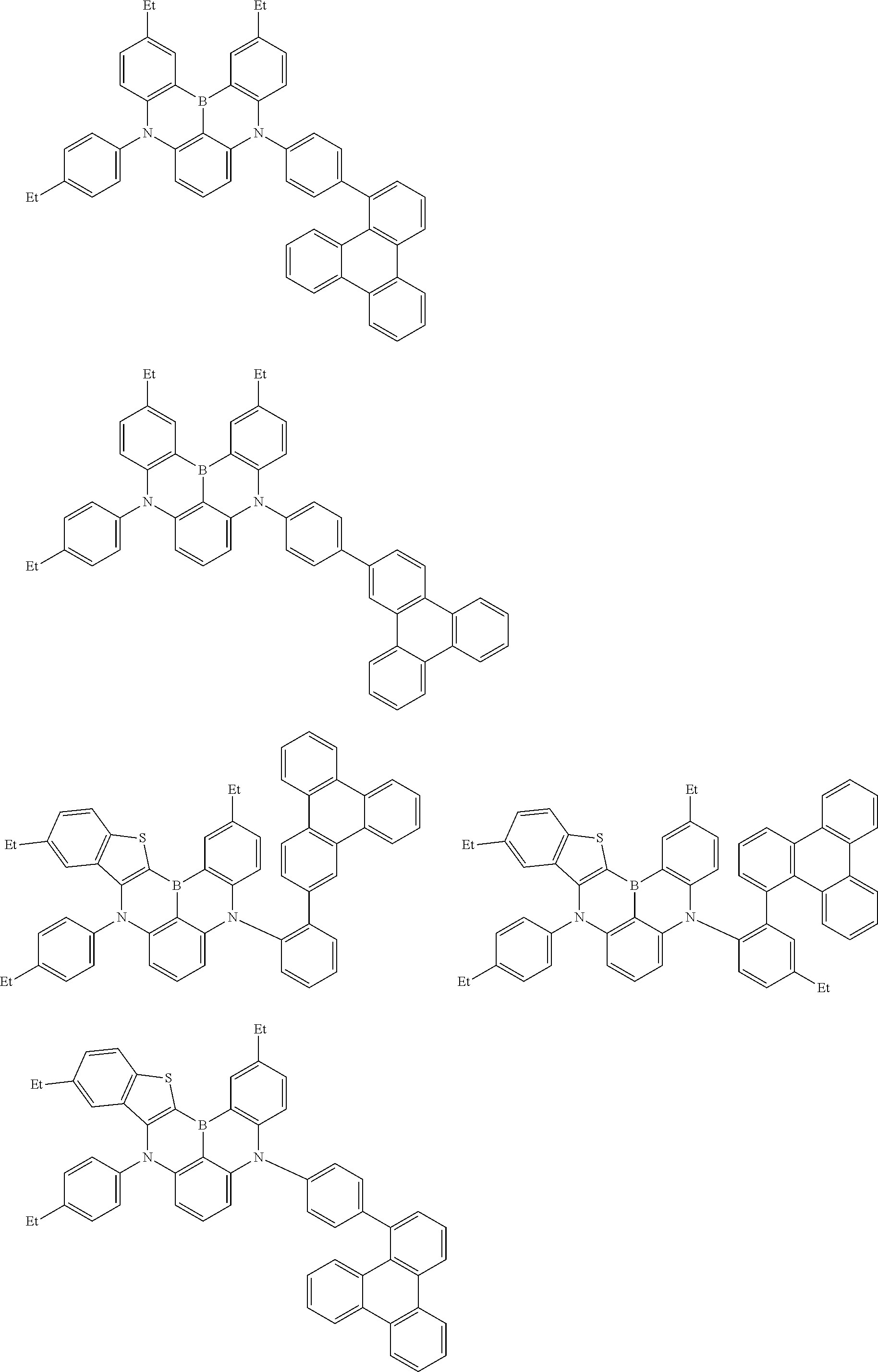 [SMILES: CCc1ccc(N2c3ccc(CC)cc3B3c4cc(CC)ccc4N(c4ccc(-c5cccc6c7ccccc7c7ccccc7c56)cc4)c4cccc2c43)cc1 ; CCc1ccc(N2c3ccc(CC)cc3B3c4cc(CC)ccc4N(c4ccc(-c5ccc6c7ccccc7c7ccccc7c6c5)cc4)c4cccc2c43)cc1 ; CCc1ccc(N2c3cccc4c3B(c3cc(CC)ccc3N4c3ccccc3-c3ccc4c5ccccc5c5ccccc5c4c3)c3sc4ccc(CC)cc4c32)cc1 ; CCc1ccc(N2c3cccc4c3B(c3cc(CC)ccc3N4c3ccc(CC)cc3-c3cccc4c5ccccc5c5ccccc5c34)c3sc4ccc(CC)cc4c32)cc1 ; CCc1ccc(N2c3cccc4c3B(c3cc(CC)ccc3N4c3ccc(-c4cccc5c6ccccc6c6ccccc6c45)cc3)c3sc4ccc(CC)cc4c32)cc1]

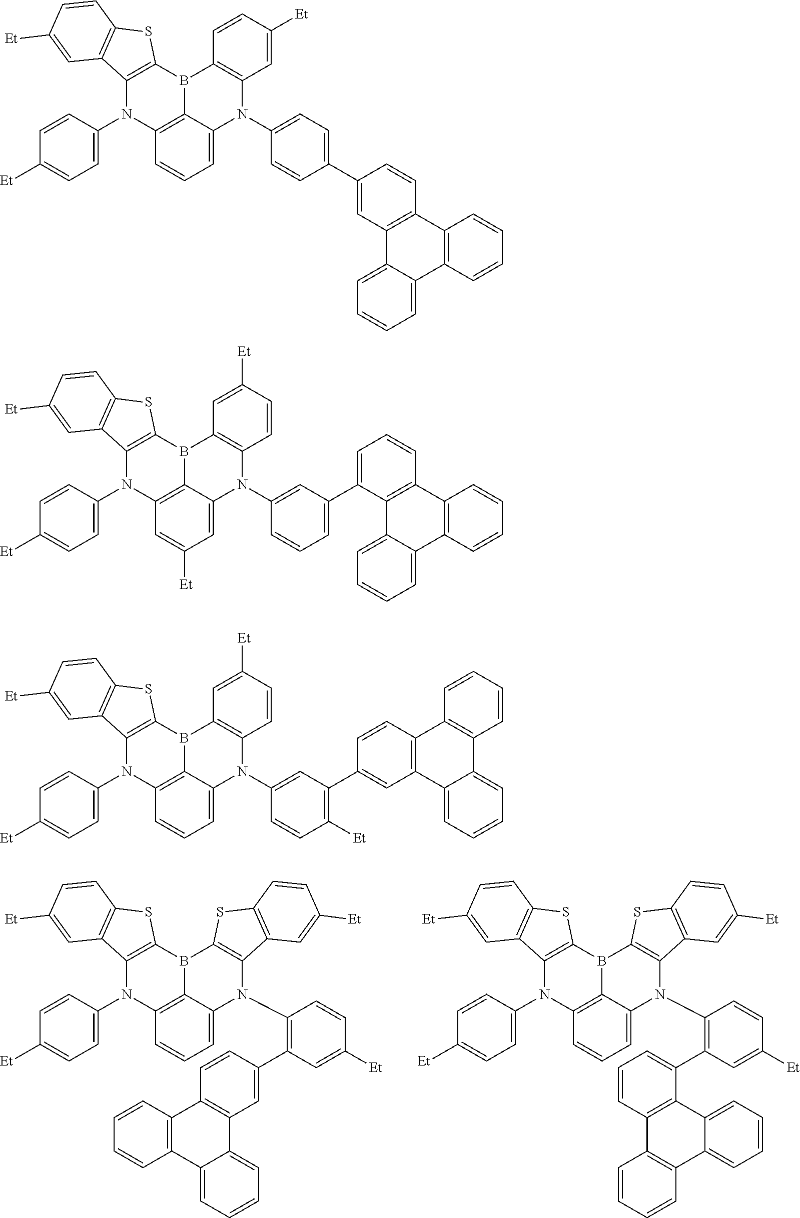

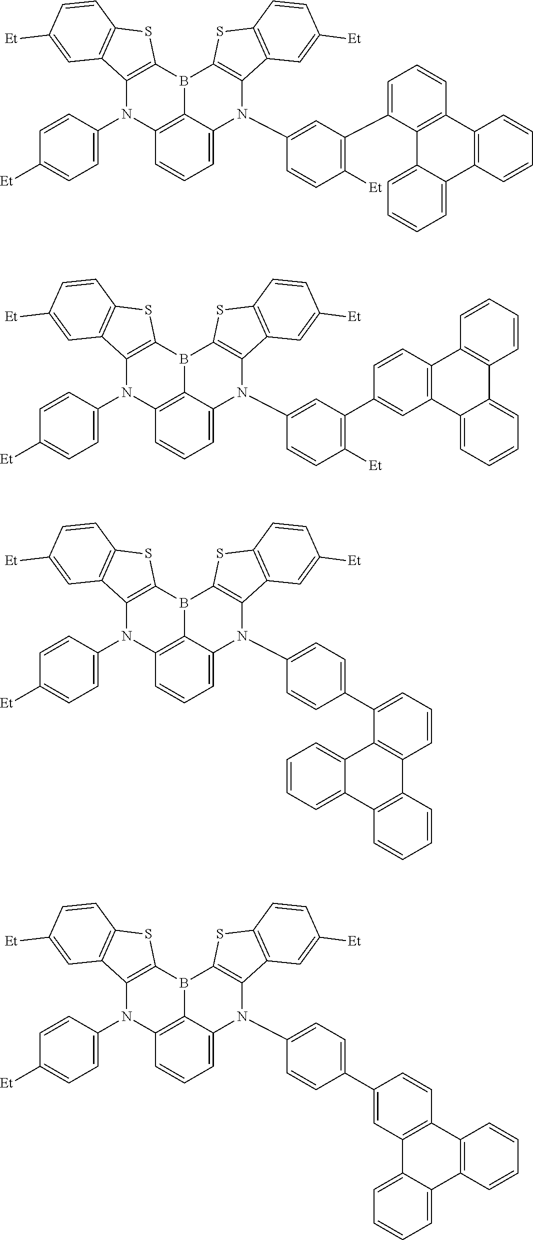 [SMILES: CCc1ccc(N2c3cccc4c3B(c3sc5ccc(CC)cc5c32)c2sc3ccc(CC)cc3c2N4c2ccc(CC)c(-c3cccc4c5ccccc5c5ccccc5c34)c2)cc1 ; CCc1ccc(N2c3cccc4c3B(c3sc5ccc(CC)cc5c32)c2sc3ccc(CC)cc3c2N4c2ccc(CC)c(-c3ccc4c5ccccc5c5ccccc5c4c3)c2)cc1 ; CCc1ccc(N2c3cccc4c3B(c3sc5ccc(CC)cc5c32)c2sc3ccc(CC)cc3c2N4c2ccc(-c3cccc4c5ccccc5c5ccccc5c34)cc2)cc1 ; CCc1ccc(N2c3cccc4c3B(c3sc5ccc(CC)cc5c32)c2sc3ccc(CC)cc3c2N4c2ccc(-c3ccc4c5ccccc5c5ccccc5c4c3)cc2)cc1]

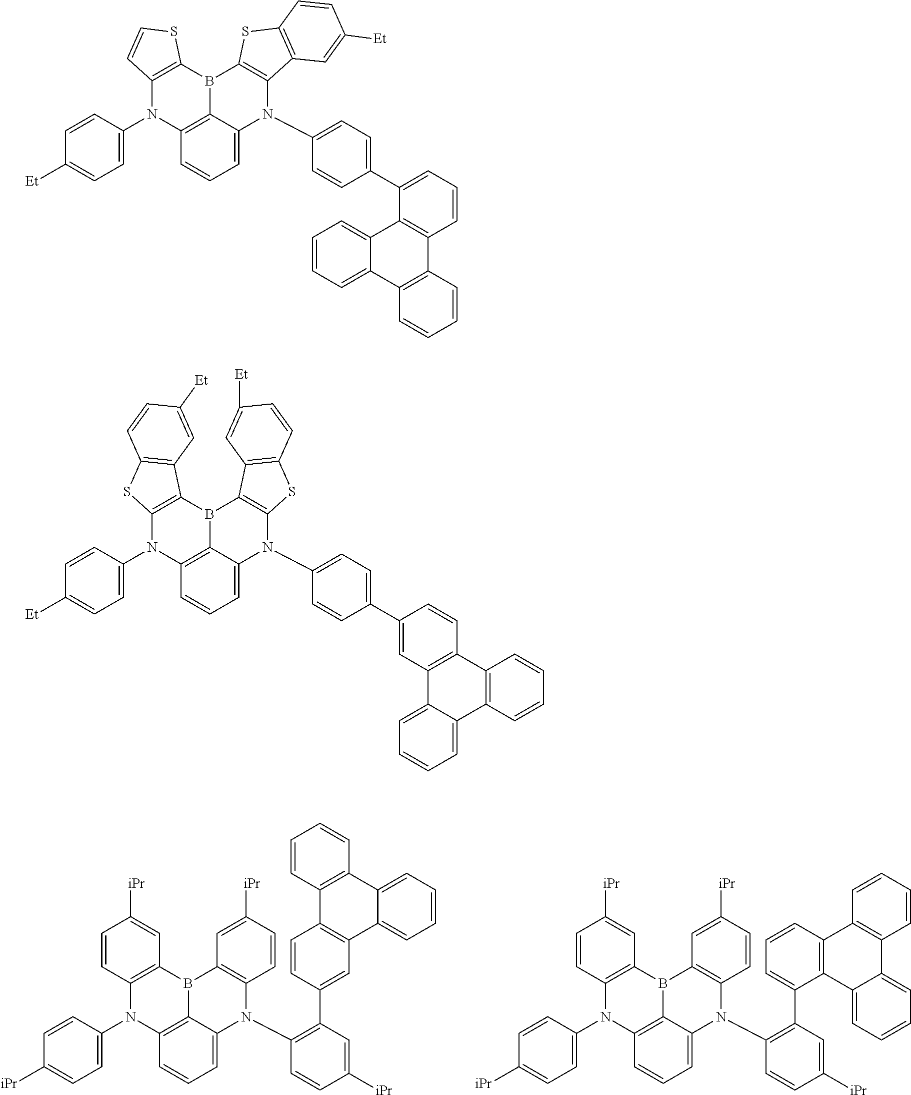 [SMILES: CCc1ccc(N2c3ccsc3B3c4sc5ccc(CC)cc5c4N(c4ccc(-c5cccc6c7ccccc7c7ccccc7c56)cc4)c4cccc2c43)cc1 ; CCc1ccc(N2c3cccc4c3B(c3c2sc2ccc(CC)cc32)c2c(sc3ccc(CC)cc23)N4c2ccc(-c3ccc4c5ccccc5c5ccccc5c4c3)cc2)cc1 ; CC(C)c1ccc(N2c3ccc(C(C)C)cc3B3c4cc(C(C)C)ccc4N(c4ccc(C(C)C)cc4-c4ccc5c6ccccc6c6ccccc6c5c4)c4cccc2c43)cc1 ; CC(C)c1ccc(N2c3ccc(C(C)C)cc3B3c4cc(C(C)C)ccc4N(c4ccc(C(C)C)cc4-c4cccc5c6ccccc6c6ccccc6c45)c4cccc2c43)cc1]

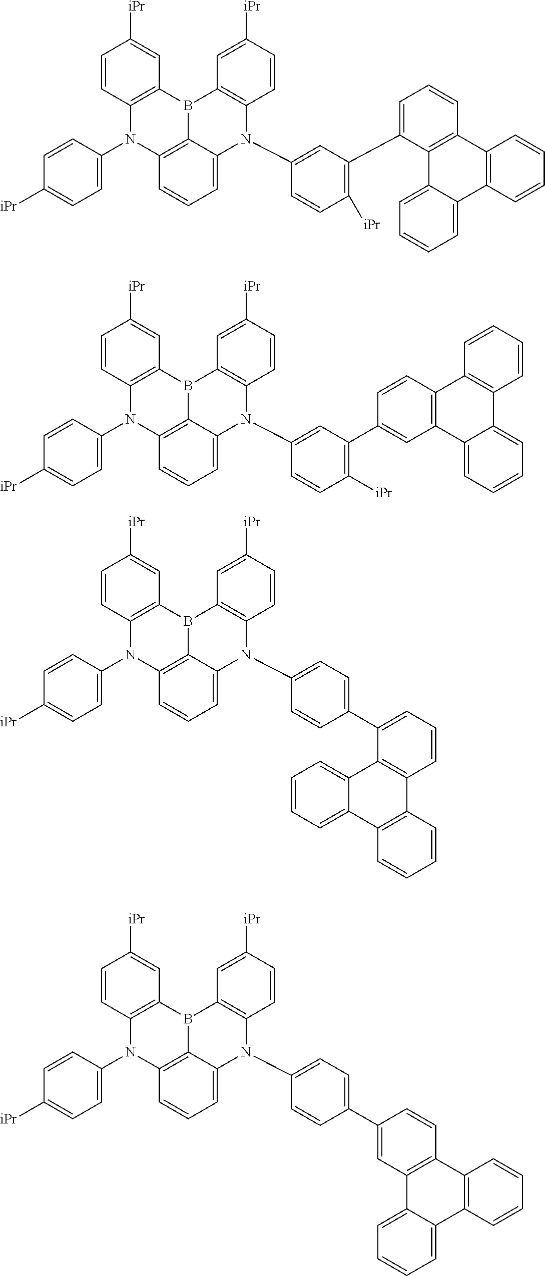 [SMILES: CC(C)c1ccc(N2c3ccc(C(C)C)cc3B3c4cc(C(C)C)ccc4N(c4ccc(C(C)C)c(-c5cccc6c7ccccc7c7ccccc7c56)c4)c4cccc2c43)cc1 ; CC(C)c1ccc(N2c3ccc(C(C)C)cc3B3c4cc(C(C)C)ccc4N(c4ccc(C(C)C)c(-c5ccc6c7ccccc7c7ccccc7c6c5)c4)c4cccc2c43)cc1 ; CC(C)c1ccc(N2c3ccc(C(C)C)cc3B3c4cc(C(C)C)ccc4N(c4ccc(-c5cccc6c7ccccc7c7ccccc7c56)cc4)c4cccc2c43)cc1 ; CC(C)c1ccc(N2c3ccc(C(C)C)cc3B3c4cc(C(C)C)ccc4N(c4ccc(-c5ccc6c7ccccc7c7ccccc7c6c5)cc4)c4cccc2c43)cc1]

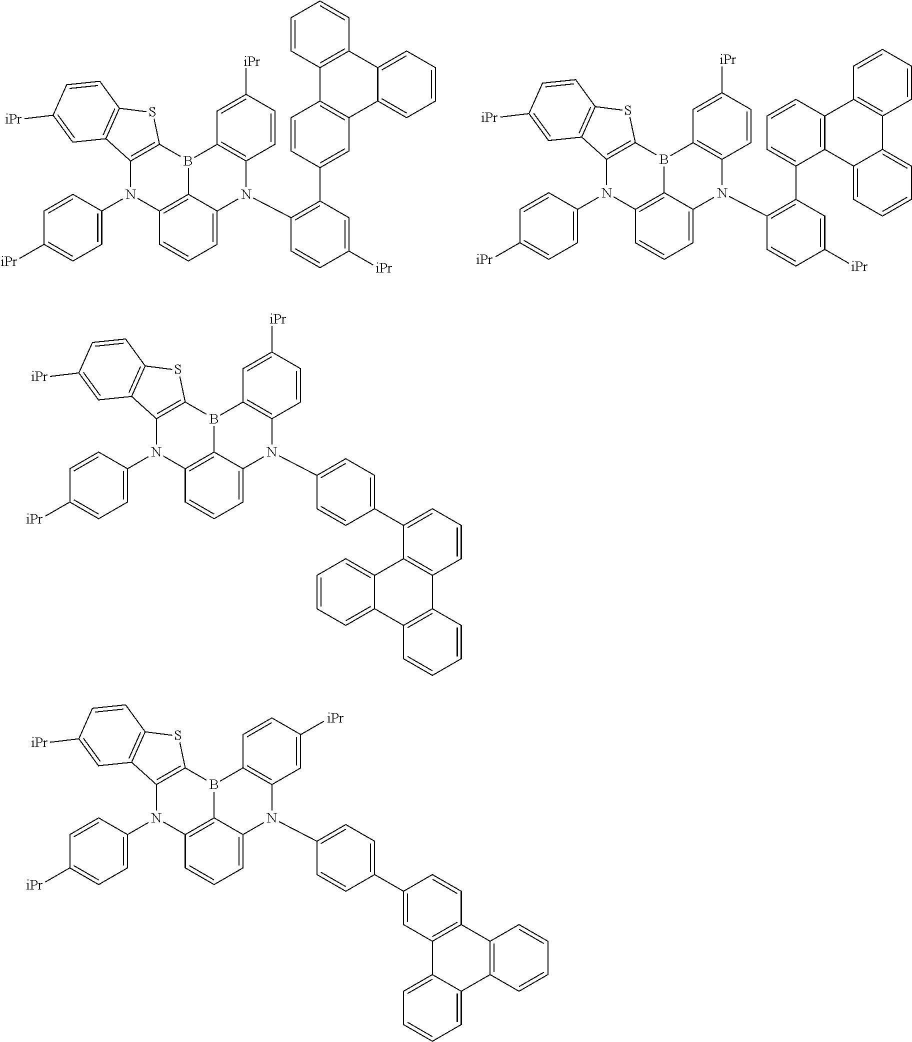 [SMILES: CC(C)c1ccc(N2c3cccc4c3B(c3cc(C(C)C)ccc3N4c3ccc(C(C)C)cc3-c3ccc4c5ccccc5c5ccccc5c4c3)c3sc4ccc(C(C)C)cc4c32)cc1 ; CC(C)c1ccc(N2c3cccc4c3B(c3cc(C(C)C)ccc3N4c3ccc(C(C)C)cc3-c3cccc4c5ccccc5c5ccccc5c34)c3sc4ccc(C(C)C)cc4c32)cc1 ; CC(C)c1ccc(N2c3cccc4c3B(c3cc(C(C)C)ccc3N4c3ccc(-c4cccc5c6ccccc6c6ccccc6c45)cc3)c3sc4ccc(C(C)C)cc4c32)cc1 ; CC(C)c1ccc(N2c3cccc4c3B(c3ccc(C(C)C)cc3N4c3ccc(-c4ccc5c6ccccc6c6ccccc6c5c4)cc3)c3sc4ccc(C(C)C)cc4c32)cc1]

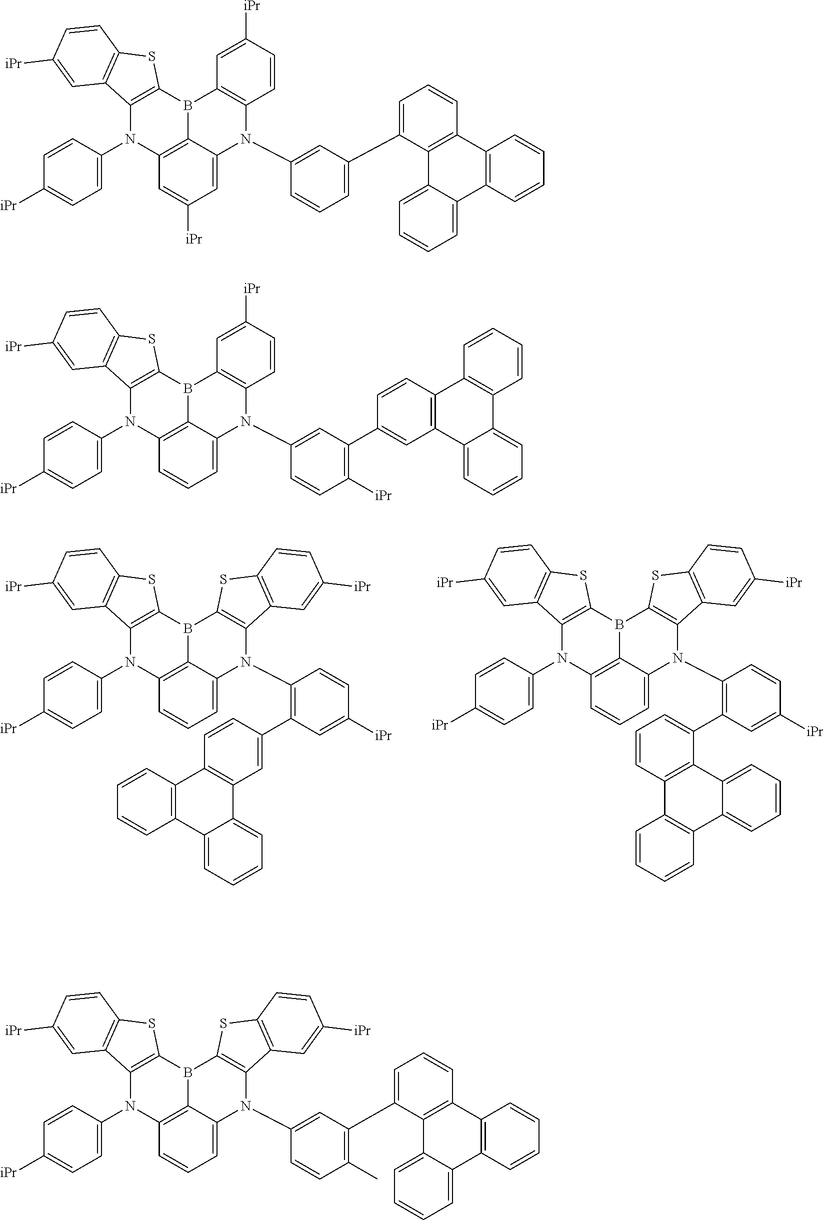

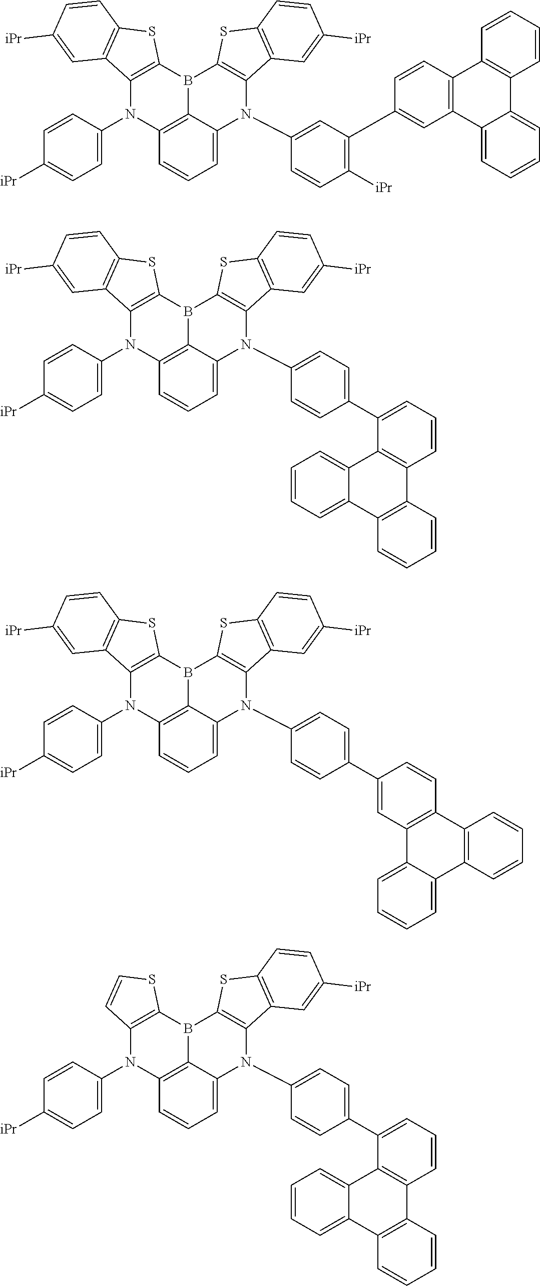 [SMILES: CC(C)c1ccc(N2c3cccc4c3B(c3sc5ccc(C(C)C)cc5c32)c2sc3ccc(C(C)C)cc3c2N4c2ccc(C(C)C)c(-c3ccc4c5ccccc5c5ccccc5c4c3)c2)cc1 ; CC(C)c1ccc(N2c3cccc4c3B(c3sc5ccc(C(C)C)cc5c3N4c3ccc(-c4cccc5c6ccccc6c6ccccc6c45)cc3)c3sc4ccc(C(C)C)cc4c32)cc1 ; CC(C)c1ccc(N2c3cccc4c3B(c3sc5ccc(C(C)C)cc5c3N4c3ccc(-c4ccc5c6ccccc6c6ccccc6c5c4)cc3)c3sc4ccc(C(C)C)cc4c32)cc1 ; CC(C)c1ccc(N2c3ccsc3B3c4sc5ccc(C(C)C)cc5c4N(c4ccc(-c5cccc6c7ccccc7c7ccccc7c56)cc4)c4cccc2c43)cc1]

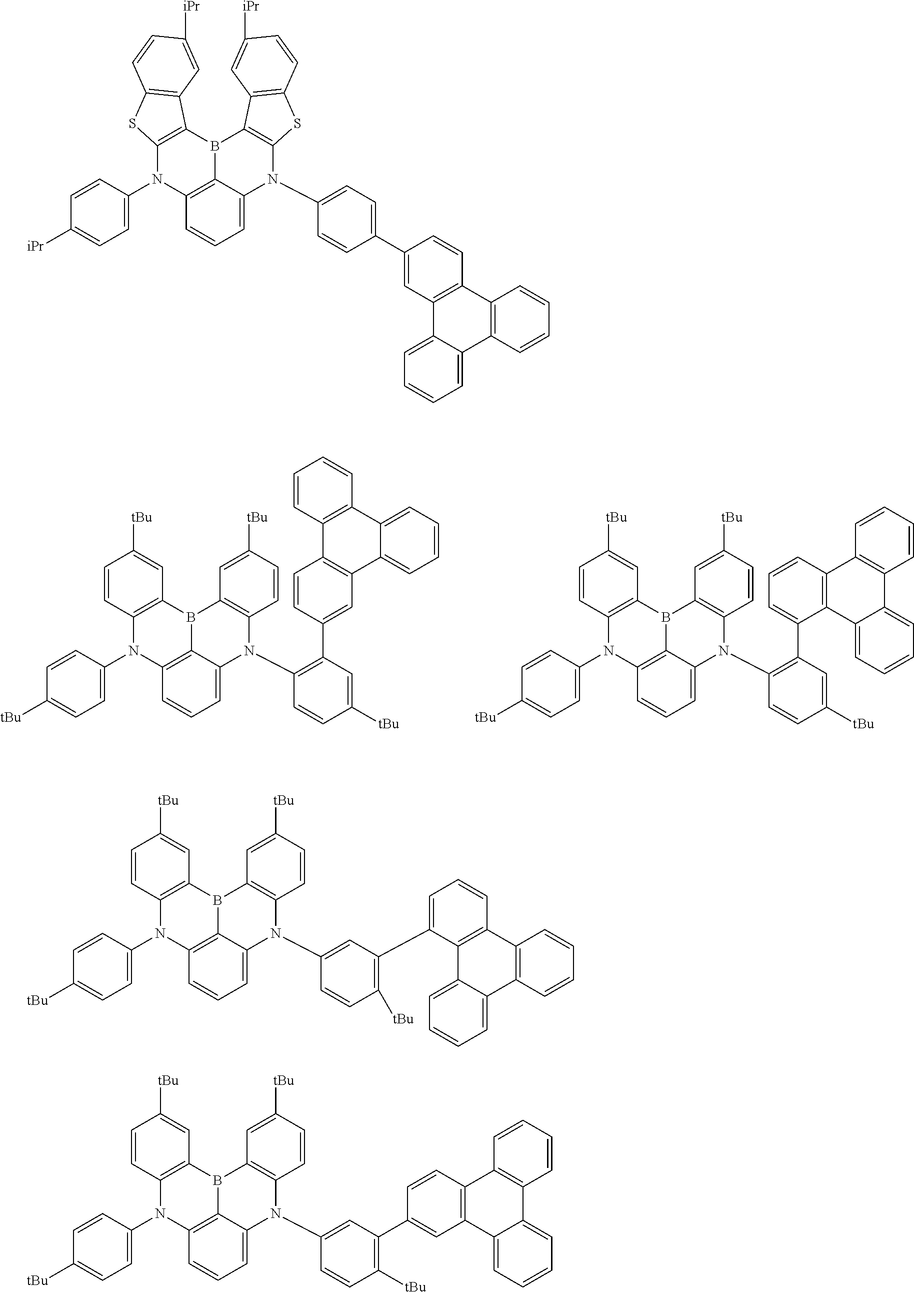

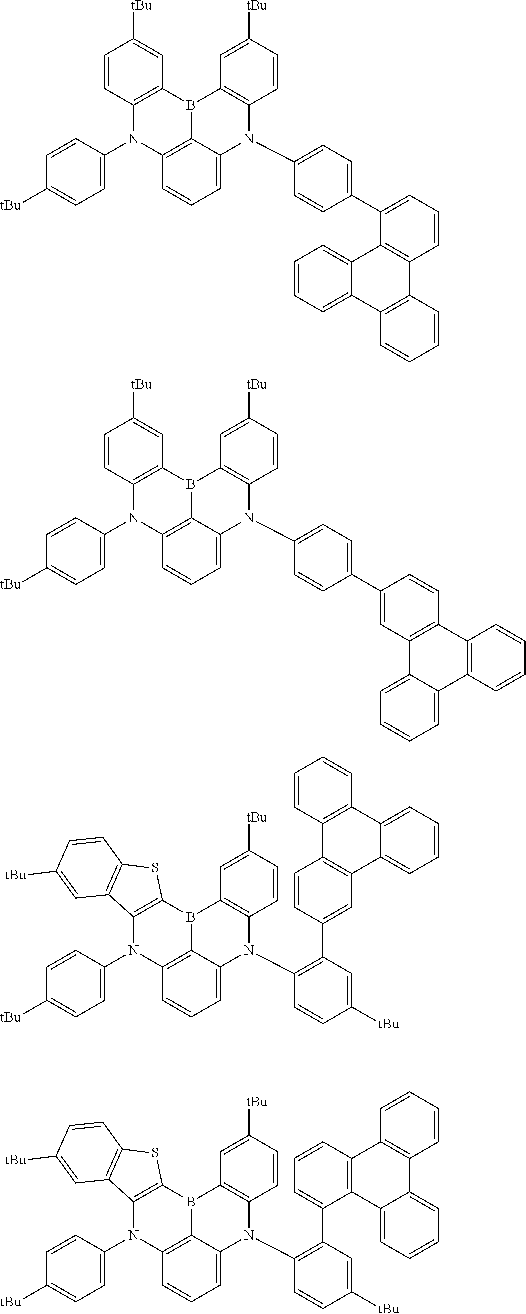 [SMILES: CC(C)(C)c1ccc(N2c3ccc(C(C)(C)C)cc3B3c4cc(C(C)(C)C)ccc4N(c4ccc(-c5cccc6c7ccccc7c7ccccc7c56)cc4)c4cccc2c43)cc1 ; CC(C)(C)c1ccc(N2c3ccc(C(C)(C)C)cc3B3c4cc(C(C)(C)C)ccc4N(c4ccc(-c5ccc6c7ccccc7c7ccccc7c6c5)cc4)c4cccc2c43)cc1 ; CC(C)(C)c1ccc(N2c3cccc4c3B(c3cc(C(C)(C)C)ccc3N4c3ccc(C(C)(C)C)cc3-c3ccc4c5ccccc5c5ccccc5c4c3)c3sc4ccc(C(C)(C)C)cc4c32)cc1 ; CC(C)(C)c1ccc(N2c3cccc4c3B(c3cc(C(C)(C)C)ccc3N4c3ccc(C(C)(C)C)cc3-c3cccc4c5ccccc5c5ccccc5c34)c3sc4ccc(C(C)(C)C)cc4c32)cc1]

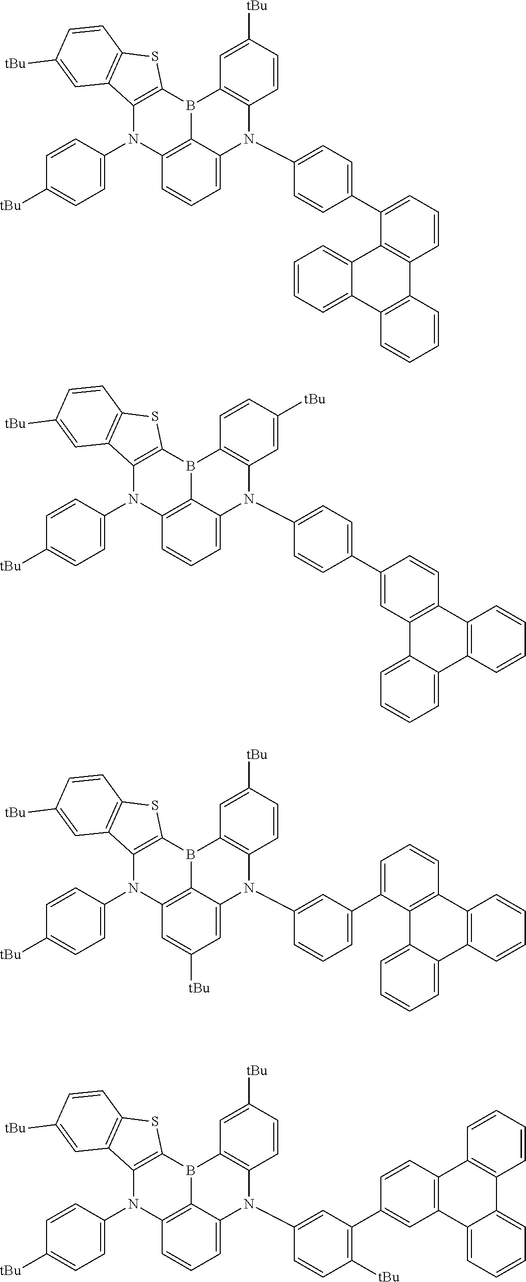 [SMILES: CC(C)(C)c1ccc(N2c3cccc4c3B(c3cc(C(C)(C)C)ccc3N4c3ccc(-c4cccc5c6ccccc6c6ccccc6c45)cc3)c3sc4ccc(C(C)(C)C)cc4c32)cc1 ; CC(C)(C)c1ccc(N2c3cccc4c3B(c3ccc(C(C)(C)C)cc3N4c3ccc(-c4ccc5c6ccccc6c6ccccc6c5c4)cc3)c3sc4ccc(C(C)(C)C)cc4c32)cc1 ; CC(C)(C)c1ccc(N2c3cc(C(C)(C)C)cc4c3B(c3cc(C(C)(C)C)ccc3N4c3cccc(-c4cccc5c6ccccc6c6ccccc6c45)c3)c3sc4ccc(C(C)(C)C)cc4c32)cc1 ; CC(C)(C)c1ccc(N2c3cccc4c3B(c3cc(C(C)(C)C)ccc3N4c3ccc(C(C)(C)C)c(-c4ccc5c6ccccc6c6ccccc6c5c4)c3)c3sc4ccc(C(C)(C)C)cc4c32)cc1]

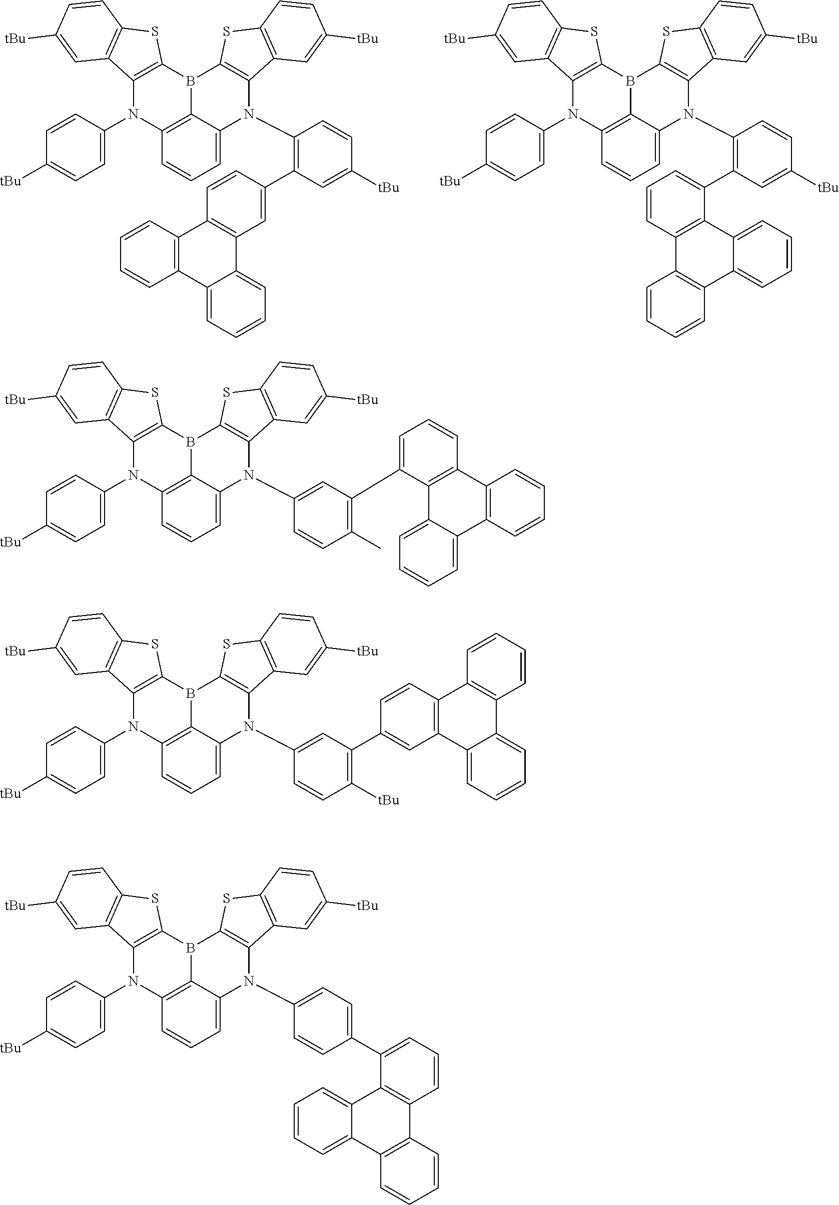

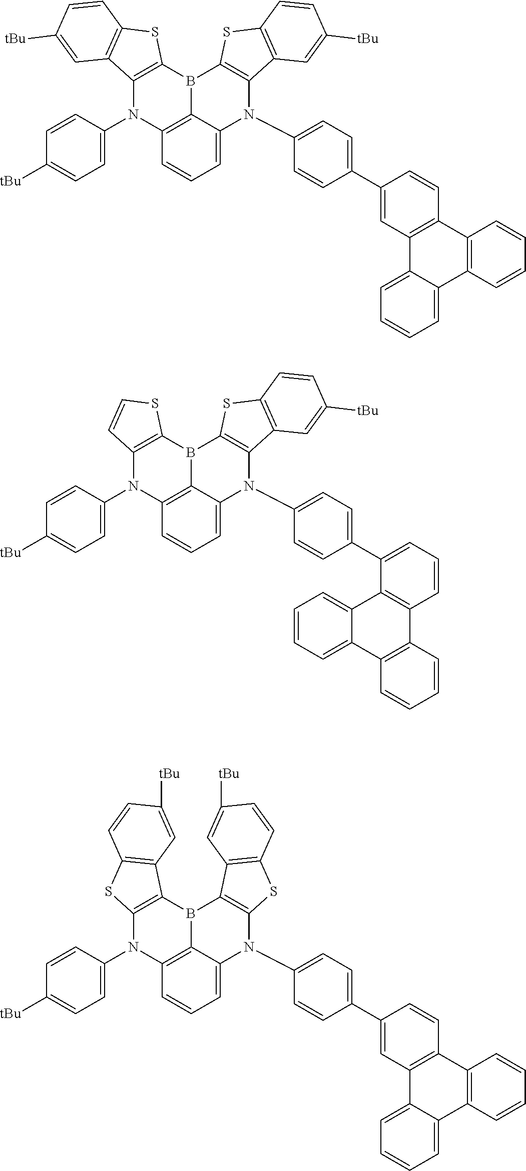 [SMILES: CC(C)(C)c1ccc(N2c3cccc4c3B(c3sc5ccc(C(C)(C)C)cc5c3N4c3ccc(-c4ccc5c6ccccc6c6ccccc6c5c4)cc3)c3sc4ccc(C(C)(C)C)cc4c32)cc1 ; CC(C)(C)c1ccc(N2c3ccsc3B3c4sc5ccc(C(C)(C)C)cc5c4N(c4ccc(-c5cccc6c7ccccc7c7ccccc7c56)cc4)c4cccc2c43)cc1 ; CC(C)(C)c1ccc(N2c3cccc4c3B(c3c(sc5ccc(C(C)(C)C)cc35)N4c3ccc(-c4ccc5c6ccccc6c6ccccc6c5c4)cc3)c3c2sc2ccc(C(C)(C)C)cc32)cc1]

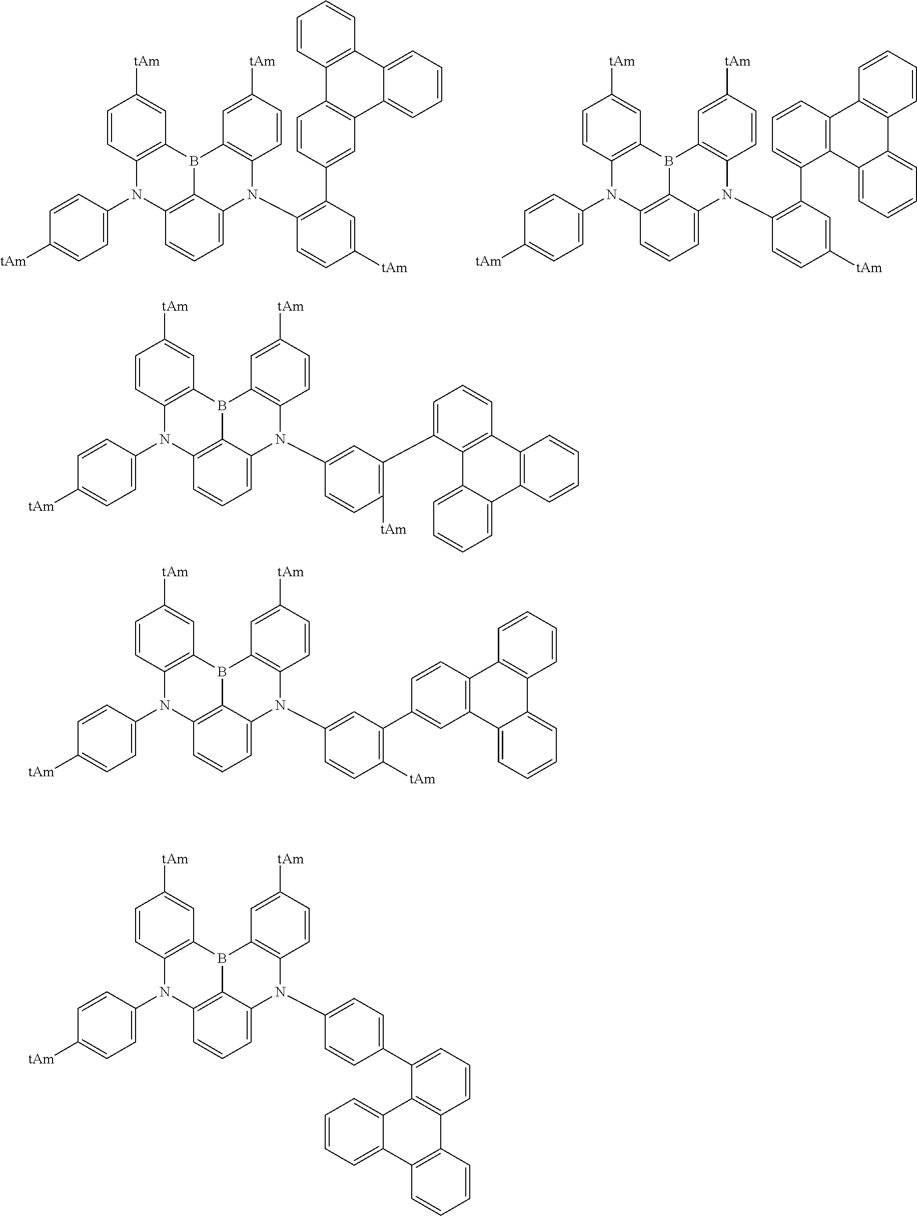

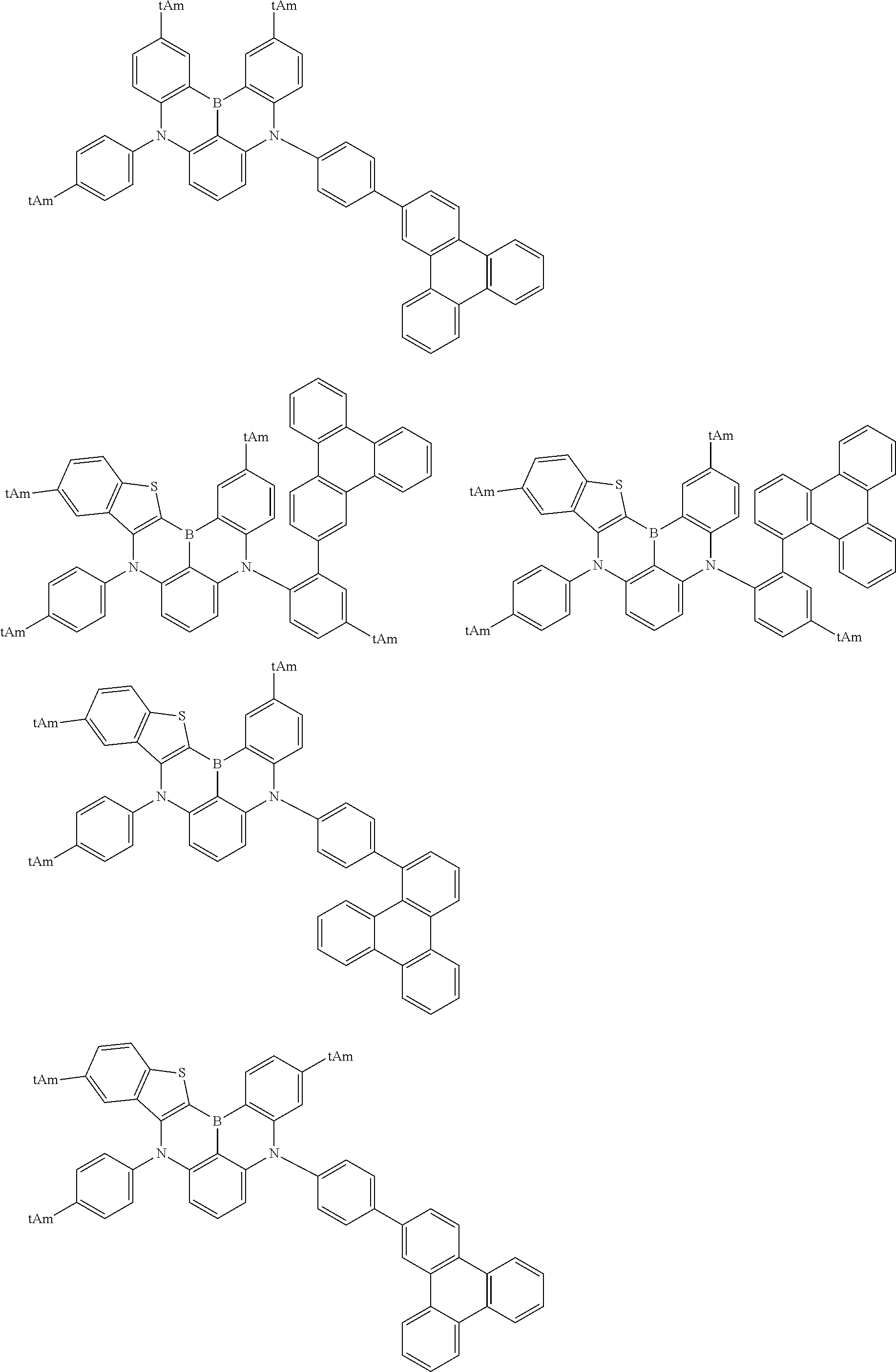

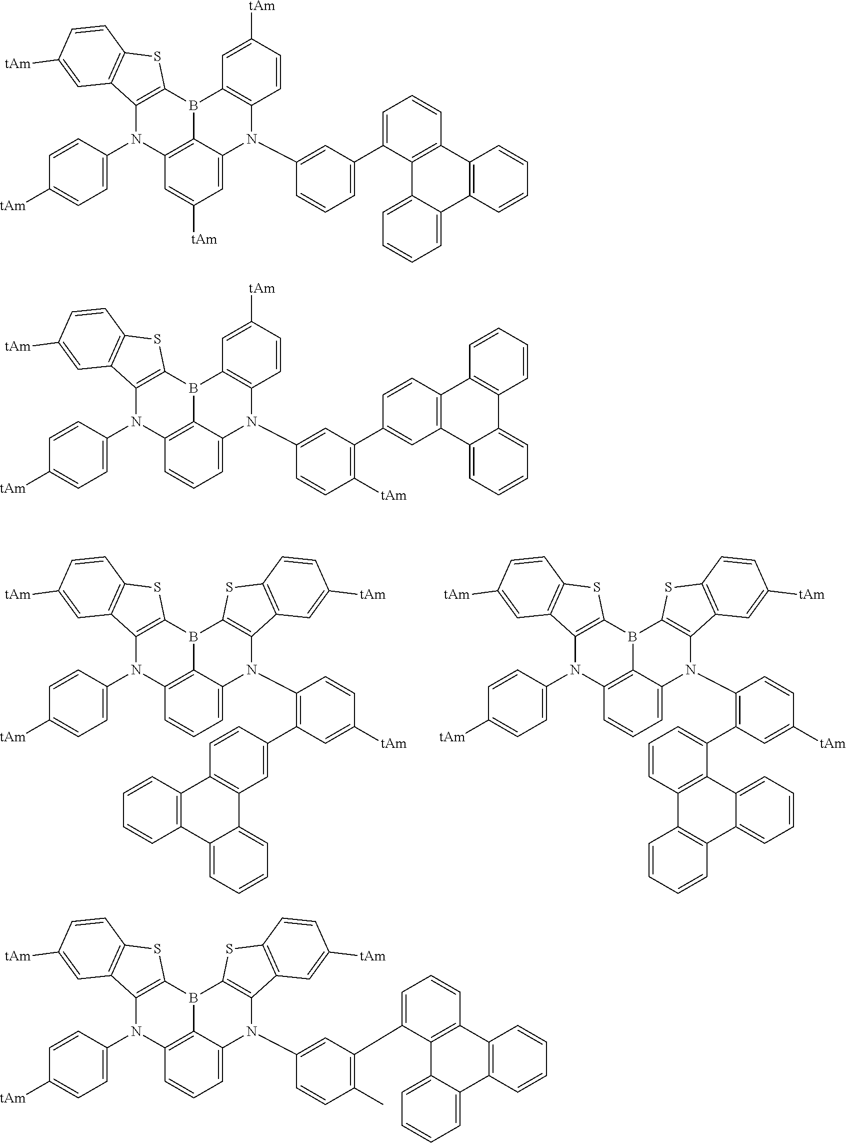

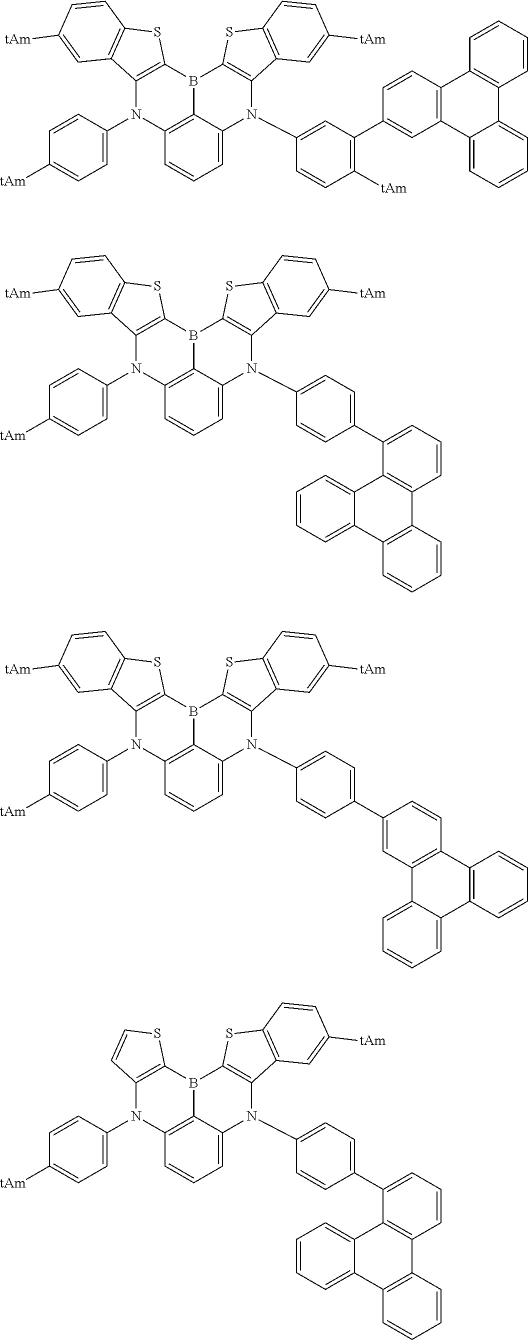

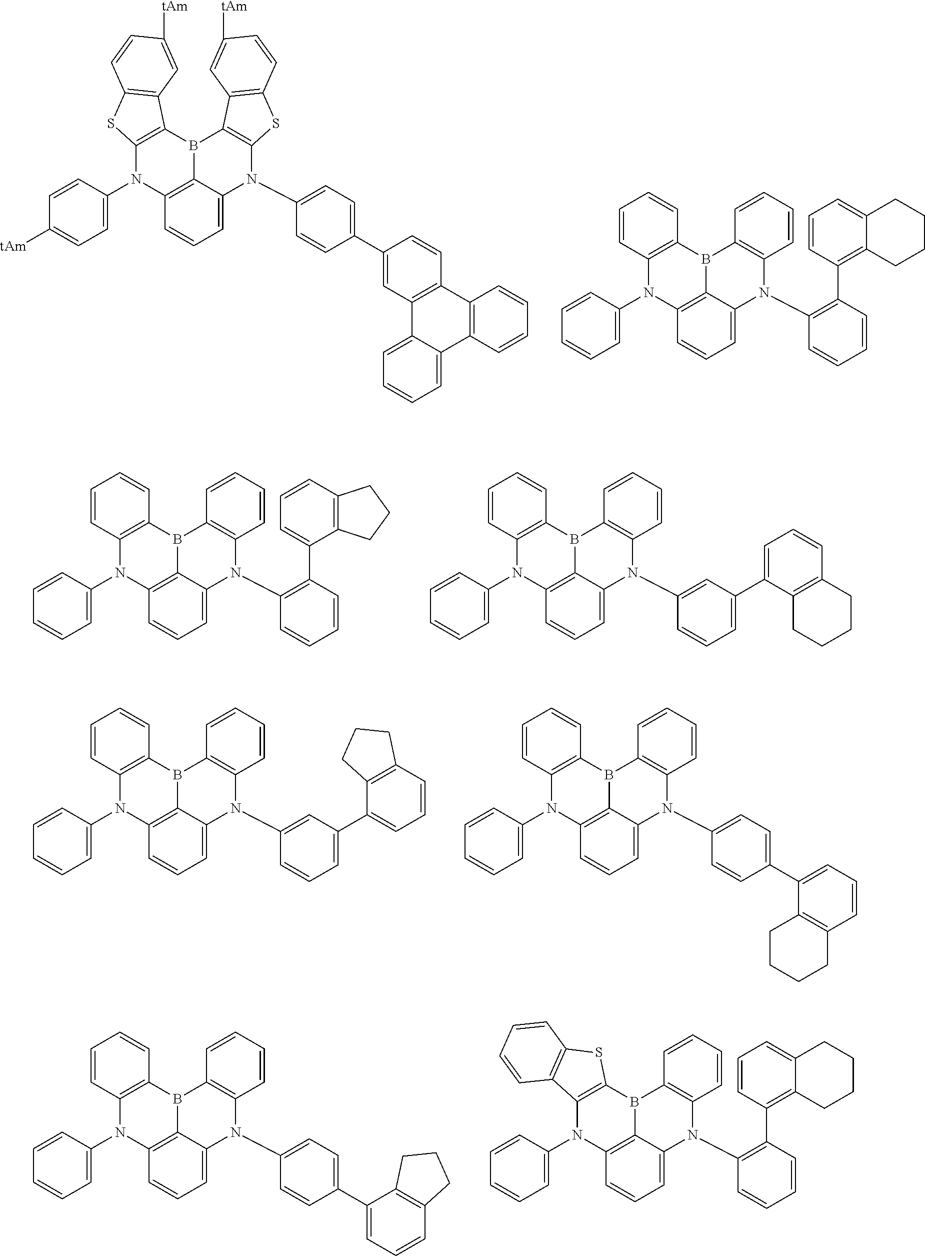

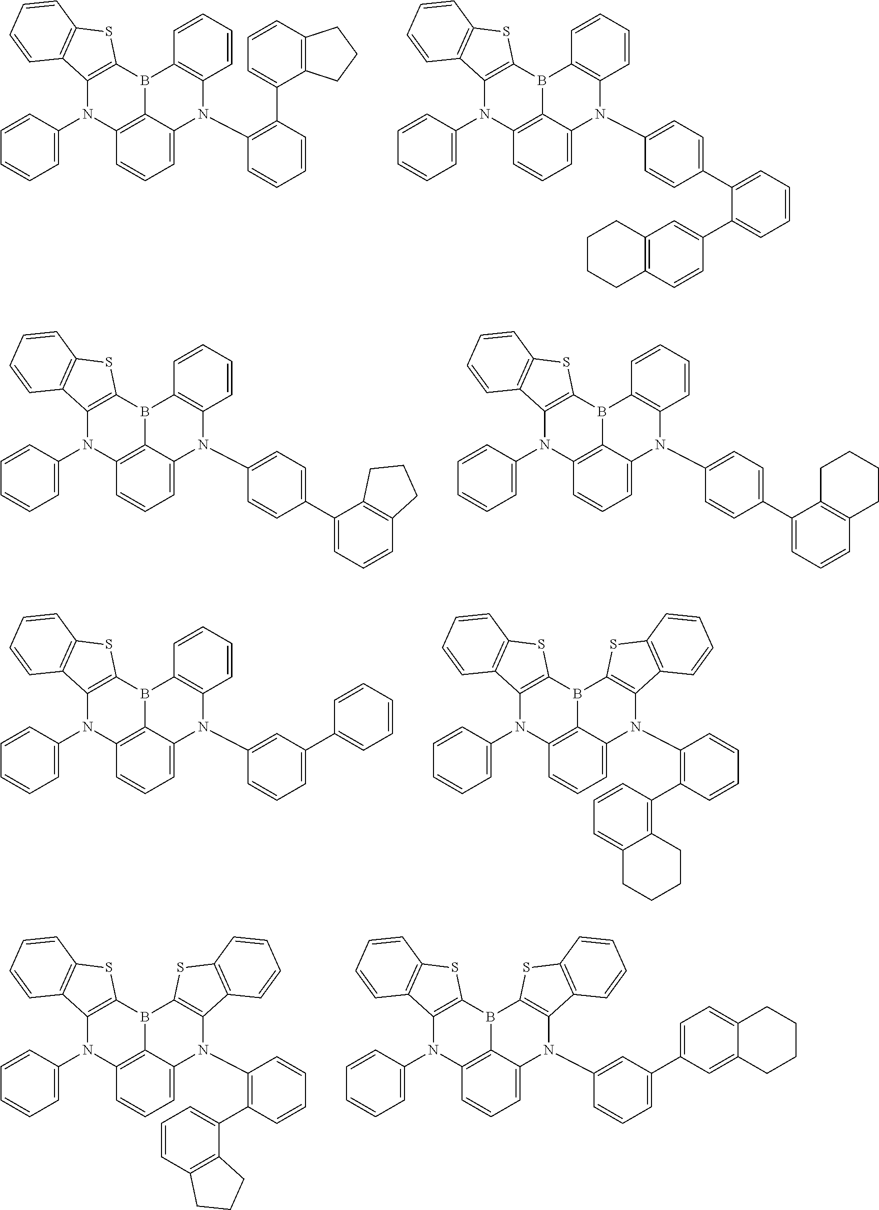

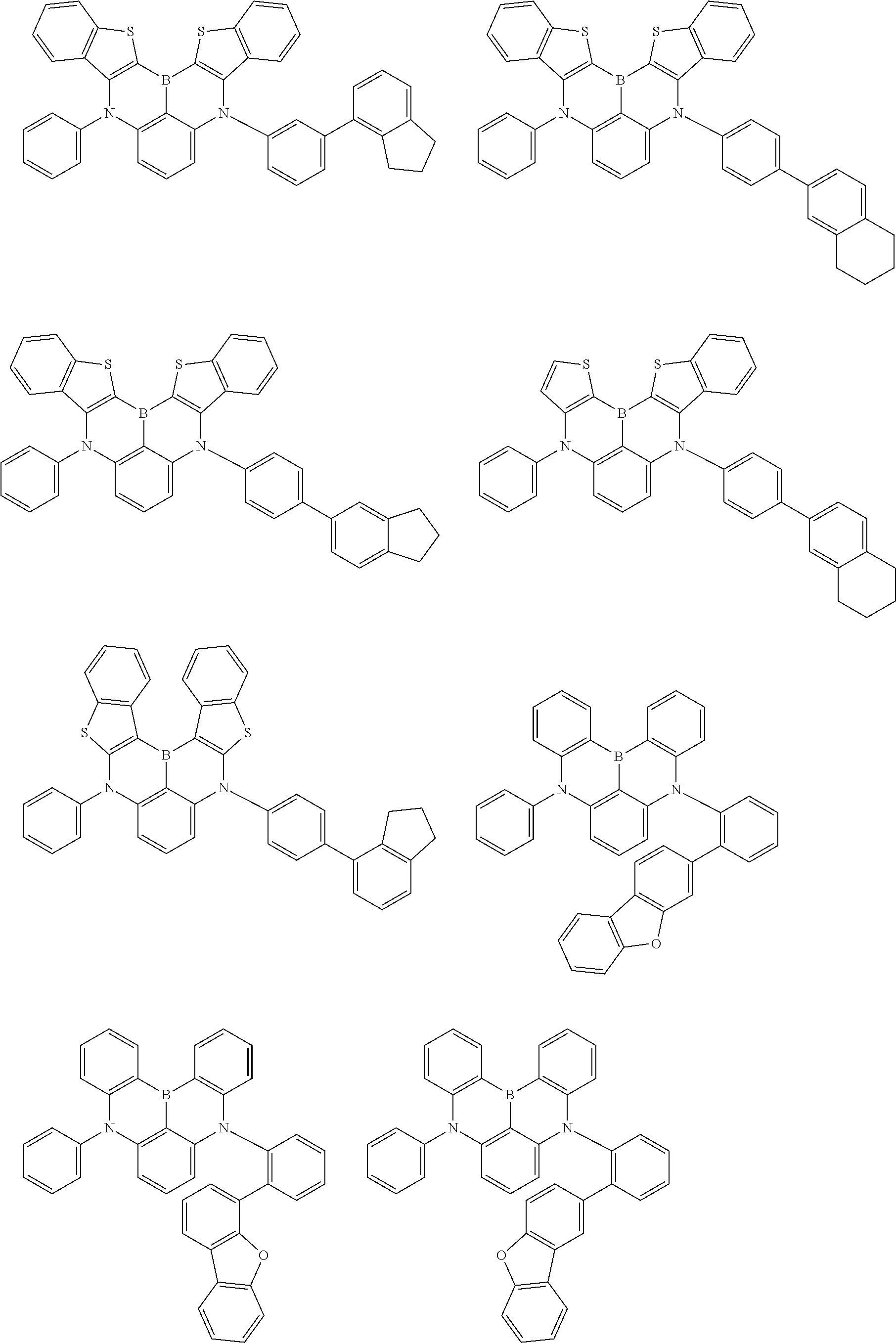

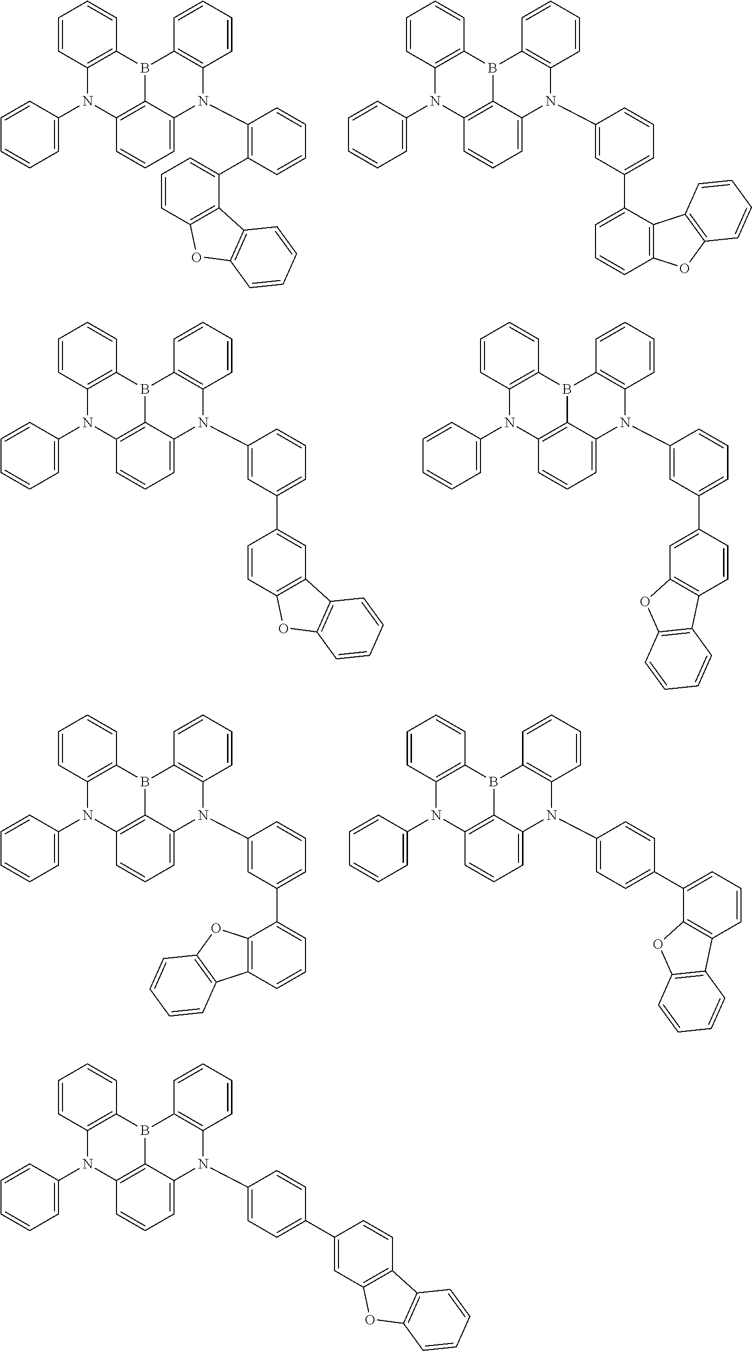

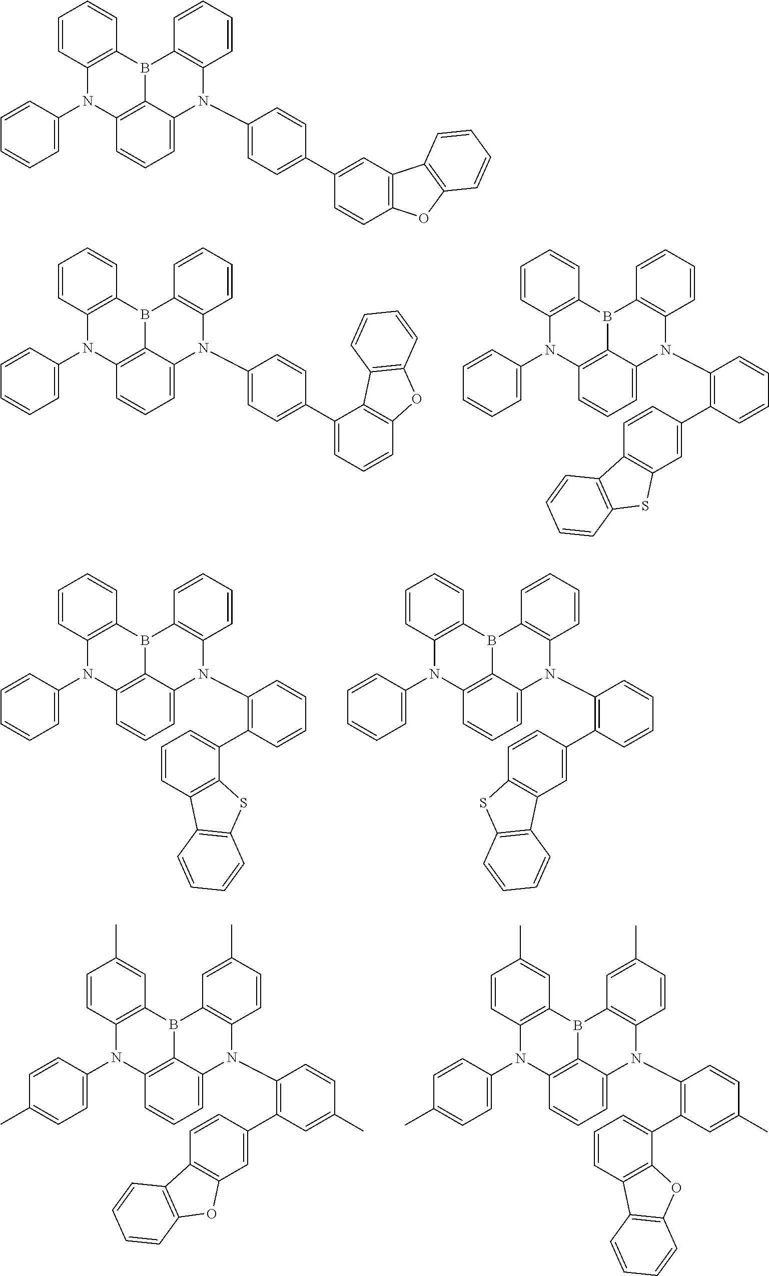

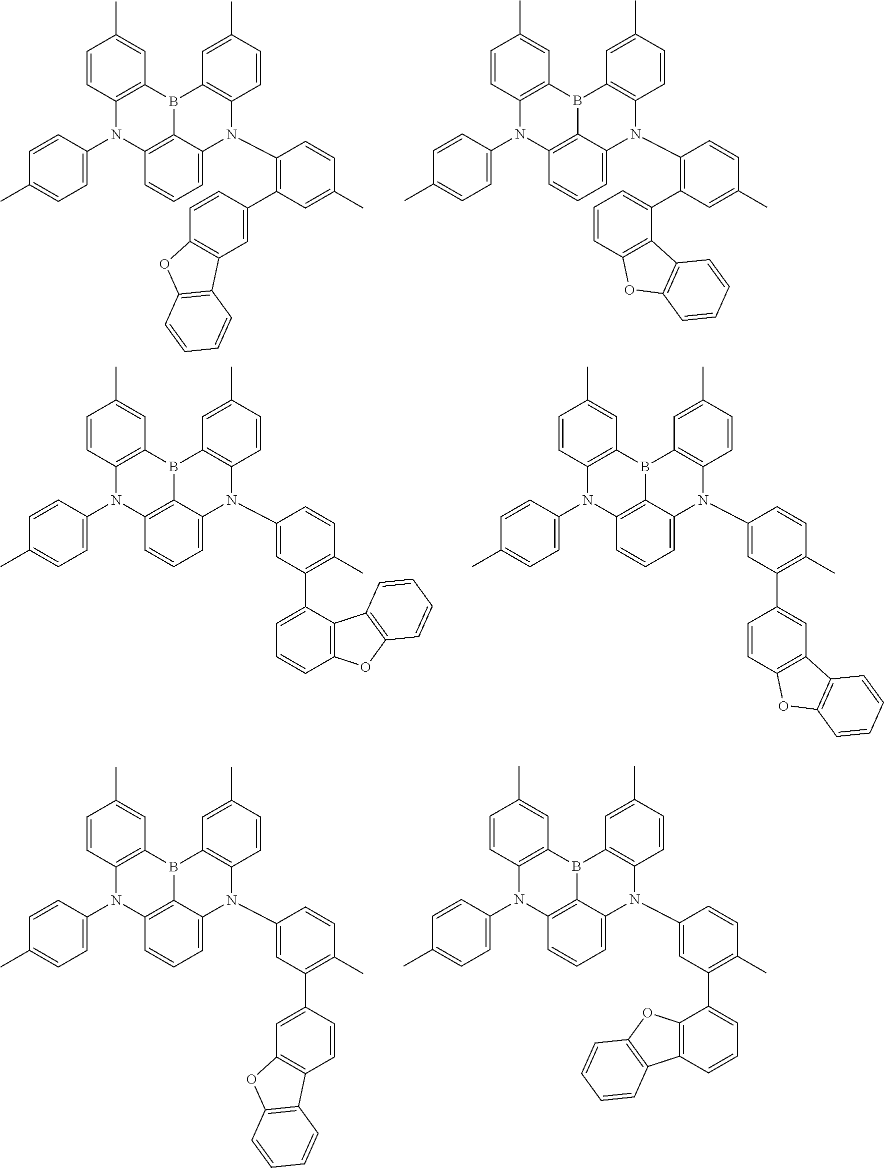

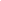

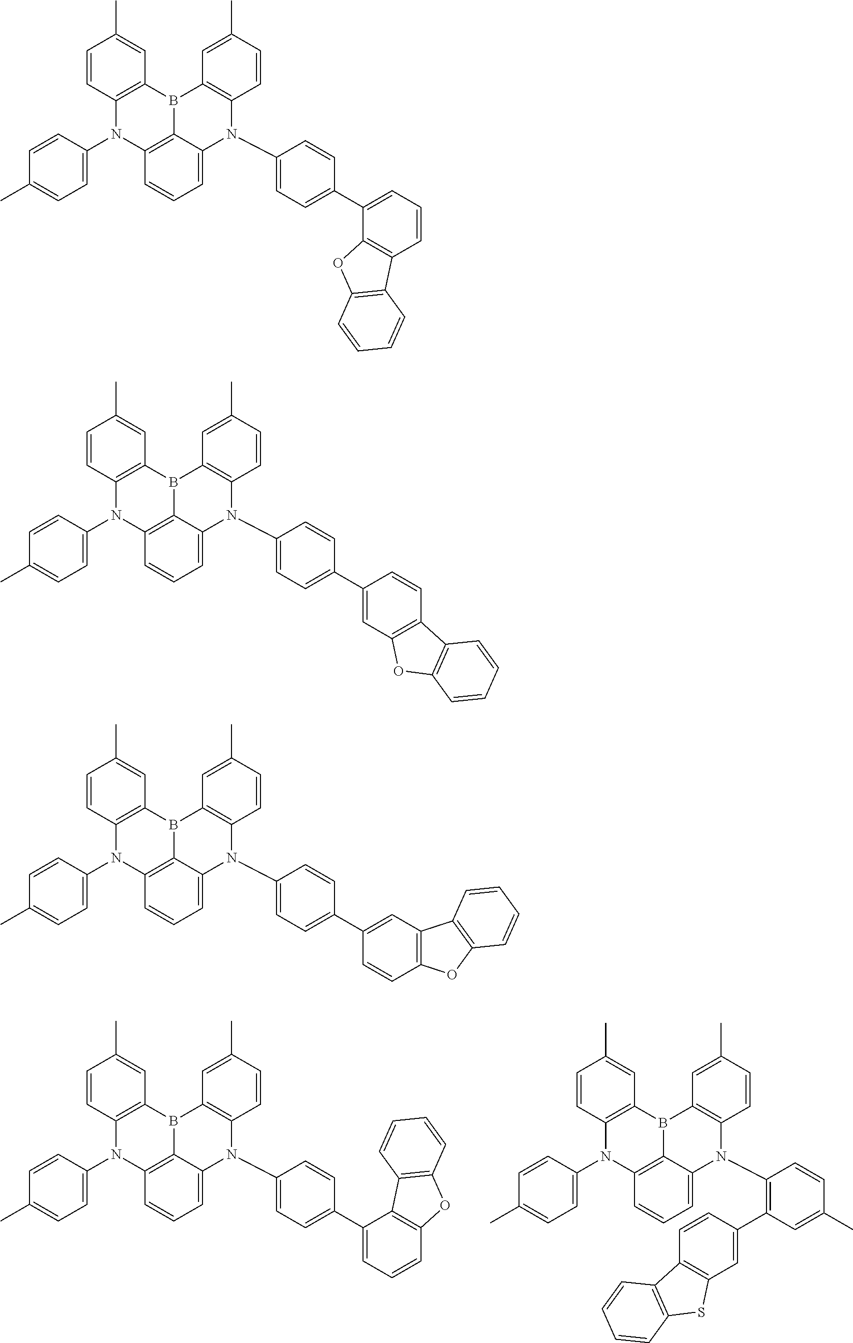

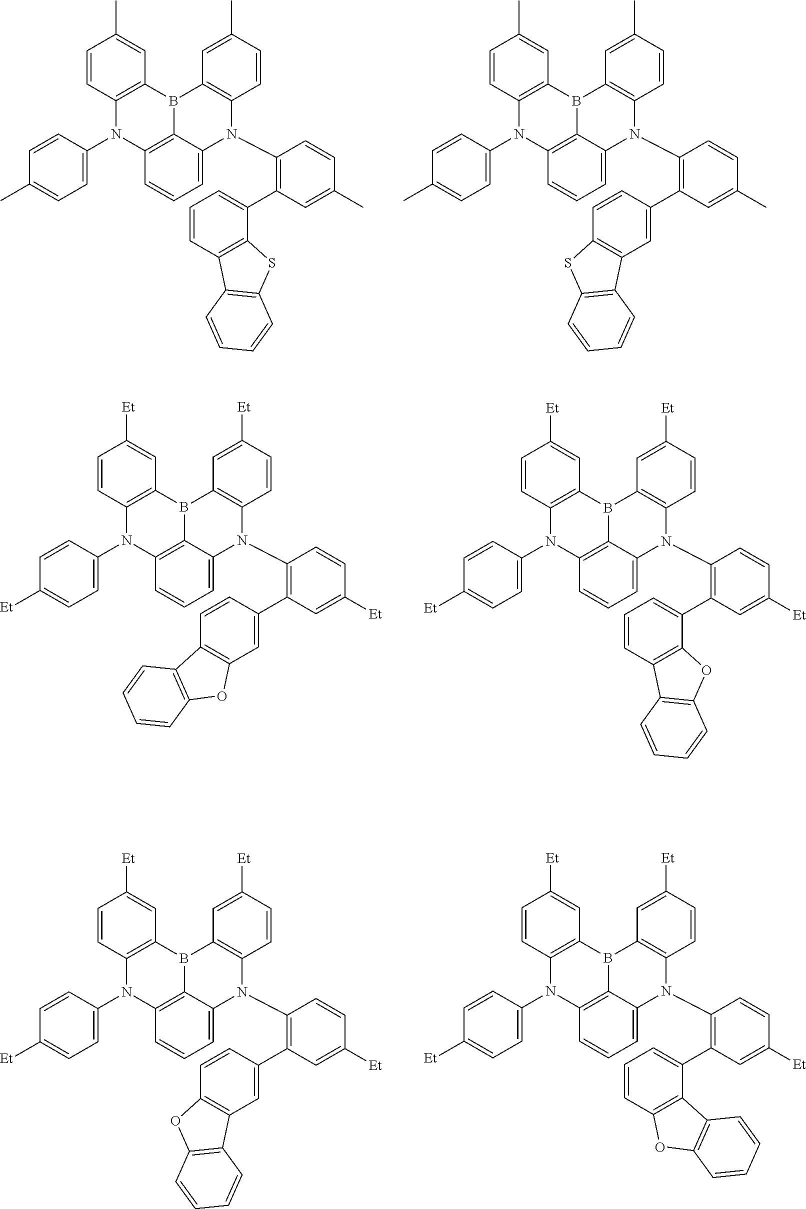

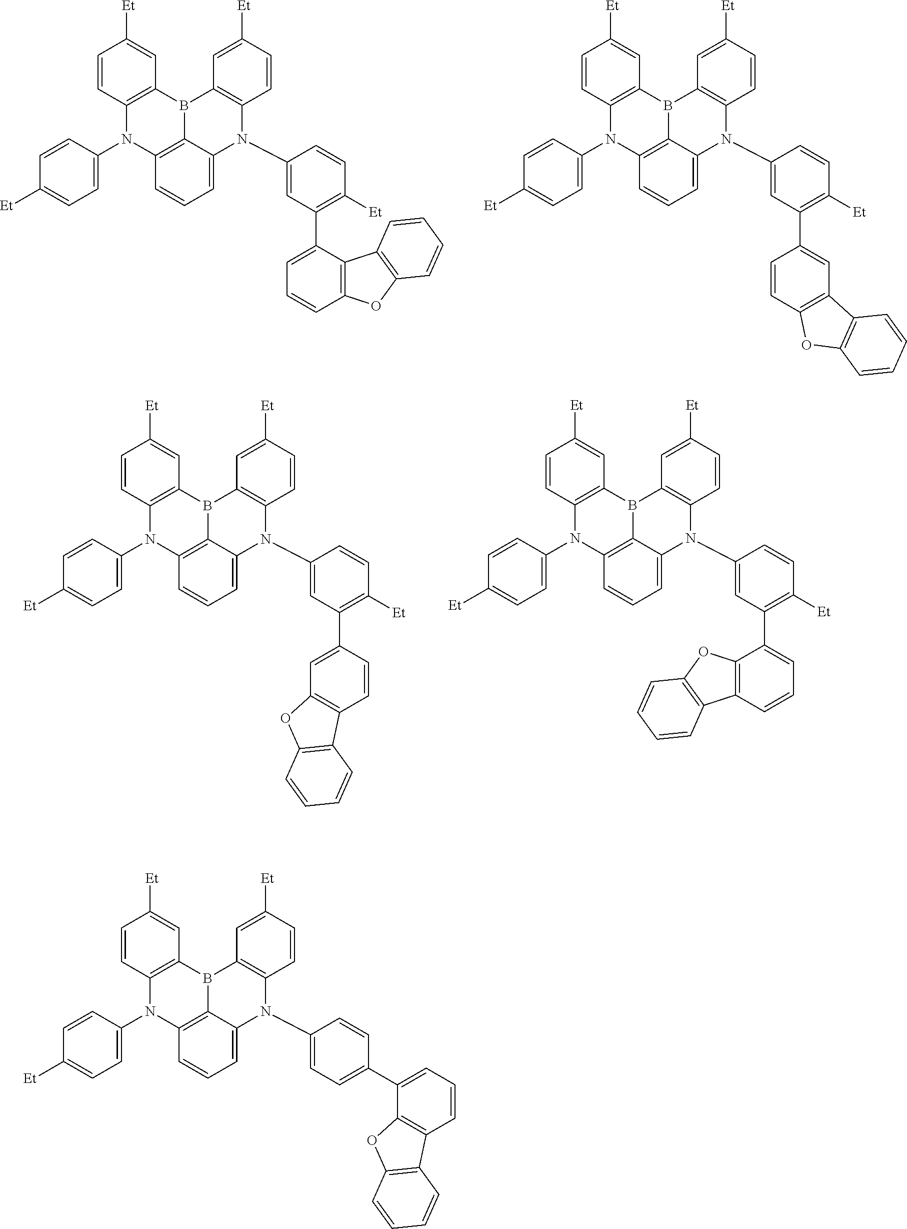 [SMILES: CCc1ccc(N2c3ccc(CC)cc3B3c4cc(CC)ccc4N(c4ccc(CC)c(-c5cccc6oc7ccccc7c56)c4)c4cccc2c43)cc1 ; CCc1ccc(N2c3ccc(CC)cc3B3c4cc(CC)ccc4N(c4ccc(CC)c(-c5ccc6oc7ccccc7c6c5)c4)c4cccc2c43)cc1 ; CCc1ccc(N2c3ccc(CC)cc3B3c4cc(CC)ccc4N(c4ccc(CC)c(-c5ccc6c(c5)oc5ccccc56)c4)c4cccc2c43)cc1 ; CCc1ccc(N2c3ccc(CC)cc3B3c4cc(CC)ccc4N(c4ccc(CC)c(-c5cccc6c5oc5ccccc56)c4)c4cccc2c43)cc1 ; CCc1ccc(N2c3ccc(CC)cc3B3c4cc(CC)ccc4N(c4ccc(-c5cccc6c5oc5ccccc56)cc4)c4cccc2c43)cc1]

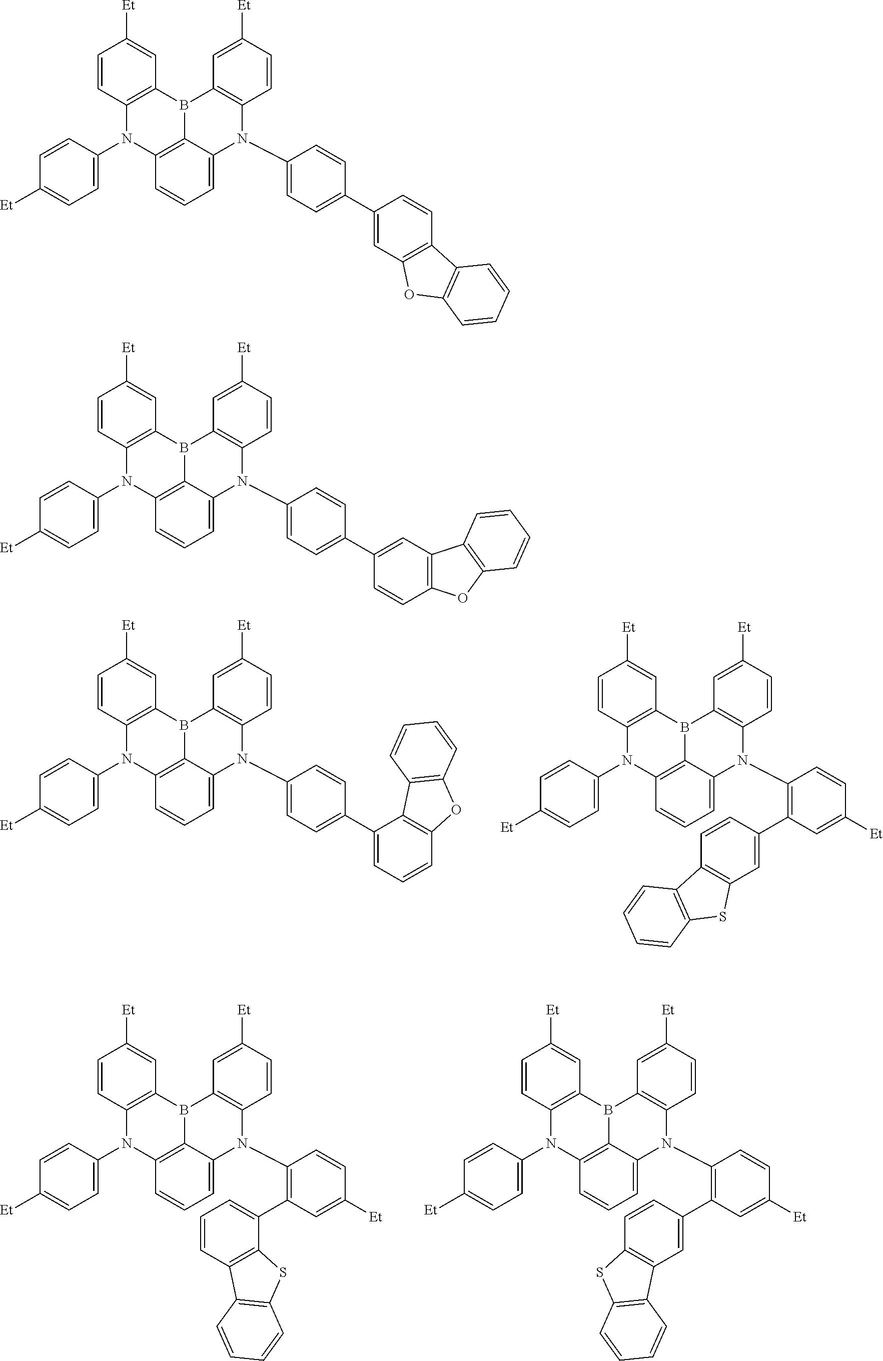

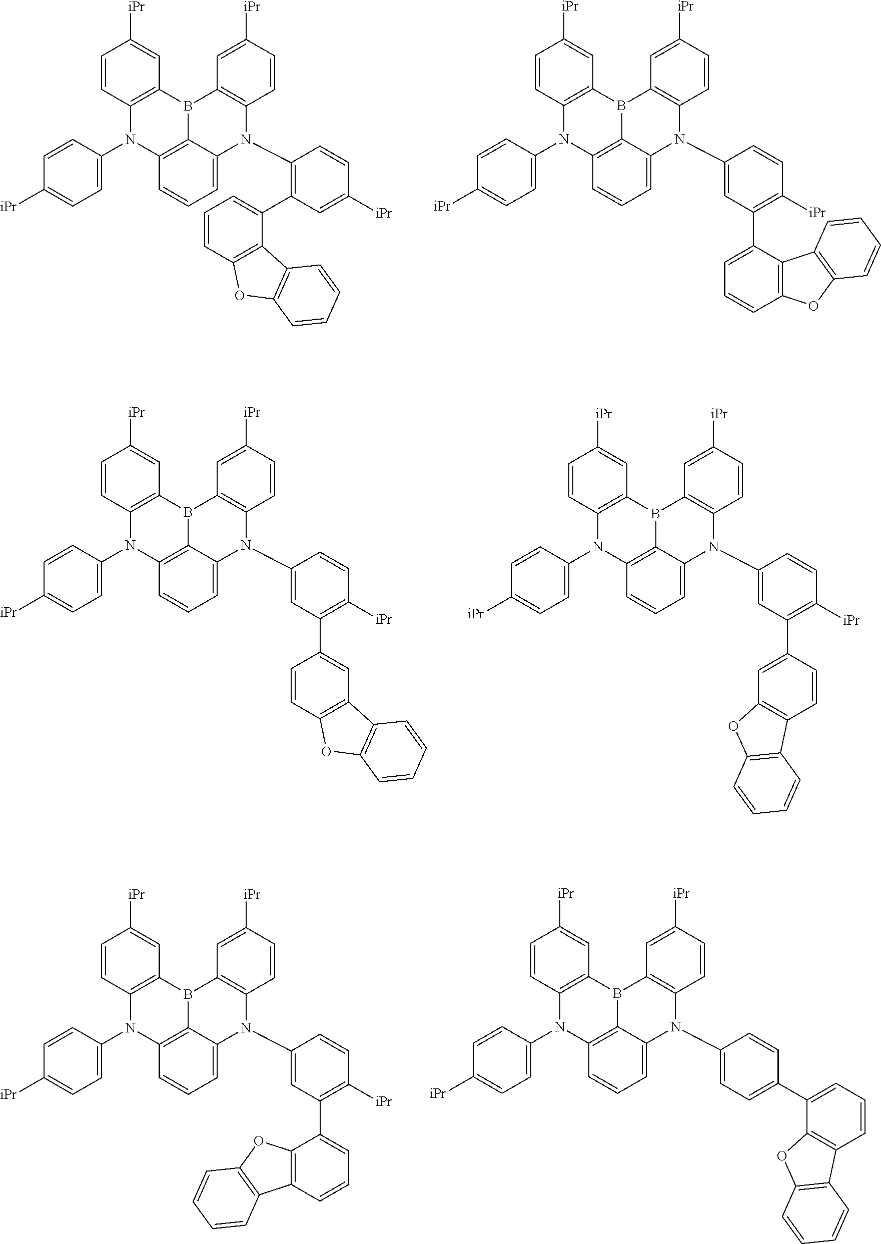

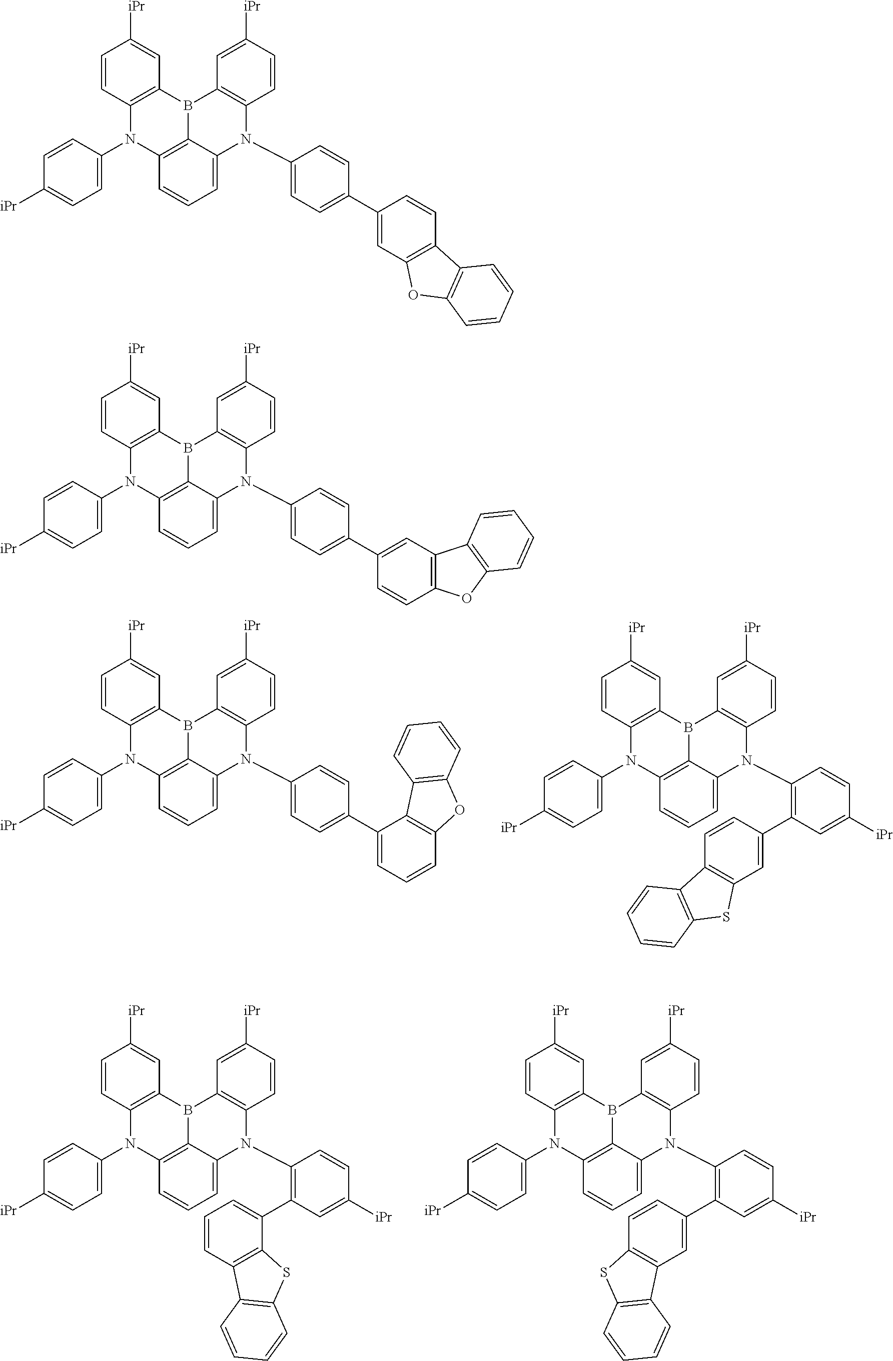

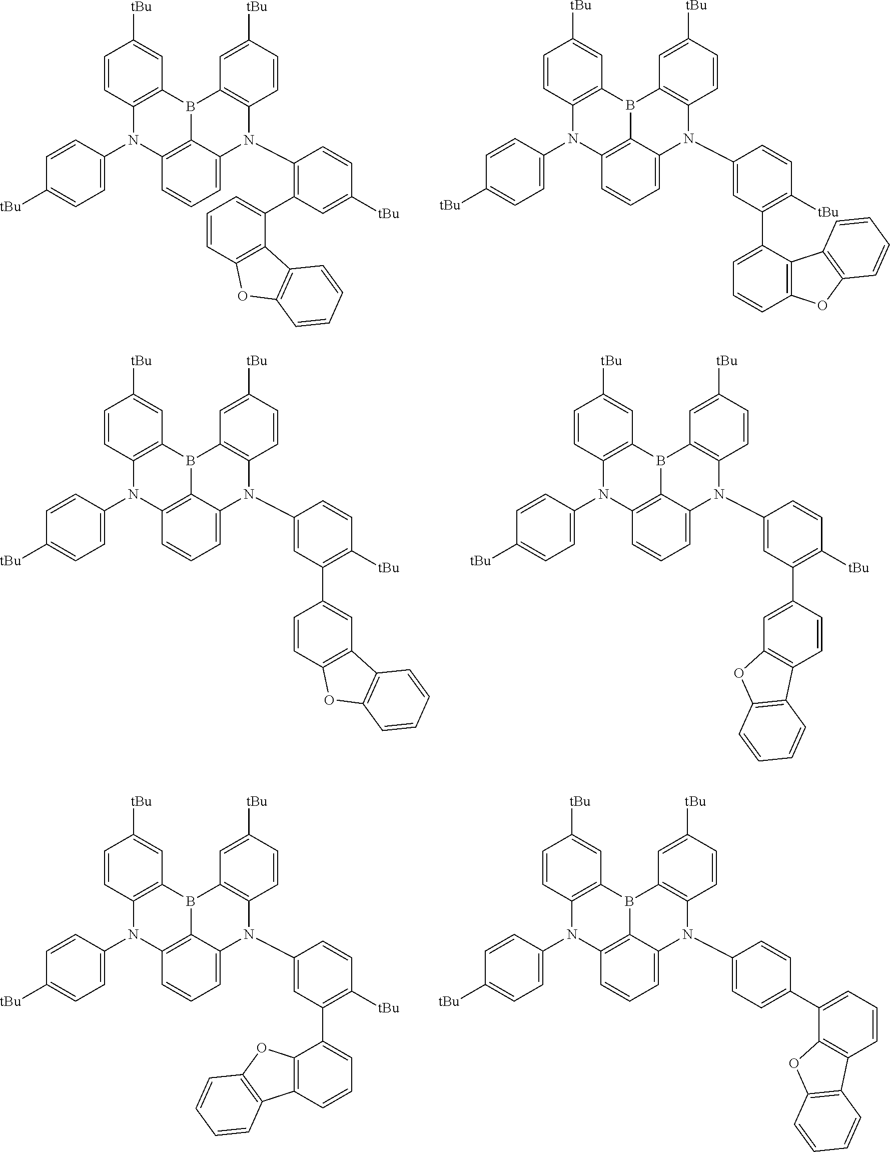

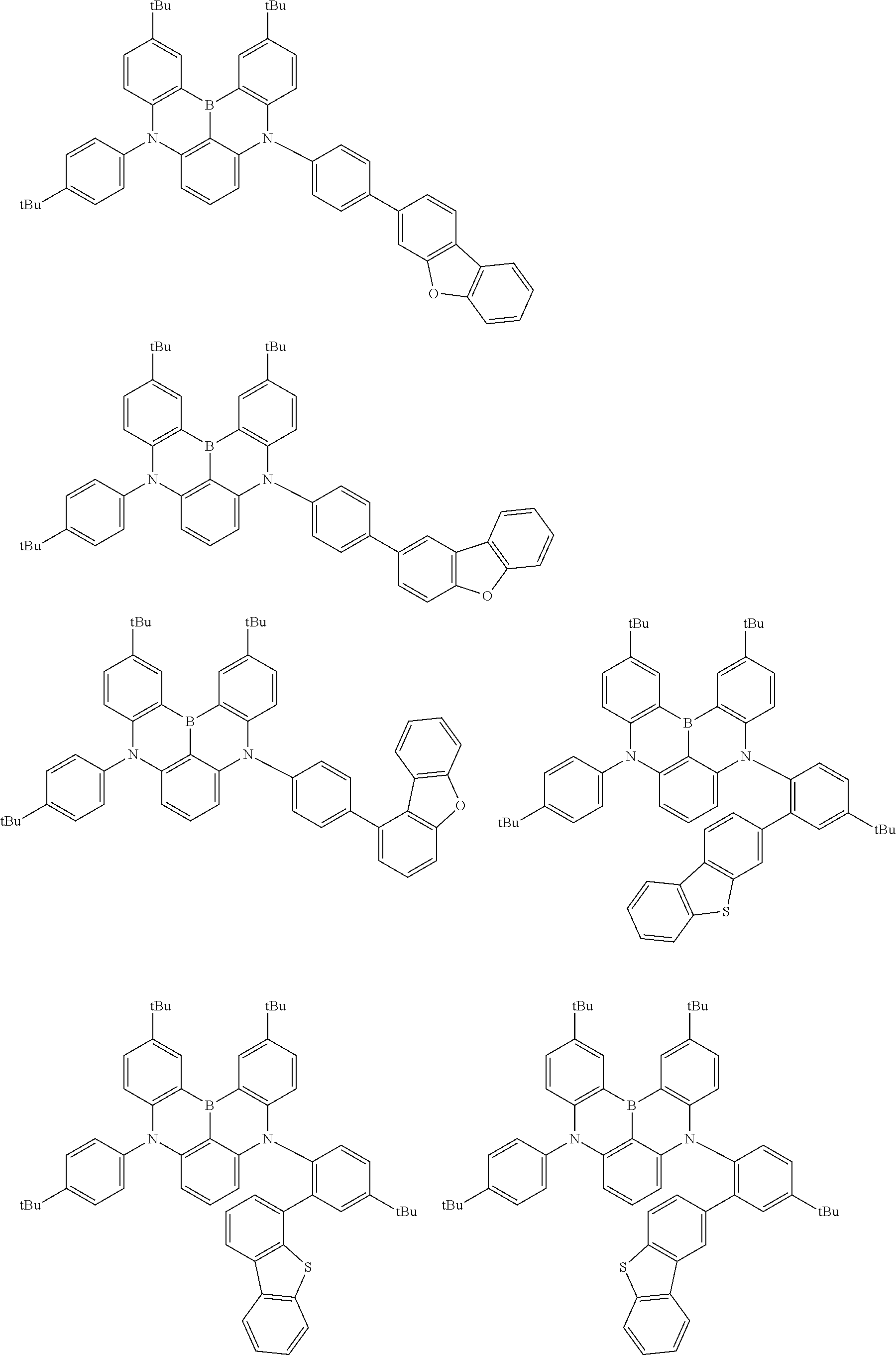

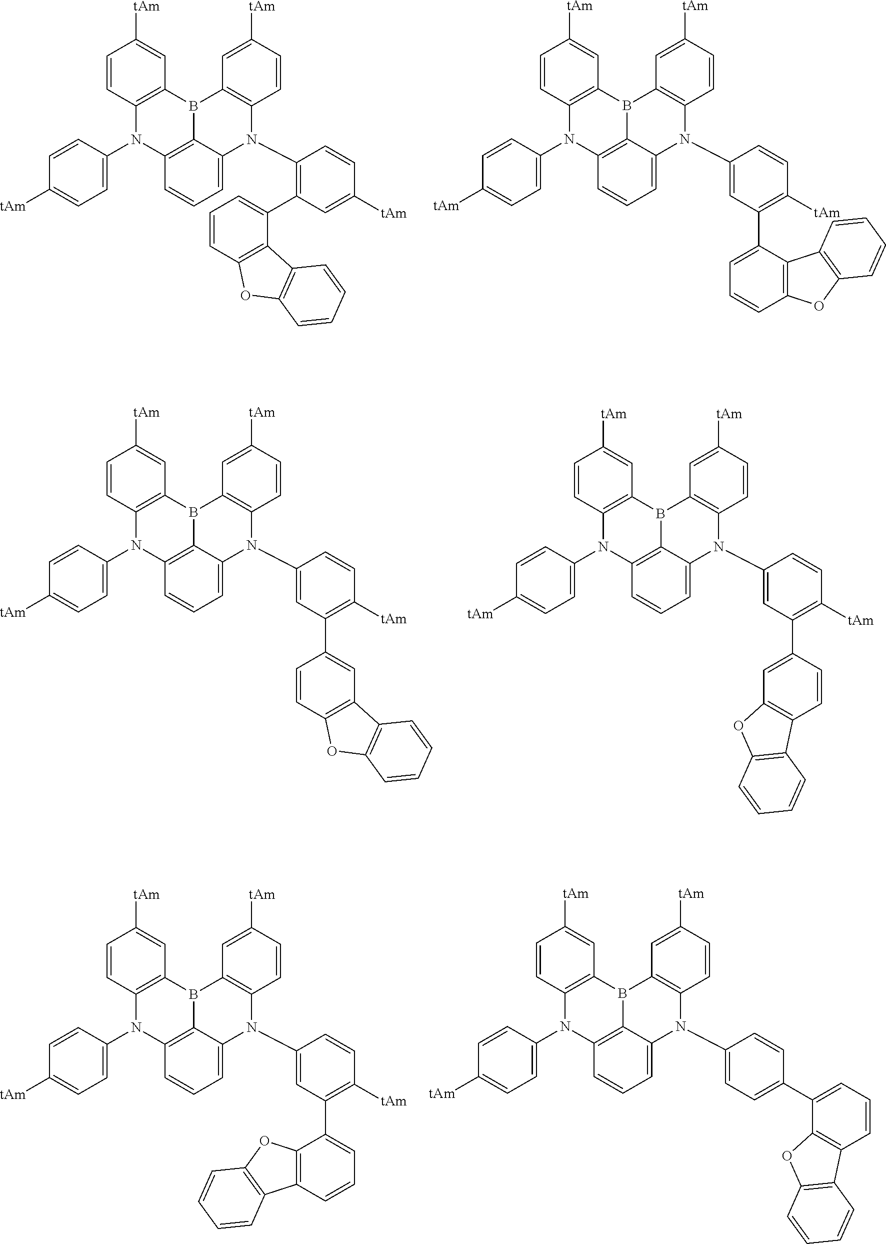

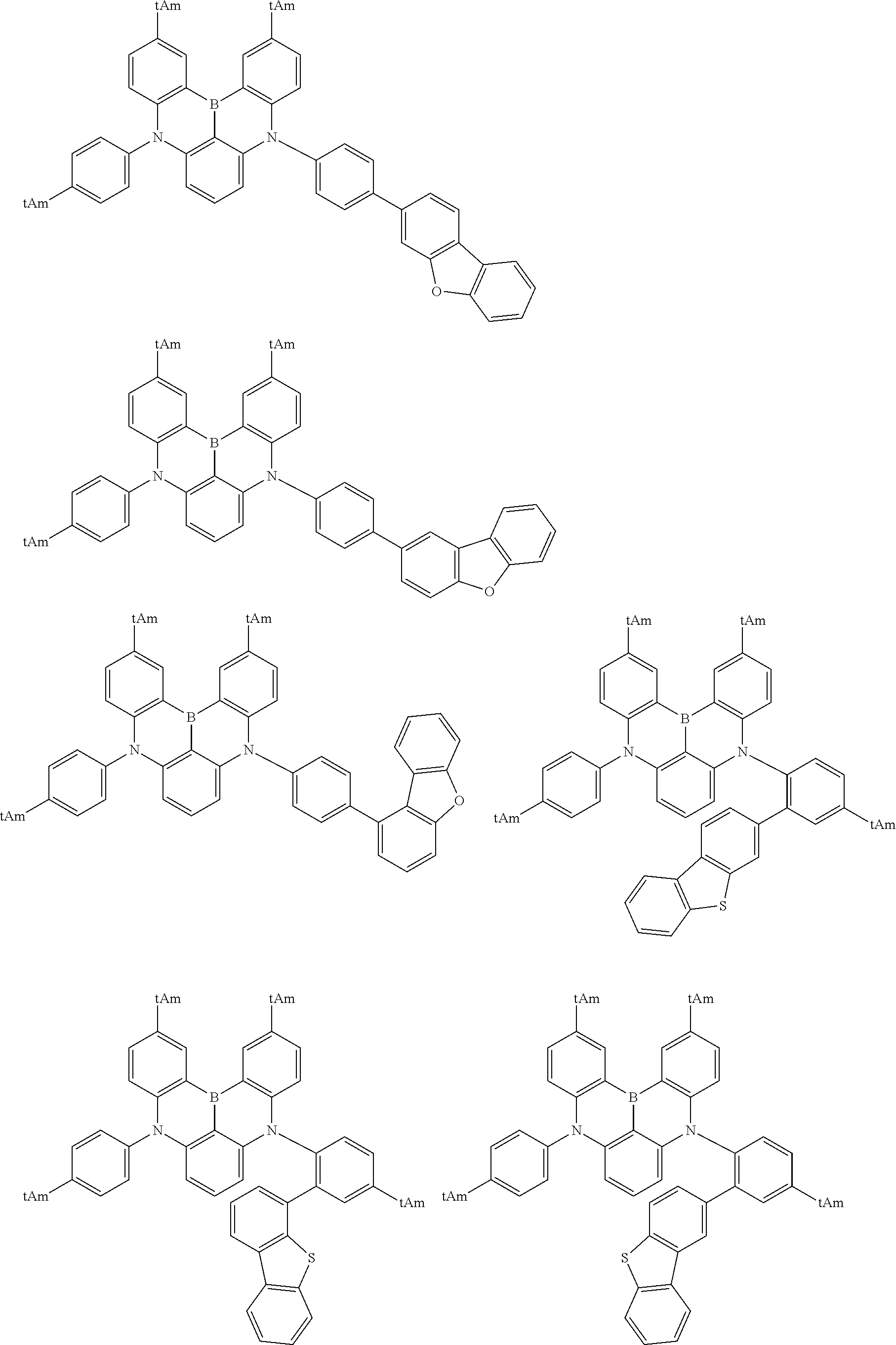

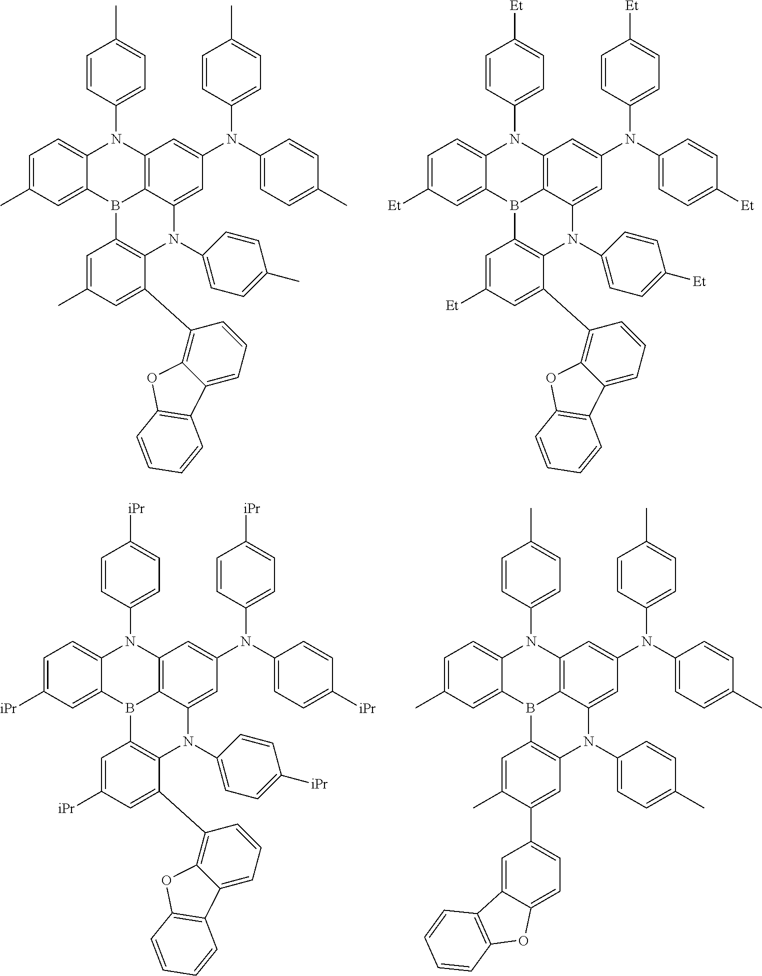

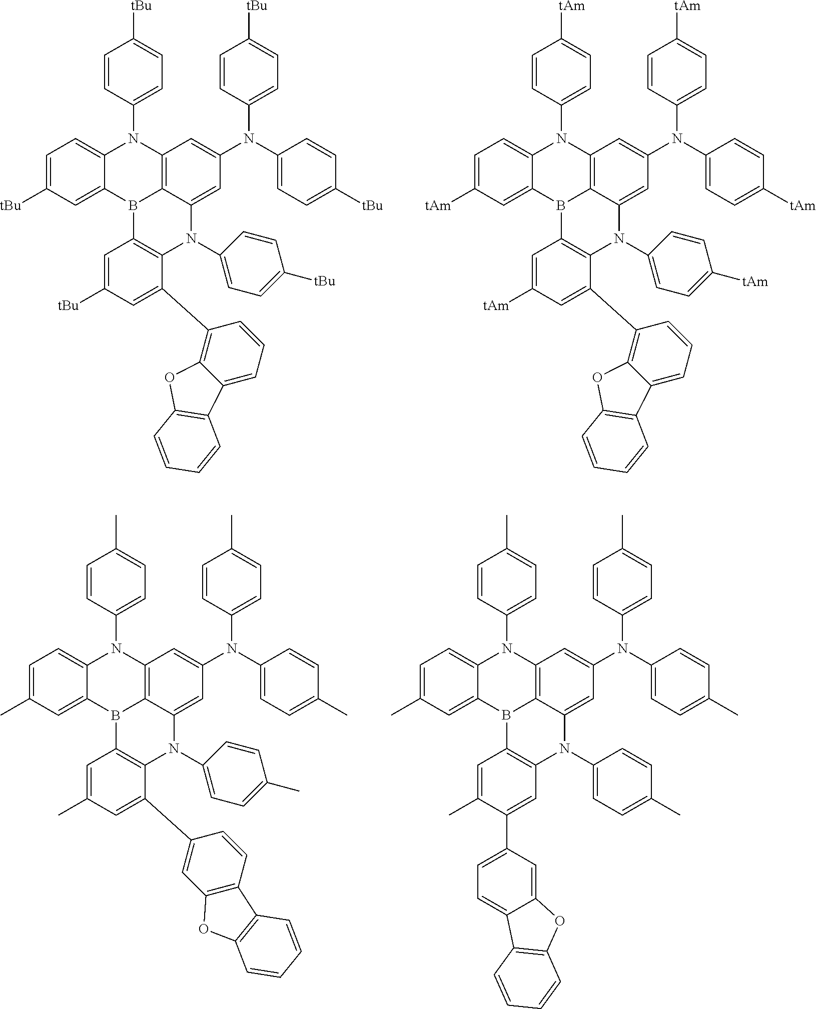

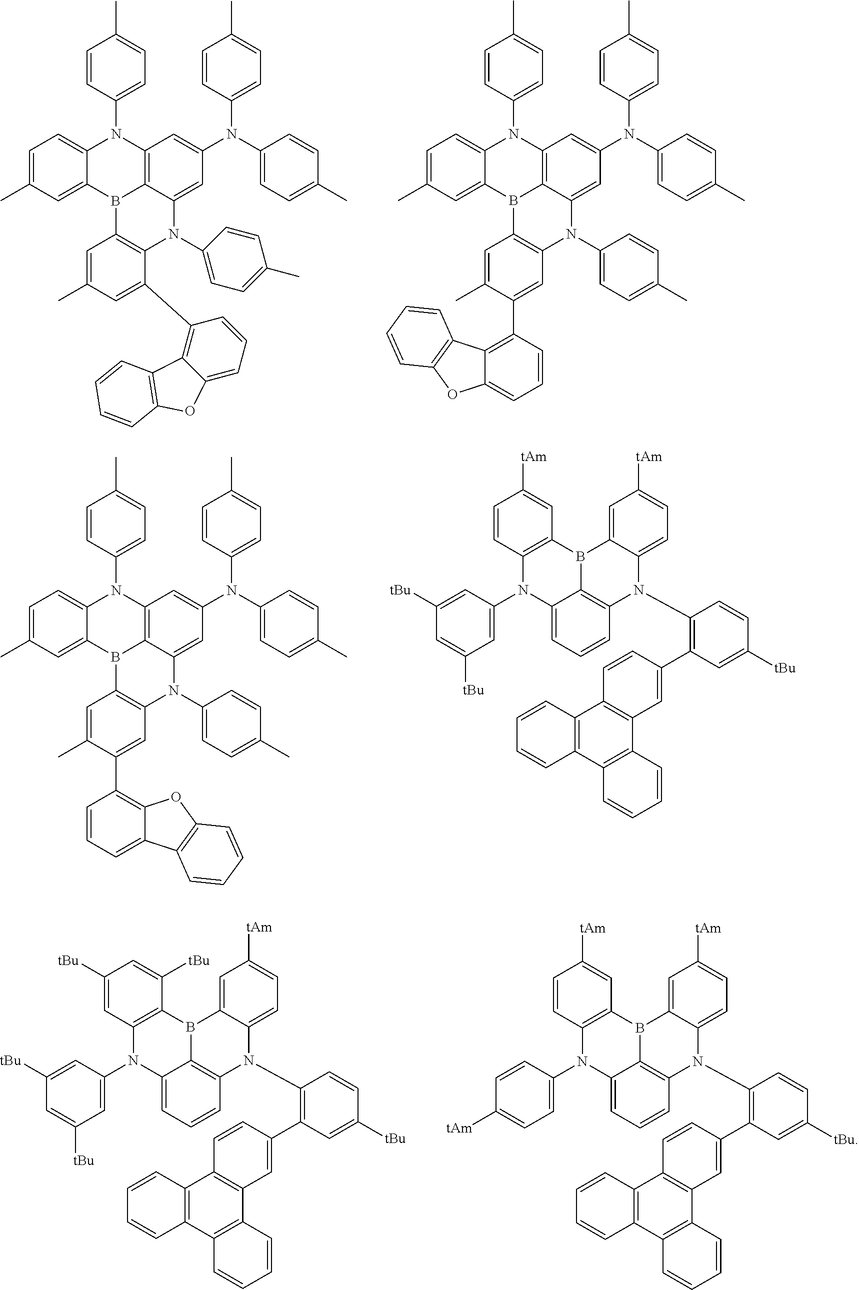

The embodiment of the present application provides the biphenyl-based organic compound containing boron (that is, a boron-nitrogen-based compound), and structures of dibenzofuran, dibenzothiophene, carbazole, a benzoquinary ring, triylene and/or naphthalene are introduced into the boron-nitrogen-based compound, which makes an overall molecular conjugation greater, thereby improving the light-emitting efficiency and service life of the light-emitting element adopting the organic compound. At the same time, an introduction of tetrahydronaphthalene and/or indane in the boron-nitrogen-based compound makes solubility of molecules better in inkjet printing processes, and is conductive to purifying the organic compound, thus improving purity of the organic compound, and further extending the light-emitting efficiency and the service life of the light-emitting element adopting the organic compound.

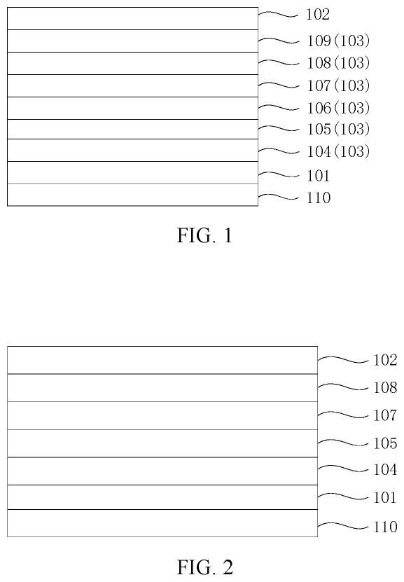

Referring to FIG. 1 and FIG. 2, the present application further provides a light-emitting element. The light-emitting element includes a pair of electrodes including a first electrode 101 and a second electrode 102 and an organic functional layer 103 located between the first electrode 101 and the second electrode 102. Materials of the organic functional layer 103 includes the organic compound described above. The first electrode 101 may be an anode, and the second electrode 102 may be a cathode.

In some embodiments, the light-emitting element may be applied to an organic light-emitting diode, an organic photovoltaic battery, an organic light-emitting battery, an organic field-effect tube, an organic light-emitting field-effect tube, an organic laser, an organic spin electron device, an organic sensor, or an organic plasmon emission diode, etc. In some embodiments, the light-emitting element may be applied to the organic light-emitting diode, the organic light-emitting battery, or the organic light-emitting field-effect tube.

In some embodiments, the light-emitting element may be applied to an electronic device such as a display panel, an illuminating device, or a lighting source, etc.

In some embodiments, the organic functional layer 103 may be a single layer, at this time, the organic functional layer 103 is a mixture layer. The mixture layer includes a first compound and a second compound. The first compound is selected from at least one organic compound described above. The second compound is selected from at least one of a hole injection material, a hole transport material, an electron transport material, a hole blocking material, a light-emitting guest material, a light-emitting host material, and an organic dye. Referring to patent documents of WO2010135519A1, US20090134784A1, and WO2011110277A1 for detailed description of various organic functional materials being included in the organic functional layer 103. All contents of the above-mentioned three patent documents are hereby incorporated into this document for reference.

The light-emitting guest material is selected from a singlet emitter (a fluorescent emitter), a triplet emitter (a phosphorescent emitter), and a thermally activated delayed fluorescence (TADF) material.

When the second compound is selected from at least one of the hole injection material, the hole transport material, the electron transport material, the hole blocking material, the light-emitting host material, and the organic dye, a mass ratio of the first compound to the second compound ranges from (1:99) to (30:70). In some embodiments, the mass ratio ranges from (1:99) to (10:90).

When the second compound is the light-emitting guest material, the mass ratio of the first compound to the second compound ranges from (99:1) to (70:30). In some embodiments, the mass ratio ranges from (99:1) to (90:10).

In some embodiments, the organic functional layer 103 may include multiple layers. When the organic functional layer 103 is multi-layers, the organic functional layer 103 includes at least the light-emitting layer 107. In some embodiments, the organic functional layer 103 includes a hole injection layer 104, a hole transport layer 105, a light-emitting layer 107, an electronic blocking layer 106, an electronic injection layer 109, an electronic transport layer 108, or a hole blocking layer.

In some embodiments, the light-emitting element may be a blue light-emitting element, a green light-emitting element, or a red light-emitting element. The light-emitting layer 107 may include at least one host material and at least one guest material. The guest material is at least one of the organic compounds described above. The host material includes a fused aromatic derivative or a heteroaromatic compound.

A wavelength of light emitted by the light-emitting element ranges from 300 nm to 1000 nm. In some embodiments, the wavelength ranges from 350 nm to 900 nm. In some embodiments, the wavelength ranges from 400 nm to 800 nm. In some embodiments, the wavelength is within a wavelength range of blue light.

In some embodiments, the host material includes at least one of an anthracene derivative, a pyrene derivative, a naphthalene derivative, a pentacene derivative, a phenanthrene compound, a fluoranthene compound, a carbazole derivative, a dibenzofuran derivative, a ladder type furan compound, and a pyrimidine derivative. In some embodiments, the host material is a blue light host material applied to the blue light-emitting element. In some embodiments, when the host material is the blue light host material, the host material is an anthracene-based organic compound.

In some embodiments, a mass ratio of the host material to the guest material ranges from (99:1) to (70:30), such as (90:10), (85:15), (80:20), (75:25), etc. In some embodiments, the mass ratio ranges from (99:1) to (90:10), such as (97:3), (96:4), (95:5), (93:7), (92:8), etc. The guest material is dispersed in the host material, and the mass ratio of the host material to the guest material ranging from (99:1) to (70:30) is conducive to inhibiting crystallization of the light-emitting layer 107 and concentration quenching caused by great concentration of the guest material, thereby improving the light-emitting efficiency of the light-emitting element.

In some embodiments, the anode is an electrode used for injecting holes, and the holes in the anode may be easily injected into the organic functional layer 103. For example, the holes in the anode may be injected into the hole injection layer, the hole transport layer, or the light-emitting layer. Materials of the anode may include at least one of conductive metal, conductive metal oxide, and conductive polymer. In some embodiments, absolute value of a difference between work function of the anode and highest occupied molecular orbital (HOMO) energy level or valence band energy level of a light-emitting material of the light-emitting layer, or a p-type semiconductor material of the hole injection layer, the hole transport layer, or the electron blocking layer is less than 0.5 eV In some embodiments, the above-mentioned absolute value is less than 0.3 eV In some embodiments, the above-mentioned absolute value is less than 0.2 eV Examples of the materials of the anode include but are not limited thereto: aluminum (Al), copper (Cu), aurum (Au), argentum (Ag), magnesium (Mg), ferrum (Fe), cobalt (Co), niccolum (Ni), manganese (Mn), palladium (Pd), platinum (Pt), indium tin oxide (ITO), and aluminum doped zinc oxide (AZO), etc. The materials of the anode may be applied to by any suitable technology, such as a suitable physical vapor deposition method including RF magnetron sputtering, vacuum thermal evaporation, electron beam (e-beam), etc. In some embodiments, the anode is patterned. A patterned ITO conductive substrate is commercially available and may be used to manufacture elements of the present application.

In some embodiments, the cathode is an electrode used for injecting electrons, and the electrons in the cathode may be easily injected into the organic functional layer 103. For example, the electrons in the cathode may be injected into the electron injection layer, the electron transport layer, or the light-emitting layer. Materials of the cathode may include at least one of conductive metal and conductive metal oxide. In some embodiments, absolute value of a difference between work function of the cathode and lowest unoccupied molecular orbital (LUMO) energy level or valence band energy level of the light-emitting material of the light-emitting layer, or a n-type semiconductor material of the electron injection layer, the electron transport layer, or the hole blocking layer is less than 0.5 eV In some embodiments, the above-mentioned absolute value is less than 0.3 eV In some embodiments, the above-mentioned absolute value is less than 0.2 eV All materials that may be used in the cathode of organic electronic devices may be used as materials of the cathode of devices applied for in the present application. The materials of the cathode include, but are not limited thereto: Al, Au, Ag, calcium (Ca), barium (Ba), Mg, LiF/Al, MgAg alloy, BaF₂/Al, Cu, Fe, Co, Ni, Mn, Pd, Pt, ITO, etc. The materials of the cathode may be applied to by any suitable technology, such as a suitable physical vapor deposition method including RF magnetron sputtering, vacuum thermal evaporation, or electron beam (e-beam), etc.

In some embodiments, the hole injection layer 104 is used for promoting an injection of holes from the anode to the light-emitting layer 107. The hole injection layer 104 includes a hole injection material. The hole injection material may be configured to receive holes injected from a positive electrode at low voltages. In some embodiments, HOMO energy level of the hole injection material is between work function of the material of the anode and HOMO energy level of a functional material (such as a hole transport material of the hole transport layer) of a film layer located on a side away from the anode. The hole injection material includes, but are not limited thereto: at least one of metalloporphyrins, oligothiophenes, organic materials based on arylamines, organic materials based on hexacyano hexaazabenzophenanthrene, organic materials based on quinacridone, organic materials based on perylene, anthraquinone, conductive polymers based on polyaniline and polythiophene, etc.

In some embodiments, the hole transport layer 105 may be used for transmitting holes to the light-emitting layer 107. The hole transport layer 105 includes hole transport materials. The hole transport materials are configured to receive holes transmitted from the anode or the hole injection layer and transfer the holes to the light-emitting layer. The hole transport materials are materials with high hole mobility known in the art. The hole transport materials may include, but are not limited thereto: at least one of organic materials based on arylamine, conductive polymer, block copolymer containing both conjugated and non-conjugated portions, etc.

In some embodiments, the electron transport layer 108 is used for transmitting electrons. The electron transport layer 108 includes electron transport materials. The electron transport materials are configured to receive electrons injected from a negative electrode and transfer the electrons to the light-emitting layer 107. The electron transport materials are materials known in the art that have high electron mobility. The electron transport materials may include, but are not limited thereto: at least one of Al-based complexes of 8-hydroxyquinoline, complexes containing Alq₃, organic radical compounds, hydroxyflavone metal complexes, 8-hydroxyquinoline lithium (LiQ), and compounds based on benzimidazole.

In some embodiments, the electron injection layer 109 is used for injecting electrons. The electron injection layer 109 includes electron injection materials. In some embodiments, the electron injection materials are configured to have ability to transmit electrons, an effect of injecting electrons from a negative electrode, an excellent effect of injecting electrons into the light-emitting layer 107 or the light-emitting material, and a function of preventing excitons generated by the light-emitting layer 107 from transferring to the hole injection layer. The electron injection materials further have excellent ability to form thin films. The electron injection materials include, but are not limited thereto: at least one of 8-hydroxyquinoline lithium (LiQ), fluorenone, anthraquinone dimethyl, biphenylquinone, thian dioxide, azole, diazole, triazole, imidazole, perylene tetracarboxylic acid, fluorene methane, anthrone, derivatives of these compounds, metal complexes, nitrogen containing 5-membered ring derivatives, etc.

In some embodiments, the hole blocking layer is used for preventing holes from reaching the negative electrode, and may generally be formed under a same condition as the hole injection layer 104. The hole blocking layer includes hole barrier materials. The hole barrier materials include but are not limited thereto: at least one of a diazole derivative or triazole derivative, phenanthroline derivatives, BCP, aluminum complexes, etc.

In some embodiments, the light-emitting element further includes a substrate 110. The first electrode 101, the hole injection layer 104, the hole transport layer 105, the electronic blocking layer 106, the light-emitting layer 107, the electronic transport layer 108, the electronic injection layer 109, and the second electrode 102 are stacked on the substrate 110 in sequence. The substrate 110 may be a transparent substrate or an opaque substrate. When the substrate 110 is the transparent substrate, a transparent light-emitting element may be provided. In some embodiments, the substrate 110 may be a rigid substrate or a flexible substrate having elasticity. In some embodiments, the substrate is made of plastic, polymer, metal, semiconductor chips, or glass. In some embodiments, the substrate 110 includes at least one smooth surface used for forming the anode on the surface. In some embodiments, the surface is free of surface defects. In some embodiments, the substrate 110 is a polymer film or the substrate 110 is made of plastic, the plastic includes but not limited to polyethylene terephthalate (PET) and polyethylene glycol (2,6-naphthalene) (PEN). A glass transition temperature of the substrate 110 is greater than or equal to 150° C. In some embodiments, the glass transition temperature is greater than or equal to 200° C. In some embodiments, the glass transition temperature is greater than or equal to 250° C. In some embodiments, the glass transition temperature is greater than or equal to 300° C.

In some embodiments, the light-emitting element may be a solution type light-emitting element, that is, at least one of organic functional layers is prepared by a printing process (such as an ink-jet printing process).

In some embodiments, the mixture layer or the light-emitting layer may be formed by a printing process or coating process of composition. The printing process or the coating process includes ink-jet printing, jet printing, letterpress printing, screen printing, dip coating, rotary coating, scraper coating, roller printing, rotary roller printing, lithographic printing, flexographic printing, rotary printing, spraying, brushing printing, pad printing, slot type extrusion coating, etc. In some embodiments, suitable printing process or the coating processes are intaglio printing, jet printing, and ink jet printing.

The composition may be a solution or suspension. The composition may include dispersions and dispersants. The dispersions are at least one of the organic compounds described above, and the dispersants are used for dispersing the dispersions.

In the composition, a mass fraction of the above-mentioned organic compound may range from 0.3% to 30%. In some embodiments, the mass fraction ranges from 0.5% to 20%. In some embodiments, the mass fraction ranges from 0.5% to 15%. In some embodiments, the mass fraction ranges from 0.5% to 10%. In some embodiments, the mass fraction ranges from 1% to 5%.

When the composition is used in the printing process, the composition may be ink. Viscosity and surface tension of the ink are important parameters, and appropriate surface tension of the ink is suitable for specific substrates and specific printing methods. In some embodiments, the surface tension of the ink at an operating temperature or at a temperature of 25° C. ranges from 19 dyne/cm to 50 dyne/cm. In some embodiments, the surface tension ranges from 22 dyne/cm to 35 dyne/cm. In some embodiments, the surface tension ranges from 25 dyne/cm to 33 dyne/cm, which is conductive to applying to the inkjet printing process.

In some embodiments, a Hansen solubility parameter of the dispersants is within following ranges: δd (dispersion force) of the dispersants ranges from 17.0 MPa1/2 to 23.2 MPa1/2, and further ranges from 18.5 MPa1/2 to 21.0 MPa1/2; 6p (polarity force) of the dispersants ranges from 0.2 MPa1/2 to 12.5 MPa1/2, and further ranges from 2.0 MPa1/2 to 6.0 MPa1/2; and δh (hydrogen bonding force) of the dispersants ranges from 0.9 MPa1/2 to 14.2 MPa1/2, and further ranges from 2.0 MPa1/2 to 6.0 MPa1/2.

In some embodiments, a boiling point of the dispersants is greater than or equal to 150° C. In some embodiments, the boiling point is greater than or equal to 180° C. In some embodiments, the boiling point is greater than or equal to 200° C. In some embodiments, the boiling point is greater than or equal to 250° C. In some embodiments, the boiling point is greater than or equal to 275° C. In some embodiments, the boiling point is greater than or equal to 300° C. The boiling point of the dispersants is at least greater than or equal to 150° C., which is conducive to preventing nozzles of the ink jet printing heads from clogging during an ink jet printing process, and a higher the boiling point, the more conducive to preventing clogging.

The dispersants may include at least one organic solvent. The organic solvent may evaporate from a solvent system to form a film containing functional materials. The organic solvent may include at least one first organic solvent, and the first organic solvent may be selected from an aromatic-based and a heteroaromatic-based solvent. In detail, the first organic solvent may be selected from p-diisopropylbenzene, pentyl benzene, tetrahydronaphthalene, cyclohexylbenzene, chloronaphthalene, 1,4-dimethylnaphthalene, 3-isopropylbiphenyl, p-methylisopropyl benzene, dipentyl benzene, tripentyl benzene, pentyl toluene, o-diethylbenzene, m-diethylbenzene, p-diethylbenzene, 1,2,3,4-tetratoluene, 1,2,3,5-tetratoluene, 1,2,4,5-tetratoluene, butadiene benzene, dodecylbenzene, dihexylbenzene, dibutylbenzene, p-diisopropylbenzene, cyclohexylbenzene, benzylbutylbenzene, dimethylnaphthalene, 3-isopropylbiphenyl, p-methylcumene, 1-methylnaphthalene, 1,2,4-trichlorobenzene, 4,4-difluorodiphenylmethane, 1,2-dimethoxy-4-(1-propenyl) benzene, diphenylmethane, 2-phenylpyridine, 3-phenylpyridine, N-methyldiphenylamine, 4-isopropylbiphenyl, α, α-dichlorodiphenylmethane, 4-(3-phenylpropyl) pyridine, benzyl benzoate, 1,1-bis(3,4-dimethylphenyl) ethane, 2-isopropylnaphthalene, quinoline, isoquinoline, methyl 2-furanoate, ethyl 2-furanoate, etc.

The first organic solvent may be selected from aromatic ketone-based solvents. In detail, the first organic solvent may be selected from 1-tetrahydronaphthalenone, 2-tetrahydronaphthalenone, 2-(phenyl epoxy) tetrahydronaphthalenone, 6-(methoxy) tetrahydronaphthalenone, acetophenone, phenylacetone, benzophenone, and derivatives of these compounds, such as 4-methylacetophenone, 3-methylacetophenone, 2-methylacetophenone, 4-methylphenylacetone, 3-methylphenylacetone, and 2-methylphenylacetone.

The first organic solvent may be selected from aromatic ether-based solvent. In detail, the first organic solvent may be selected from 3-phenoxytoluene, butoxybenzene, p-anisaldehyde dimethyl acetal, tetrahydro-2-phenoxy-2H-pyran, 1,2-dimethoxy-4-(1-propenyl) benzene, 1,4-benzodioxane, 1,3-dipropylbenzene, 2,5-dimethoxytoluene, 4-ethylbasic ether, 1,3-dipropoxybenzene, 1,2,4-trimethoxybenzene, 4-(1-propenyl)-1,2-dimethoxybenzene, 1,3-dimethoxybenzene, glycidyl phenyl ether, dibenzyl ether, 4-tert-butyl anisole, trans-p-propenylanisole, 1,2-dimethoxybenzene, 1-methoxynaphthalene, diphenyl ether, 2-phenoxymethyl ether, 2-phenoxytetrahydrofuran, and ethyl-2-naphthyl ether.

The first organic solvent may be selected from aliphatic ketones. In detail, the first organic solvent may be selected from 2-nonone, 3-nonone, 5-nonone, 2-decanone, 2,5-hexanedione, 2,6,8-trimethyl-4-nonone, fenone, phorone, isophorone, and di-n-pentyl ketone, and aliphatic ether, such as amyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, and tetraethylene glycol dimethyl ether.

The first organic solvent may be selected from organic ester-based solvent. In detail, the first solvent may be selected from octanoate, sebacate, stearate, benzoate, phenylacetate, cinnamate, oxalate, maleate, alkyl lactone, oleate, etc. In some embodiments, the ester-based solvents may be selected from octyl octanoate, diethyl sebacate, diallyl phthalate, and isononyl isononanoate.

The organic solvent may further include a second organic solvent. The second organic solvent may be selected from at least one of methanol, ethanol, 2-methoxyethanol, dichloromethane, chloroform, chlorobenzene, o-dichlorobenzene, tetrahydrofuran, anisole, morpholine, toluene, o-xylene, m-xylene, p-xylene, 1,4-dioxane, acetone, methyl ethyl ketone, 1,2-dichloroethane, 3-phenoxytoluene, 1,1,1-trichloroethane, 1,1,2,2-tetrachloroethane, ethyl acetate, butyl acetate, dimethylformamide, dimethylacetamide, dimethyl sulfoxide, tetralin, naphthane, and indene.

In addition to the dispersions and the dispersants described above, the composition may further include at least one component, such as surfactant, lubricant, wetting agent, dispersant, hydrophobic agent, adhesive, etc., which may be used for adjusting viscosity, forming performance of films, and improving adhesion, etc.

Exemplary manufacturing methods of the organic compound provided by the present application are shown in following exemplary embodiment 1 to embodiment 20.

### Embodiment 1

### Synthesis of Organic Compound M1

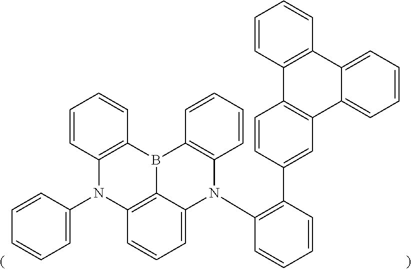 [SMILES: c1ccc(N2c3ccccc3B3c4ccccc4N(c4ccccc4-c4ccc5c6ccccc6c6ccccc6c5c4)c4cccc2c43)cc1]

Synthetic Route of the Organic Compound M1 is as following:

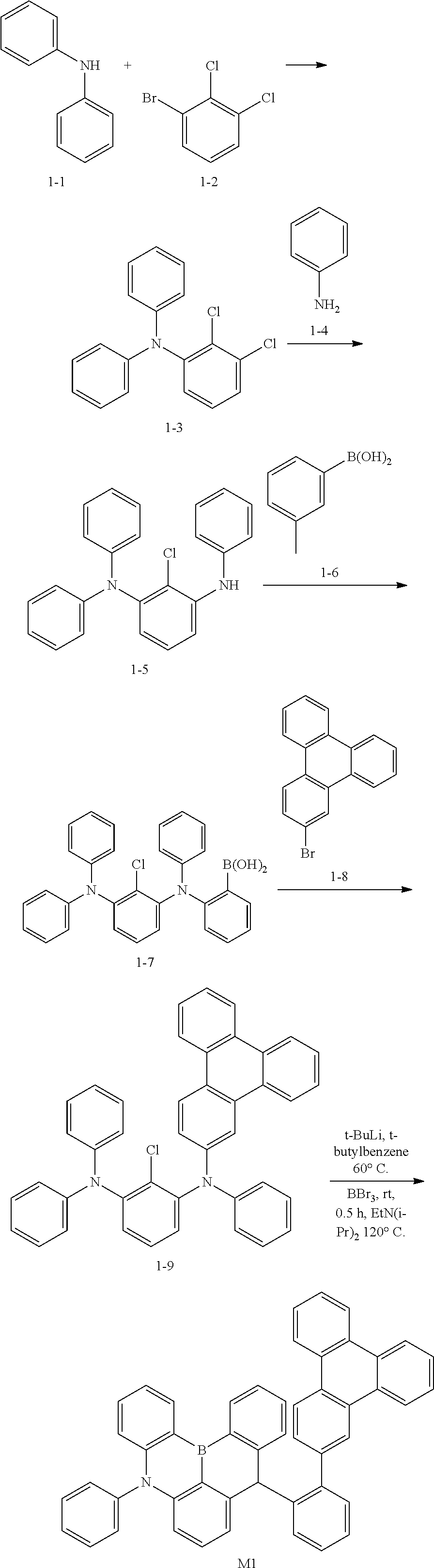

Specific synthesis steps of the organic compound M1 are as following:

(1) Synthesis of intermediate compound 1-3:
dissolve 10 mmol of compound 1-1, 10 mmol of compound 1-2, 0.1 mmol of palladium dibenzylidene acetone (Pd(dba)₂), 0.2 mmol of tri tert butyl phosphine (TTBP), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 7.22 mmol of the intermediate compound 1-3. A yield is 72.2%. A result of atmospheric solids analysis probe-mass spectrometry (ASAP-MS) of the intermediate compound 1-3 is as following: MS (ASAP)=313.

(2) Synthesis of intermediate compound 1-5:
dissolve 10 mmol of the intermediate compound 1-3, 10 mmol of compound 1-4, 0.1 mmol of bis (di tert butyl-4-dimethylaminophenyl phosphine) palladium chloride (Pd-132), 0.2 mmol of 2-dicyclohexylphosphine-2′,6′-dimethoxy-1,1′-biphenyl (S-Phos), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 6.18 mmol of the intermediate compound 1-5. A yield is 61.8%. A result of ASAP-MS of the intermediate compound 1-5 is as following: MS (ASAP)=370.

(3) Synthesis of intermediate compound 1-7:
dissolve 10 mmol of the intermediate compound 1-5, 10 mmol of compound 1-6, 0.1 mmol of Pd₂(dba)₃, 0.2 mmol of 2-dicyclohexylphosphine-2′, 6′-dimethoxy-1,1′-biphenyl (S-Phos), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 5.89 mmol of the intermediate compound 1-7. A yield is 58.9%. A result of ASAP-MS of the intermediate compound 1-7 is as following: MS (ASAP)=490.

(4) Synthesis of intermediate compound 1-9:
dissolve 10 mmol of the intermediate compound 1-7 and 10 mmol of compound 1-8 in mixed solvents of 1,4-dioxane and water (21 mL:2 mL). Add 0.1 mmol of Pd(PPh₃)₄ and 30 mmol of potassium carbonate. After cooling, rotary evaporate the solution to remove most of the solvents. Then extract the solution, wash with water, and purify the organic phase in column chromatography to obtain 6.11 mmol of the intermediate compound 1-9. A yield is 61.1%. A result of ASAP-MS of the intermediate compound 1-9 is as following: MS (ASAP)=672.

(5) Synthesis of the organic compound M1:
add 10 mmol of the intermediate compound 1-9 and 100 mL of dry tert butyl benzene into a three necked flask (250 mL). Cool the solution to a temperature of −30° C. in nitrogen atmosphere. Add n-hexane solution of 21 mmol of tert butyl lithium (t-BuLi) dropwise to the solution. Raise the temperature of the solution to 60° C., react for 2 hours, and then evaporate n-hexane of the n-hexane solution under reduced pressure. Cool the reaction solution to a temperature of −30° C. again. Add 21 mmol of boron tribromide. Raise the temperature of the reaction solution to room temperature and stir it for 0.5 hour. Then cool the reaction solution to a temperature of 0° C. Add 42 mmol of N, N-diisopropylethylamine. After dropping, raise the temperature of the reaction solution to room temperature and stir it. Then continue to raise the temperature of the reaction solution to 120° C. and stir it for 3 hours. Cool the reaction solution to room temperature. Add sodium carbonate aqueous solution and ethyl acetate for quenching reaction. Extract aqueous phase with ethyl acetate, and combine organic phase. Rotary evaporate the organic phase to remove solvent to obtain crude product. Purify the crude product with silica gel column to obtain pure product. Recrystallize the pure product with toluene and ethyl acetate to obtain light yellow solid powder, namely the organic compound M1. A yield is 41.5%. A result of ASAP-MS of the organic compound M1 is as following: MS (ASAP)=646.

### Embodiment 2

### Synthesis of Organic Compound M2

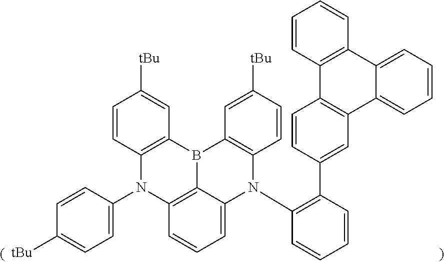 [SMILES: CC(C)(C)c1ccc(N2c3ccc(C(C)(C)C)cc3B3c4cc(C(C)(C)C)ccc4N(c4ccccc4-c4ccc5c6ccccc6c6ccccc6c5c4)c4cccc2c43)cc1]

Synthetic Route of the Organic Compound M2 is as following:

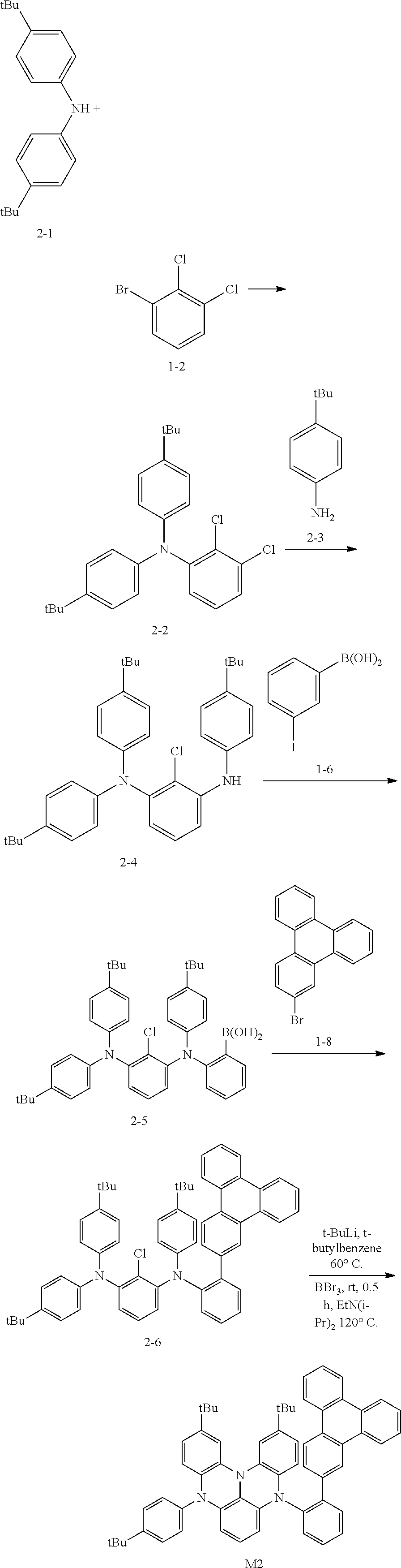

Specific synthesis steps of the organic compound M2 are as following:

(1) Synthesis of intermediate compound 2-2:
dissolve 10 mmol of compound 2-1, 10 mmol of compound 1-2, 0.1 mmol of palladium dibenzylidene acetone (Pd(dba)₂), 0.2 mmol of tri tert butyl phosphine (TTBP), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 8.17 mmol of the intermediate compound 2-2. A yield is 81.7%. A result of ASAP-MS of the intermediate compound 2-2 is as following: MS (ASAP)=425.

(2) Synthesis of intermediate compound 2-4:
dissolve 10 mmol of the intermediate compound 2-2, 10 mmol of compound 2-3, 0.1 mmol of bis (di tert butyl-4-dimethylaminophenyl phosphine) palladium chloride (Pd-132), 0.2 mmol of 2-dicyclohexylphosphine-2′,6′-dimethoxy-1,1′-biphenyl (S-Phos), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 5.91 mmol of the intermediate compound 2-4. A yield is 59.1%. A result of ASAP-MS of the intermediate compound 2-4 is as following: MS (ASAP)=538.

(3) Synthesis of intermediate compound 2-5:
dissolve 10 mmol of the intermediate compound 2-4, 10 mmol of compound 1-6, 0.1 mmol of Pd₂(dba)₃, 0.2 mmol of 2-dicyclohexylphosphine-2′,6′-dimethoxy-1,1′-biphenyl (S-Phos), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 5.11 mmol of the intermediate compound 2-5. A yield is 51.1%. A result of ASAP-MS of the intermediate compound 2-5 is as following: MS (ASAP)=658.

(4) Synthesis of intermediate compound 2-6:
dissolve 10 mmol of the intermediate compound 2-5 and 10 mmol of the compound 1-8 in mixed solvents of 1,4-dioxane and water (21 mL:2 mL). Add 0.1 mmol of Pd(PPh₃)₄ and 30 mmol of potassium carbonate. In nitrogen atmosphere, stir the solution at a temperature of 100° C. for 6 hours. After cooling, rotary evaporate the solution to remove most of the solvents. Then extract the solution, wash with water, and purify the organic phase in column chromatography and recrystallize it to obtain 6.57 mmol of the intermediate compound 2-6. A yield is 65.7%. A result of ASAP-MS of the intermediate compound 2-6 is as following: MS (ASAP)=840.

(5) Synthesis of the organic compound M2:
add 10 mmol of the intermediate compound 2-6 and 100 mL of dry tert butyl benzene into a three necked flask (250 mL). Cool the solution to a temperature of −30° C. in nitrogen atmosphere. Add n-hexane solution of 21 mmol of tert butyl lithium (t-BuLi) dropwise to the solution. Raise the temperature of the solution to 60° C., react for 2 hours, and then evaporate n-hexane of the n-hexane solution under reduced pressure. Cool the reaction solution to a temperature of −30° C. again. Add 21 mmol of boron tribromide. Raise the temperature of the reaction solution to room temperature and stir it for 0.5 hour. Then cool the reaction solution to a temperature of 0° C. Add 42 mmol of N, N-diisopropylethylamine. After dropping, raise the temperature of the reaction solution to room temperature and stir it. Then continue to raise the temperature of the reaction solution to 120° C. and stir it for 3 hours. Cool the reaction solution to room temperature. Add sodium carbonate aqueous solution and ethyl acetate for quenching reaction. Extract aqueous phase with ethyl acetate, and combine organic phase. Rotary evaporate the organic phase to remove solvent to obtain crude product. Purify the crude product with silica gel column to obtain pure product. Recrystallize the pure product with toluene and ethyl acetate to obtain light yellow solid powder, namely the organic compound M2. A yield is 30.8%. A result of ASAP-MS of the organic compound M2 is as following: MS (ASAP)=814.

### Embodiment 3

### Synthesis of Organic Compound M3

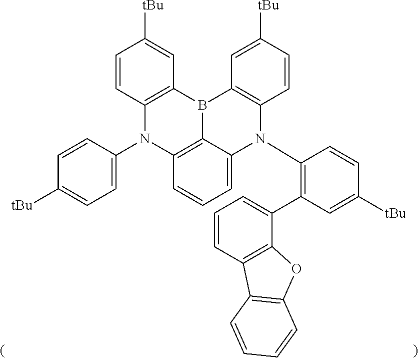 [SMILES: CC(C)(C)c1ccc(N2c3ccc(C(C)(C)C)cc3B3c4cc(C(C)(C)C)ccc4N(c4ccc(C(C)(C)C)cc4-c4cccc5c4oc4ccccc45)c4cccc2c43)cc1]

Synthetic Route of the Organic Compound M3 is as following:

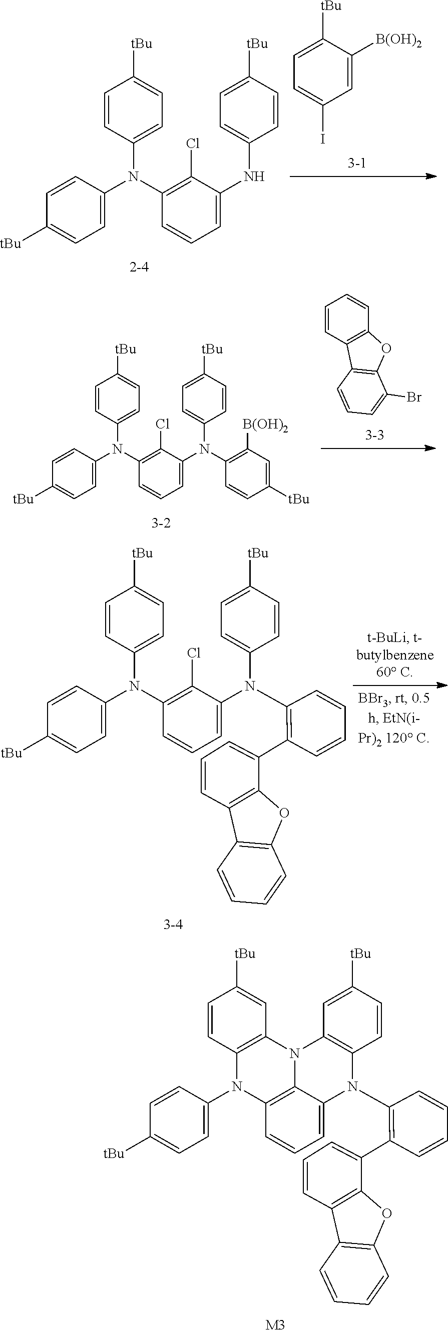

Specific synthesis steps of the organic compound M3 are as following:

(1) Synthesis of intermediate compound 3-2:
dissolve 10 mmol of the intermediate compound 2-4, 10 mmol of compound 3-1, 0.1 mmol of Pd₂(dba)₃, 0.2 mmol of 2-dicyclohexylphosphine-2′,6′-dimethoxy-1,1′-biphenyl (S-Phos), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 5.86 mmol of the intermediate compound 3-2. A yield is 58.6%. A result of ASAP-MS of the intermediate compound 3-2 is as following: MS (ASAP)=714.

(2) Synthesis of intermediate compound 3-4:
dissolve 10 mmol of the intermediate compound 3-2 and 10 mmol of compound 3-3 in mixed solvents of 1,4-dioxane and water (21 mL:2 mL). Add 0.1 mmol of Pd(PPh₃)₄ and 30 mmol of potassium carbonate. In nitrogen atmosphere, stir the solution at a temperature of 100° C. for 6 hours. After cooling, rotary evaporate the solution to remove most of the solvents. Then extract the solution, wash with water, and purify the organic phase in column chromatography and recrystallize it to obtain 5.41 mmol of the intermediate compound 3-4. A yield is 54.1%. A result of ASAP-MS of the intermediate compound 3-4 is as following: MS (ASAP)=836.

(3) Synthesis of the organic compound M3:
add 10 mmol of the intermediate compound 3-4 and 100 mL of dry tert butyl benzene into a three necked flask (250 mL). Cool the solution to a temperature of −30° C. in nitrogen atmosphere. Add n-hexane solution of 21 mmol of tert butyl lithium (t-BuLi) dropwise to the solution. Raise the temperature of the solution to 60° C., react for 2 hours, and then evaporate n-hexane of the n-hexane solution under reduced pressure. Cool the reaction solution to a temperature of −30° C. again. Add 21 mmol of boron tribromide. Raise the temperature of the reaction solution to room temperature and stir it for 0.5 hour. Then cool the reaction solution to a temperature of 0° C. Add 42 mmol of N, N-diisopropylethylamine. After dropping, raise the temperature of the reaction solution to room temperature and stir it. Then continue to raise the temperature of the reaction solution to 120° C. and stir it for 3 hours. Cool the reaction solution to room temperature. Add sodium carbonate aqueous solution and ethyl acetate for quenching reaction. Extract aqueous phase with ethyl acetate, and combine organic phase. Rotary evaporate the organic phase to remove solvent to obtain crude product. Purify the crude product with silica gel column to obtain pure product. Recrystallize the pure product with toluene and ethyl acetate to obtain light yellow solid powder, namely the organic compound M3. A yield is 37.8%. A result of ASAP-MS of the organic compound M3 is as following: MS (ASAP)=810.

### Embodiment 4

### Synthesis of Organic Compound M4

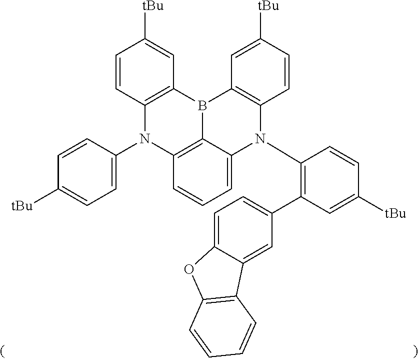 [SMILES: CC(C)(C)c1ccc(N2c3ccc(C(C)(C)C)cc3B3c4cc(C(C)(C)C)ccc4N(c4ccc(C(C)(C)C)cc4-c4ccc5oc6ccccc6c5c4)c4cccc2c43)cc1]

Synthetic Route of the Organic Compound M4 is as following:

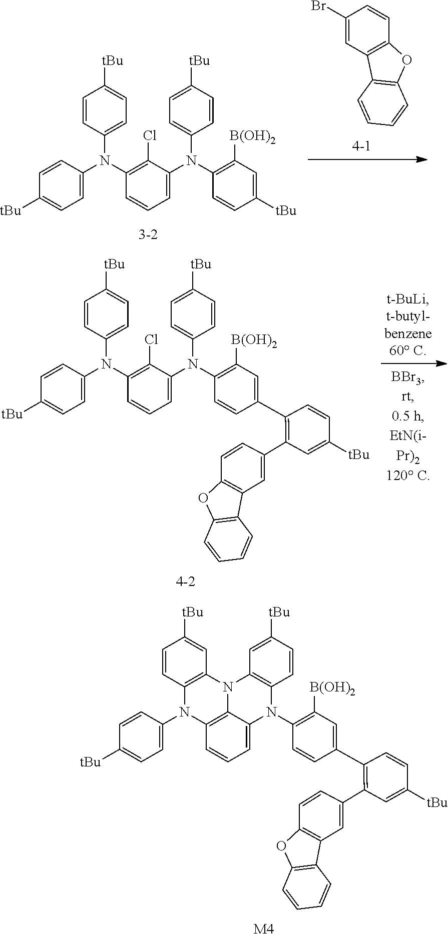 [SMILES: CC(C)(C)c1ccc(N(c2ccc(C(C)(C)C)cc2)c2cccc(N(c3ccc(C(C)(C)C)cc3)c3ccc(C(C)(C)C)cc3B(O)O)c2Cl)cc1 ; Brc1ccc2oc3ccccc3c2c1 ; CC(C)(C)c1ccc(N(c2ccc(C(C)(C)C)cc2)c2cccc(N(c3ccc(C(C)(C)C)cc3)c3ccc(-c4ccc(C(C)(C)C)cc4-c4ccc5oc6ccccc6c5c4)cc3B(O)O)c2Cl)cc1 ; CC(C)(C)c1ccc(N2c3ccc(C(C)(C)C)cc3N3c4cc(C(C)(C)C)ccc4N(c4ccc(-c5ccc(C(C)(C)C)cc5-c5ccc6oc7ccccc7c6c5)cc4B(O)O)c4cccc2c43)cc1 ; "M4"]

Specific synthesis steps of the organic compound M4 are as following:

(1) Synthesis of intermediate compound 4-2:
dissolve 10 mmol of the intermediate compound 3-2 and 10 mmol of compound 4-1 (10 mmol) in mixed solvents of 1,4-dioxane and water (21 mL: 2 mL). Add 0.1 mmol of Pd(PPh₃)₄ and 30 mmol of potassium carbonate. In nitrogen atmosphere, stir the solution at a temperature of 100° C. for 6 hours. After cooling, rotary evaporate the solution to remove most of the solvents. Then extract the solution, wash with water, and purify the organic phase in column chromatography and recrystallize it to obtain 6.23 mmol of the intermediate compound 4-2. A yield is 62.3%. A result of ASAP-MS of the intermediate compound 4-2 is as following: MS (ASAP)=836.

(2) Synthesis of the organic compound M4:
add 10 mmol of the intermediate compound 4-2 and 100 mL of dry tert butyl benzene into a three necked flask (250 mL). Cool the solution to a temperature of −30° C. in nitrogen atmosphere. Add n-hexane solution of 21 mmol of tert butyl lithium (t-BuLi) dropwise to the solution. Raise the temperature of the solution to 60° C., react for 2 hours, and then evaporate n-hexane of the n-hexane solution under reduced pressure. Cool the reaction solution to a temperature of −30° C. again. Add 21 mmol of boron tribromide. Raise the temperature of the reaction solution to room temperature and stir it for 0.5 hour. Then cool the reaction solution to a temperature of 0° C. Add 42 mmol of N, N-diisopropylethylamine. After dropping, raise the temperature of the reaction solution to room temperature and stir it. Then continue to raise the temperature of the reaction solution to 120° C. and stir it for 3 hours. Cool the reaction solution to room temperature. Add sodium carbonate aqueous solution and ethyl acetate for quenching reaction. Extract aqueous phase with ethyl acetate, and combine organic phase. Rotary evaporate the organic phase to remove solvent to obtain crude product. Purify the crude product with silica gel column to obtain pure product. Recrystallize the pure product with toluene and ethyl acetate to obtain light yellow solid powder, namely the organic compound M4. A yield is 42.9%. A result of ASAP-MS of the organic compound M4 is as following: MS (ASAP)=810.

### Embodiment 5

### Synthesis of Organic Compound M5

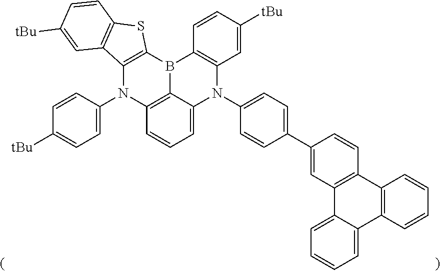 [SMILES: CC(C)(C)c1ccc(N2c3cccc4c3B(c3ccc(C(C)(C)C)cc3N4c3ccc(-c4ccc5c6ccccc6c6ccccc6c5c4)cc3)c3sc4ccc(C(C)(C)C)cc4c32)cc1]

Synthetic Route of the Organic Compound M5 is as following:

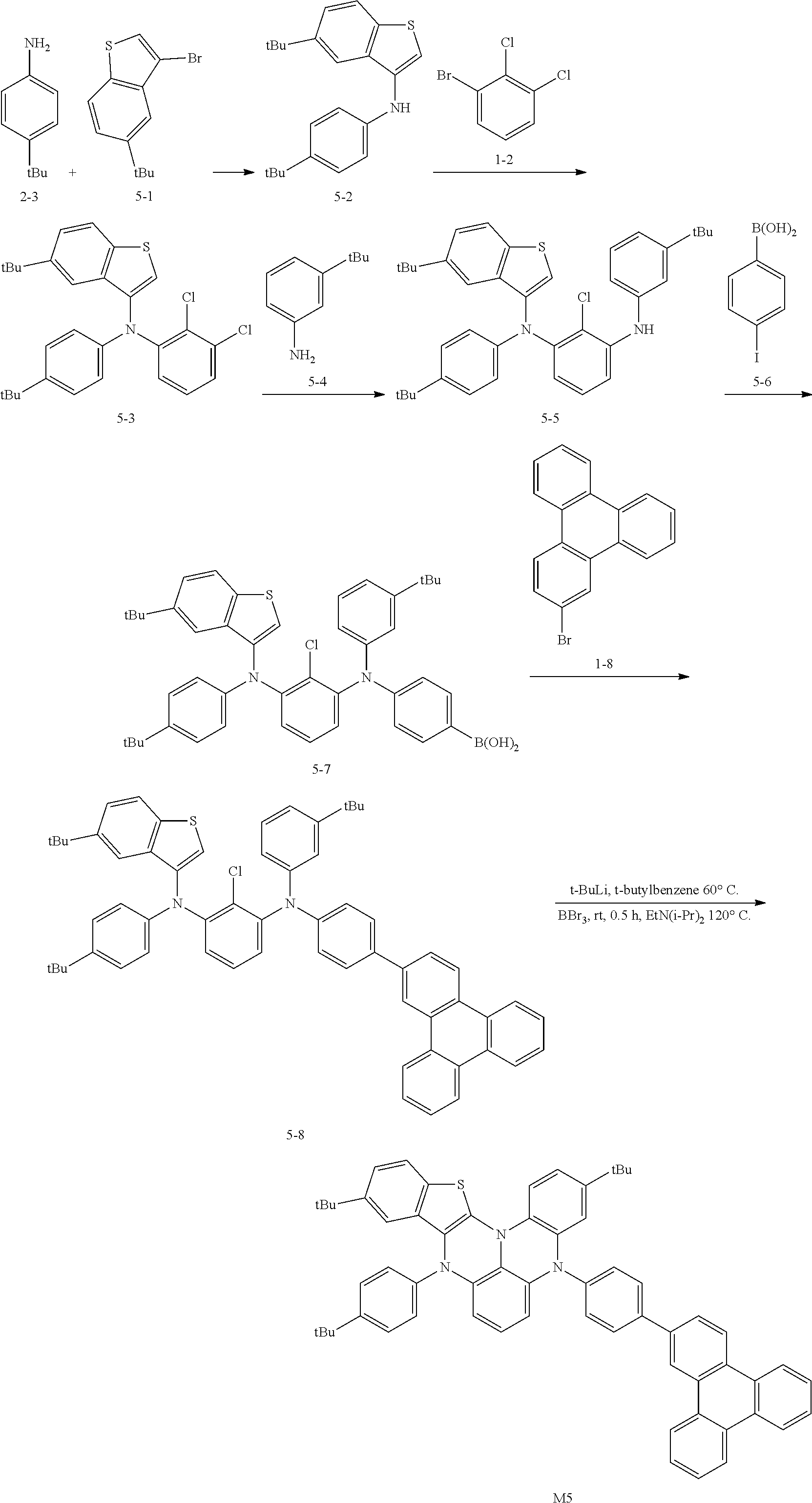

Specific synthesis steps of the organic compound M5 are as following:

(1) Synthesis of intermediate compound 5-2:
dissolve 10 mmol of compound 5-1, 10 mmol of the compound 2-3, 0.1 mmol of palladium dibenzylidene acetone (Pd(dba)₂), 0.2 mmol of tri tert butyl phosphine (TTBP), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 8.09 mmol of the intermediate compound 5-2. A yield is 80.9%. A result of ASAP-MS of the intermediate compound 5-2 is as following: MS (ASAP)=337.

(2) Synthesis of intermediate compound 5-3:
dissolve 10 mmol of the intermediate compound 5-2, 10 mmol of the compound 1-2, 0.1 mmol of palladium dibenzylidene acetone (Pd(dba)₂), 0.2 mmol of tri tert butyl phosphine (TTBP), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 7.13 mmol of the intermediate compound 5-3. A yield is 71.3%. A result of ASAP-MS of the intermediate compound 5-3 is as following: MS (ASAP)=481.

(3) Synthesis of intermediate compound 5-5:
dissolve 10 mmol of the intermediate compound 5-3, 10 mmol of compound 5-4, 0.1 mmol of bis (di tert butyl-4-dimethylaminophenyl phosphine) palladium chloride (Pd-132), 0.2 mmol of 2-dicyclohexylphosphine-2′,6′-dimethoxy-1,1′-biphenyl (S-Phos), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 5.29 mmol of the intermediate compound 5-5. A yield is 52.9%. A result of ASAP-MS of the intermediate compound 5-5 is as following: MS (ASAP)=594.

(4) Synthesis of intermediate compound 5-7:
dissolve 10 mmol of the intermediate compound 5-5, 10 mmol of compound 5-6, 0.1 mmol of Pd₂(dba)₃, 0.2 mmol of 2-dicyclohexylphosphine-2′,6′-dimethoxy-1,1′-biphenyl (S-Phos), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 5.28 mmol of the intermediate compound 5-7. A yield is 52.8%. A result of ASAP-MS of the intermediate compound 5-7 is as following: MS (ASAP)=714.

(5) Synthesis of intermediate compound 5-8:
dissolve 10 mmol of the intermediate compound 5-7 and 10 mmol of the compound 1-8 in mixed solvents of 1,4-dioxane and water (21 mL:2 mL). Add 0.1 mmol of Pd(PPh₃)₄ and 30 mmol of potassium carbonate. After cooling, rotary evaporate the solution to remove most of the solvents. Then extract the solution, wash with water, and purify the organic phase in column chromatography to obtain 6.35 mmol of the intermediate compound 5-8. A yield is 63.5%. A result of ASAP-MS of the intermediate compound 5-8 is as following: MS (ASAP)=896.

(6) Synthesis of the organic compound M5:
add 10 mmol of the intermediate compound 5-8 and 100 mL of dry tert butyl benzene into a three necked flask (250 mL). Cool the solution to a temperature of −30° C. in nitrogen atmosphere. Add n-hexane solution of 21 mmol of tert butyl lithium (t-BuLi) dropwise to the solution. Raise the temperature of the solution to 60° C., react for 2 hours, and then evaporate n-hexane of the n-hexane solution under reduced pressure. Cool the reaction solution to a temperature of −30° C. again. Add 21 mmol of boron tribromide. Raise the temperature of the reaction solution to room temperature and stir it for 0.5 hour. Then cool the reaction solution to a temperature of 0° C. Add 42 mmol of N, N-diisopropylethylamine. After dropping, raise the temperature of the reaction solution to room temperature and stir it. Then continue to raise the temperature of the reaction solution to 120° C. and stir it for 3 hours. Cool the reaction solution to room temperature. Add sodium carbonate aqueous solution and ethyl acetate for quenching reaction. Extract aqueous phase with ethyl acetate, and combine organic phase. Rotary evaporate the organic phase to remove solvent to obtain crude product. Purify the crude product with silica gel column to obtain pure product. Recrystallize the pure product with toluene and ethyl acetate to obtain light yellow solid powder, namely the organic compound M5. A yield is 28.4%. A result of ASAP-MS of the organic compound M5 is as following: MS (ASAP)=870.

### Embodiment 6

### Synthesis of Organic Compound M6

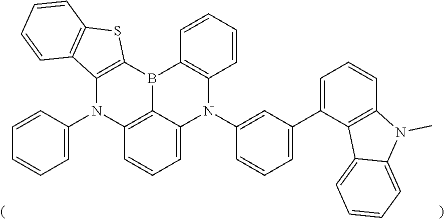 [SMILES: Cn1c2ccccc2c2c(-c3cccc(N4c5ccccc5B5c6sc7ccccc7c6N(c6ccccc6)c6cccc4c65)c3)cccc21]

Synthetic Route of the Organic Compound M6 is as following:

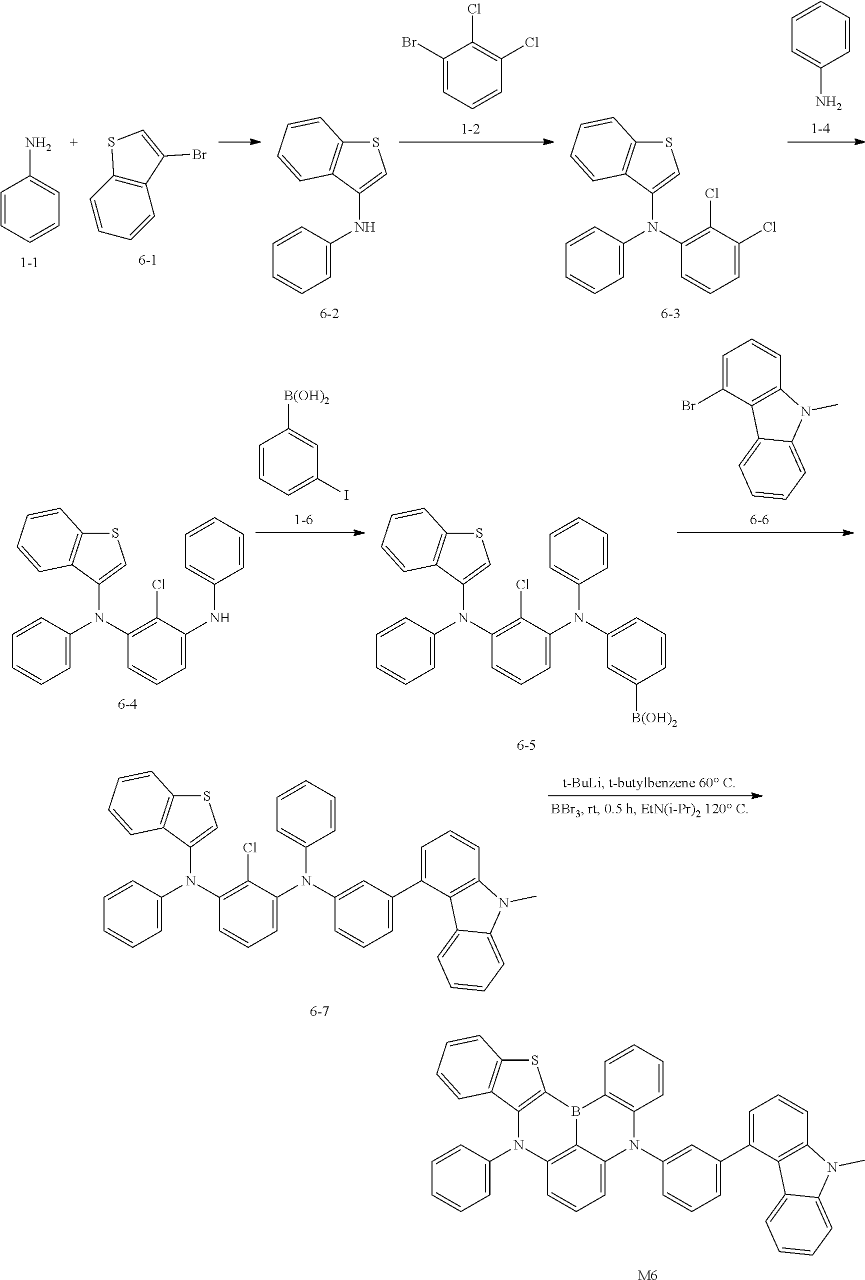

Specific synthesis steps of the organic compound M6 are as following:

(1) Synthesis of intermediate compound 6-2:
dissolve 10 mmol of compound 6-1, 10 mmol of the compound 1-4, 0.1 mmol of palladium dibenzylidene acetone (Pd(dba)₂), 0.2 mmol of tri tert butyl phosphine (TTBP), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 8.54 mmol of the intermediate compound 6-2. A yield is 85.4%. A result of ASAP-MS of the intermediate compound 6-2 is as following: MS (ASAP)=225.

(2) Synthesis of intermediate compound 6-3:
dissolve 10 mmol of the intermediate compound 6-2, 10 mmol of the compound 1-2, 0.1 mmol of palladium dibenzylidene acetone (Pd(dba)₂), 0.2 mmol of tri tert butyl phosphine (TTBP), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 7.67 mmol of the intermediate compound 6-3. A yield is 76.7%. A result of ASAP-MS of the intermediate compound 6-3 is as following: MS (ASAP)=369.

(3) Synthesis of intermediate compound 6-4:
dissolve 10 mmol of the intermediate compound 6-3, 10 mmol of the compound 1-4, 0.1 mmol of bis (di tert butyl-4-dimethylaminophenyl phosphine) palladium chloride (Pd-132), 0.2 mmol of 2-dicyclohexylphosphine-2′,6′-dimethoxy-1,1′-biphenyl (S-Phos), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 5.33 mmol of the intermediate compound 6-4. A yield is 53.3%. A result of ASAP-MS of the intermediate compound 6-4 is as following: MS (ASAP)=426.

(4) Synthesis of intermediate compound 6-5:
dissolve 10 mmol of the intermediate compound 6-4, 10 mmol of the compound 1-6, 0.1 mmol of Pd₂(dba)₃, 0.2 mmol of 2-dicyclohexylphosphine-2′,6′-dimethoxy-1,1′-biphenyl (S-Phos), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 6.48 mmol of the intermediate compound 6-5. A yield is 64.8%. A result of ASAP-MS of the intermediate compound 6-5 is as following: MS (ASAP)=546.

(5) Synthesis of intermediate compound 6-7:
dissolve 10 mmol of the intermediate compound 6-5 and 10 mmol of compound 6-6 in mixed solvents of 1,4-dioxane and water (21 mL:2 mL). Add 0.1 mmol of Pd(PPh₃)₄ and 30 mmol of potassium carbonate. After cooling, rotary evaporate the solution to remove most of the solvents. Then extract the solution, wash with water, and purify the organic phase in column chromatography to obtain 6.28 mmol of the intermediate compound 6-7. A yield is 62.8%. A result of ASAP-MS of the intermediate compound 6-7 is as following: MS (ASAP)=681.

(6) Synthesis of the organic compound M6:
add 10 mmol of the intermediate compound 6-7 and 100 mL of dry tert butyl benzene into a three necked flask (250 mL). Cool the solution to a temperature of −30° C. in nitrogen atmosphere. Add n-hexane solution of 21 mmol of tert butyl lithium (t-BuLi) dropwise to the solution. Raise the temperature of the solution to 60° C., react for 2 hours, and then evaporate n-hexane of the n-hexane solution under reduced pressure. Cool the reaction solution to a temperature of −30° C. again. Add 21 mmol of boron tribromide. Raise the temperature of the reaction solution to room temperature and stir it for 0.5 hour. Then cool the reaction solution to a temperature of 0° C. Add 42 mmol of N, N-diisopropylethylamine. After dropping, raise the temperature of the reaction solution to room temperature and stir it. Then continue to raise the temperature of the reaction solution to 120° C. and stir it for 3 hours. Cool the reaction solution to room temperature. Add sodium carbonate aqueous solution and ethyl acetate for quenching reaction. Extract aqueous phase with ethyl acetate, and combine organic phase. Rotary evaporate the organic phase to remove solvent to obtain crude product. Purify the crude product with silica gel column to obtain pure product. Recrystallize the pure product with toluene and ethyl acetate to obtain light yellow solid powder, namely the organic compound M6. A yield is 44.8%. A result of ASAP-MS of the organic compound M6 is as following: MS (ASAP)=655.

### Embodiment 7

### Synthesis of Organic Compound M7

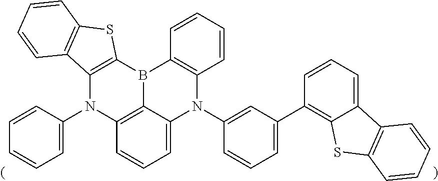 [SMILES: c1ccc(N2c3cccc4c3B(c3ccccc3N4c3cccc(-c4cccc5c4sc4ccccc45)c3)c3sc4ccccc4c32)cc1]

Synthetic Route of the Organic Compound M7 is as following:

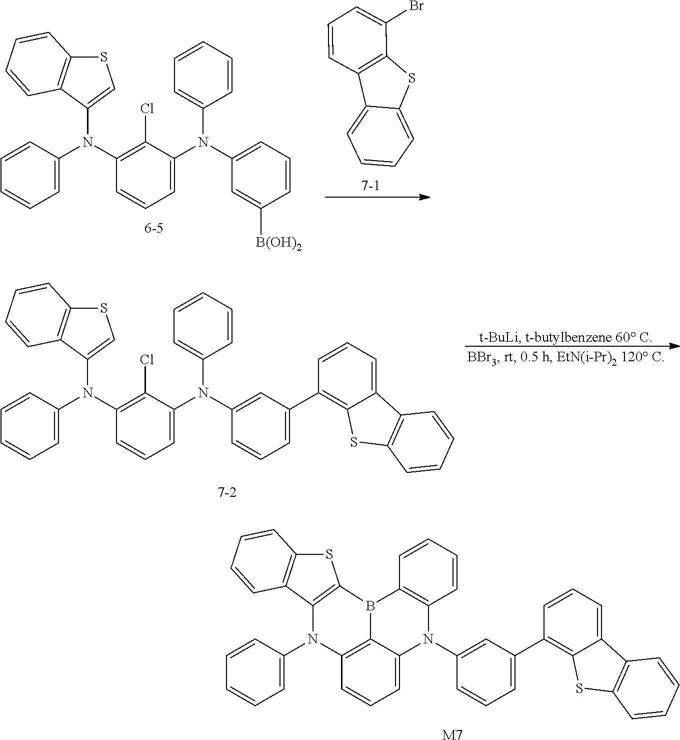

Specific synthesis steps of the organic compound M7 are as following:

(1) Synthesis of intermediate compound 7-2:
dissolve 10 mmol of the intermediate compound 6-5 and 10 mmol of compound 7-1 in mixed solvents of 1,4-dioxane and water (21 mL:2 mL). Add 0.1 mmol of Pd(PPh₃)₄ and 30 mmol of potassium carbonate. After cooling, rotary evaporate the solution to remove most of the solvents. Then extract the solution, wash with water, and purify the organic phase in column chromatography to obtain 6.59 mmol of the intermediate compound 7-2. A yield is 65.9%. A result of ASAP-MS of the intermediate compound 7-2 is as following: MS (ASAP)=684.

(2) Synthesis of the organic compound M7: add 10 mmol of the intermediate compound 7-2 and 100 mL of dry tert butyl benzene into a three necked flask (250 mL). Cool the solution to a temperature of −30° C. in nitrogen atmosphere. Add n-hexane solution of 21 mmol of tert butyl lithium (t-BuLi) dropwise to the solution. Raise the temperature of the solution to 60° C., react for 2 hours, and then evaporate n-hexane of the n-hexane solution under reduced pressure. Cool the reaction solution to a temperature of −30° C. again. Add 21 mmol of boron tribromide. Raise the temperature of the reaction solution to room temperature and stir it for 0.5 hour. Then cool the reaction solution to a temperature of 0° C. Add 42 mmol of N, N-diisopropylethylamine. After dropping, raise the temperature of the reaction solution to room temperature and stir it. Then continue to raise the temperature of the reaction solution to 120° C. and stir it for 3 hours. Cool the reaction solution to room temperature. Add sodium carbonate aqueous solution and ethyl acetate for quenching reaction. Extract aqueous phase with ethyl acetate, and combine organic phase. Rotary evaporate the organic phase to remove solvent to obtain crude product. Purify the crude product with silica gel column to obtain pure product. Recrystallize the pure product with toluene and ethyl acetate to obtain light yellow solid powder, namely the organic compound M7. A yield is 33.5%. A result of ASAP-MS of the organic compound M7 is as following: MS (ASAP)=658.

### Embodiment 8

### Synthesis of Organic Compound M8

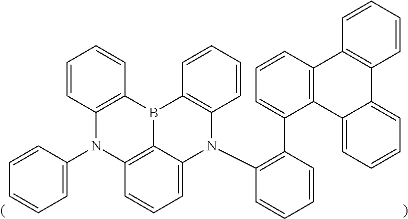 [SMILES: c1ccc(N2c3ccccc3B3c4ccccc4N(c4ccccc4-c4cccc5c6ccccc6c6ccccc6c45)c4cccc2c43)cc1]

Synthetic Route of the Organic Compound M8 is as following:

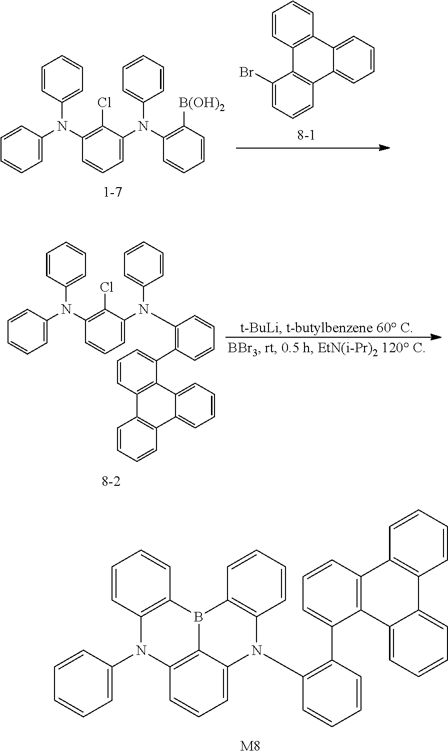 [SMILES: OB(O)c1ccccc1N(c1ccccc1)c1cccc(N(c2ccccc2)c2ccccc2)c1Cl ; Brc1cccc2c3ccccc3c3ccccc3c12 ; Clc1c(N(c2ccccc2)c2ccccc2)cccc1N(c1ccccc1)c1ccccc1-c1cccc2c3ccccc3c3ccccc3c12 ; c1ccc(N2c3ccccc3B3c4ccccc4N(c4ccccc4-c4cccc5c6ccccc6c6ccccc6c45)c4cccc2c43)cc1 ; "M8"]

Specific synthesis steps of the organic compound M8 are as following:

(1) Synthesis of intermediate compound 8-2:
dissolve 10 mmol of the intermediate compound 1-7 and 10 mmol of compound 8-1 in mixed solvents of 1,4-dioxane and water (21 mL:2 mL). Add 0.1 mmol of Pd(PPh₃)₄ and 30 mmol of potassium carbonate. After cooling, rotary evaporate the solution to remove solvent. Then extract the solution, wash with water, and purify the organic phase in column chromatography to obtain 7.25 mmol of the intermediate compound 8-2. A yield is 72.5%. A result of ASAP-MS of the intermediate compound 8-2 is as following: MS (ASAP)=672.

(2) Synthesis of the organic compound M8:
add 10 mmol of the intermediate compound 8-2 and 100 mL of dry tert butyl benzene into a three necked flask (250 mL). Cool the solution to a temperature of −30° C. in nitrogen atmosphere. Add n-hexane solution of 21 mmol of tert butyl lithium (t-BuLi) dropwise to the solution. Raise the temperature of the solution to 60° C., react for 2 hours, and then evaporate n-hexane of the n-hexane solution under reduced pressure. Cool the reaction solution to a temperature of −30° C. again. Add 21 mmol of boron tribromide. Raise the temperature of the reaction solution to room temperature and stir it for 0.5 hour. Then cool the reaction solution to a temperature of 0° C. Add 42 mmol of N, N-diisopropylethylamine. After dropping, raise the temperature of the reaction solution to room temperature and stir it. Then continue to raise the temperature of the reaction solution to 120° C. and stir it for 3 hours. Cool the reaction solution to room temperature. Add sodium carbonate aqueous solution and ethyl acetate for quenching reaction. Extract aqueous phase with ethyl acetate, and combine organic phase. Rotary evaporate the organic phase to remove solvent to obtain crude product. Purify the crude product with silica gel column to obtain pure product. Recrystallize the pure product with toluene and ethyl acetate to obtain light yellow solid powder, namely the organic compound M8. A yield is 29.4%. A result of ASAP-MS of the organic compound M8 is as following: MS (ASAP)=646.

### Embodiment 9

### Synthesis of Organic Compound M9

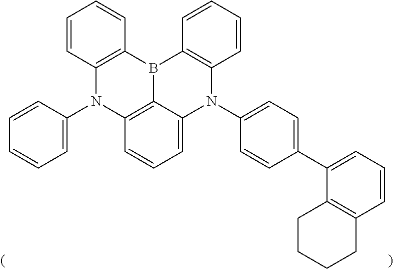 [SMILES: c1ccc(N2c3ccccc3B3c4ccccc4N(c4ccc(-c5cccc6c5CCCC6)cc4)c4cccc2c43)cc1]

Synthetic Route of the Organic Compound M9 is as following:

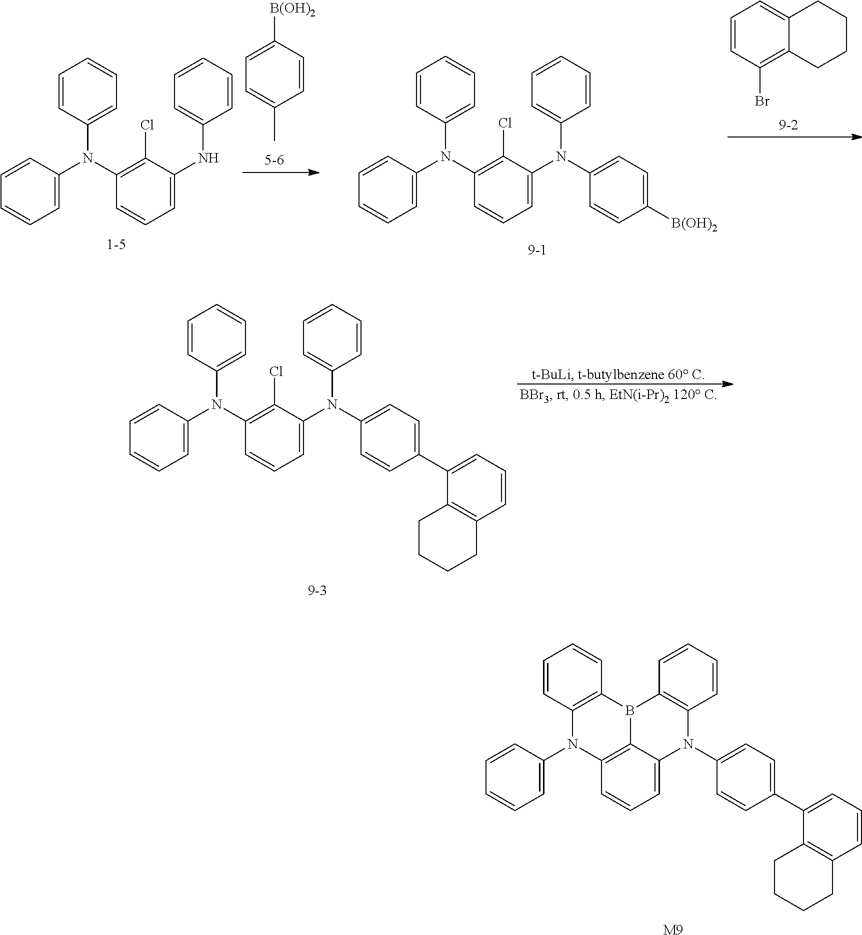

Specific synthesis steps of the organic compound M9 are as following:

(1) Synthesis of intermediate compound 9-1:
dissolve 10 mmol of the intermediate compound 1-5, 10 mmol of the compound 5-6, 0.1 mmol of palladium dibenzylidene acetone (Pd(dba)₂), 0.2 mmol of tri tert butyl phosphine (TTBP), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 6.47 mmol of the intermediate compound 9-1. A yield is 64.7%. A result of ASAP-MS of the intermediate compound 9-1 is as following: MS (ASAP)=490.

(2) Synthesis of intermediate compound 9-3:
dissolve 10 mmol of the intermediate compound 9-1 and 10 mmol of compound 9-2 in mixed solvents of 1,4-dioxane and water (21 mL:2 mL). Add 0.1 mmol of Pd(PPh₃)₄ and 30 mmol of potassium carbonate. After cooling, rotary evaporate the solution to remove most of the solvents. Then extract the solution, wash with water, and purify the organic phase in column chromatography to obtain 5.73 mmol of the intermediate compound 9-3. A yield is 57.3%. A result of ASAP-MS of the intermediate compound 9-3 is as following: MS (ASAP)=576.

(3) Synthesis of the organic compound M9: add 10 mmol of the intermediate compound 9-3 and 100 mL of dry tert butyl benzene into a three necked flask (250 mL). Cool the solution to a temperature of −30° C. in nitrogen atmosphere. Add n-hexane solution of 21 mmol of tert butyl lithium (t-BuLi) dropwise to the solution. Raise the temperature of the solution to 60° C., react for 2 hours, and then evaporate n-hexane of the n-hexane solution under reduced pressure. Cool the reaction solution to a temperature of −30° C. again. Add 21 mmol of boron tribromide. Raise the temperature of the reaction solution to room temperature and stir it for 0.5 hour. Then cool the reaction solution to a temperature of 0° C. Add 42 mmol of N, N-diisopropylethylamine. After dropping, raise the temperature of the reaction solution to room temperature and stir it. Then continue to raise the temperature of the reaction solution to 120° C. and stir it for 3 hours. Cool the reaction solution to room temperature. Add sodium carbonate aqueous solution and ethyl acetate for quenching reaction. Extract aqueous phase with ethyl acetate, and combine organic phase. Rotary evaporate the organic phase to remove solvent to obtain crude product. Purify the crude product with silica gel column to obtain pure product. Recrystallize the pure product with toluene and ethyl acetate to obtain light yellow solid powder, namely the organic compound M9. A yield is 30.9%. A result of ASAP-MS of the organic compound M9 is as following: MS (ASAP)=550.

### Embodiment 10

Synthesis of Organic Compound M10

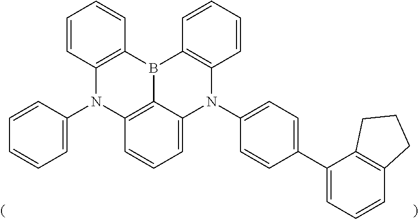 [SMILES: c1ccc(N2c3ccccc3B3c4ccccc4N(c4ccc(-c5cccc6c5CCC6)cc4)c4cccc2c43)cc1]

Synthetic Route of the Organic Compound M10 is as following:

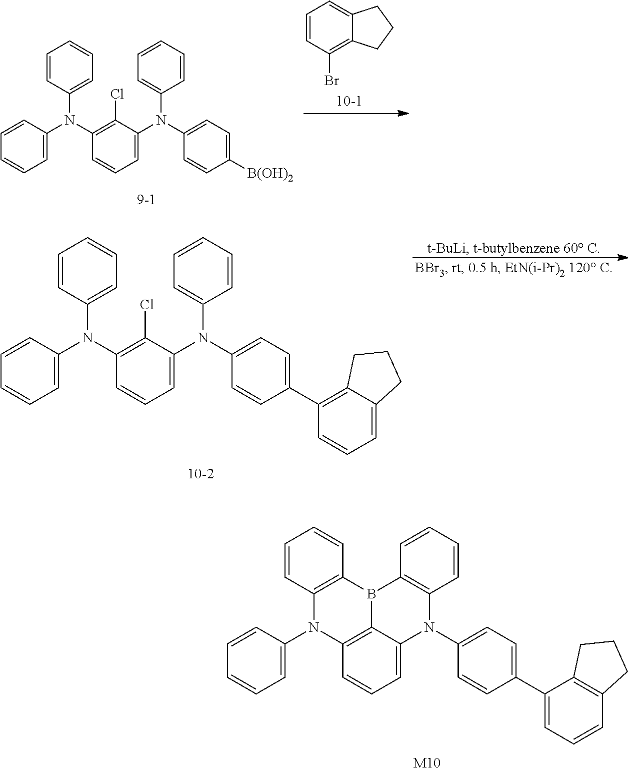 [SMILES: OB(O)c1ccc(N(c2ccccc2)c2cccc(N(c3ccccc3)c3ccccc3)c2Cl)cc1 ; Brc1cccc2c1CCC2 ; Clc1c(N(c2ccccc2)c2ccccc2)cccc1N(c1ccccc1)c1ccc(-c2cccc3c2CCC3)cc1 ; c1ccc(N2c3ccccc3B3c4ccccc4N(c4ccc(-c5cccc6c5CCC6)cc4)c4cccc2c43)cc1 ; "M10"]

Specific synthesis steps of the organic compound M10 are as following:

(1) Synthesis of intermediate compound 10-2:
dissolve 10 mmol of the intermediate compound 9-1 and 10 mmol of compound 10-1 in mixed solvents of 1,4-dioxane and water (21 mL:2 mL). Add 0.1 mmol of Pd(PPh₃)₄ and 30 mmol of potassium carbonate. After cooling, rotary evaporate the solution to remove most of the solvents. Then extract the solution, wash with water, and purify the organic phase in column chromatography to obtain 5.27 mmol of the intermediate compound 10-2. A yield is 52.7%. A result of ASAP-MS of the intermediate compound 10-2 is as following: MS (ASAP)=562.

(2) Synthesis of the organic compound M10:
add 10 mmol of the intermediate compound 10-2 and 100 mL of dry tert butyl benzene into a three necked flask (250 mL). Cool the solution to a temperature of −30° C. in nitrogen atmosphere. Add n-hexane solution of 21 mmol of tert butyl lithium (t-BuLi) dropwise to the solution. Raise the temperature of the solution to 60° C., react for 2 hours, and then evaporate n-hexane of the n-hexane solution under reduced pressure. Cool the reaction solution to a temperature of −30° C. again. Add 21 mmol of boron tribromide. Raise the temperature of the reaction solution to room temperature and stir it for 0.5 hour. Then cool the reaction solution to a temperature of 0° C. Add 42 mmol of N, N-diisopropylethylamine. After dropping, raise the temperature of the reaction solution to room temperature and stir it. Then continue to raise the temperature of the reaction solution to 120° C. and stir it for 3 hours. Cool the reaction solution to room temperature. Add sodium carbonate aqueous solution and ethyl acetate for quenching reaction. Extract aqueous phase with ethyl acetate, and combine organic phase. Rotary evaporate the organic phase to remove solvent to obtain crude product. Purify the crude product with silica gel column to obtain pure product. Recrystallize the pure product with toluene and ethyl acetate to obtain light yellow solid powder, namely the organic compound M10. A yield is 35.5%. A result of ASAP-MS of the organic compound M10 is as following: MS (ASAP)=536.

### Embodiment 11

Synthesis of Organic Compound M11

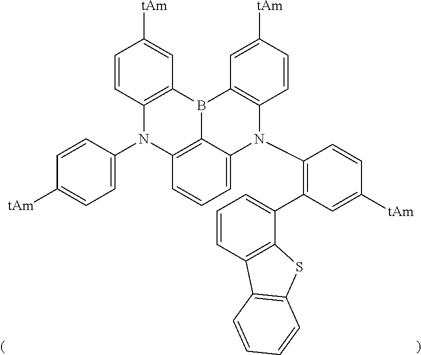

Synthetic Route of the Organic Compound M11 is as following:

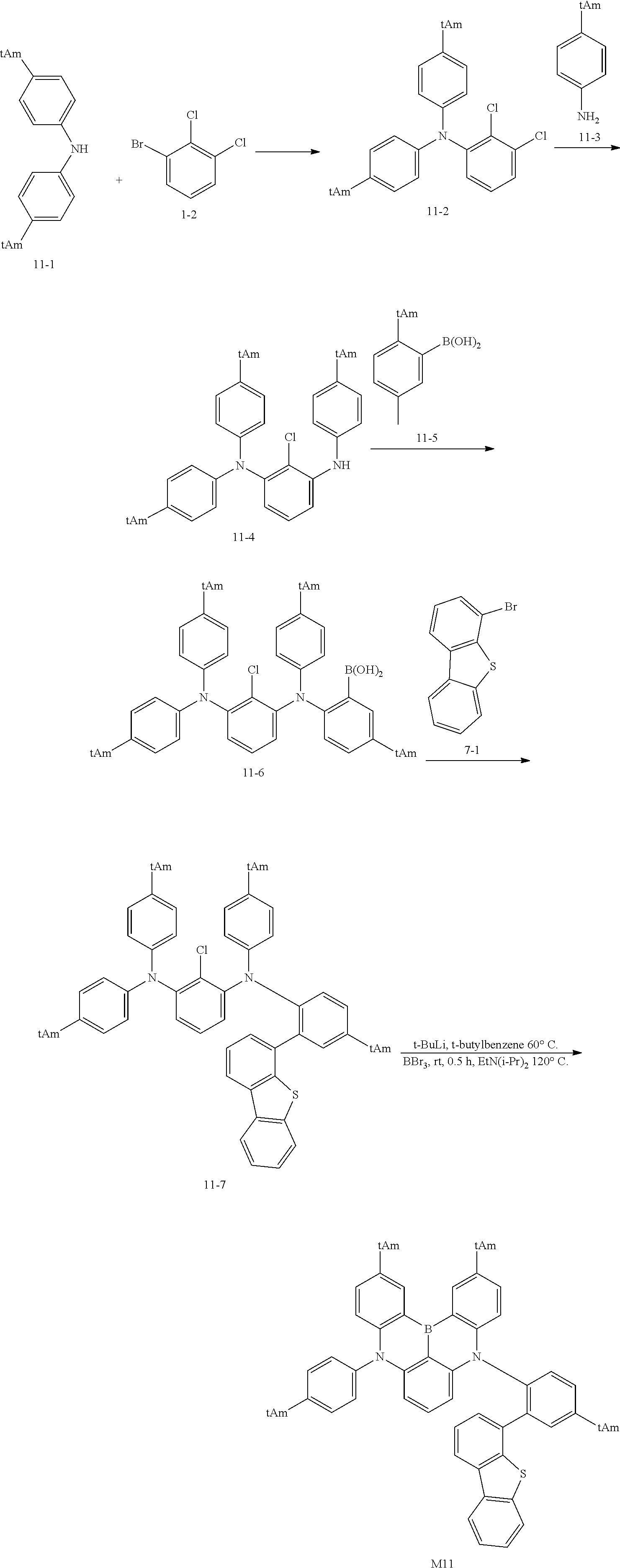

Specific synthesis steps of the organic compound M11 are as following:

(1) Synthesis of intermediate compound 11-2:
dissolve 10 mmol of compound 11-1, 10 mmol of the compound 1-2, 0.1 mmol of palladium dibenzylidene acetone (Pd(dba)₂), 0.2 mmol of tri tert butyl phosphine (TTBP), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 7.43 mmol of the intermediate compound 11-2. A yield is 74.3%. A result of ASAP-MS of the intermediate compound 11-2 is as following: MS (ASAP)=453.

(2) Synthesis of intermediate compound 11-4:
dissolve 10 mmol of the intermediate compound 11-2, 10 mmol of compound 11-3, 0.1 mmol of bis (di tert butyl-4-dimethylaminophenyl phosphine) palladium chloride (Pd-132), 0.2 mmol of 2-dicyclohexylphosphine-2′,6′-dimethoxy-1,1′-biphenyl (S-Phos), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 5.37 mmol of the intermediate compound 11-4. A yield is 53.7%. A result of ASAP-MS of the intermediate compound 11-4 is as following: MS (ASAP)=580.

(3) Synthesis of intermediate compound 11-6:
dissolve 10 mmol of the intermediate compound 11-4, 10 mmol of compound 11-5, 0.1 mmol of Pd₂(dba)₃, 0.2 mmol of 2-dicyclohexylphosphine-2′,6′-dimethoxy-1,1′-biphenyl (S-Phos), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 6.59 mmol of the intermediate compound 11-6. A yield is 65.9%. A result of ASAP-MS of the intermediate compound 11-6 is as following: MS (ASAP)=770.

(4) Synthesis of intermediate compound 11-7:
dissolve 10 mmol of the intermediate compound 11-6 and 10 mmol of the compound 7-1 in mixed solvents of 1,4-dioxane and water (21 mL:2 mL). Add 0.1 mmol of Pd(PPh₃)₄ and 30 mmol of potassium carbonate. After cooling, rotary evaporate the solution to remove most of the solvents. Then extract the solution, wash with water, and purify the organic phase in column chromatography to obtain 6.28 mmol of the intermediate compound 11-7. A yield is 62.8%. A result of ASAP-MS of the intermediate compound 11-7 is as following: MS (ASAP)=908.

(5) Synthesis of the organic compound M11:
add 10 mmol of the intermediate compound 11-7 and 100 mL of dry tert butyl benzene into a three necked flask (250 mL). Cool the solution to a temperature of −30° C. in nitrogen atmosphere. Add n-hexane solution of 21 mmol of tert butyl lithium (t-BuLi) dropwise to the solution. Raise the temperature of the solution to 60° C., react for 2 hours, and then evaporate n-hexane of the n-hexane solution under reduced pressure. Cool the reaction solution to a temperature of −30° C. again. Add 21 mmol of boron tribromide. Raise the temperature of the reaction solution to room temperature and stir it for 0.5 hour. Then cool the reaction solution to a temperature of 0° C. Add 42 mmol of N, N-diisopropylethylamine. After dropping, raise the temperature of the reaction solution to room temperature and stir it. Then continue to raise the temperature of the reaction solution to 120° C. and stir it for 3 hours. Cool the reaction solution to room temperature. Add sodium carbonate aqueous solution and ethyl acetate for quenching reaction. Extract aqueous phase with ethyl acetate, and combine organic phase. Rotary evaporate the organic phase to remove solvent to obtain crude product. Purify the crude product with silica gel column to obtain pure product. Recrystallize the pure product with toluene and ethyl acetate to obtain light yellow solid powder, namely the organic compound M11. A yield is 36.9%. A result of ASAP-MS of the organic compound M11 is as following: MS (ASAP)=882.

### Embodiment 12

### Synthesis of Organic Compound M12

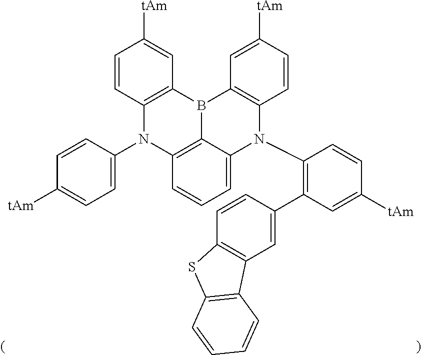

Synthetic Route of the Organic Compound M12 is as following:

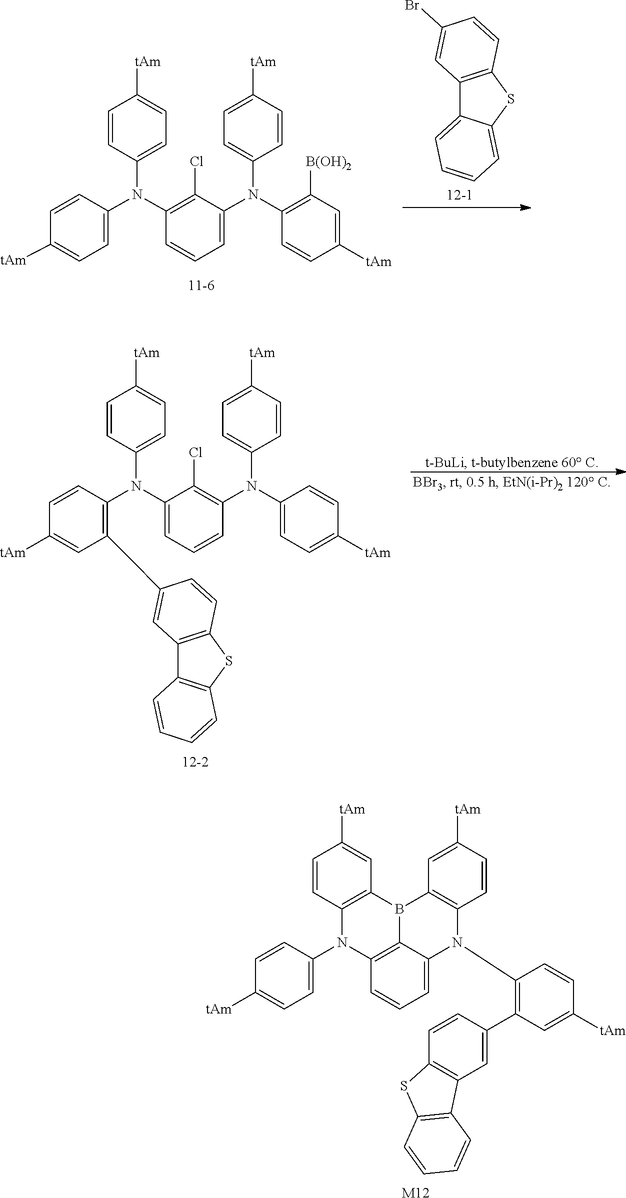

Specific synthesis steps of the organic compound M12 are as following:

(1) Synthesis of intermediate compound 12-2:
dissolve 10 mmol of the intermediate compound 11-6 and 10 mmol of compound 12-1 in mixed solvents of 1,4-dioxane and water (21 mL:2 mL). Add 0.1 mmol of Pd(PPh₃)₄ and 30 mmol of potassium carbonate. After cooling, rotary evaporate the solution to remove most of the solvents. Then extract the solution, wash with water, and purify the organic phase in column chromatography to obtain 7.15 mmol of the intermediate compound 12-2. A yield is 71.5%. A result of ASAP-MS of the intermediate compound 12-2 is as following: MS (ASAP)=908.

(2) Synthesis of the organic compound M12:
add 10 mmol of the intermediate compound 1-9 and 100 mL of dry tert butyl benzene into a three necked flask (250 mL). Cool the solution to a temperature of −30° C. in nitrogen atmosphere. Add n-hexane solution of 21 mmol of tert butyl lithium (t-BuLi) dropwise to the solution. Raise the temperature of the solution to 60° C., react for 2 hours, and then evaporate n-hexane of the n-hexane solution under reduced pressure. Cool the reaction solution to a temperature of −30° C. again. Add 21 mmol of boron tribromide. Raise the temperature of the reaction solution to room temperature and stir it for 0.5 hour. Then cool the reaction solution to a temperature of 0° C. Add 42 mmol of N, N-diisopropylethylamine. After dropping, raise the temperature of the reaction solution to room temperature and stir it. Then continue to raise the temperature of the reaction solution to 120° C. and stir it for 3 hours. Cool the reaction solution to room temperature. Add sodium carbonate aqueous solution and ethyl acetate for quenching reaction. Extract aqueous phase with ethyl acetate, and combine organic phase. Rotary evaporate the organic phase to remove solvent to obtain crude product. Purify the crude product with silica gel column to obtain pure product. Recrystallize the pure product with toluene and ethyl acetate to obtain light yellow solid powder, namely the organic compound M12. A yield is 40.8%. A result of ASAP-MS of the organic compound M12 is as following: MS (ASAP)=882.

### Embodiment 13

### Synthesis of Organic Compound M13

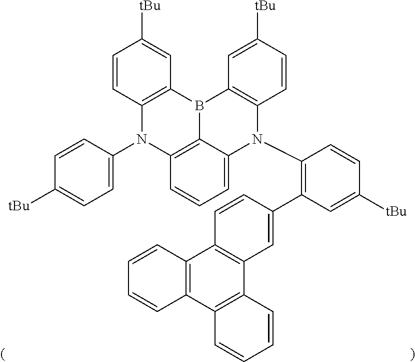 [SMILES: CC(C)(C)c1ccc(N2c3ccc(C(C)(C)C)cc3B3c4cc(C(C)(C)C)ccc4N(c4ccc(C(C)(C)C)cc4-c4ccc5c6ccccc6c6ccccc6c5c4)c4cccc2c43)cc1]

Synthetic Route of the Organic Compound M13 is as following:

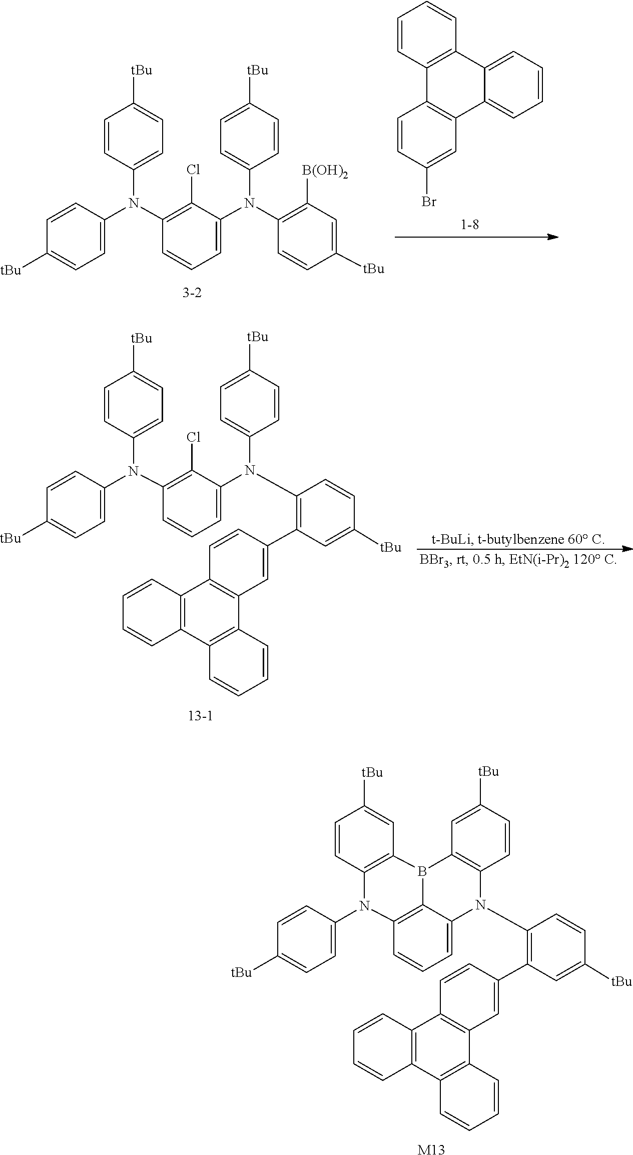

Specific synthesis steps of the organic compound M13 are as following:

(1) Synthesis of intermediate compound 13-1:
dissolve 10 mmol of the intermediate compound 3-2 and 10 mmol of the compound 1-8 in mixed solvents of 1,4-dioxane and water (21 mL:2 mL). Add 0.1 mmol of Pd(PPh₃)₄ and 30 mmol of potassium carbonate. After cooling, rotary evaporate the solution to remove most of the solvents. Then extract the solution, wash with water, and purify the organic phase in column chromatography to obtain 7.55 mmol of the intermediate compound 13-1. A yield is 75.5%. A result of ASAP-MS of the intermediate compound 13-1 is as following: MS (ASAP)=896.

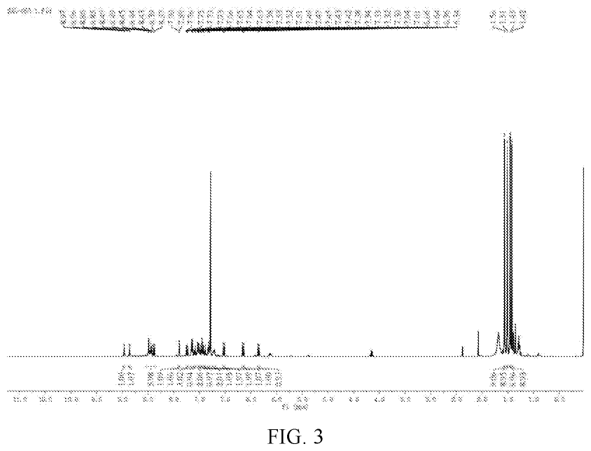

(2) Synthesis of the organic compound M13:
add 10 mmol of the intermediate compound 13-1 and 100 mL of dry tert butyl benzene into a three necked flask (250 mL). Cool the solution to a temperature of −30° C. in nitrogen atmosphere. Add n-hexane solution of 21 mmol of tert butyl lithium (t-BuLi) dropwise to the solution. Raise the temperature of the solution to 60° C., react for 2 hours, and then evaporate n-hexane of the n-hexane solution under reduced pressure. Cool the reaction solution to a temperature of −30° C. again. Add 21 mmol of boron tribromide. Raise the temperature of the reaction solution to room temperature and stir it for 0.5 hour. Then cool the reaction solution to a temperature of 0° C. Add 42 mmol of N, N-diisopropylethylamine. After dropping, raise the temperature of the reaction solution to room temperature and stir it. Then continue to raise the temperature of the reaction solution to 120° C. and stir it for 3 hours. Cool the reaction solution to room temperature. Add sodium carbonate aqueous solution and ethyl acetate for quenching reaction. Extract aqueous phase with ethyl acetate, and combine organic phase. Rotary evaporate the organic phase to remove solvent to obtain crude product. Purify the crude product with silica gel column to obtain pure product. Recrystallize the pure product with toluene and ethyl acetate to obtain light yellow solid powder, namely the organic compound M13. A yield is 31.4%. A result of ASAP-MS of the organic compound M13 is as following: MS (ASAP)=870. Please refer to FIG. 3, a result of nuclear magnetic resonance hydrogen spectrum of the organic compound M13 indicates a formation of the organic compound M13.

### Embodiment 14

### Synthesis of Organic Compound M14

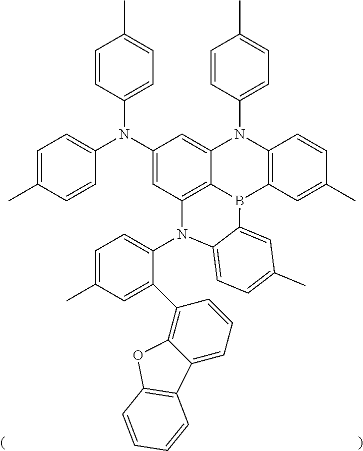

Synthetic Route of the Organic Compound M14 is as following:

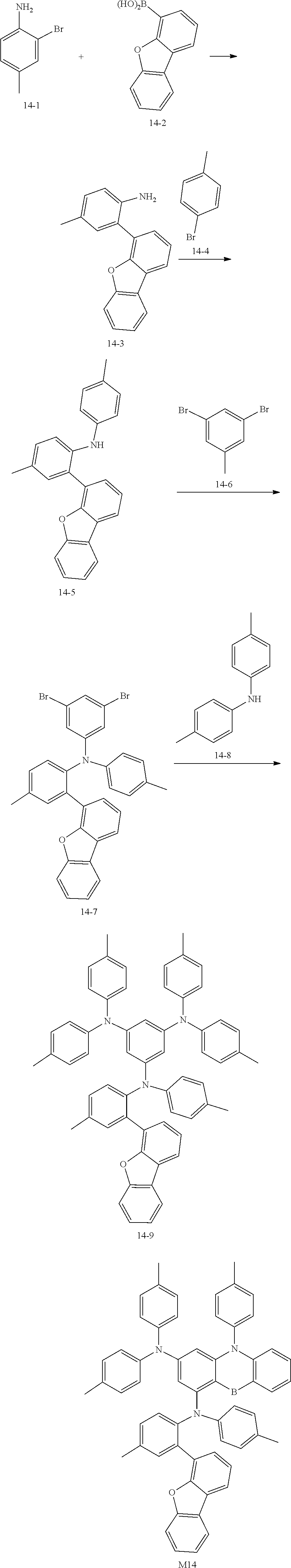

Specific synthesis steps of the organic compound M14 are as following:

(1) Synthesis of intermediate compound 14-3:
dissolve 10 mmol of compound 14-1 and 10 mmol of compound 14-2 in mixed solvents of 1,4-dioxane and water (21 mL:2 mL). Add 0.1 mmol of Pd(PPh₃)₄ and 30 mmol of potassium carbonate. After cooling, rotary evaporate the solution to remove most of the solvents. Then extract the solution, wash with water, and purify the organic phase in column chromatography to obtain 7.32 mmol of the intermediate compound 14-3. A yield is 73.2%. A result of ASAP-MS of the intermediate compound 14-3 is as following: MS (ASAP)=273.

(2) Synthesis of intermediate compound 14-5:
dissolve 10 mmol of the intermediate compound 14-3, 10 mmol of compound 14-4, 0.1 mmol of palladium dibenzylidene acetone (Pd(dba)₂), 0.2 mmol of tri tert butyl phosphine (TTBP), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 7.17 mmol of the intermediate compound 14-5. A yield is 71.7%. A result of ASAP-MS of the intermediate compound 14-5 is as following: MS (ASAP)=363.

(3) Synthesis of intermediate compound 14-7:
dissolve 10 mmol of the intermediate compound 14-5, 10 mmol of compound 14-6, 0.1 mmol of palladium dibenzylidene acetone (Pd(dba)₂), 0.2 mmol of tri tert butyl phosphine (TTBP), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 6.58 mmol of the intermediate compound 14-7. A yield is 65.8%. A result of ASAP-MS of the intermediate compound 14-7 is as following: MS (ASAP)=595.

(4) Synthesis of intermediate compound 14-9:
dissolve 10 mmol of the intermediate compound 14-7, 20 mmol of compound 14-8, 0.2 mmol of palladium dibenzylidene acetone (Pd(dba)₂), 0.4 mmol of tri tert butyl phosphine (TTBP), and 60 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 5.47 mmol of the intermediate compound 14-9. A yield is 54.7%. A result of ASAP-MS of the intermediate compound 14-9 is as following: MS (ASAP)=829.

(5) Synthesis of the organic compound M14:
prepare a dry schlenk bottle (100 mL), set up a reaction device, evacuate vacuum, and supply nitrogen. Keep nitrogen flowing in the reaction bottle. Add 10 mmol of the intermediate compound 14-9 and 20 mL of toluene into the reaction bottle. Evacuate vacuum, and circulate and supply nitrogen for three times. Raise a temperature of the reaction solution to 120° C. Slowly add 20 mmol of boron triiodide into the reaction bottle dropwise, tighten a cap of the reaction bottle, and react for 12 hours. Then extract the reaction solution with dichloromethane (DCM). Rotary evaporate the solution to remove solvent, and purify the product in column chromatography (an eluent is petroleum ether) to obtain a yellow green solid, namely the organic compound M14. A yield is 45.9%. A result of ASAP-MS of the organic compound M14 is as following: MS (ASAP)=837.

### Embodiment 15

### Synthesis of Organic Compound M15

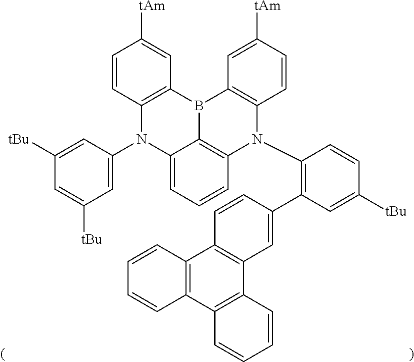

Synthetic Route of the Organic Compound M15 is as following:

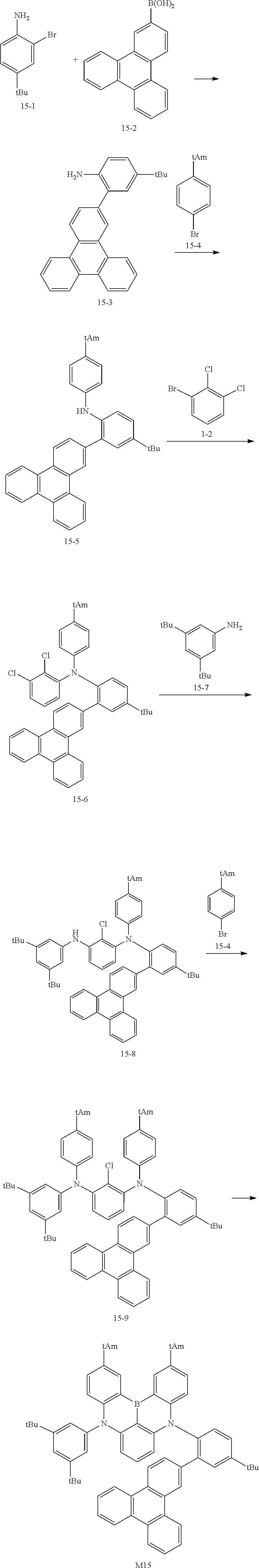

Specific synthesis steps of the organic compound M15 are as following:

(1) Synthesis of intermediate compound 15-3:
dissolve 10 mmol of compound 15-1 and 10 mmol of compound 15-2 in mixed solvents of 1,4-dioxane and water (21 mL:2 mL). Add 0.1 mmol of Pd(PPh₃)₄ and 30 mmol of potassium carbonate. After cooling, rotary evaporate the solution to remove most of the solvents. Then extract the solution, wash with water, and purify the organic phase in column chromatography to obtain 8.21 mmol of the intermediate compound 15-3. A yield is 82.1%. A result of ASAP-MS of the intermediate compound 15-3 is as following: MS (ASAP)=375.

(2) Synthesis of intermediate compound 15-5:
dissolve 10 mmol of the intermediate compound 15-3, 10 mmol of compound 15-4, 0.1 mmol of palladium dibenzylidene acetone (Pd(dba)₂), 0.2 mmol of tri tert butyl phosphine (TTBP), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 7.03 mmol of the intermediate compound 15-5. A yield is 70.3%. A result of ASAP-MS of the intermediate compound 15-5 is as following: MS (ASAP)=521.

(3) Synthesis of intermediate compound 15-6:
dissolve 10 mmol of the intermediate compound 15-5, 10 mmol of the compound 1-2, 0.1 mmol of palladium dibenzylidene acetone (Pd(dba)₂), 0.2 mmol of tri tert butyl phosphine (TTBP), and 30 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 6.12 mmol of the intermediate compound 15-6. A yield is 61.2%. A result of ASAP-MS of the intermediate compound 15-6 is as following: MS (ASAP)=665.

(4) Synthesis of intermediate compound 15-8:
dissolve 10 mmol of the intermediate compound 15-6, 10 mmol of the intermediate compound 5-7, 0.2 mmol of palladium dibenzylidene acetone (Pd(dba)₂), 0.4 mmol of tri tert butyl phosphine (TTBP), and 60 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 5.03 mmol of the intermediate compound 15-8. A yield is 50.3%. A result of ASAP-MS of the intermediate compound 15-8 is as following: MS (ASAP)=834.

(5) Synthesis of intermediate compound 15-9:
dissolve 10 mmol of the intermediate compound 15-8, 10 mmol of the compound 15-4, 0.2 mmol of palladium dibenzylidene acetone (Pd(dba)₂), 0.4 mmol of tri tert butyl phosphine (TTBP), and 60 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 4.89 mmol of the intermediate compound 15-9. A yield is 48.9%. A result of ASAP-MS of the intermediate compound 15-9 is as following: MS (ASAP)=980.

(6) Synthesis of the organic compound M15:
add 10 mmol of the intermediate compound 15-9 and 100 mL of dry tert butyl benzene into a three necked flask (250 mL). Cool the solution to a temperature of −30° C. in nitrogen atmosphere. Add n-hexane solution of 21 mmol of tert butyl lithium (t-BuLi) dropwise to the solution. Raise the temperature of the solution to 60° C., react for 2 hours, and then evaporate n-hexane of the n-hexane solution under reduced pressure. Cool the reaction solution to a temperature of −30° C. again. Add 21 mmol of boron tribromide. Raise the temperature of the reaction solution to room temperature and stir it for 0.5 hour. Then cool the reaction solution to a temperature of 0° C. Add 42 mmol of N, N-diisopropylethylamine. After dropping, raise the temperature of the reaction solution to room temperature and stir it. Then continue to raise the temperature of the reaction solution to 120° C. and stir it for 3 hours. Cool the reaction solution to room temperature. Add sodium carbonate aqueous solution and ethyl acetate for quenching reaction. Extract aqueous phase with ethyl acetate, and combine organic phase. Rotary evaporate the organic phase to remove solvent to obtain crude product. Purify the crude product with silica gel column to obtain pure product. Recrystallize the pure product with toluene and ethyl acetate to obtain light yellow solid powder, namely the organic compound M15. A yield is 33.7%. A result of ASAP-MS of the organic compound M15 is as following: MS (ASAP)=954.

### Embodiment 16

### Synthesis of Organic Compound M16

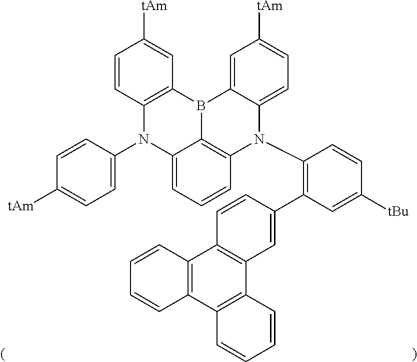

Synthetic Route of the Organic Compound M16 is as following:

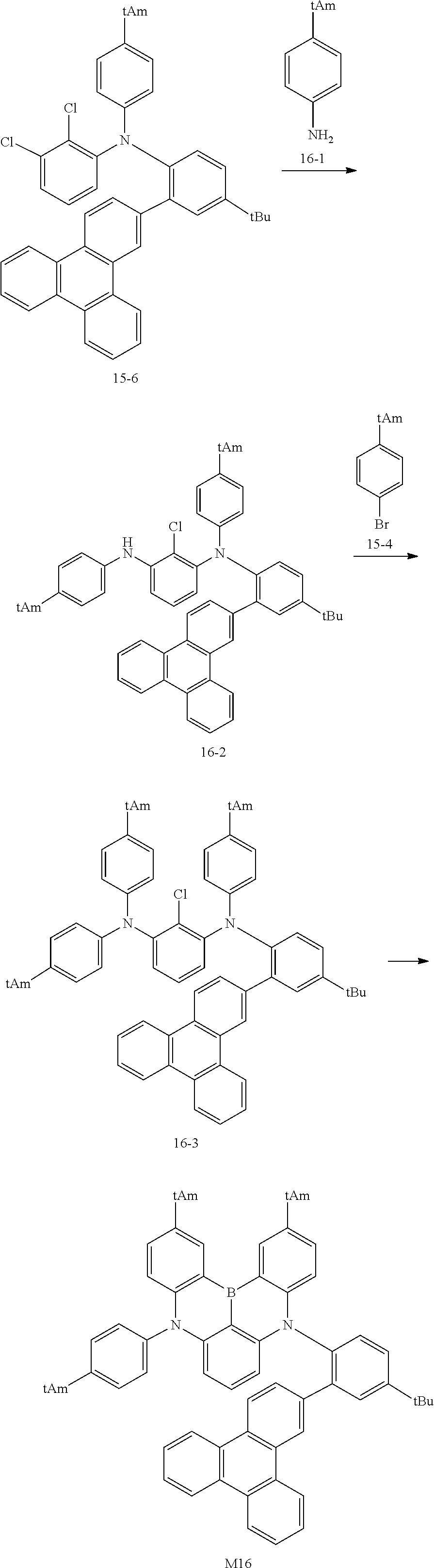

Specific synthesis steps of the organic compound M16 are as following:

(1) Synthesis of intermediate compound 16-2:
dissolve 10 mmol of the intermediate compound 15-6, 10 mmol of compound 16-1, 0.2 mmol of palladium dibenzylidene acetone (Pd(dba)₂), 0.4 mmol of tri tert butyl phosphine (TTBP), and 60 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 6.27 mmol of the intermediate compound 16-2. A yield is 62.7%. A result of ASAP-MS of the intermediate compound 16-2 is as following: MS (ASAP)=792.

(2) Synthesis of intermediate compound 16-3:
dissolve 10 mmol of the intermediate compound 16-2, 10 mmol of the compound 15-4, 0.2 mmol of palladium dibenzylidene acetone (Pd(dba)₂), 0.4 mmol of tri tert butyl phosphine (TTBP), and 60 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 4.33 mmol of the intermediate compound 16-3. A yield is 43.3%. A result of ASAP-MS of the intermediate compound 16-3 is as following: MS (ASAP)=938.

(3) Synthesis of the organic compound M16:
add 10 mmol of the intermediate compound 16-3 and 100 mL of dry tert butyl benzene into a three necked flask (250 mL). Cool the solution to a temperature of −30° C. in nitrogen atmosphere. Add n-hexane solution of 21 mmol of tert butyl lithium (t-BuLi) dropwise to the solution. Raise the temperature of the solution to 60° C., react for 2 hours, and then evaporate n-hexane of the n-hexane solution under reduced pressure. Cool the reaction solution to a temperature of −30° C. again. Add 21 mmol of boron tribromide. Raise the temperature of the reaction solution to room temperature and stir it for 0.5 hour. Then cool the reaction solution to a temperature of 0° C. Add 42 mmol of N, N-diisopropylethylamine. After dropping, raise the temperature of the reaction solution to room temperature and stir it. Then continue to raise the temperature of the reaction solution to 120° C. and stir it for 3 hours. Cool the reaction solution to room temperature. Add sodium carbonate aqueous solution and ethyl acetate for quenching reaction. Extract aqueous phase with ethyl acetate, and combine organic phase. Rotary evaporate the organic phase to remove solvent to obtain crude product. Purify the crude product with silica gel column to obtain pure product. Recrystallize the pure product with toluene and ethyl acetate to obtain light yellow solid powder, namely the organic compound M16. A yield is 38.9%. A result of ASAP-MS of the organic compound M16 is as following: MS (ASAP)=912.

### Embodiment 17

### Synthesis of Organic Compound M17

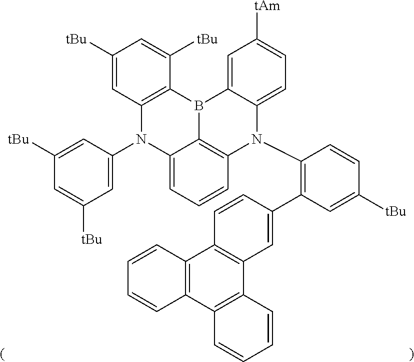

Synthetic Route of the Organic Compound M17 is as following:

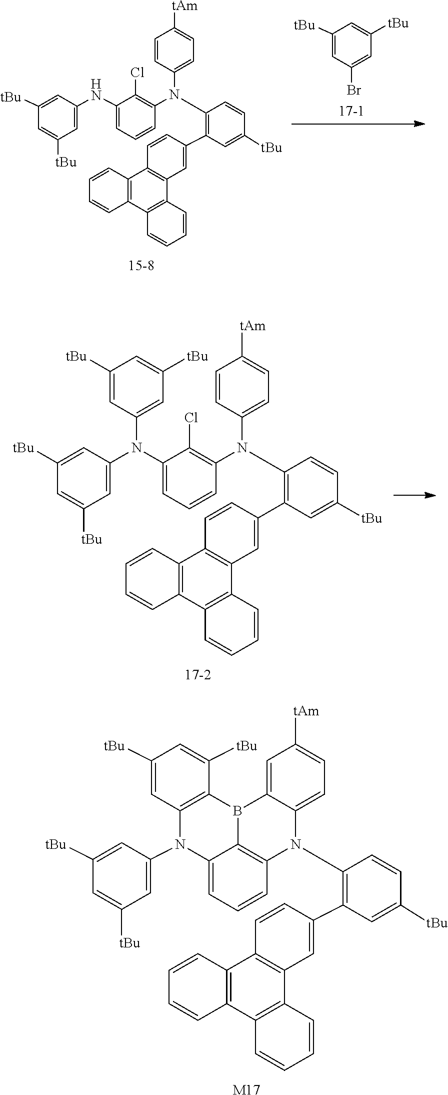

Specific synthesis steps of the organic compound M17 are as following:

(1) Synthesis of intermediate compound 17-2:
dissolve 10 mmol of the intermediate compound 15-8, 10 mmol of compound 17-1, 0.2 mmol of palladium dibenzylidene acetone (Pd(dba)₂), 0.4 mmol of tri tert butyl phosphine (TTBP), and 60 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 5.78 mmol of the intermediate compound 17-2. A yield is 57.8%. A result of ASAP-MS of the intermediate compound 17-2 is as following: MS (ASAP)=1022.

(2) Synthesis of the organic compound M17:
add 10 mmol of the intermediate compound 17-2 and 100 mL of dry tert butyl benzene into a three necked flask (250 mL). Cool the solution to a temperature of −30° C. in nitrogen atmosphere. Add n-hexane solution of 21 mmol of tert butyl lithium (t-BuLi) dropwise to the solution. Raise the temperature of the solution to 60° C., react for 2 hours, and then evaporate n-hexane of the n-hexane solution under reduced pressure. Cool the reaction solution to a temperature of −30° C. again. Add 21 mmol of boron tribromide. Raise the temperature of the reaction solution to room temperature and stir it for 0.5 hour. Then cool the reaction solution to a temperature of 0° C. Add 42 mmol of N, N-diisopropylethylamine. After dropping, raise the temperature of the reaction solution to room temperature and stir it. Then continue to raise the temperature of the reaction solution to 120° C. and stir it for 3 hours. Cool the reaction solution to room temperature. Add sodium carbonate aqueous solution and ethyl acetate for quenching reaction. Extract aqueous phase with ethyl acetate, and combine organic phase. Rotary evaporate the organic phase to remove solvent to obtain crude product. Purify the crude product with silica gel column to obtain pure product. Recrystallize the pure product with toluene and ethyl acetate to obtain light yellow solid powder, namely the organic compound M17. A yield is 41.5%. A result of ASAP-MS of the organic compound M17 is as following: MS (ASAP)=996.

### Embodiment 18

### Synthesis of Organic Compound M18

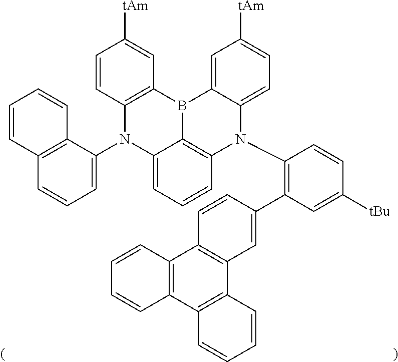

Synthetic Route of a biphenyl-based organic compound M18 containing boron is as following:

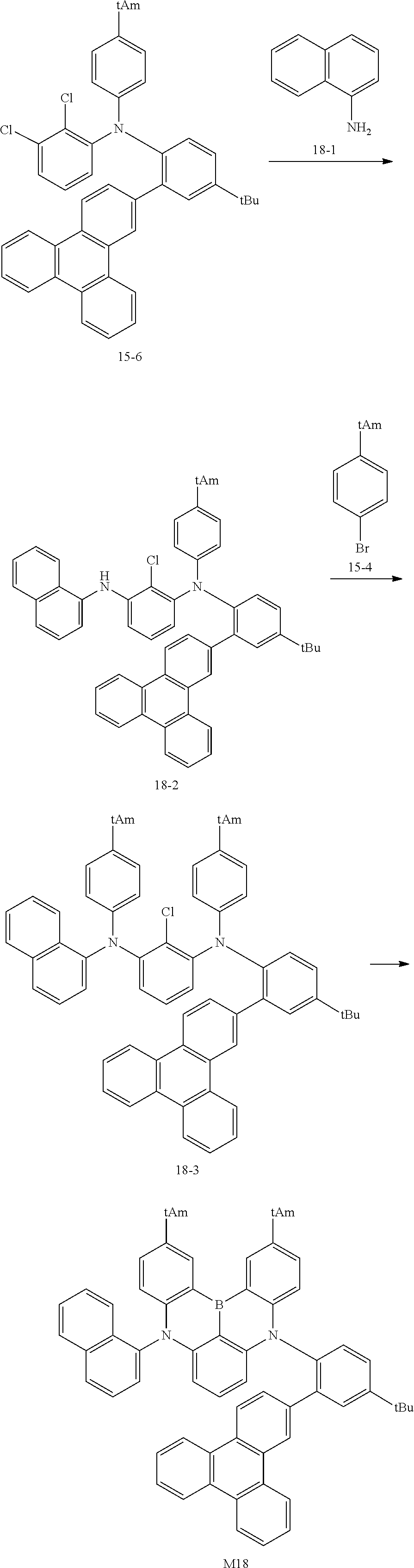

Specific synthesis steps of the organic compound M18 are as following:

(1) Synthesis of intermediate compound 18-2:
dissolve 10 mmol of the intermediate compound 15-6, 10 mmol of compound 18-1, 0.2 mmol of palladium dibenzylidene acetone (Pd(dba)₂), 0.4 mmol of tri tert butyl phosphine (TTBP), and 60 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 6.39 mmol of the intermediate compound 18-2. A yield is 63.9%. MS (ASAP)=772.

(2) Synthesis of intermediate compound 18-3:
dissolve 10 mmol of the intermediate compound 18-2, 10 mmol of the compound 15-4, 0.2 mmol of palladium dibenzylidene acetone (Pd(dba)₂), 0.4 mmol of tri tert butyl phosphine (TTBP), and 60 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 5.26 mmol of the intermediate compound 18-3. A yield is 52.6%. MS (ASAP)=918.

(3) Synthesis of the organic compound M18: add 10 mmol of the intermediate compound 18-3 and 100 mL of dry tert butyl benzene into a three necked flask (250 mL). Cool the solution to a temperature of −30° C. in nitrogen atmosphere. Add n-hexane solution of 21 mmol of tert butyl lithium (t-BuLi) dropwise to the solution. Raise the temperature of the solution to 60° C., react for 2 hours, and then evaporate n-hexane of the n-hexane solution under reduced pressure. Cool the reaction solution to a temperature of −30° C. again. Add 21 mmol of boron tribromide. Raise the temperature of the reaction solution to room temperature and stir it for 0.5 hour. Then cool the reaction solution to a temperature of 0° C. Add 42 mmol of N, N-diisopropylethylamine. After dropping, raise the temperature of the reaction solution to room temperature and stir it. Then continue to raise the temperature of the reaction solution to 120° C. and stir it for 3 hours. Cool the reaction solution to room temperature. Add sodium carbonate aqueous solution and ethyl acetate for quenching reaction. Extract aqueous phase with ethyl acetate, and combine organic phase. Rotary evaporate the organic phase to remove solvent to obtain crude product. Purify the crude product with silica gel column to obtain pure product. Recrystallize the pure product with toluene and ethyl acetate to obtain light yellow solid powder, namely the organic compound M18. A yield is 32.7%. MS (ASAP)=892.

### Embodiment 19

### Synthesis of Organic Compound M19

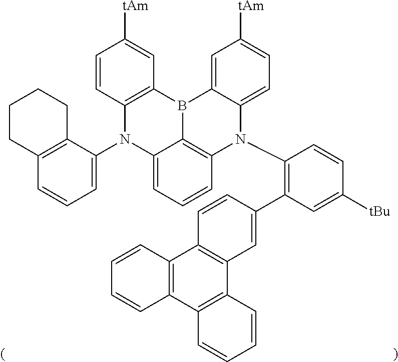

Synthetic Route of the Organic Compound M19 is as following:

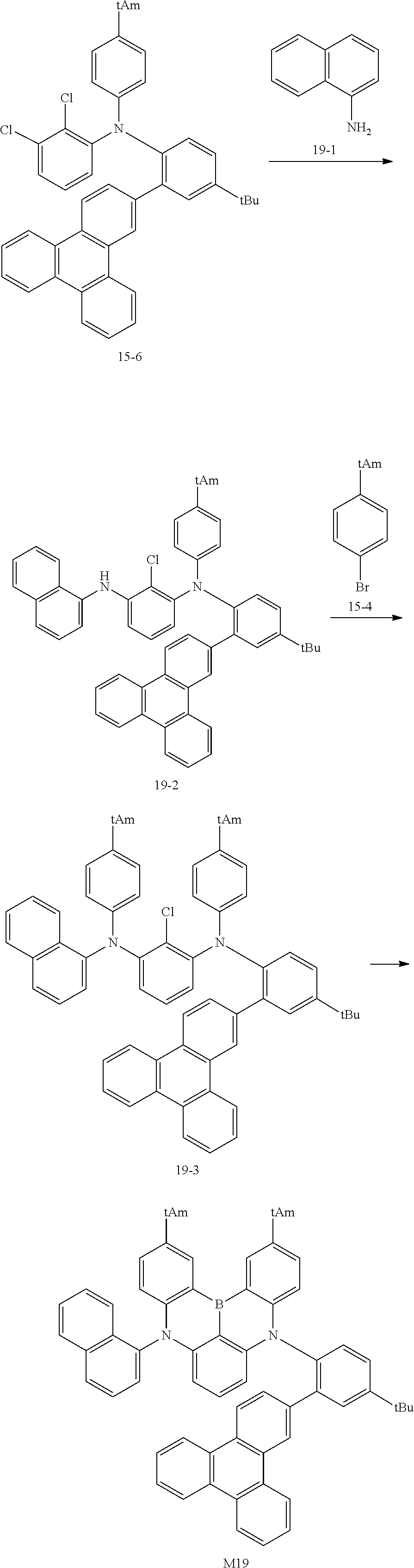

Specific synthesis steps of the organic compound M19 are as following:

(1) Synthesis of intermediate compound 19-2:
dissolve 10 mmol of the intermediate compound 15-6, 10 mmol of the intermediate compound 9-1, 0.2 mmol of palladium dibenzylidene acetone (Pd(dba)₂), 0.4 mmol of tri tert butyl phosphine (TTBP), and 60 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 7.59 mmol of the intermediate compound 19-2. A yield is 75.9%. MS (ASAP)=776.

(2) Synthesis of intermediate compound 19-3:
dissolve 10 mmol of the intermediate compound 19-2, 10 mmol of the compound 15-4, 0.2 mmol of palladium dibenzylidene acetone (Pd(dba)₂), 0.4 mmol of tri tert butyl phosphine (TTBP), and 60 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 6.57 mmol of the intermediate compound 19-3. A yield is 65.7%. MS (ASAP)=922.

(3) Synthesis of the organic compound M19: add 10 mmol of the intermediate compound 19-3 and 100 mL of dry tert butyl benzene into a three necked flask (250 mL). Cool the solution to a temperature of −30° C. in nitrogen atmosphere. Add n-hexane solution of 21 mmol of tert butyl lithium (t-BuLi) dropwise to the solution. Raise the temperature of the solution to 60° C., react for 2 hours, and then evaporate n-hexane of the n-hexane solution under reduced pressure. Cool the reaction solution to a temperature of −30° C. again. Add 21 mmol of boron tribromide. Raise the temperature of the reaction solution to room temperature and stir it for 0.5 hour. Then cool the reaction solution to a temperature of 0° C. Add 42 mmol of N, N-diisopropylethylamine. After dropping, raise the temperature of the reaction solution to room temperature and stir it. Then continue to raise the temperature of the reaction solution to 120° C. and stir it for 3 hours. Cool the reaction solution to room temperature. Add sodium carbonate aqueous solution and ethyl acetate for quenching reaction. Extract aqueous phase with ethyl acetate, and combine organic phase. Rotary evaporate the organic phase to remove solvent to obtain crude product. Purify the crude product with silica gel column to obtain pure product. Recrystallize the pure product with toluene and ethyl acetate to obtain light yellow solid powder, namely the organic compound M19. A yield is 45.3%. MS (ASAP)=896.

### Embodiment 20

### Synthesis of Organic Compound M20

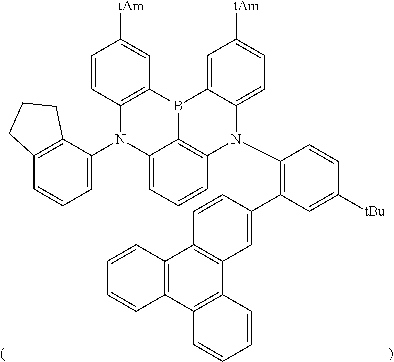

Synthetic Route of the Organic Compound M20 is as following:

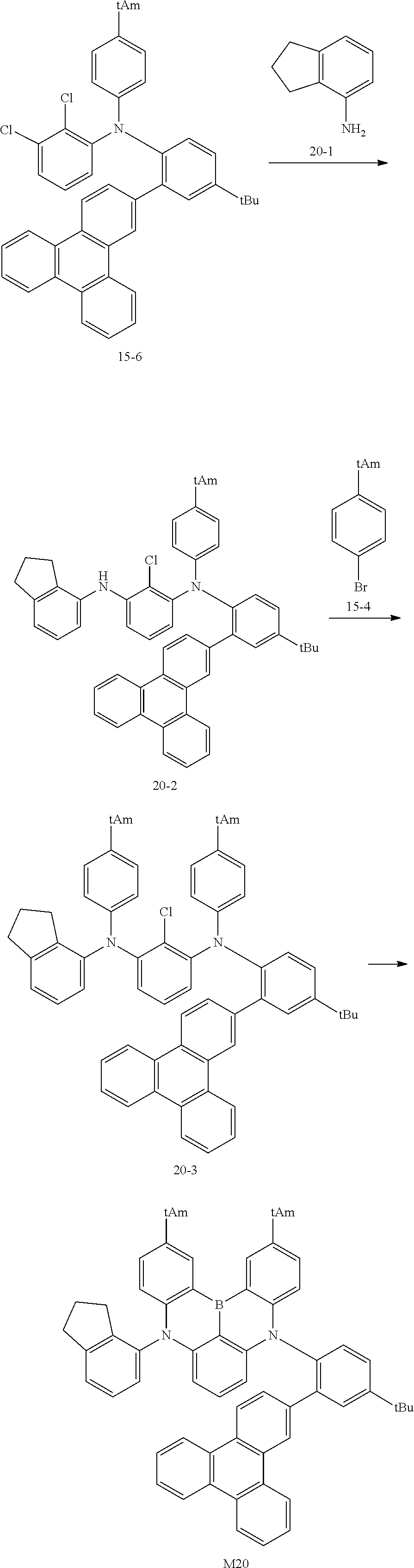

Specific synthesis steps of the organic compound M20 are as following:

(1) Synthesis of intermediate compound 20-2:
dissolve 10 mmol of the intermediate compound 15-6, 10 mmol of compound 20-1, 0.2 mmol of palladium dibenzylidene acetone (Pd(dba)₂), 0.4 mmol of tri tert butyl phosphine (TTBP), and 60 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 7.12 mmol of the intermediate compound 20-2. A yield is 71.2%. MS (ASAP)=762.

(2) Synthesis of intermediate compound 20-3:
dissolve 10 mmol of the intermediate compound 20-2, 10 mmol of the compound 15-4, 0.2 mmol of palladium dibenzylidene acetone (Pd(dba)₂), 0.4 mmol of tri tert butyl phosphine (TTBP), and 60 mmol of sodium tert butoxide in toluene. In nitrogen atmosphere, stir the solution at a temperature of 100° C. for 6 hours. After cooling, rotary evaporate the solution to remove solvent. Then extract the solution, wash with water, and purify the organic phase in column chromatography to obtain 5.48 mmol of the intermediate compound 20-3. A yield is 54.8%. MS (ASAP)=908.

(3) Synthesis of the organic compound M20:
add 10 mmol of the intermediate compound 20-3 and 100 mL of dry tert butyl benzene into a three necked flask (250 mL). Cool the solution to a temperature of −30° C. in nitrogen atmosphere. Add n-hexane solution of 21 mmol of tert butyl lithium (t-BuLi) dropwise to the solution. Raise the temperature of the solution to 60° C., react for 2 hours, and then evaporate n-hexane of the n-hexane solution under reduced pressure. Cool the reaction solution to a temperature of −30° C. again. Add 21 mmol of boron tribromide. Raise the temperature of the reaction solution to room temperature and stir it for 0.5 hour. Then cool the reaction solution to a temperature of 0° C. Add 42 mmol of N, N-diisopropylethylamine. After dropping, raise the temperature of the reaction solution to room temperature and stir it. Then continue to raise the temperature of the reaction solution to 120° C. and stir it for 3 hours. Cool the reaction solution to room temperature. Add sodium carbonate aqueous solution and ethyl acetate for quenching reaction. Extract aqueous phase with ethyl acetate, and combine organic phase. Rotary evaporate the organic phase to remove solvent to obtain crude product. Purify the crude product with silica gel column to obtain pure product. Recrystallize the pure product with toluene and ethyl acetate to obtain light yellow solid powder, namely the organic compound M20. A yield is 47.9%. MS (ASAP)=882.

### Comparative Example 1

Comparative compound 1 of the comparative example 1 is adopted as a comparative compound of the above-mentioned organic compounds in embodiment 1 to embodiment 20. The comparative compound 1 is represented by formula as following:

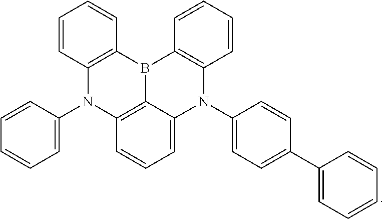 [SMILES: c1ccc(-c2ccc(N3c4ccccc4B4c5ccccc5N(c5ccccc5)c5cccc3c54)cc2)cc1]

As shown in table 1, highest occupied molecular orbital (HOMO) energy levels, lowest unoccupied molecular orbital (LUMO) energy levels, first excited triplet state (Ti) energy levels, and first excited singlet state (Si) energy levels of the organic compounds M1 to M20 respectively obtained from the embodiments 1 to 20 and the comparative compound 1 of the comparative example 1 can be obtained through quantum calculation. In detail, time-dependent density functional theory (TD-DFT) is adopted to optimize molecular geometry through Gaussian 09W (Gaussian Inc.). Referring to WO201141110 for specific simulation methods. A semi-empirical method “Ground State/Semi empirical/Default Spin/AM1” (Charge 0/Spin Single) is first adopted to optimize molecular geometry. Then energy structures of organic molecules are calculated by the TD-DFT method to obtain “TD-SCF/DFT/Default Spin/B3PW91” and a base group “6-31G (d)” (Charge 0/Spin Single). The HOMO energy levels and the LUMO energy levels are calculated according to following calibration formulas. The Si energy levels and the Ti energy levels are adopted directly.

HOMO (eV)=((HOMO (G)×27.212)−0.9899)/1.1206

LUMO (eV)=((LUMO (G)×27.212)−2.0041)/1.385

The HOMO energy levels, the LUMO energy levels, the Ti energy levels, and the Si energy levels are direct calculation results of Gaussian09W, and units of the HOMO energy levels, the LUMO energy levels, the Ti energy levels, and the Si energy levels are all Hartree.

Table 1 is calculation results of the HOMO energy levels, the LUMO energy levels, the Si energy levels, and the Ti energy levels of the organic compounds M1 to M20 and the comparative compound 1.

TABLE 1

| | | HOMO | LUMO | T1 | S1 |
|---|---|---|---|---|---|
| | | energy | energy | energy | energy |
| | | level | level | level | level |
| | Compound | (eV) | (eV) | (eV) | (eV) |
| Embodiment 1 | Organic | −5.13 | −2.27 | 2.59 | 3.0 |
| | compound M1 | | | | |
| Embodiment 2 | Organic | −5.15 | −2.25 | 2.48 | 3.02 |
| | compound M2 | | | | |
| Embodiment 3 | Organic | −5.17 | −2.23 | 2.59 | 3.12 |
| | compound M3 | | | | |
| Embodiment 4 | Organic | −5.13 | −2.29 | 2.61 | 3.14 |
| | compound M4 | | | | |
| Embodiment 5 | Organic | −5.08 | −2.31 | 2.54 | 3.02 |
| | compound M5 | | | | |
| Embodiment 6 | Organic | −5.12 | −2.35 | 2.53 | 3.00 |
| | compound M6 | | | | |
| Embodiment 7 | Organic | −4.98 | −2.26 | 2.59 | 2.97 |
| | compound M7 | | | | |
| Embodiment 8 | Organic | −5.15 | −2.21 | 2.51 | 2.99 |
| | compound M8 | | | | |
| Embodiment 9 | Organic | −5.13 | −2.30 | 2.49 | 3.08 |
| | compound M9 | | | | |
| Embodiment 10 | Organic | −5.09 | −2.31 | 2.43 | 3.02 |
| | compound M10 | | | | |
| Embodiment 11 | Organic | −5.18 | −2.30 | 2.56 | 3.00 |
| | compound M11 | | | | |
| Embodiment 12 | Organic | −4.97 | −2.32 | 2.59 | 2.98 |
| | compound M12 | | | | |
| Embodiment 13 | Organic | −4.96 | −2.31 | 2.54 | 3.02 |
| | compound M13 | | | | |
| Embodiment 14 | Organic | −5.05 | −2.27 | 2.58 | 3.05 |
| | compound M14 | | | | |
| Embodiment 15 | Organic | −5.01 | −2.27 | 2.51 | 3.01 |
| | compound M15 | | | | |
| Embodiment 16 | Organic | −5.05 | −2.32 | 2.57 | 3.00 |
| | compound M16 | | | | |
| Embodiment 17 | Organic | −5.02 | −2.29 | 2.57 | 3.06 |
| | compound M17 | | | | |
| Embodiment 18 | Organic | −4.91 | −2.23 | 2.42 | 3.02 |
| | compound M18 | | | | |
| Embodiment 19 | Organic | −5.01 | −2.37 | 2.51 | 3.05 |
| | compound M19 | | | | |
| Embodiment 20 | Organic | −5.00 | −2.15 | 2.59 | 2.98 |
| | compound M20 | | | | |
| Comparative | Comparative | −5.02 | −2.25 | 2.46 | 2.89 |
| example 1 | compound 1 | | | | |

It can be seen from the results in table 1 that the Ti energy levels and the Si energy levels of the organic compounds M1 to M20 provided in embodiments 1 to 20 of the present application are greater than the Ti energy level and the Si energy level of the comparative compound 1, indicating that compared with the comparative compound 1, blue light emitted by blue light-emitting elements adopting the organic compounds M1 to M20 as guest materials in light-emitting layers is more inclined to dark blue, which is conductive to obtaining better color coordinates for the blue light-emitting elements.

Exemplary manufacturing steps of the light-emitting elements provided by the embodiments are shown in following exemplary embodiment 21.

### Embodiment 21

In the light-emitting elements provided by the embodiment, indium tin oxide (ITO) is adopted as a material of the anode. Polyethylene dioxythiophene (PEDOT, Clevios™ AI4083) is adopted as a material of the hole injection layer. PVK (Sigma Aldrich, an average molecular weight ranges from 25000 to 50000) is adopted as a material of the hole transport layer. BH-1 to BH-3 are adopted as host materials in the light-emitting layers of corresponding light-emitting elements. The organic compounds M1 to M20 respectively obtained from the embodiments 1 to 20 and the comparative compound 1 of the comparative example 1 are independently adopted as a guest material in the light-emitting layer of the corresponding light-emitting element. ET and 8-hydroxyquinoline lithium (Liq) are adopted as materials of the electron transport layer. Al is adopted as a material of the cathode. Specific manufacturing steps are as following:
a, cleaning of an ITO anode: clean ITO conductive glass with chloroform, acetone, and/or isopropanol, and then perform an ultraviolet ozone treatment on the ITO anode;
b, forming the hole injection layer: spin coating the hole injection material of PEDOT on the ITO anode, and treat it on a hot plate at a temperature of 180° C. for 10 minutes. A thickness of the hole injection layer is 40 nm;
c, forming the hole transport layer: spin coating toluene solution of PVK with a concentration of 5 mg/mL on the hole injection layer, and then treat it on a hot plate at a temperature of 180° C. for 60 minutes. A thickness of the hole transport layer is 20 nm;
d, forming the light-emitting layer: in a nitrogen glovebox, spin coating the light-emitting materials on the hole transport layer, and then treat them on a hot plate at a temperature of 140° C. for 10 minutes. The host materials in the light-emitting layers of different light-emitting elements corresponds to BH-1, BH-2, or BH-3. The guest material in each of the light-emitting layers of corresponding light-emitting element corresponds to one of the organic compounds M1 to M20 respectively. A solvent is methyl benzoate. Amass ratio of the host material to the guest material in each light-emitting layer is 95:5. A concentration of the light-emitting material is 15 mg/mL. A thickness of a final formed light-emitting layer is 40 nm;
e, forming the electron transport layer: in a vacuum cavity, place ET and Liq above the light-emitting layer in different evaporation units. At a high vacuum (ix 10⁶ mbar) atmosphere, deposit ET and Liq together at a weight ratio of 50:50, so as to form the electron transport layer with a thickness of 20 nm;
f, forming the cathode: deposit Al on the electron transport layer to obtain the cathode containing Al with a thickness of 100 nm; and
g, encapsulation: encapsulate devices in a nitrogen glovebox with UV cured resin.

In detail, in the embodiment, light-emitting elements 1 to 21 and comparative elements 1 to 3 are obtained through the above-mentioned steps. The guest materials adopted in the light-emitting elements 1 to 20 are respectively the organic compounds M1 to M20. The host materials adopted in the light-emitting elements 1 to 20 are all BH-1. The guest materials adopted in the light-emitting element 21 and the light-emitting element 22 are the organic compound M4 and the organic compound M5, respectively. The host materials adopted in the light-emitting element 18 and the light-emitting element 19 are both BH-2. The guest materials adopted in the light-emitting element 23 and the light-emitting element 24 are the organic compound M4 and the organic compound M5, respectively. The host materials adopted in the light-emitting element 23 and the light-emitting element 24 are both BH-3. The guest materials adopted in the comparative elements 1 to 3 are the comparative compound 1. The host materials adopted in the comparative elements 1 to 3 are BH-1, BH-2, and BH-3, respectively.

In detail structural formulas of BH-1. BH-2. BH-3, ET, and Liq are as following:

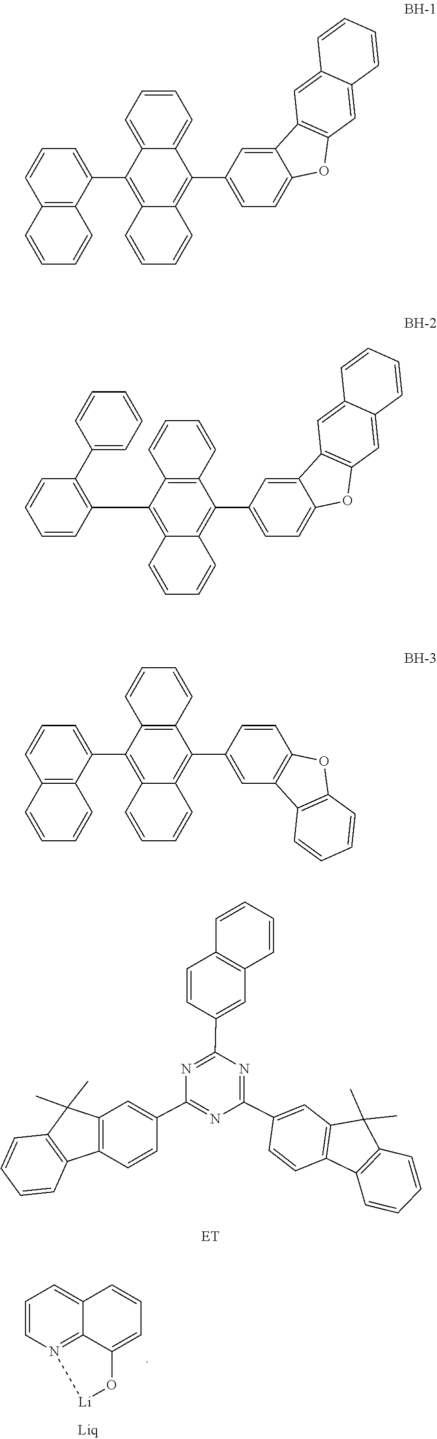

In the embodiment, current-voltage (J-V) characteristics of the light-emitting elements 1 to 24 and the comparative elements 1 to 3 are tested to obtain chromaticity coordinates (CIE, (x, y)), driving voltages (voltage@1 knits, V) at brightness of 1 knits, and light-emitting efficiency (CE@1 knits, cd/A) obtained at a current density of 10 mA/cm², and times (LT90@1 knits, h) taken for brightness to decrease from initial brightness of 1 knits to 90% of the initial brightness of each light-emitting element and each comparative element. Specific results are shown in table 2.

Table 2 shows performance data of the light-emitting elements 1 to 24 and the comparative elements 1 to 3.

TABLE 2

| | | | | Voltage | CE@ | LT90@ |
|---|---|---|---|---|---|---|
| | | Host | CIE | @1knits | 1knits | 1knits |
| | Gust material | material | (x, y) | (V) | (cd/A) | (h) |
| Light-emitting element 1 | Organic compound M1 | BH-1 | 0.141, 0.083 | 5.5 | 5.7 | 131 |
| Light-emitting element 2 | Organic compound M2 | BH-1 | 0.141, 0.082 | 5.5 | 6.4 | 163 |
| Light-emitting element 3 | Organic compound M3 | BH-1 | 0.143, 0.081 | 5.5 | 6.2 | 167 |
| Light-emitting element 4 | Organic compound M4 | BH-1 | 0.143, 0.081 | 5.5 | 6.4 | 168 |
| Light-emitting element 5 | Organic compound M5 | BH-1 | 0.141, 0.081 | 5.5 | 6.5 | 170 |
| Light-emitting element 6 | Organic compound M6 | BH-1 | 0.143, 0.082 | 5.5 | 5.7 | 135 |
| Light-emitting element 7 | Organic compound M7 | BH-1 | 0.142, 0.082 | 5.6 | 5.8 | 131 |
| Light-emitting element 8 | Organic compound M8 | BH-1 | 0.141, 0.087 | 5.5 | 5.7 | 130 |
| Light-emitting element 9 | Organic compound M9 | BH-1 | 0.141, 0.087 | 5.5 | 5.8 | 133 |
| Light-emitting element 10 | Organic compound M10 | BH-1 | 0.142, 0.086 | 5.7 | 5.7 | 129 |
| Light-emitting element 11 | Organic compound M11 | BH-1 | 0.141, 0.087 | 5.5 | 5.9 | 134 |
| Light-emitting element 12 | Organic compound M12 | BH-1 | 0.141, 0.087 | 5.5 | 5.9 | 141 |
| Light-emitting element 13 | Organic compound M13 | BH-1 | 0.141, 0.084 | 5.5 | 6.4 | 165 |
| Light-emitting element 14 | Organic compound M14 | BH-1 | 0.141, 0.083 | 5.5 | 6.2 | 161 |
| Light-emitting element 15 | Organic compound M15 | BH-1 | 0.141, 0.081 | 5.5 | 6.1 | 160 |
| Light-emitting element 16 | Organic compound M16 | BH-1 | 0.141, 0.083 | 5.5 | 6.3 | 167 |
| Light-emitting element 17 | Organic compound M17 | BH-1 | 0.141, 0.083 | 5.5 | 6.1 | 161 |
| Light-emitting element 18 | Organic compound M18 | BH-1 | 0.143, 0.089 | 5.5 | 5.8 | 151 |
| Light-emitting element 19 | Organic compound M19 | BH-1 | 0.143, 0.090 | 5.5 | 5.8 | 153 |
| Light-emitting element 20 | Organic compound M20 | BH-1 | 0.143, 0.089 | 5.5 | 5.9 | 160 |
| Light-emitting element 21 | Organic compound M4 | BH-2 | 0.143, 0.102 | 5.5 | 5.9 | 167 |
| Light-emitting element 22 | Organic compound M5 | BH-2 | 0.143, 0.099 | 5.5 | 5.8 | 163 |
| Light-emitting element 23 | Organic compound M4 | BH-3 | 0.143, 0.094 | 5.6 | 6.0 | 159 |
| Light-emitting element 24 | Organic compound M5 | BH-3 | 0.143, 0.097 | 5.6 | 6.1 | 161 |
| Comparative element 1 | Comparative compound 1 | BH-1 | 0.152, 0.138 | 6.0 | 3.1 | 102 |
| Comparative element 2 | Comparative compound 1 | BH-2 | 0.154, 0141 | 5.8 | 2.8 | 116 |
| Comparative element 3 | Comparative compound 1 | BH-3 | 0.157, 0161 | 6.0 | 3.3 | 125 |

It can be seen from table 2 that the light-emitting elements 1 to 24 obtained by adopting the organic compounds 1 to 20 as guest materials in the light-emitting layers have better color coordinates than the comparative elements 1 to 3. Further, light-emitting efficiency of the light-emitting elements 1 to 24 range from 5.7 cd/A to 6.5 cd/A, indicating that the light-emitting efficiency is much greater than light-emitting efficiency of the comparative elements 1 to 3. Furthermore, times taken for brightness of the light-emitting elements 1 to 24 to decrease from initial brightness of 1 knits to 90% of the initial brightness are all range from 129 hours to 170 hours. Compared with the times taken for brightness of the comparative elements 1 to 3 to decrease from initial brightness of 1 knits to 90% of the initial brightness, an increase amplitude of the light-emitting elements 1 to 24 ranges from 30% to 70%, indicating that life of the light-emitting elements 1 to 24 are significantly improved.

At the same time, compared with the comparative example 1, an introduction of benzene ring and aromatic ring in the organic compounds M1 to M20 makes overall molecular solubility better, and purification is easily performed in manufacturing of the organic compounds, so as to improve purity of the organic compounds, thus improving the light-emitting efficiency and the life of the light-emitting elements.

In addition, the light-emitting efficiency of the light-emitting elements 2, 3, 4, 5, 13, 14, 15, 16, and 17 are all in a range of 6.2 cd/A to 6.5 cd/A, and their life are about 160 hours. This is because compared with the guest materials in other light-emitting elements, overall molecular conjugation of the above-mentioned elements are greater, and quantities of solubilizing groups of the above-mentioned guest materials are more, which improves solubility of the guest materials, and further improves the light-emitting efficiency and the life of the light-emitting elements.

In the light-emitting elements disclosed by the embodiments of the present application, by adopting boron-nitrogen-based compounds, and introducing groups that make the overall conjugation of the boron-nitrogen-based compounds greater in the boron-nitrogen compounds, performances of materials adopting the boron-nitrogen-based compounds can be improved, which improves the light-emitting efficiency of the light-emitting elements and prolongs the life of the light-emitting elements.

A display panel is further disclosed in another embodiment of the present application. The display panel includes any of the above-mentioned light-emitting elements.

The display panel further includes an array substrate disposed on a side of the light-emitting element and an encapsulating layer disposed on a side of the light-emitting element away from the array substrate and covering the light-emitting element. The display panel further includes a polarizer layer located at a side of the encapsulating layer away from the light-emitting element and a cover plate layer located at a side of the polarizer layer away from the light-emitting element. The polarizer layer may be replaced by a color film layer. The color film layer may include a plurality of color resistors and black matrixes. The black matrix is located on both sides of the color resistor.

In the display panel disclosed by the embodiment of the present application, by adopting the light-emitting element containing the boron-nitrogen-based compound, and introducing groups that make the overall conjugation of the boron-nitrogen-based compounds greater in the boron-nitrogen compounds, a conjugation effect of materials adopted in the light-emitting element can be enhanced, which improves performances of the materials adopting the boron-nitrogen-based compound, improves light-emitting efficiency of the display panel, and prolongs life of the display panel.

The embodiments of the present application disclose the organic compound, the light-emitting element containing the organic compound, and the display panel including the light-emitting element. The organic compound is represented by Formula (1):

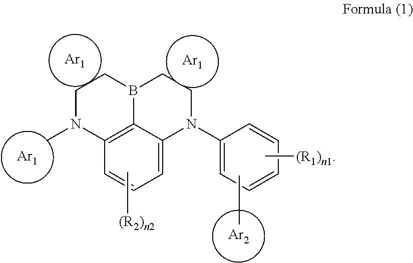

By introducing groups that make the overall conjugation of the boron-nitrogen-based compound greater in the boron-nitrogen compound, performances of materials adopting the boron-nitrogen-based compound can be improved, which improves the light-emitting efficiency of the light-emitting element and prolongs the life of the light-emitting element.

The organic compound, the light-emitting element, and the display panel provided by the embodiments of the present application are described in detail. In this paper, specific embodiments are adopted to illustrate a principle and implementation modes of the present application. The description of the above-mentioned embodiments is only used to help understand methods and a core idea of the present application. At the same time, for those skilled in the art, according to the idea of the present application, there will be changes in specific implementation modes and a scope of the present application. In conclusion, contents of the specification should not be interpreted as a limitation of the present application.

What is claimed is:

1. An organic compound represented by Formula (1): 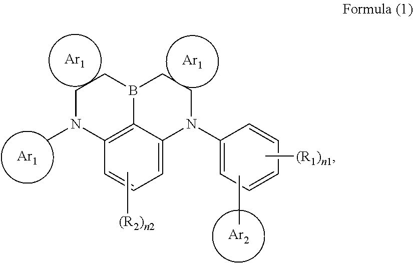
wherein each of Ar₁ groups is independently selected from structures represented by formula (A-1) to formula (A-5): 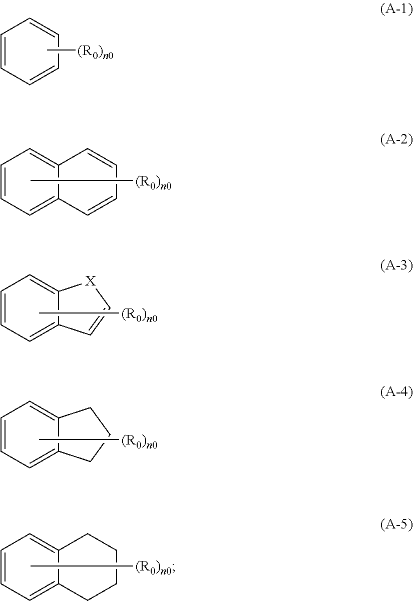
Ar₂ is selected from —H and structures represented by formula (B-1) to formula (B-4): 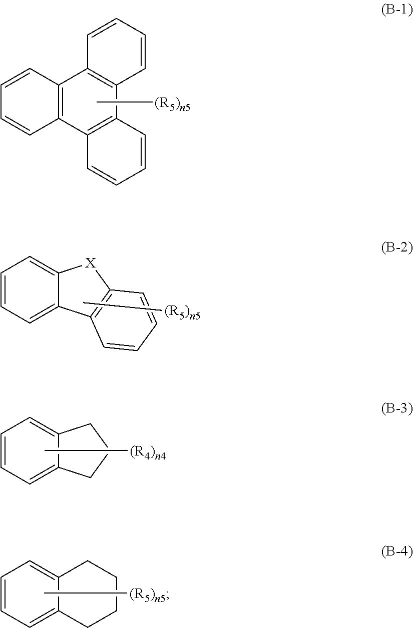
X is independently selected from O, S, N—CH₃, N-Ph, and C(CH₃)₂;
each of n₀, n₁, n₂, and n₅ is independently selected from 0 to 11;
each of R₀, R₁, R₂, and R₅ is independently selected from —H, -D, a C₁-C₂₀ linear alkyl group, a C₃-C₂₀ branched alkyl group, a substituted or unsubstituted aromatic group containing 6 to 30 ring atoms, and a substituted or unsubstituted heteroaromatic group containing 5 to 30 ring atoms; and
when n₀ is greater than or equal to 2, a ring is formed or no ring is formed between two adjacent R₀ groups; when n₁ is greater than or equal to 2, a ring is formed or no ring is formed between two adjacent R₁ groups; when n₂ is greater than or equal to 2, a ring is formed or no ring is formed between two adjacent R₂ groups; and when n₅ is greater than or equal to 2, a ring is formed or no ring is formed between two adjacent R₅ groups.

2. The organic compound of claim 1, wherein the organic compound is represented by any one of formula (2-1) to formula (2-18): 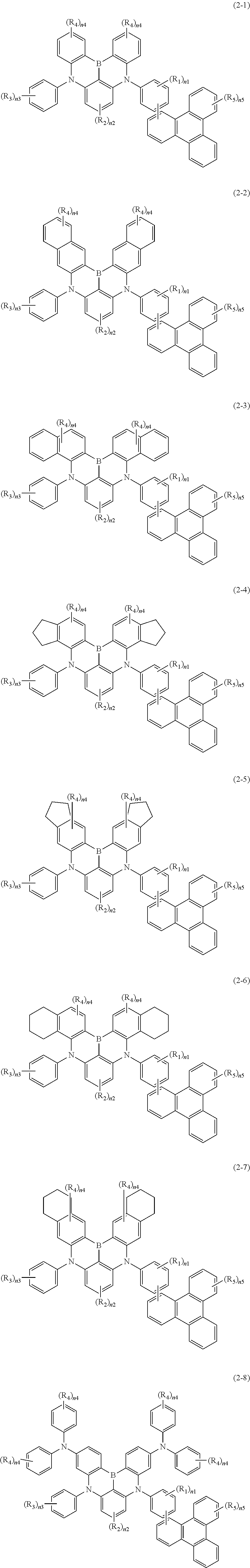 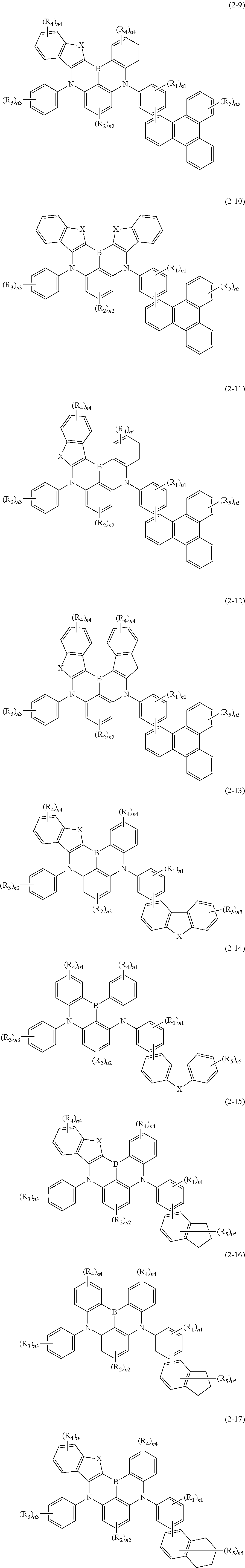 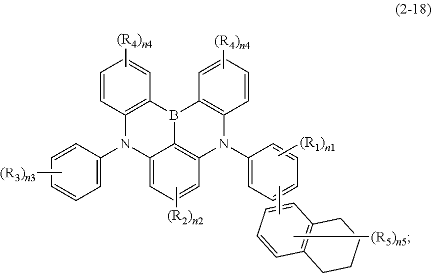
wherein each of R₃ and R₄ is independently selected from —H, -D, a C₁-C₂₀ linear alkyl group, a C₃-C₂₀ branched alkyl group, a substituted or unsubstituted aromatic group containing 6 to 30 ring atoms, and a substituted or unsubstituted heteroaromatic group containing 5 to 30 ring atoms;
each of n₃ and n₄ is independently selected from 0 to 11; and
when n₃ is greater than or equal to 2, a ring is formed or no ring is formed between two adjacent R₃ groups; and when n₄ is greater than or equal to 2, a ring is formed or no ring is formed between two adjacent R₄ groups.

3. The organic compound of claim 2, wherein each of R₁, R₂, R₃, R₄, and R₅ is independently selected from —H, -D, a C₁-C₁₀ linear alkyl group, and a C₃-C₁₀ branched alkyl group.

4. The organic compound of claim 3, wherein each of R₁, R₂, R₃, R₄, and R₅ is independently selected from —H, -D, a C₁-C₄ linear alkyl group, and a C₃-C₅ branched alkyl group.

5. The organic compound of claim 1, wherein a structure represented by the formula (A-3) is 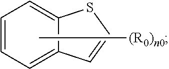
and
a structure represented by the formula (B-2) is

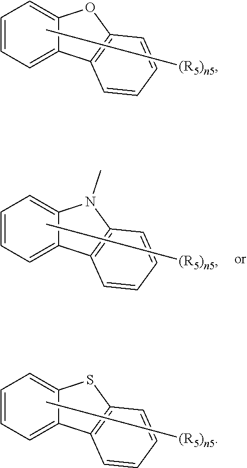

6. The organic compound of claim 1, wherein the organic compound is selected from compounds as following:

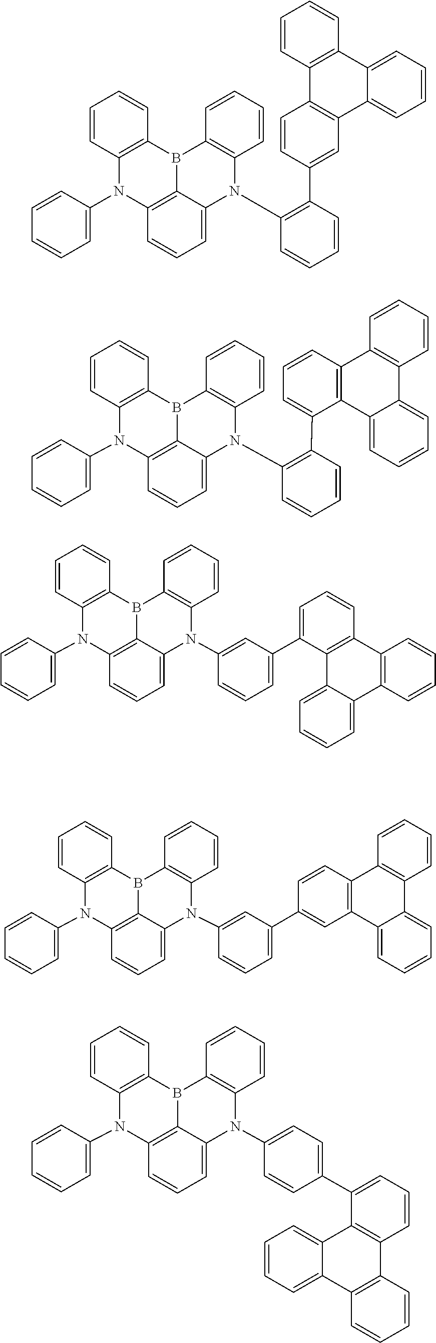

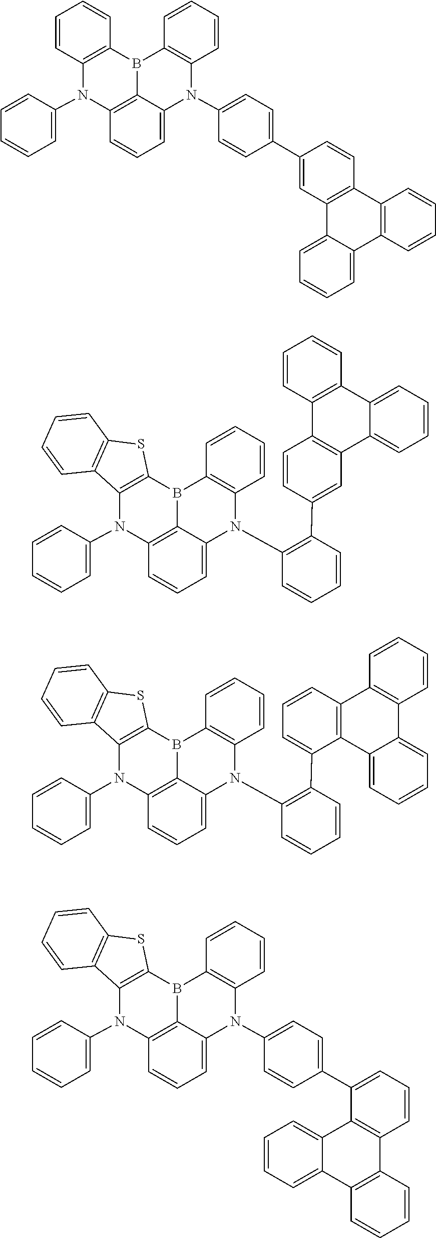

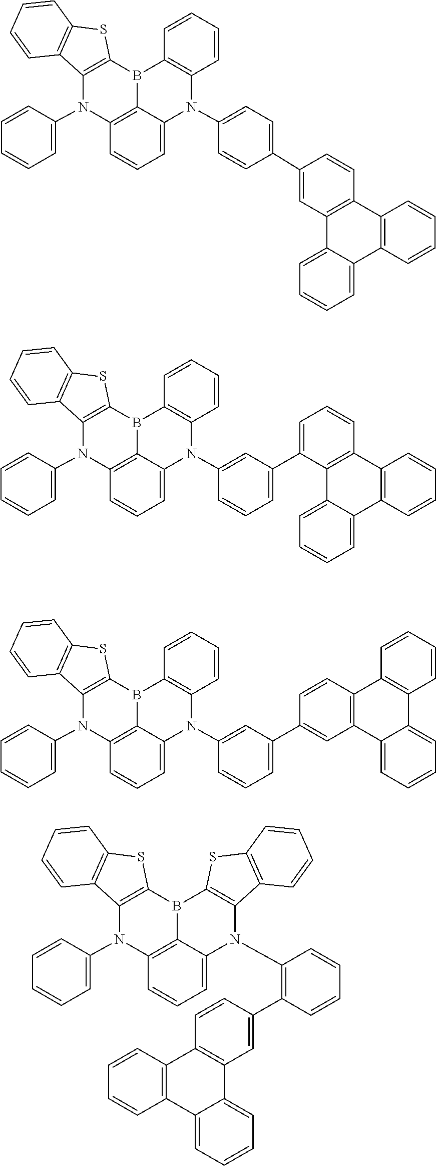

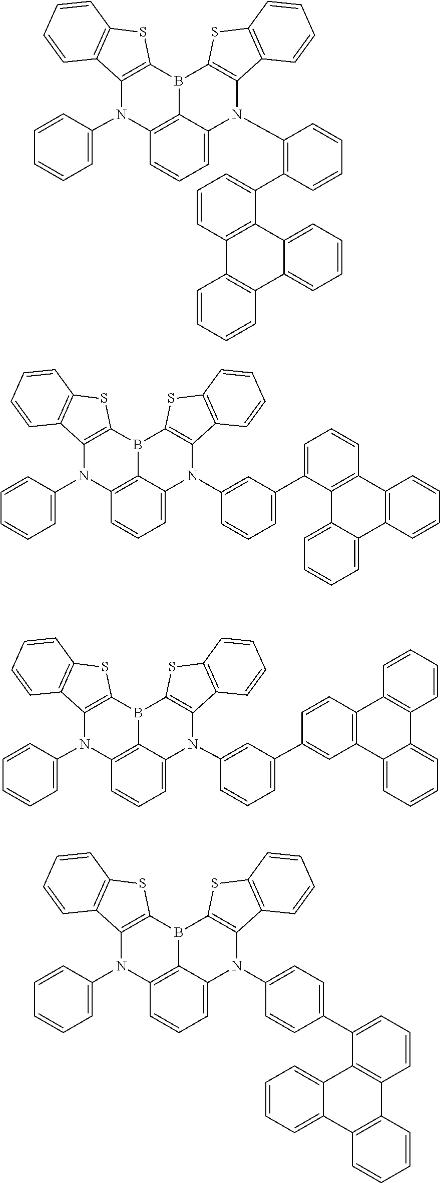

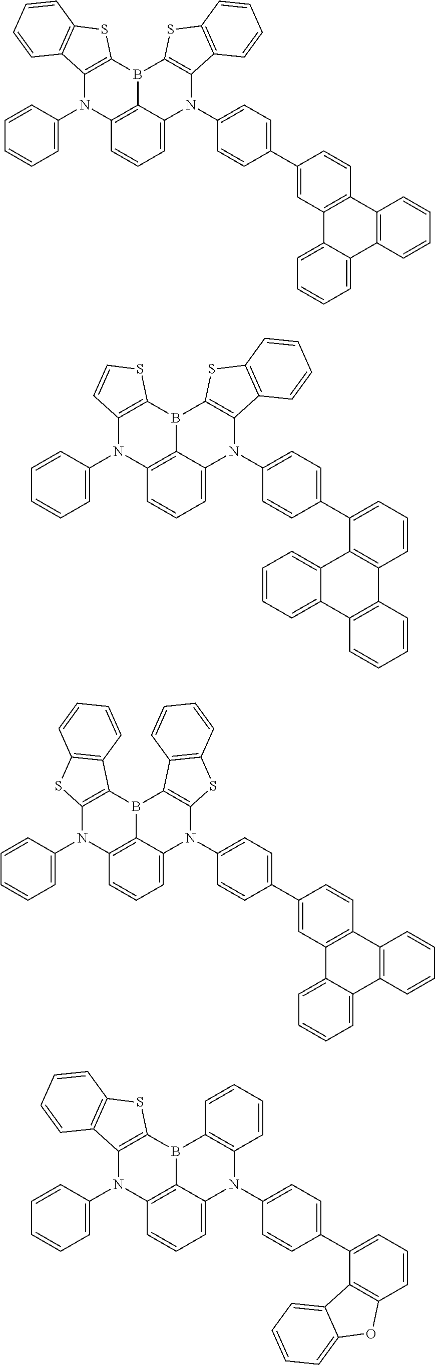 [SMILES: c1ccc(N2c3cccc4c3B(c3sc5ccccc5c32)c2sc3ccccc3c2N4c2ccc(-c3ccc4c5ccccc5c5ccccc5c4c3)cc2)cc1 ; c1ccc(N2c3ccsc3B3c4sc5ccccc5c4N(c4ccc(-c5cccc6c7ccccc7c7ccccc7c56)cc4)c4cccc2c43)cc1 ; c1ccc(N2c3cccc4c3B(c3c2sc2ccccc32)c2c(sc3ccccc23)N4c2ccc(-c3ccc4c5ccccc5c5ccccc5c4c3)cc2)cc1 ; c1ccc(N2c3cccc4c3B(c3ccccc3N4c3ccc(-c4cccc5oc6ccccc6c45)cc3)c3sc4ccccc4c32)cc1]

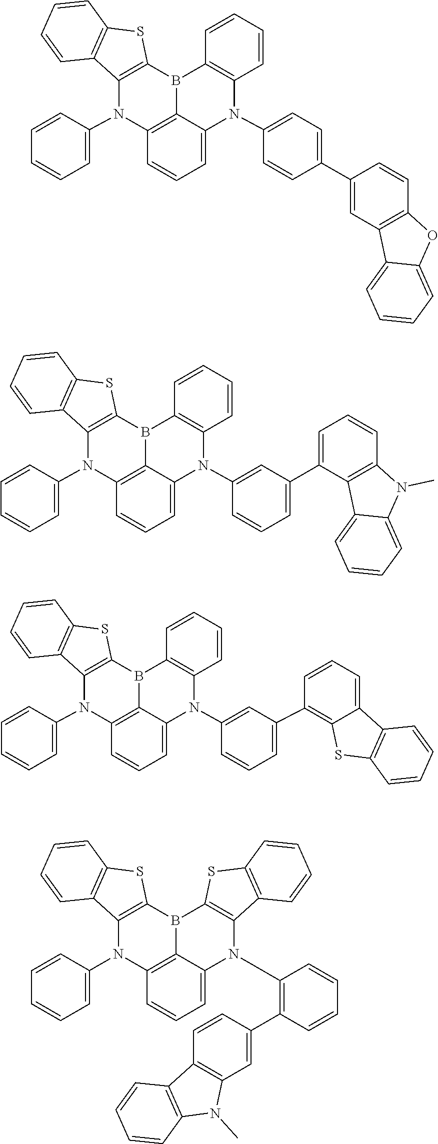 [SMILES: c1ccc(N2c3cccc4c3B(c3ccccc3N4c3ccc(-c4ccc5oc6ccccc6c5c4)cc3)c3sc4ccccc4c32)cc1 ; Cn1c2ccccc2c2c(-c3cccc(N4c5ccccc5B5c6sc7ccccc7c6N(c6ccccc6)c6cccc4c65)c3)cccc21 ; c1ccc(N2c3cccc4c3B(c3ccccc3N4c3cccc(-c4cccc5c4sc4ccccc45)c3)c3sc4ccccc4c32)cc1 ; Cn1c2ccccc2c2ccc(-c3ccccc3N3c4cccc5c4B(c4sc6ccccc6c4N5c4ccccc4)c4sc5ccccc5c43)cc21]

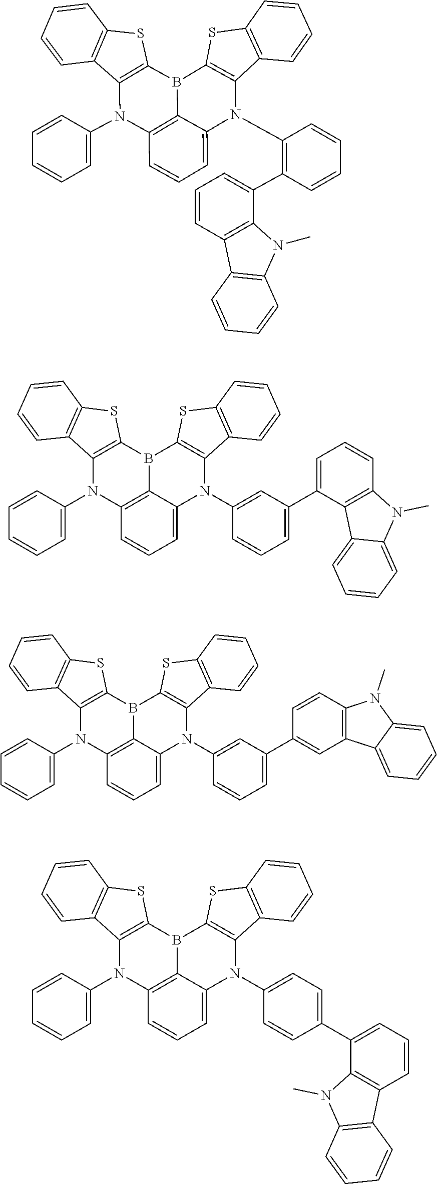 [SMILES: Cn1c2ccccc2c2cccc(-c3ccccc3N3c4cccc5c4B(c4sc6ccccc6c4N5c4ccccc4)c4sc5ccccc5c43)c21 ; Cn1c2ccccc2c2c(-c3cccc(N4c5cccc6c5B(c5sc7ccccc7c5N6c5ccccc5)c5sc6ccccc6c54)c3)cccc21 ; Cn1c2ccccc2c2cc(-c3cccc(N4c5cccc6c5B(c5sc7ccccc7c5N6c5ccccc5)c5sc6ccccc6c54)c3)ccc21 ; Cn1c2ccccc2c2cccc(-c3ccc(N4c5cccc6c5B(c5sc7ccccc7c5N6c5ccccc5)c5sc6ccccc6c54)cc3)c21]

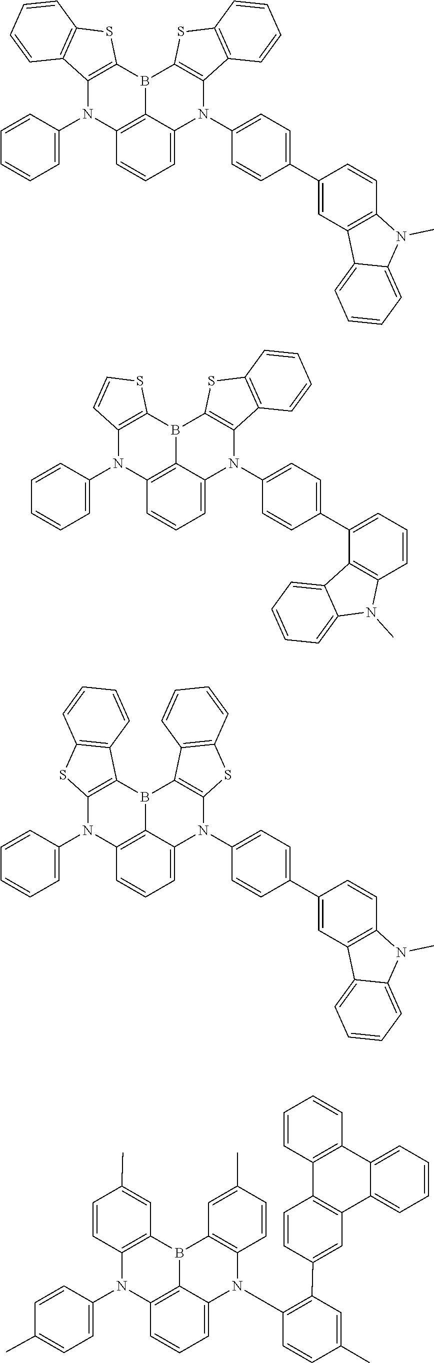

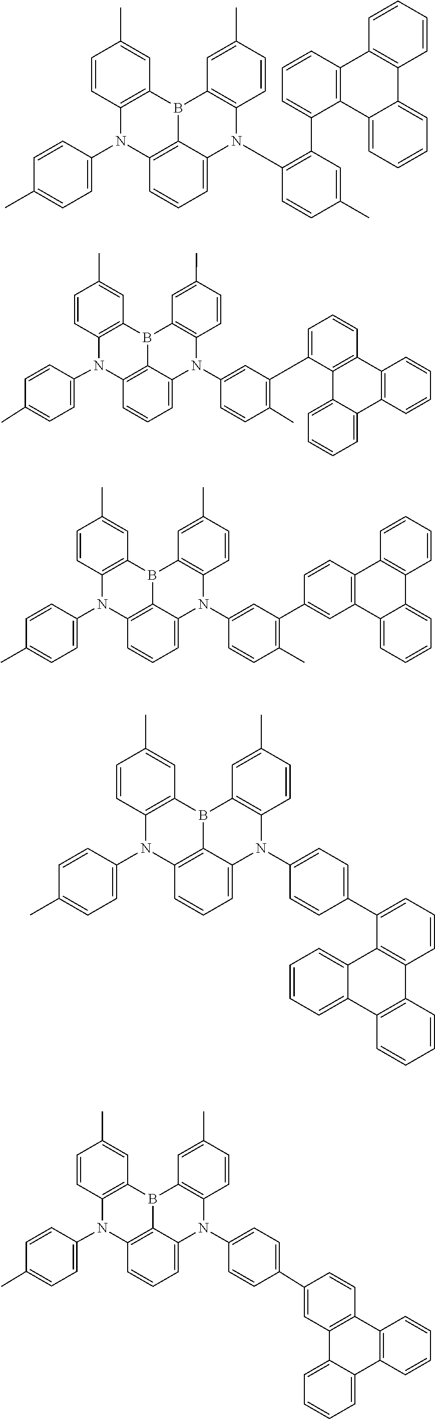 [SMILES: Cc1ccc(N2c3ccc(C)cc3B3c4cc(C)ccc4N(c4ccc(C)cc4-c4cccc5c6ccccc6c6ccccc6c45)c4cccc2c43)cc1 ; Cc1ccc(N2c3ccc(C)cc3B3c4cc(C)ccc4N(c4ccc(C)c(-c5cccc6c7ccccc7c7ccccc7c56)c4)c4cccc2c43)cc1 ; Cc1ccc(N2c3ccc(C)cc3B3c4cc(C)ccc4N(c4ccc(C)c(-c5ccc6c7ccccc7c7ccccc7c6c5)c4)c4cccc2c43)cc1 ; Cc1ccc(N2c3ccc(C)cc3B3c4cc(C)ccc4N(c4ccc(-c5cccc6c7ccccc7c7ccccc7c56)cc4)c4cccc2c43)cc1 ; Cc1ccc(N2c3ccc(C)cc3B3c4cc(C)ccc4N(c4ccc(-c5ccc6c7ccccc7c7ccccc7c6c5)cc4)c4cccc2c43)cc1]

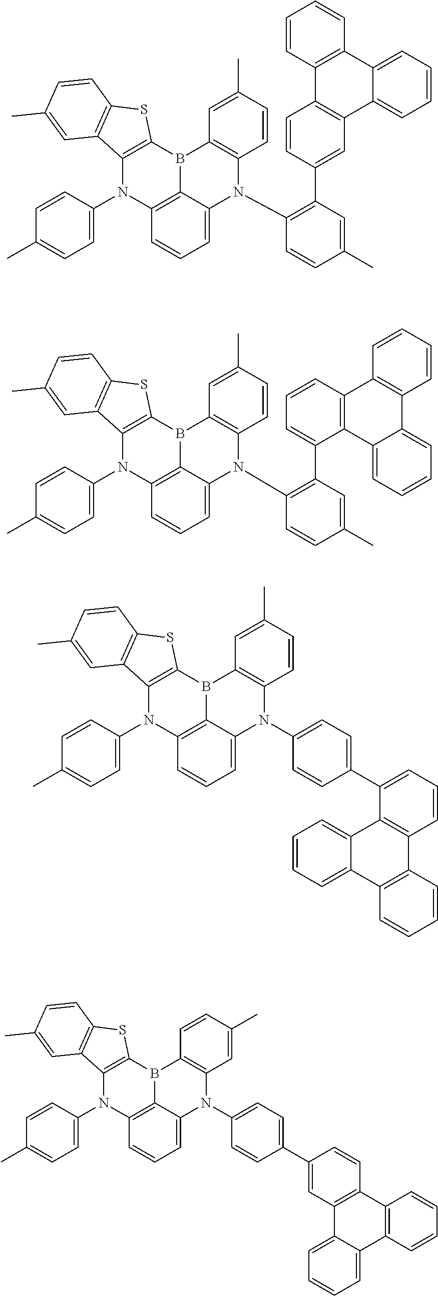 [SMILES: Cc1ccc(N2c3cccc4c3B(c3cc(C)ccc3N4c3ccc(C)cc3-c3ccc4c5ccccc5c5ccccc5c4c3)c3sc4ccc(C)cc4c32)cc1 ; Cc1ccc(N2c3cccc4c3B(c3cc(C)ccc3N4c3ccc(C)cc3-c3cccc4c5ccccc5c5ccccc5c34)c3sc4ccc(C)cc4c32)cc1 ; Cc1ccc(N2c3cccc4c3B(c3cc(C)ccc3N4c3ccc(-c4cccc5c6ccccc6c6ccccc6c45)cc3)c3sc4ccc(C)cc4c32)cc1 ; Cc1ccc(N2c3cccc4c3B(c3ccc(C)cc3N4c3ccc(-c4ccc5c6ccccc6c6ccccc6c5c4)cc3)c3sc4ccc(C)cc4c32)cc1]

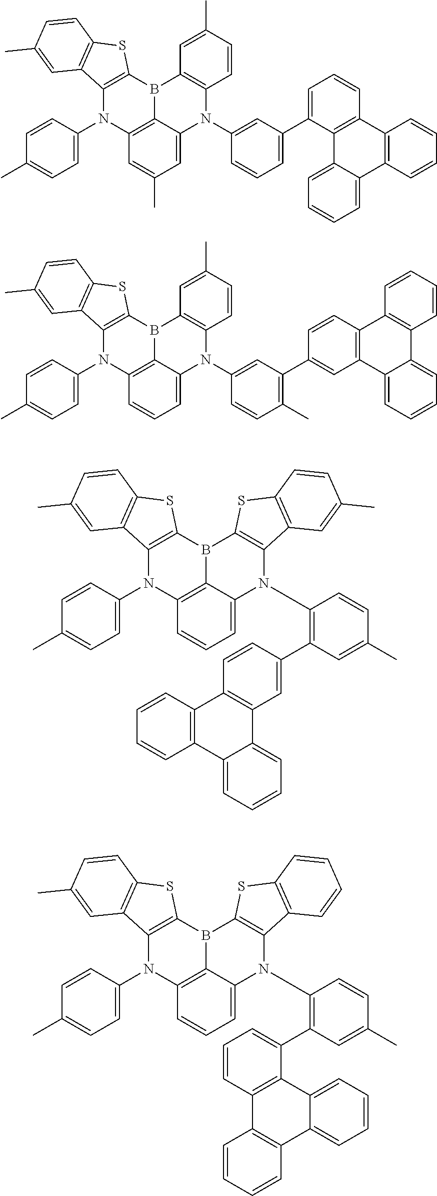

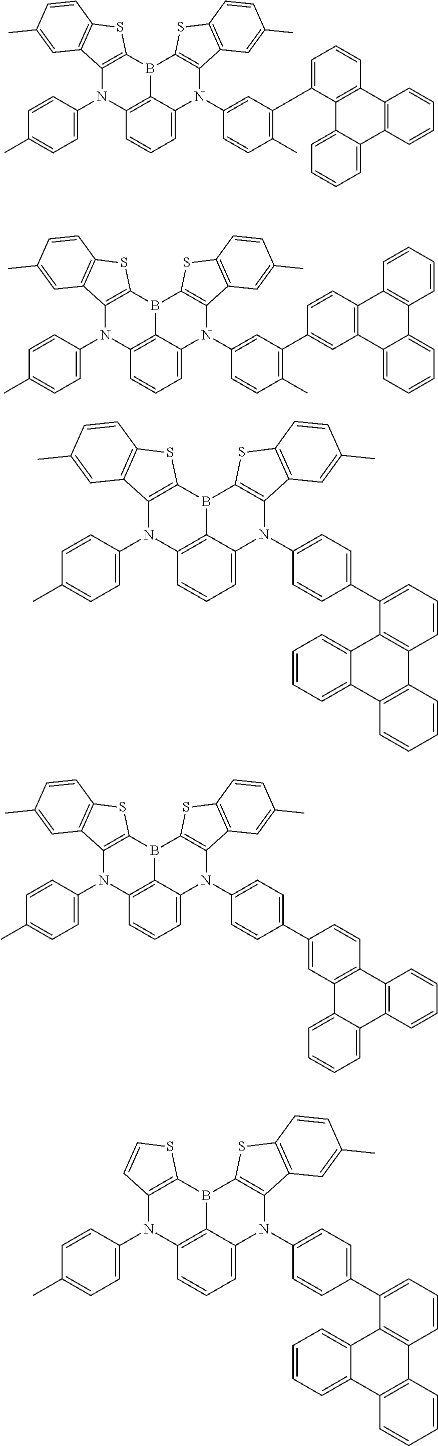

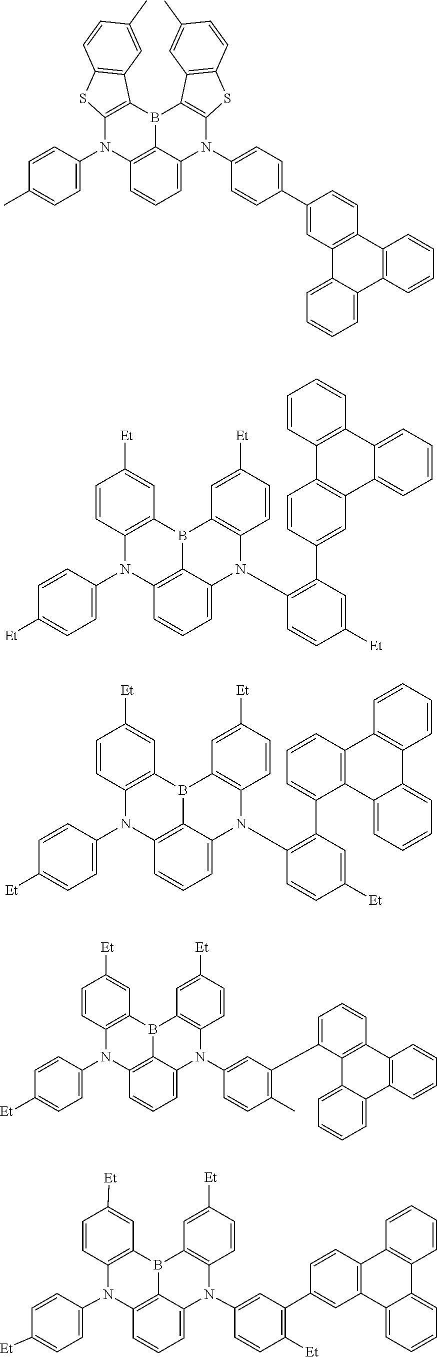 [SMILES: Cc1ccc(N2c3cccc4c3B(c3c2sc2ccc(C)cc32)c2c(sc3ccc(C)cc23)N4c2ccc(-c3ccc4c5ccccc5c5ccccc5c4c3)cc2)cc1 ; CCc1ccc(N2c3ccc(CC)cc3B3c4cc(CC)ccc4N(c4ccc(CC)cc4-c4ccc5c6ccccc6c6ccccc6c5c4)c4cccc2c43)cc1 ; CCc1ccc(N2c3ccc(CC)cc3B3c4cc(CC)ccc4N(c4ccc(CC)cc4-c4cccc5c6ccccc6c6ccccc6c45)c4cccc2c43)cc1 ; CCc1ccc(N2c3ccc(CC)cc3B3c4cc(CC)ccc4N(c4ccc(C)c(-c5cccc6c7ccccc7c7ccccc7c56)c4)c4cccc2c43)cc1 ; CCc1ccc(N2c3ccc(CC)cc3B3c4cc(CC)ccc4N(c4ccc(CC)c(-c5ccc6c7ccccc7c7ccccc7c6c5)c4)c4cccc2c43)cc1]

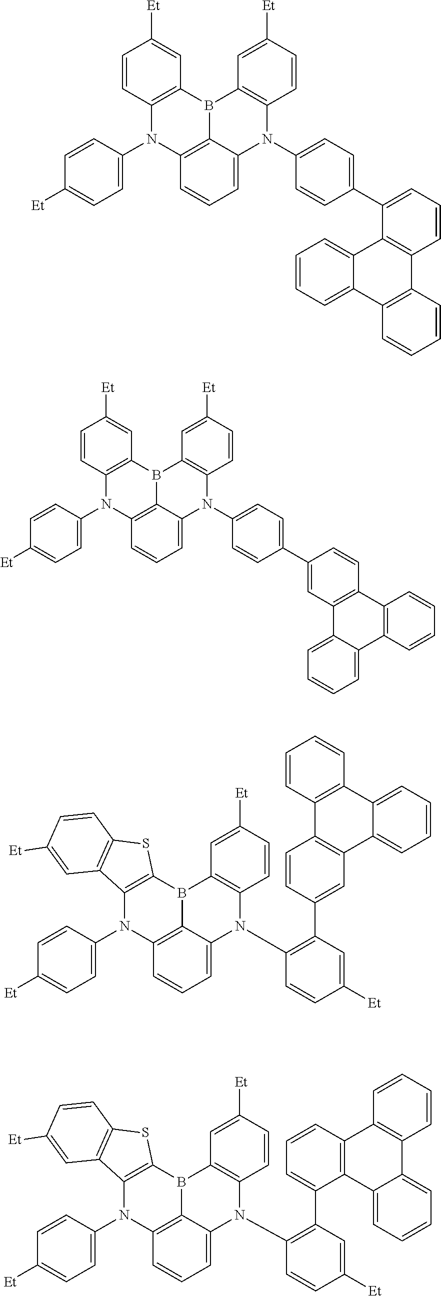

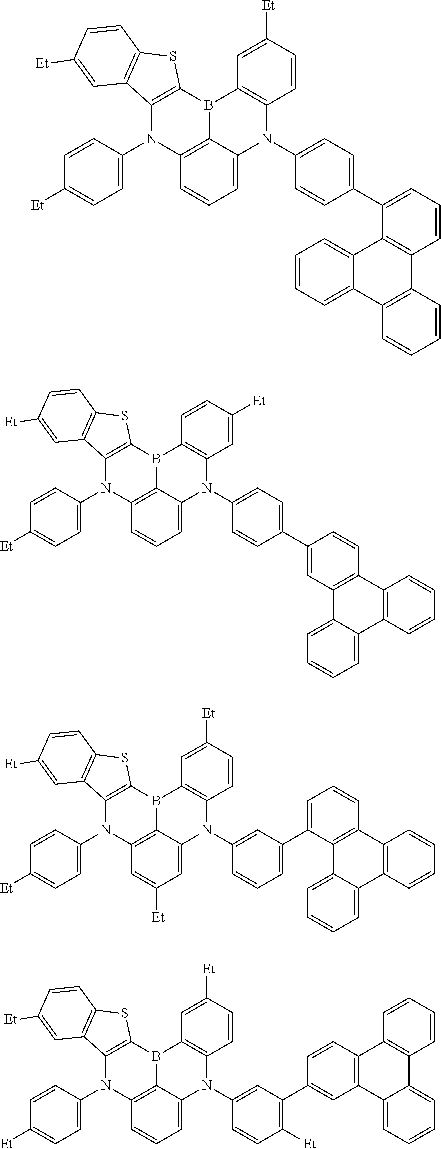 [SMILES: CCc1ccc(N2c3cccc4c3B(c3cc(CC)ccc3N4c3ccc(-c4cccc5c6ccccc6c6ccccc6c45)cc3)c3sc4ccc(CC)cc4c32)cc1 ; CCc1ccc(N2c3cccc4c3B(c3ccc(CC)cc3N4c3ccc(-c4ccc5c6ccccc6c6ccccc6c5c4)cc3)c3sc4ccc(CC)cc4c32)cc1 ; CCc1ccc(N2c3cc(CC)cc4c3B(c3cc(CC)ccc3N4c3cccc(-c4cccc5c6ccccc6c6ccccc6c45)c3)c3sc4ccc(CC)cc4c32)cc1 ; CCc1ccc(N2c3cccc4c3B(c3cc(CC)ccc3N4c3ccc(CC)c(-c4ccc5c6ccccc6c6ccccc6c5c4)c3)c3sc4ccc(CC)cc4c32)cc1]

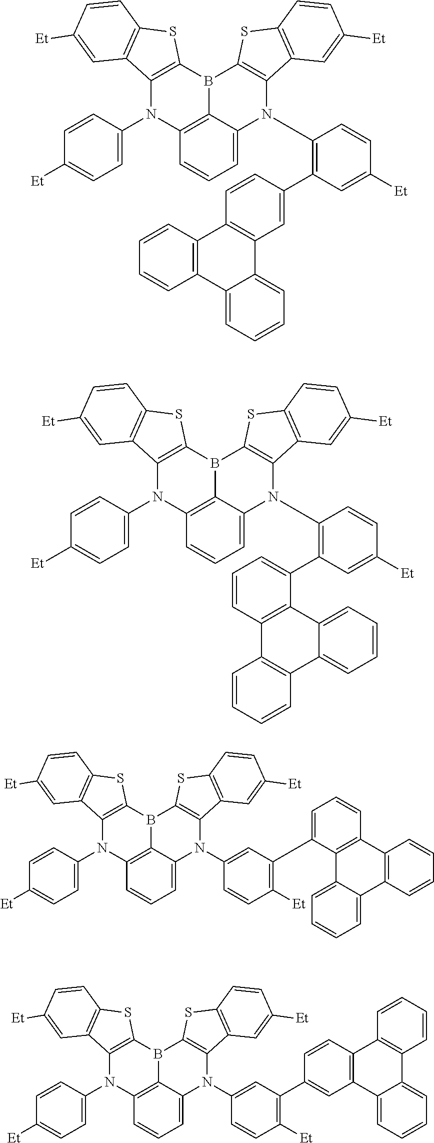

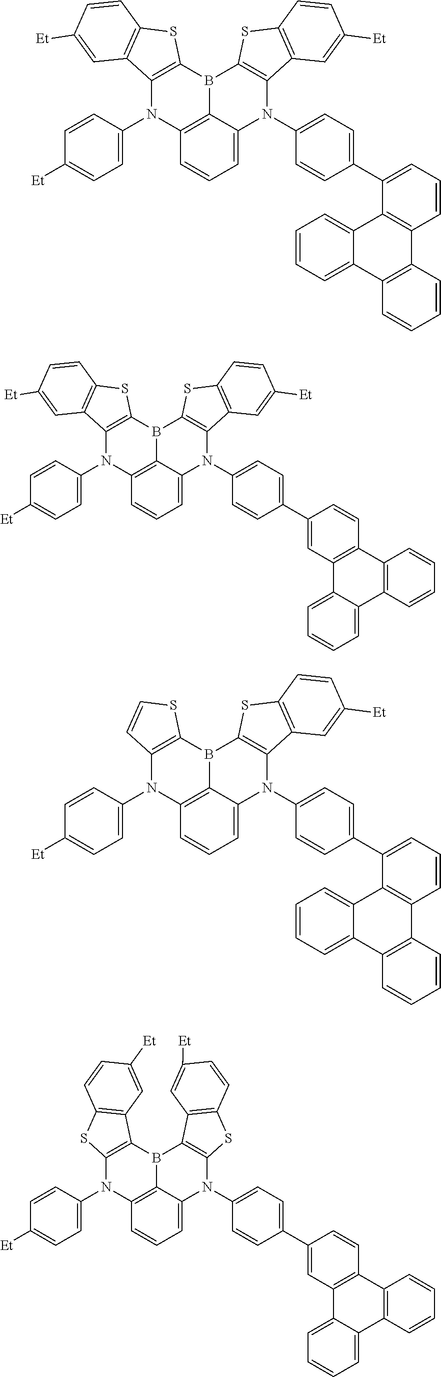

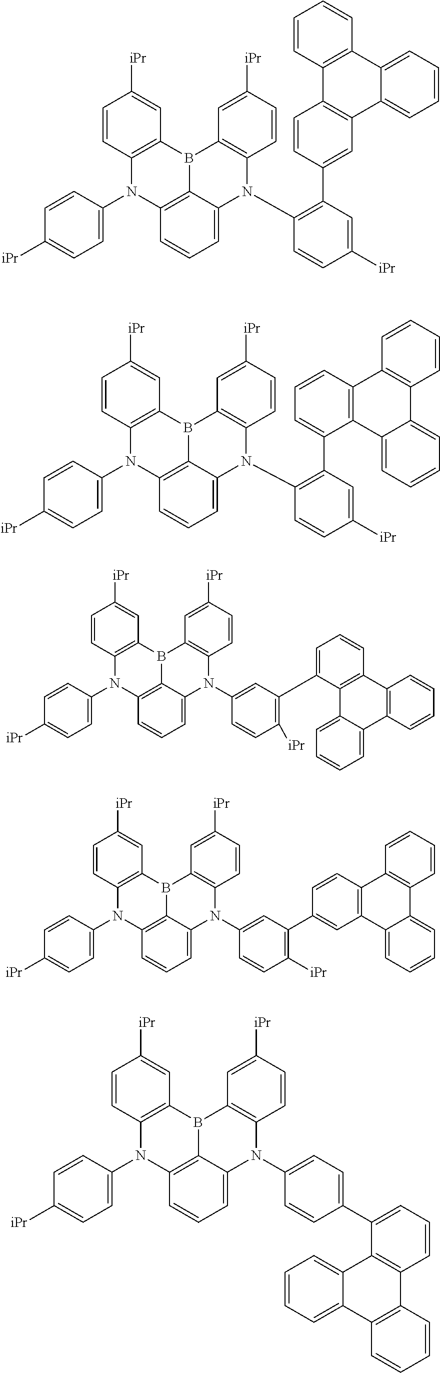

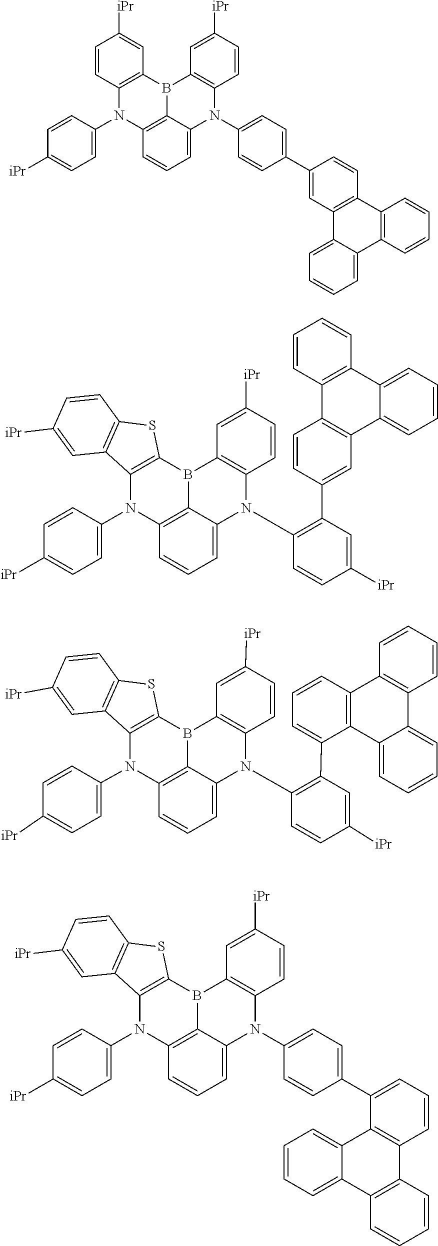

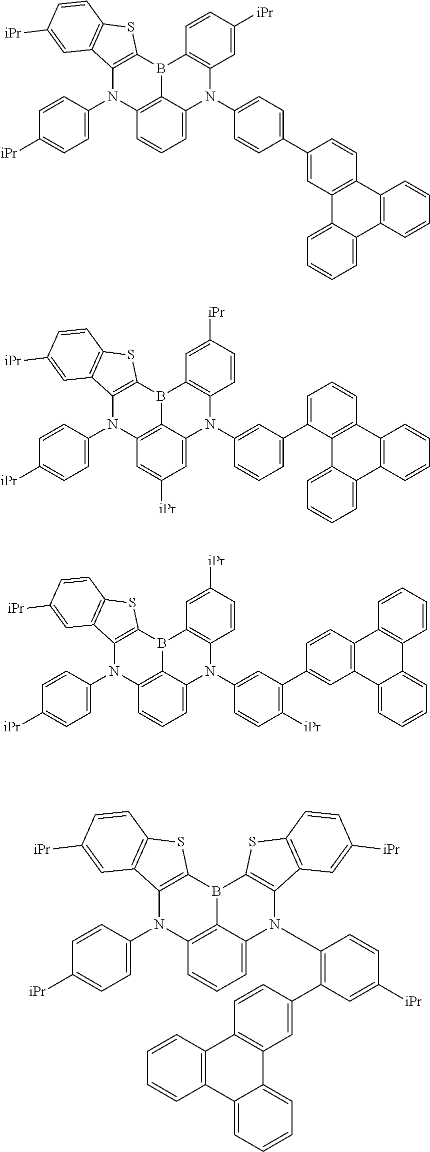 [SMILES: CC(C)c1ccc(N2c3cccc4c3B(c3ccc(C(C)C)cc3N4c3ccc(-c4ccc5c6ccccc6c6ccccc6c5c4)cc3)c3sc4ccc(C(C)C)cc4c32)cc1 ; CC(C)c1ccc(N2c3cc(C(C)C)cc4c3B(c3cc(C(C)C)ccc3N4c3cccc(-c4cccc5c6ccccc6c6ccccc6c45)c3)c3sc4ccc(C(C)C)cc4c32)cc1 ; CC(C)c1ccc(N2c3cccc4c3B(c3cc(C(C)C)ccc3N4c3ccc(C(C)C)c(-c4ccc5c6ccccc6c6ccccc6c5c4)c3)c3sc4ccc(C(C)C)cc4c32)cc1 ; CC(C)c1ccc(N2c3cccc4c3B(c3sc5ccc(C(C)C)cc5c32)c2sc3ccc(C(C)C)cc3c2N4c2ccc(C(C)C)cc2-c2ccc3c4ccccc4c4ccccc4c3c2)cc1]

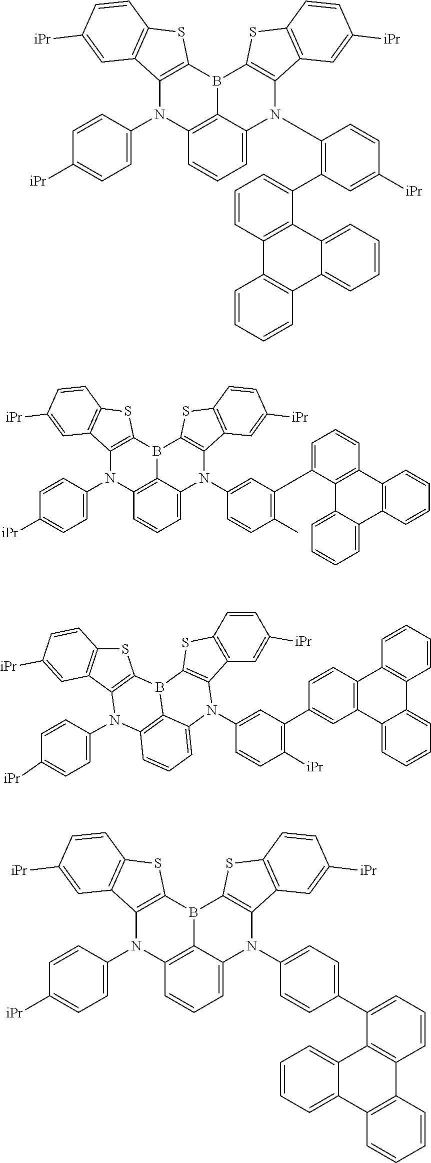 [SMILES: CC(C)c1ccc(N2c3cccc4c3B(c3sc5ccc(C(C)C)cc5c32)c2sc3ccc(C(C)C)cc3c2N4c2ccc(C(C)C)cc2-c2cccc3c4ccccc4c4ccccc4c23)cc1 ; Cc1ccc(N2c3cccc4c3B(c3sc5ccc(C(C)C)cc5c3N4c3ccc(C(C)C)cc3)c3sc4ccc(C(C)C)cc4c32)cc1-c1cccc2c3ccccc3c3ccccc3c12 ; CC(C)c1ccc(N2c3cccc4c3B(c3sc5ccc(C(C)C)cc5c32)c2sc3ccc(C(C)C)cc3c2N4c2ccc(C(C)C)c(-c3ccc4c5ccccc5c5ccccc5c4c3)c2)cc1 ; CC(C)c1ccc(N2c3cccc4c3B(c3sc5ccc(C(C)C)cc5c3N4c3ccc(-c4cccc5c6ccccc6c6ccccc6c45)cc3)c3sc4ccc(C(C)C)cc4c32)cc1]

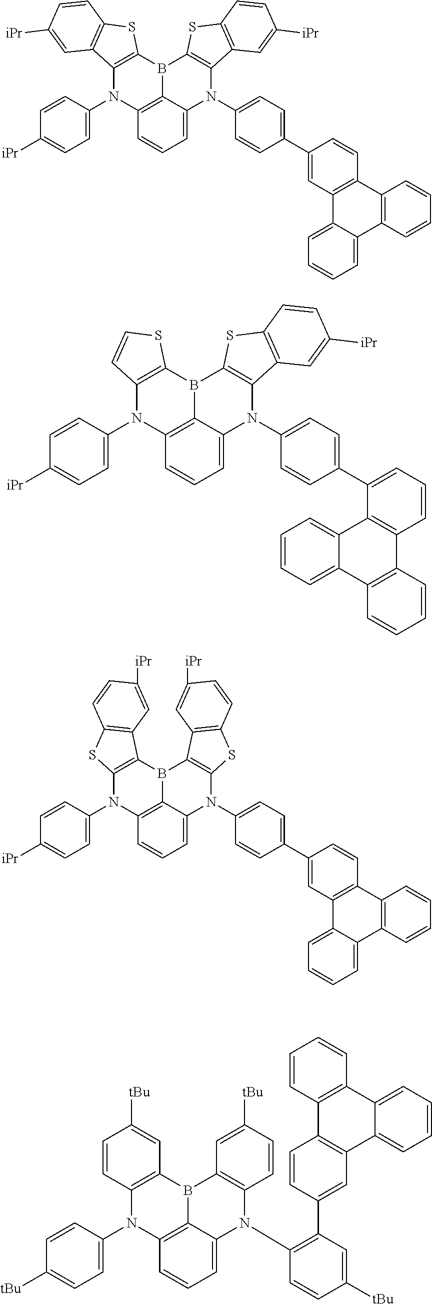

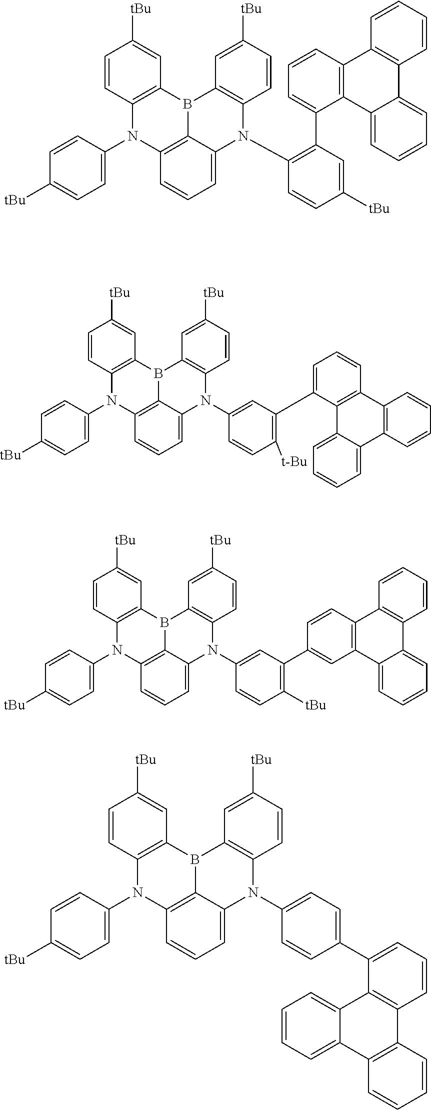 [SMILES: CC(C)(C)c1ccc(N2c3ccc(C(C)(C)C)cc3B3c4cc(C(C)(C)C)ccc4N(c4ccc(C(C)(C)C)cc4-c4cccc5c6ccccc6c6ccccc6c45)c4cccc2c43)cc1 ; CC(C)(C)c1ccc(N2c3ccc(C(C)(C)C)cc3B3c4cc(C(C)(C)C)ccc4N(c4ccc(C(C)(C)C)c(-c5cccc6c7ccccc7c7ccccc7c56)c4)c4cccc2c43)cc1 ; CC(C)(C)c1ccc(N2c3ccc(C(C)(C)C)cc3B3c4cc(C(C)(C)C)ccc4N(c4ccc(C(C)(C)C)c(-c5ccc6c7ccccc7c7ccccc7c6c5)c4)c4cccc2c43)cc1 ; CC(C)(C)c1ccc(N2c3ccc(C(C)(C)C)cc3B3c4cc(C(C)(C)C)ccc4N(c4ccc(-c5cccc6c7ccccc7c7ccccc7c56)cc4)c4cccc2c43)cc1]

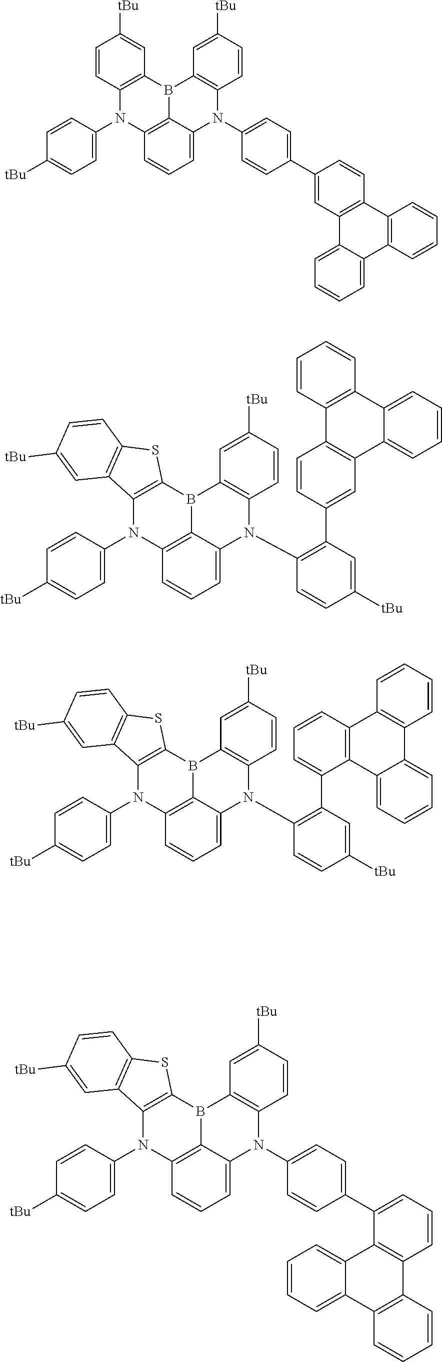

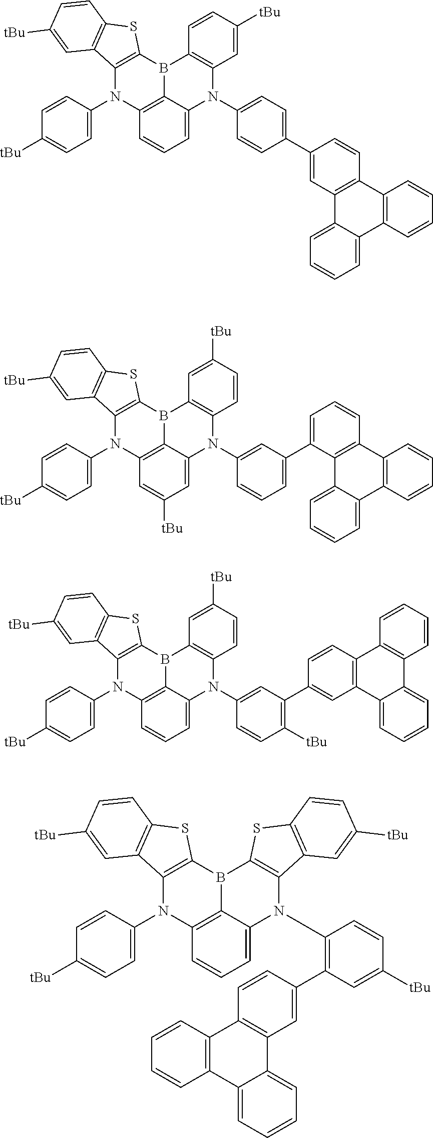 [SMILES: CC(C)(C)c1ccc(N2c3cccc4c3B(c3ccc(C(C)(C)C)cc3N4c3ccc(-c4ccc5c6ccccc6c6ccccc6c5c4)cc3)c3sc4ccc(C(C)(C)C)cc4c32)cc1 ; CC(C)(C)c1ccc(N2c3cc(C(C)(C)C)cc4c3B(c3cc(C(C)(C)C)ccc3N4c3cccc(-c4cccc5c6ccccc6c6ccccc6c45)c3)c3sc4ccc(C(C)(C)C)cc4c32)cc1 ; CC(C)(C)c1ccc(N2c3cccc4c3B(c3cc(C(C)(C)C)ccc3N4c3ccc(C(C)(C)C)c(-c4ccc5c6ccccc6c6ccccc6c5c4)c3)c3sc4ccc(C(C)(C)C)cc4c32)cc1 ; CC(C)(C)c1ccc(N2c3cccc4c3B(c3sc5ccc(C(C)(C)C)cc5c32)c2sc3ccc(C(C)(C)C)cc3c2N4c2ccc(C(C)(C)C)cc2-c2ccc3c4ccccc4c4ccccc4c3c2)cc1]

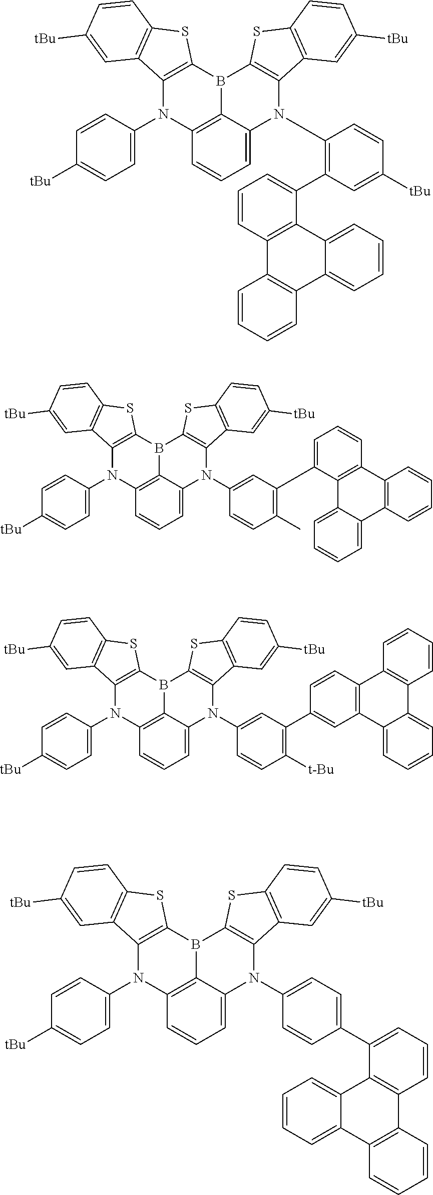

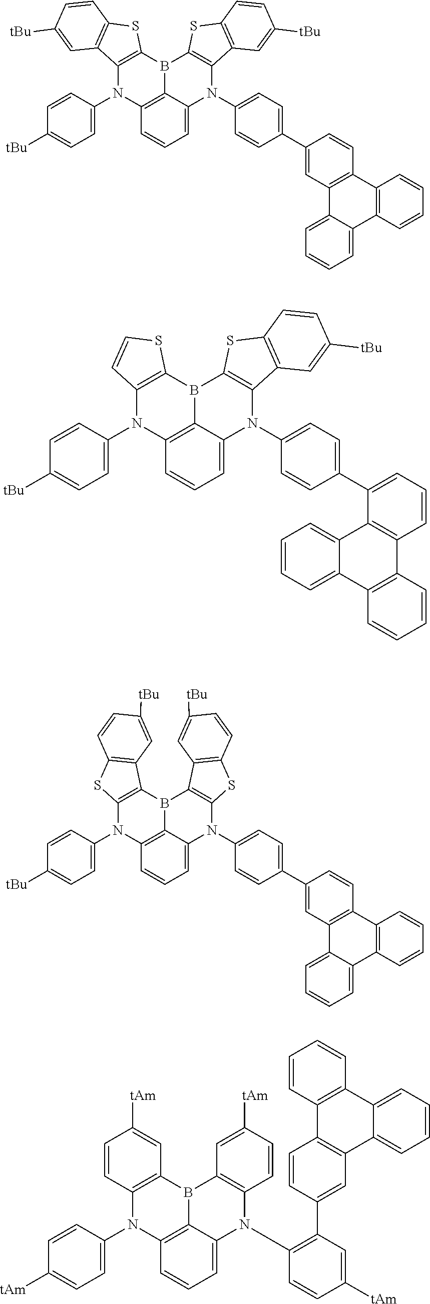

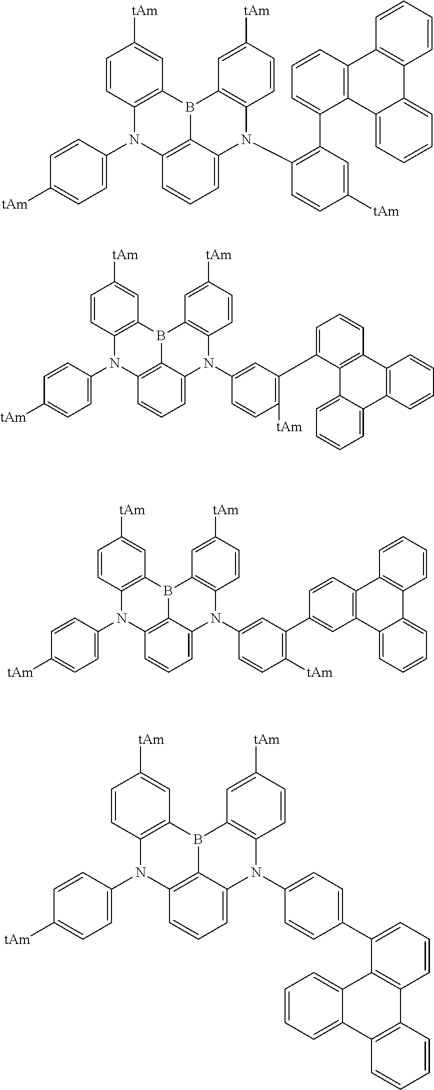

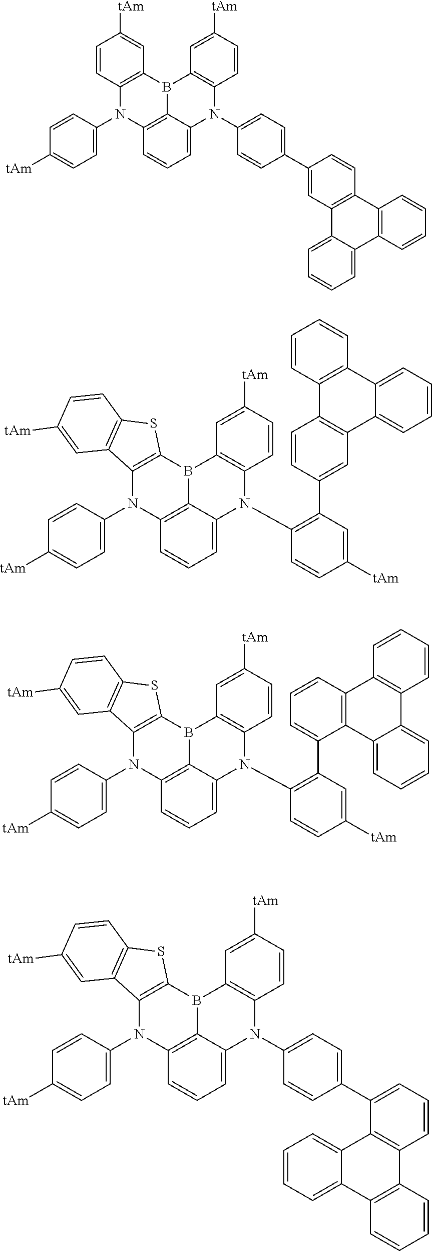

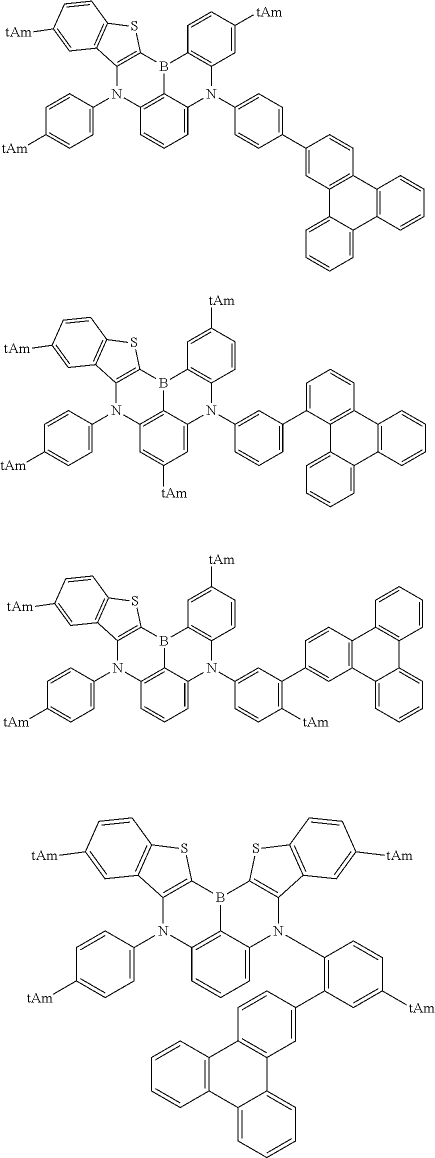

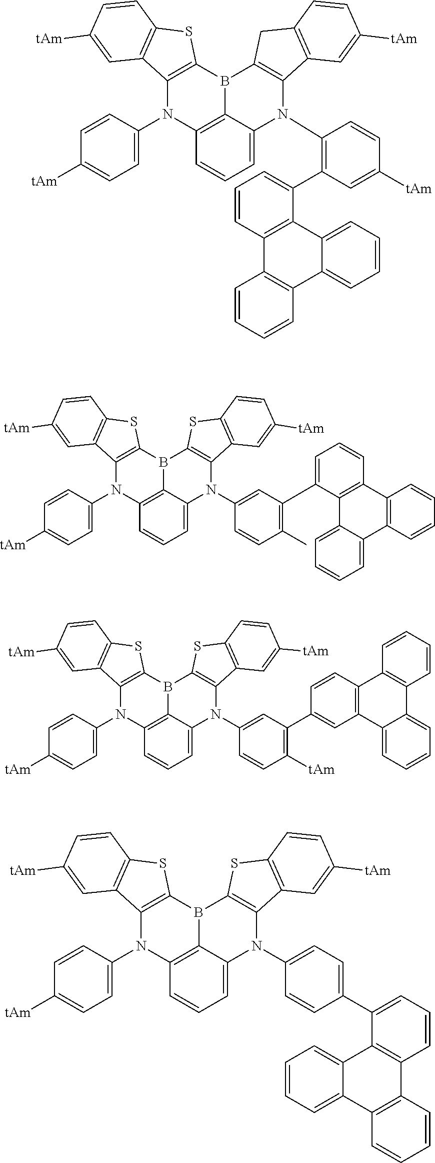

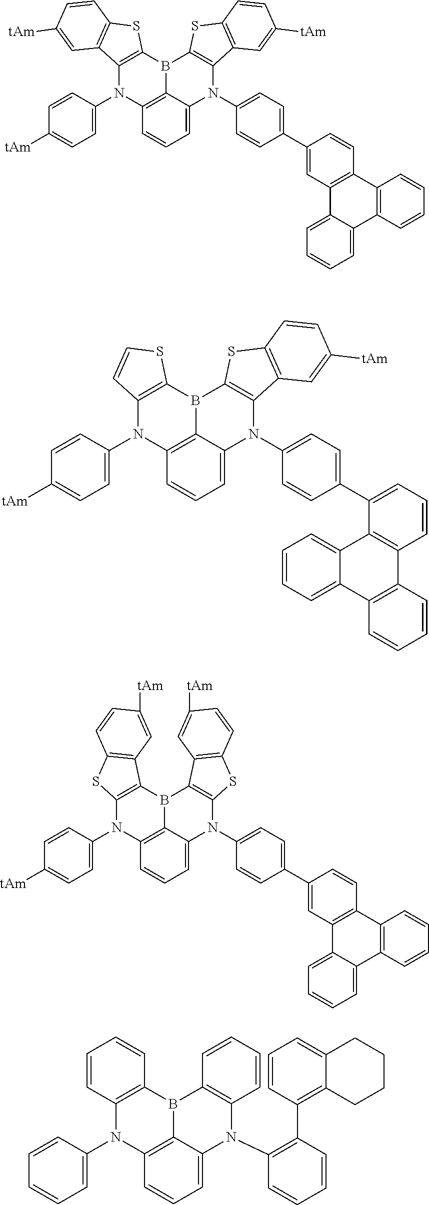

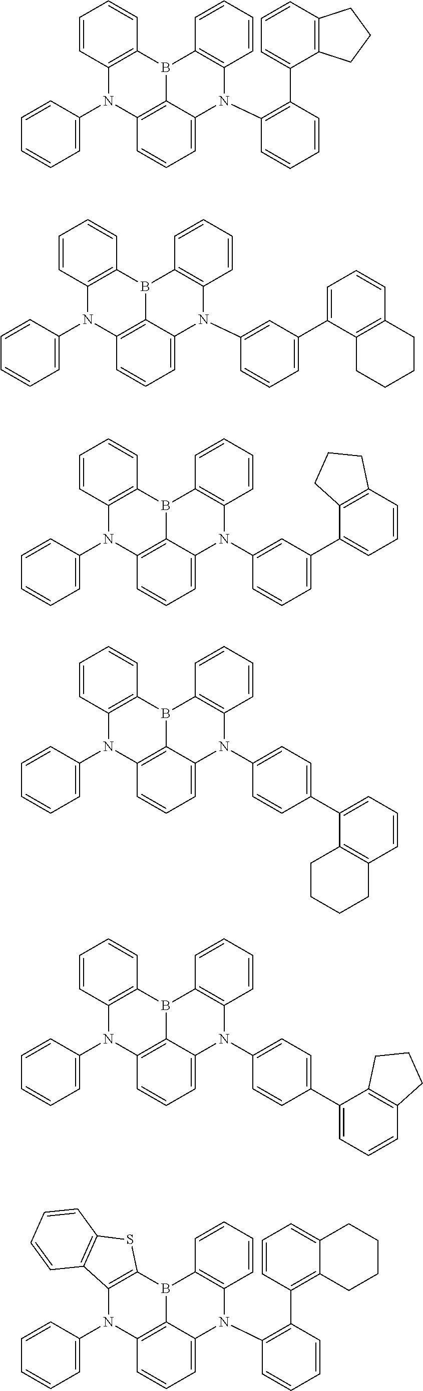 [SMILES: c1ccc(N2c3ccccc3B3c4ccccc4N(c4ccccc4-c4cccc5c4CCC5)c4cccc2c43)cc1 ; c1ccc(N2c3ccccc3B3c4ccccc4N(c4cccc(-c5cccc6c5CCCC6)c4)c4cccc2c43)cc1 ; c1ccc(N2c3ccccc3B3c4ccccc4N(c4cccc(-c5cccc6c5CCC6)c4)c4cccc2c43)cc1 ; c1ccc(N2c3ccccc3B3c4ccccc4N(c4ccc(-c5cccc6c5CCCC6)cc4)c4cccc2c43)cc1 ; c1ccc(N2c3ccccc3B3c4ccccc4N(c4ccc(-c5cccc6c5CCC6)cc4)c4cccc2c43)cc1 ; c1ccc(N2c3cccc4c3B(c3ccccc3N4c3ccccc3-c3cccc4c3CCCC4)c3sc4ccccc4c32)cc1]

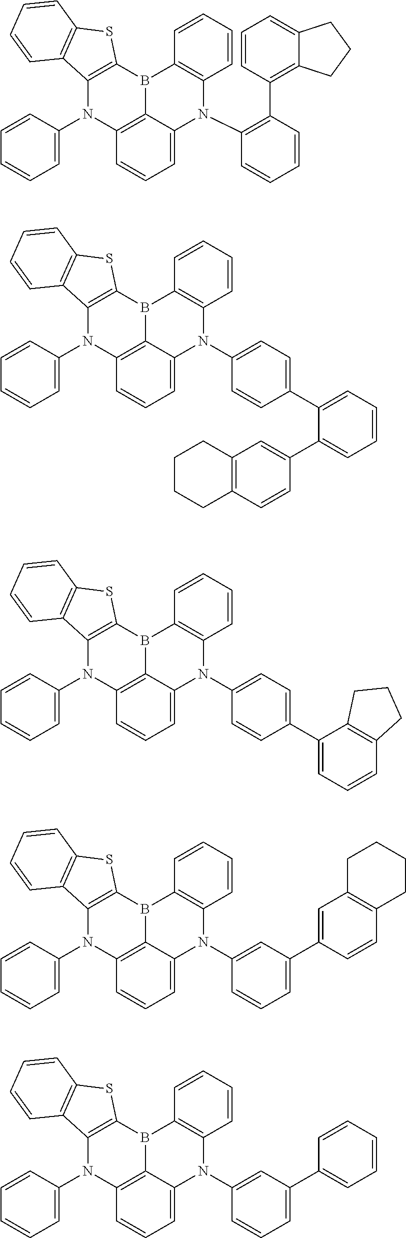 [SMILES: c1ccc(N2c3cccc4c3B(c3ccccc3N4c3ccccc3-c3cccc4c3CCC4)c3sc4ccccc4c32)cc1 ; c1ccc(N2c3cccc4c3B(c3ccccc3N4c3ccc(-c4ccccc4-c4ccc5c(c4)CCCC5)cc3)c3sc4ccccc4c32)cc1 ; c1ccc(N2c3cccc4c3B(c3ccccc3N4c3ccc(-c4cccc5c4CCC5)cc3)c3sc4ccccc4c32)cc1 ; c1ccc(N2c3cccc4c3B(c3ccccc3N4c3cccc(-c4ccc5c(c4)CCCC5)c3)c3sc4ccccc4c32)cc1 ; c1ccc(-c2cccc(N3c4ccccc4B4c5sc6ccccc6c5N(c5ccccc5)c5cccc3c54)c2)cc1]

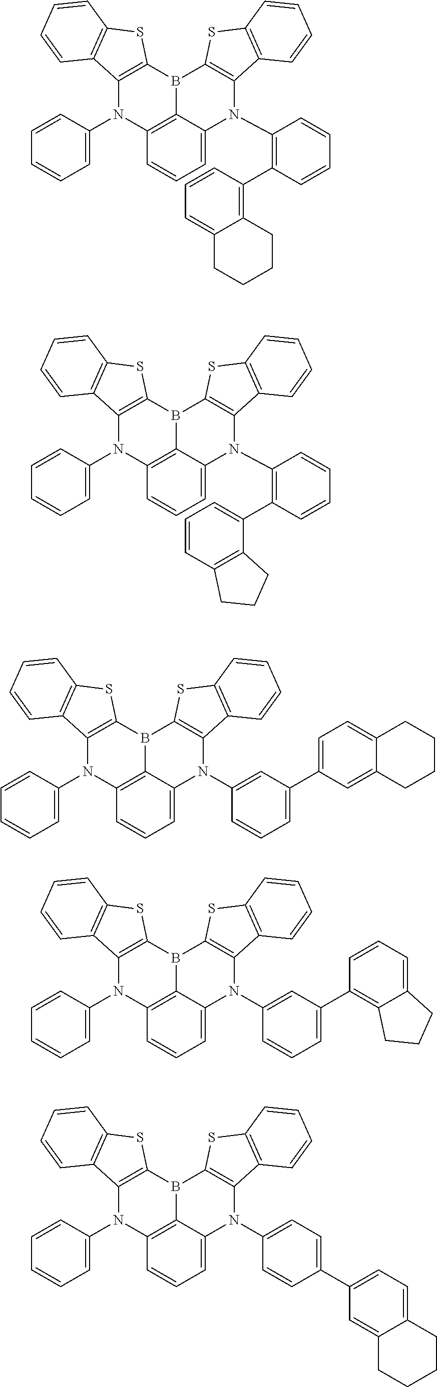

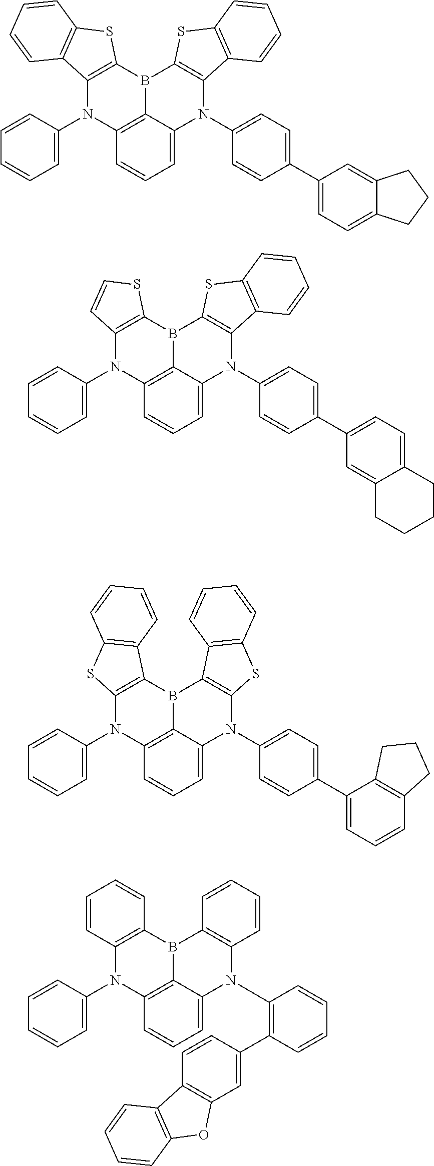 [SMILES: c1ccc(N2c3cccc4c3B(c3sc5ccccc5c32)c2sc3ccccc3c2N4c2ccc(-c3ccc4c(c3)CCC4)cc2)cc1 ; c1ccc(N2c3ccsc3B3c4sc5ccccc5c4N(c4ccc(-c5ccc6c(c5)CCCC6)cc4)c4cccc2c43)cc1 ; c1ccc(N2c3cccc4c3B(c3c2sc2ccccc32)c2c(sc3ccccc23)N4c2ccc(-c3cccc4c3CCC4)cc2)cc1 ; c1ccc(N2c3ccccc3B3c4ccccc4N(c4ccccc4-c4ccc5c(c4)oc4ccccc45)c4cccc2c43)cc1]

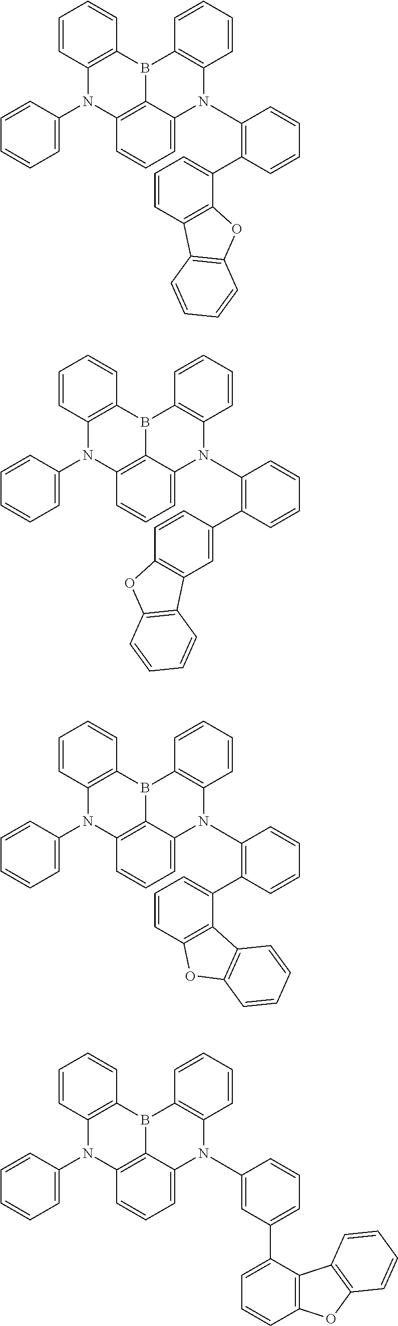

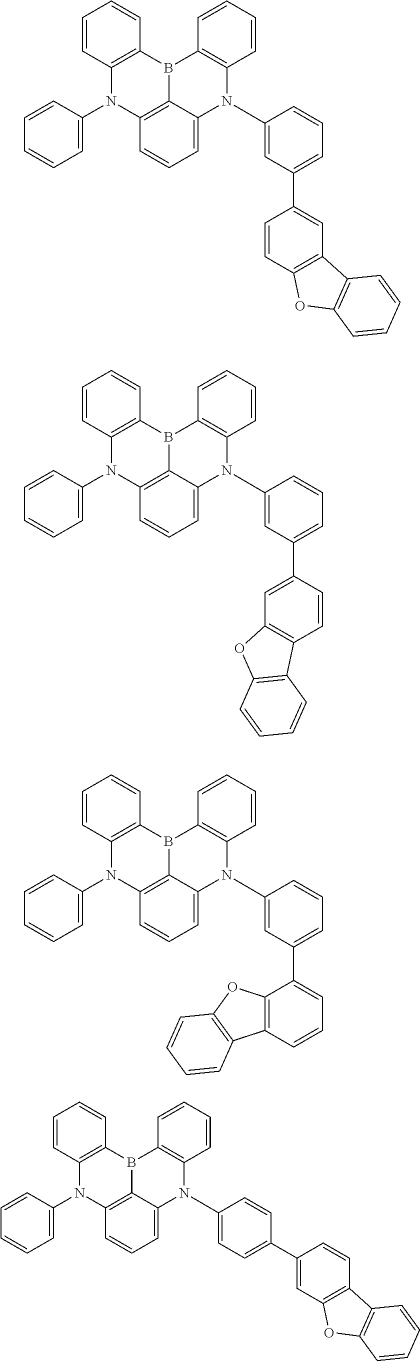

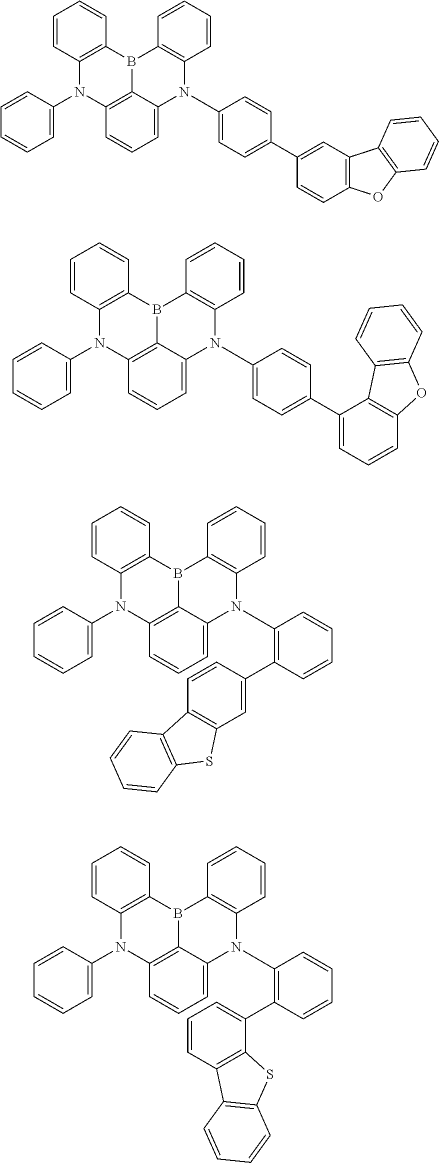 [SMILES: c1ccc(N2c3ccccc3B3c4ccccc4N(c4ccc(-c5ccc6oc7ccccc7c6c5)cc4)c4cccc2c43)cc1 ; c1ccc(N2c3ccccc3B3c4ccccc4N(c4ccc(-c5cccc6oc7ccccc7c56)cc4)c4cccc2c43)cc1 ; c1ccc(N2c3ccccc3B3c4ccccc4N(c4ccccc4-c4ccc5c(c4)sc4ccccc45)c4cccc2c43)cc1 ; c1ccc(N2c3ccccc3B3c4ccccc4N(c4ccccc4-c4cccc5c4sc4ccccc45)c4cccc2c43)cc1]

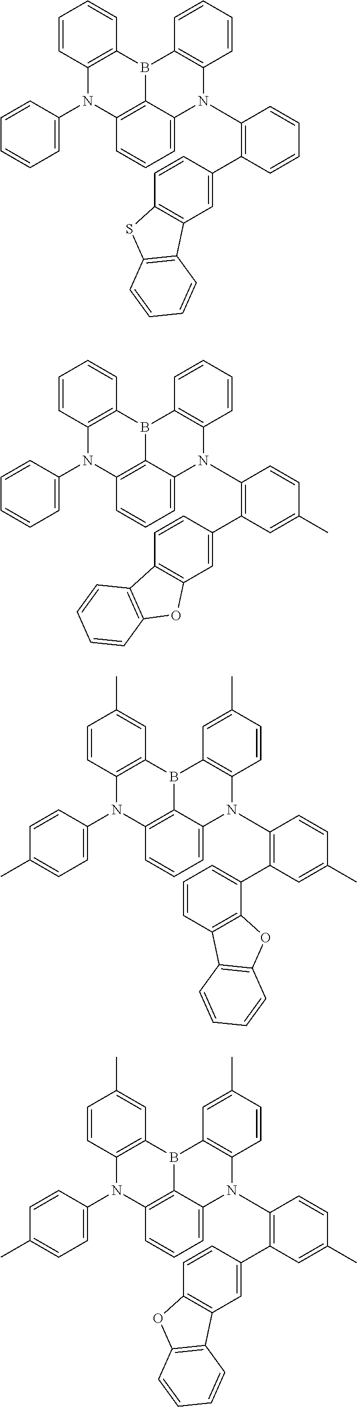

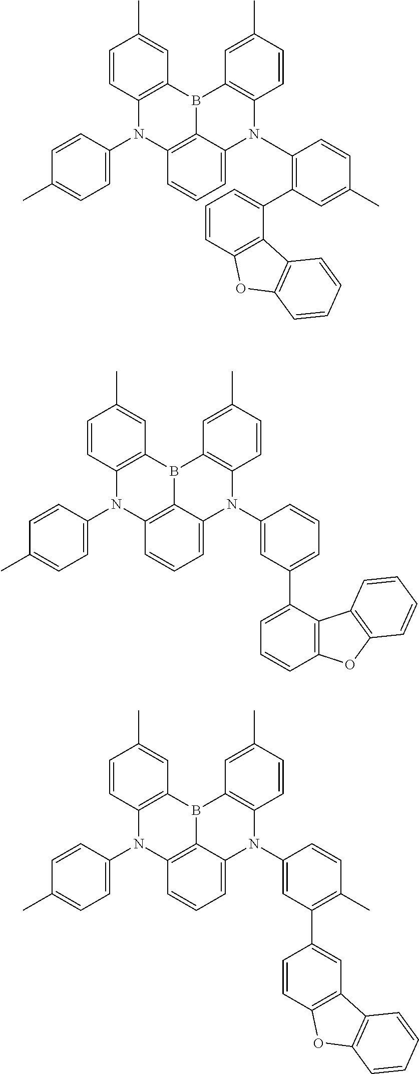

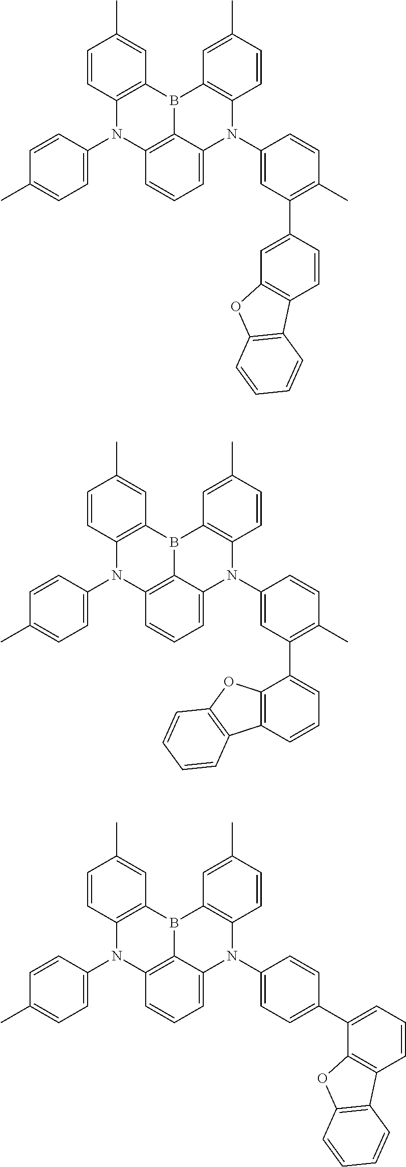

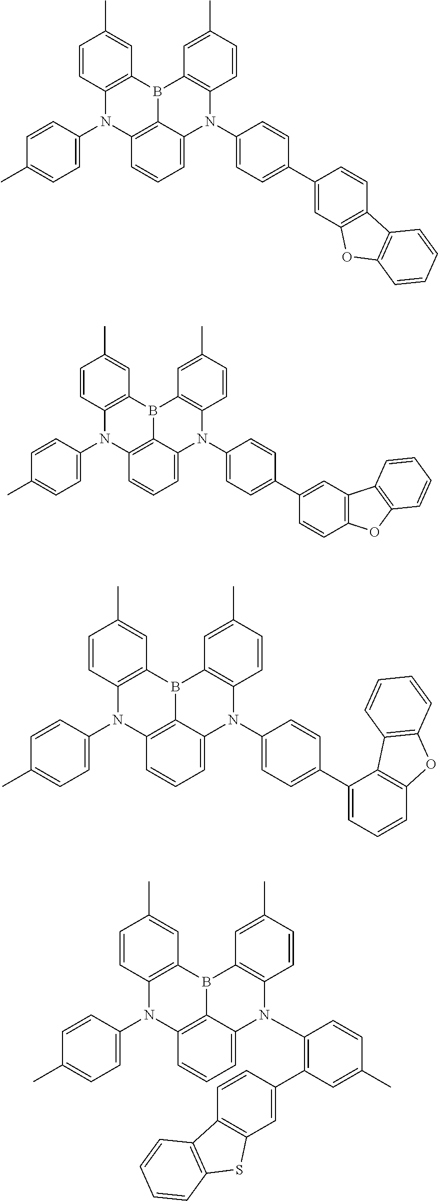

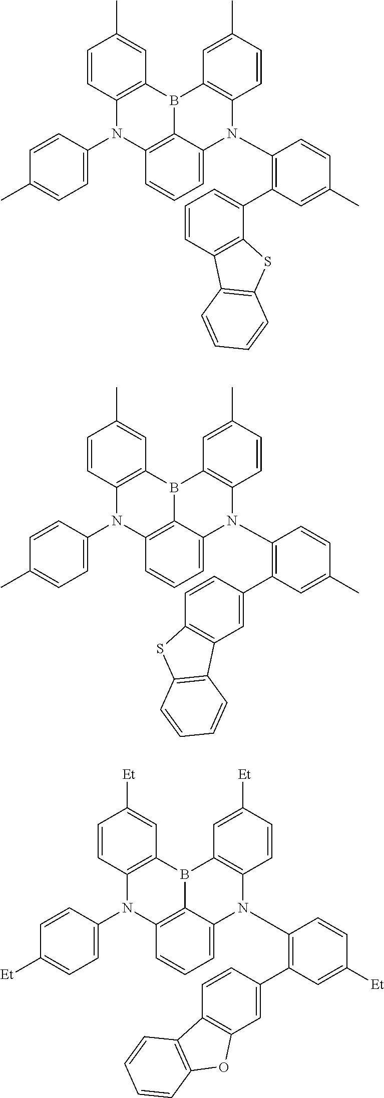

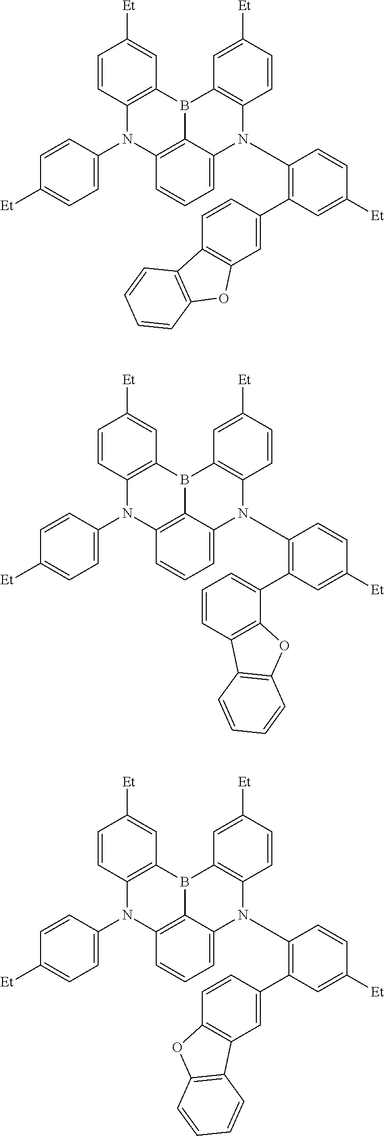 [SMILES: CCc1ccc(N2c3ccc(CC)cc3B3c4cc(CC)ccc4N(c4ccc(CC)cc4-c4ccc5c(c4)oc4ccccc45)c4cccc2c43)cc1 ; CCc1ccc(N2c3ccc(CC)cc3B3c4cc(CC)ccc4N(c4ccc(CC)cc4-c4cccc5c4oc4ccccc45)c4cccc2c43)cc1 ; CCc1ccc(N2c3ccc(CC)cc3B3c4cc(CC)ccc4N(c4ccc(CC)cc4-c4ccc5oc6ccccc6c5c4)c4cccc2c43)cc1]

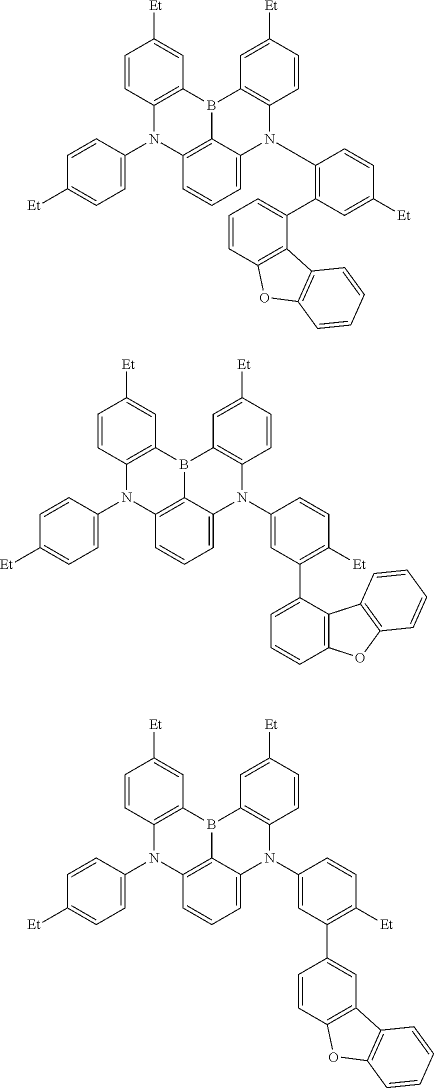 [SMILES: CCc1ccc(N2c3ccc(CC)cc3B3c4cc(CC)ccc4N(c4ccc(CC)cc4-c4cccc5oc6ccccc6c45)c4cccc2c43)cc1 ; CCc1ccc(N2c3ccc(CC)cc3B3c4cc(CC)ccc4N(c4ccc(CC)c(-c5cccc6oc7ccccc7c56)c4)c4cccc2c43)cc1 ; CCc1ccc(N2c3ccc(CC)cc3B3c4cc(CC)ccc4N(c4ccc(CC)c(-c5ccc6oc7ccccc7c6c5)c4)c4cccc2c43)cc1]

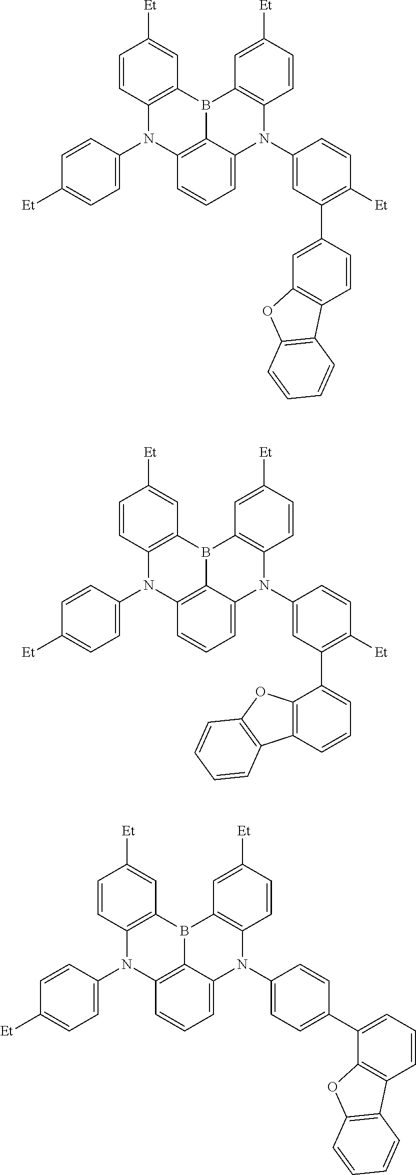 [SMILES: CCc1ccc(N2c3ccc(CC)cc3B3c4cc(CC)ccc4N(c4ccc(CC)c(-c5ccc6c(c5)oc5ccccc56)c4)c4cccc2c43)cc1 ; CCc1ccc(N2c3ccc(CC)cc3B3c4cc(CC)ccc4N(c4ccc(CC)c(-c5cccc6c5oc5ccccc56)c4)c4cccc2c43)cc1 ; CCc1ccc(N2c3ccc(CC)cc3B3c4cc(CC)ccc4N(c4ccc(-c5cccc6c5oc5ccccc56)cc4)c4cccc2c43)cc1]

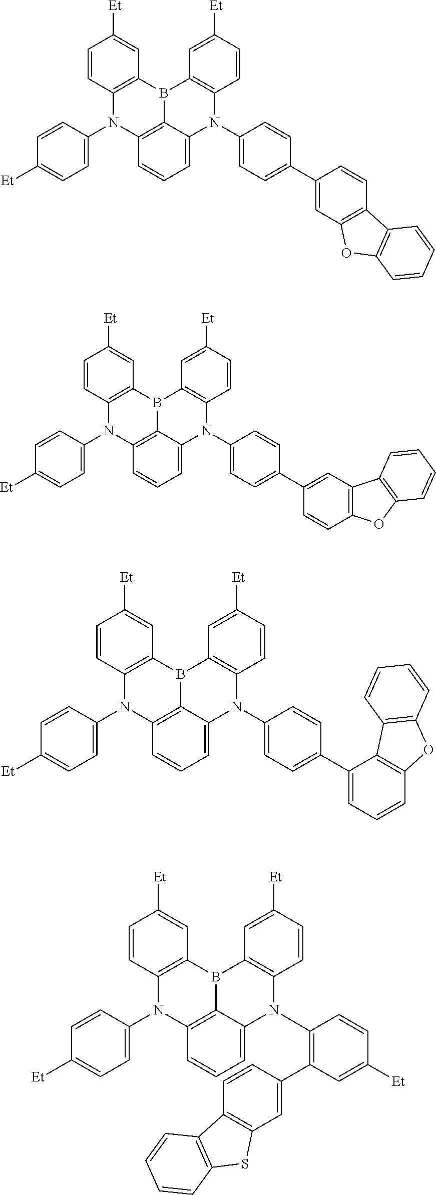 [SMILES: CCc1ccc(N2c3ccc(CC)cc3B3c4cc(CC)ccc4N(c4ccc(-c5ccc6c(c5)oc5ccccc56)cc4)c4cccc2c43)cc1 ; CCc1ccc(N2c3ccc(CC)cc3B3c4cc(CC)ccc4N(c4ccc(-c5ccc6oc7ccccc7c6c5)cc4)c4cccc2c43)cc1 ; CCc1ccc(N2c3ccc(CC)cc3B3c4cc(CC)ccc4N(c4ccc(-c5cccc6oc7ccccc7c56)cc4)c4cccc2c43)cc1 ; CCc1ccc(N2c3ccc(CC)cc3B3c4cc(CC)ccc4N(c4ccc(CC)cc4-c4ccc5c(c4)sc4ccccc45)c4cccc2c43)cc1]

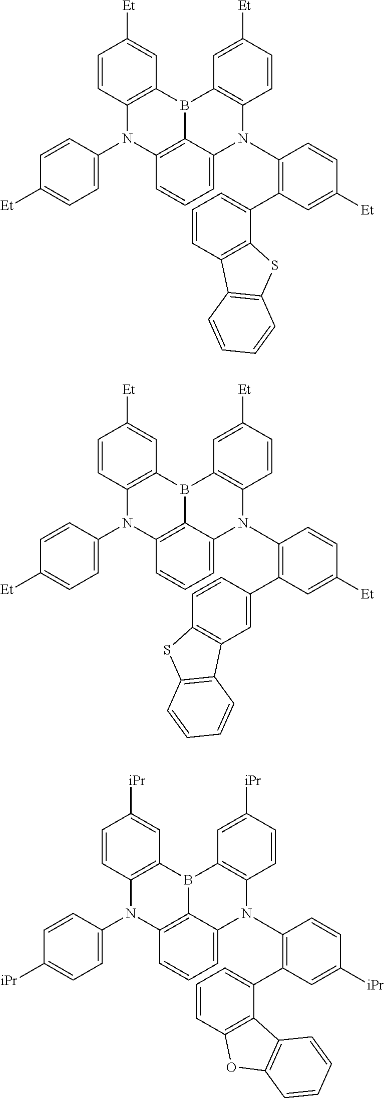

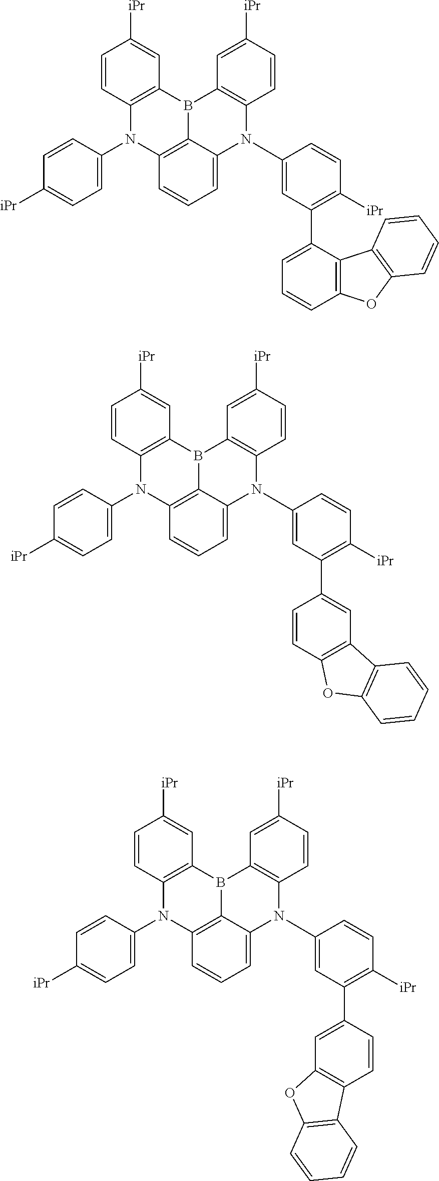 [SMILES: CC(C)c1ccc(N2c3ccc(C(C)C)cc3B3c4cc(C(C)C)ccc4N(c4ccc(C(C)C)c(-c5cccc6oc7ccccc7c56)c4)c4cccc2c43)cc1 ; CC(C)c1ccc(N2c3ccc(C(C)C)cc3B3c4cc(C(C)C)ccc4N(c4ccc(C(C)C)c(-c5ccc6oc7ccccc7c6c5)c4)c4cccc2c43)cc1 ; CC(C)c1ccc(N2c3ccc(C(C)C)cc3B3c4cc(C(C)C)ccc4N(c4ccc(C(C)C)c(-c5ccc6c(c5)oc5ccccc56)c4)c4cccc2c43)cc1]

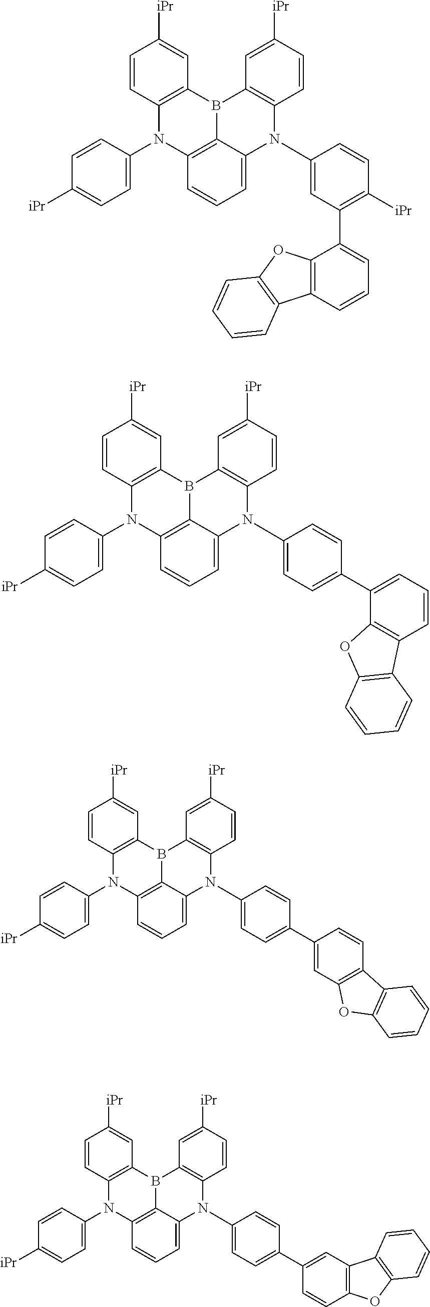 [SMILES: CC(C)c1ccc(N2c3ccc(C(C)C)cc3B3c4cc(C(C)C)ccc4N(c4ccc(C(C)C)c(-c5cccc6c5oc5ccccc56)c4)c4cccc2c43)cc1 ; CC(C)c1ccc(N2c3ccc(C(C)C)cc3B3c4cc(C(C)C)ccc4N(c4ccc(-c5cccc6c5oc5ccccc56)cc4)c4cccc2c43)cc1 ; CC(C)c1ccc(N2c3ccc(C(C)C)cc3B3c4cc(C(C)C)ccc4N(c4ccc(-c5ccc6c(c5)oc5ccccc56)cc4)c4cccc2c43)cc1 ; CC(C)c1ccc(N2c3ccc(C(C)C)cc3B3c4cc(C(C)C)ccc4N(c4ccc(-c5ccc6oc7ccccc7c6c5)cc4)c4cccc2c43)cc1]

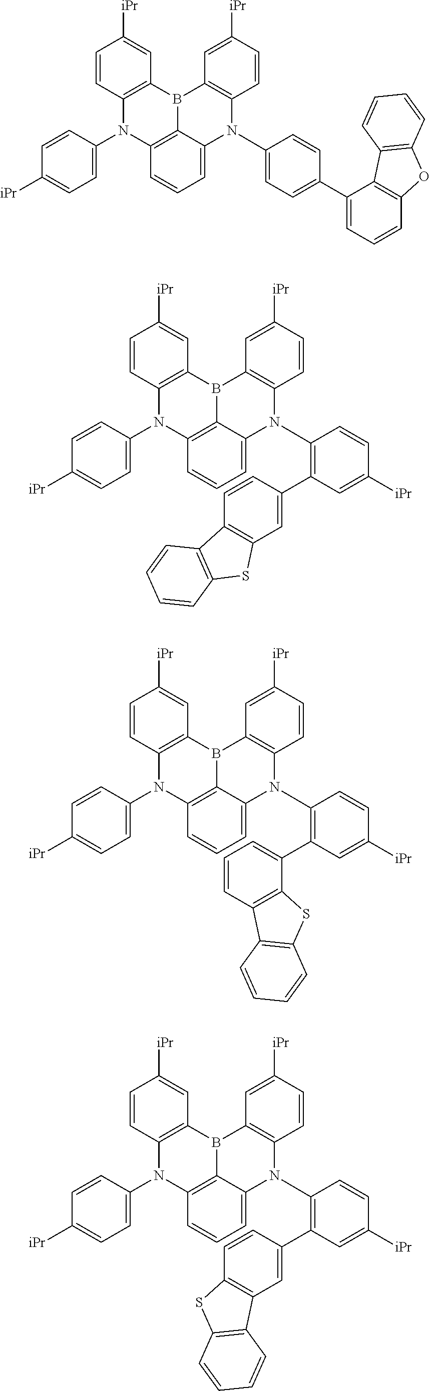

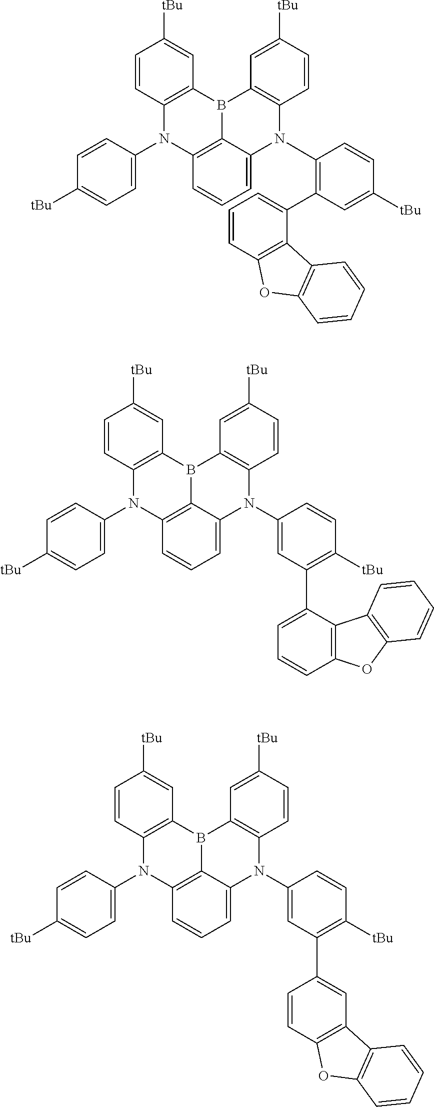 [SMILES: CC(C)(C)c1ccc(N2c3ccc(C(C)(C)C)cc3B3c4cc(C(C)(C)C)ccc4N(c4ccc(C(C)(C)C)cc4-c4cccc5oc6ccccc6c45)c4cccc2c43)cc1 ; CC(C)(C)c1ccc(N2c3ccc(C(C)(C)C)cc3B3c4cc(C(C)(C)C)ccc4N(c4ccc(C(C)(C)C)c(-c5cccc6oc7ccccc7c56)c4)c4cccc2c43)cc1 ; CC(C)(C)c1ccc(N2c3ccc(C(C)(C)C)cc3B3c4cc(C(C)(C)C)ccc4N(c4ccc(C(C)(C)C)c(-c5ccc6oc7ccccc7c6c5)c4)c4cccc2c43)cc1]

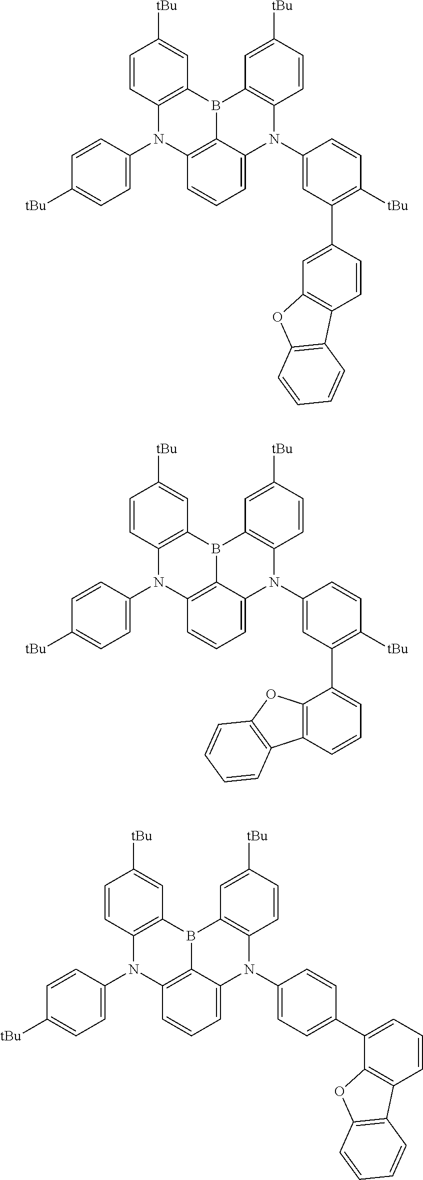 [SMILES: CC(C)(C)c1ccc(N2c3ccc(C(C)(C)C)cc3B3c4cc(C(C)(C)C)ccc4N(c4ccc(C(C)(C)C)c(-c5ccc6c(c5)oc5ccccc56)c4)c4cccc2c43)cc1 ; CC(C)(C)c1ccc(N2c3ccc(C(C)(C)C)cc3B3c4cc(C(C)(C)C)ccc4N(c4ccc(C(C)(C)C)c(-c5cccc6c5oc5ccccc56)c4)c4cccc2c43)cc1 ; CC(C)(C)c1ccc(N2c3ccc(C(C)(C)C)cc3B3c4cc(C(C)(C)C)ccc4N(c4ccc(-c5cccc6c5oc5ccccc56)cc4)c4cccc2c43)cc1]

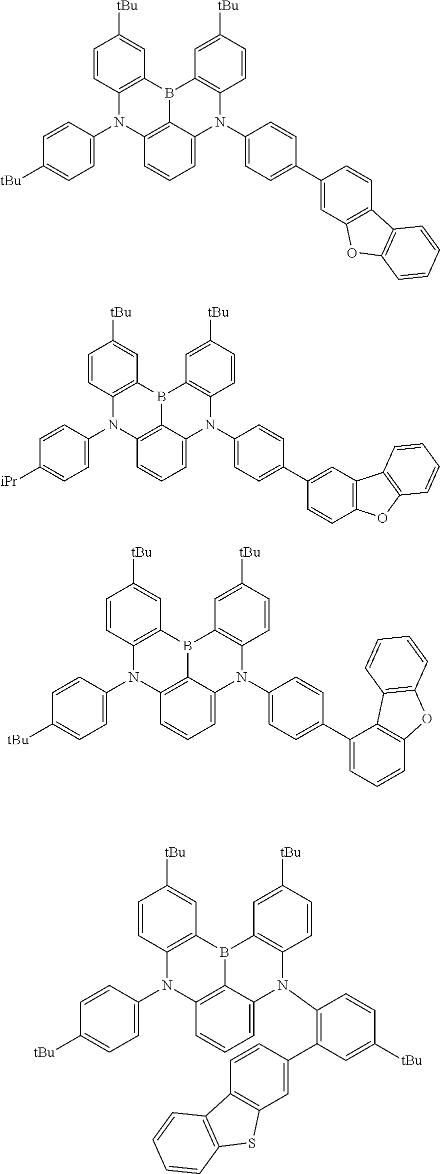 [SMILES: CC(C)(C)c1ccc(N2c3ccc(C(C)(C)C)cc3B3c4cc(C(C)(C)C)ccc4N(c4ccc(-c5ccc6c(c5)oc5ccccc56)cc4)c4cccc2c43)cc1 ; CC(C)c1ccc(N2c3ccc(C(C)(C)C)cc3B3c4cc(C(C)(C)C)ccc4N(c4ccc(-c5ccc6oc7ccccc7c6c5)cc4)c4cccc2c43)cc1 ; CC(C)(C)c1ccc(N2c3ccc(C(C)(C)C)cc3B3c4cc(C(C)(C)C)ccc4N(c4ccc(-c5cccc6oc7ccccc7c56)cc4)c4cccc2c43)cc1 ; CC(C)(C)c1ccc(N2c3ccc(C(C)(C)C)cc3B3c4cc(C(C)(C)C)ccc4N(c4ccc(C(C)(C)C)cc4-c4ccc5c(c4)sc4ccccc45)c4cccc2c43)cc1]

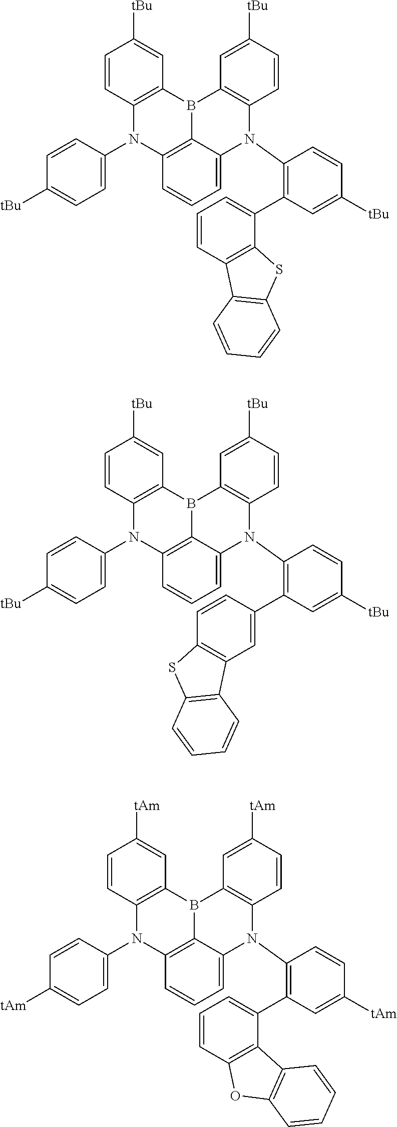

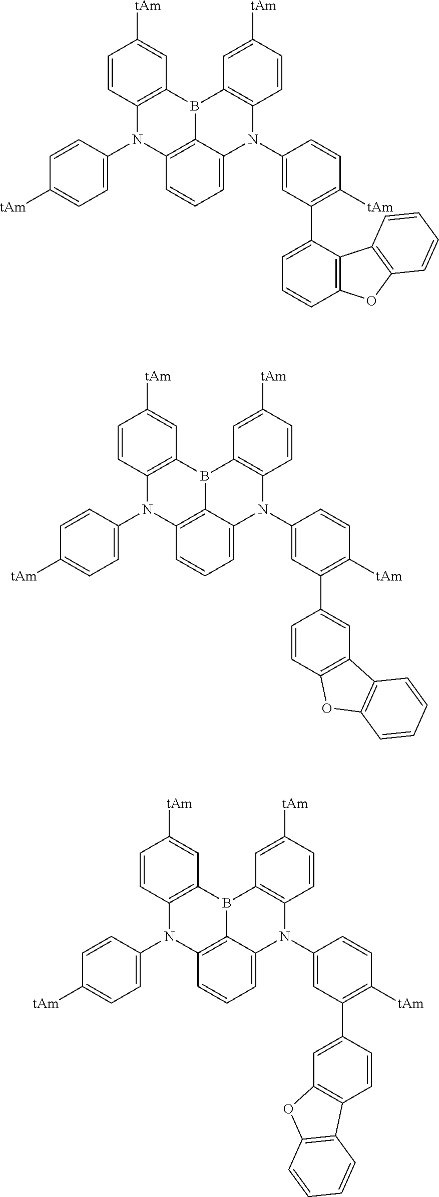

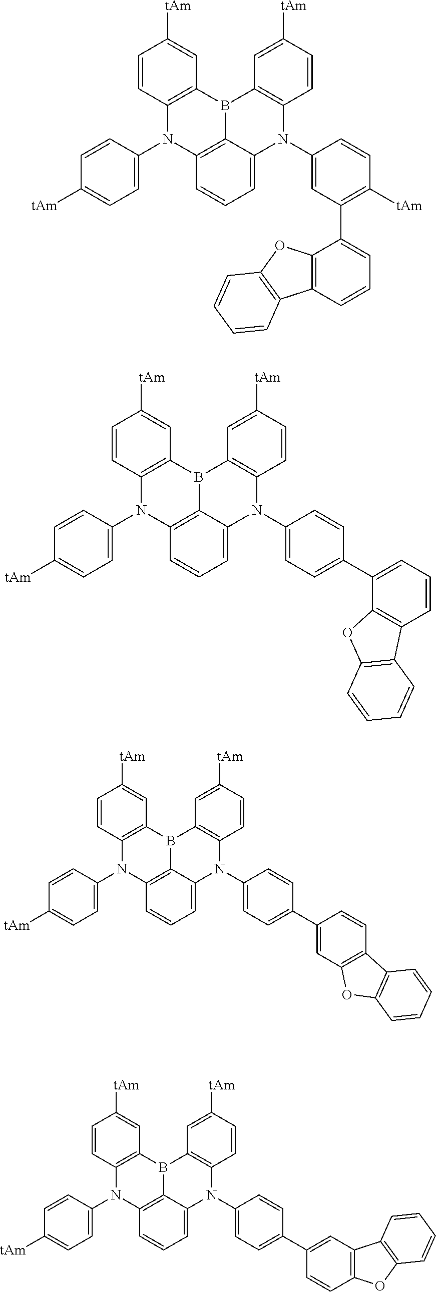

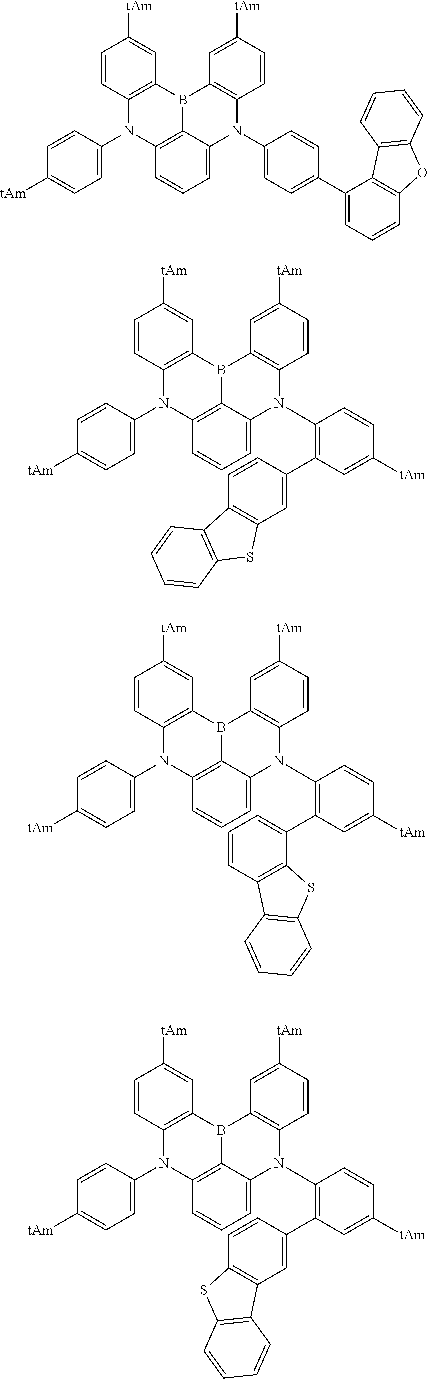

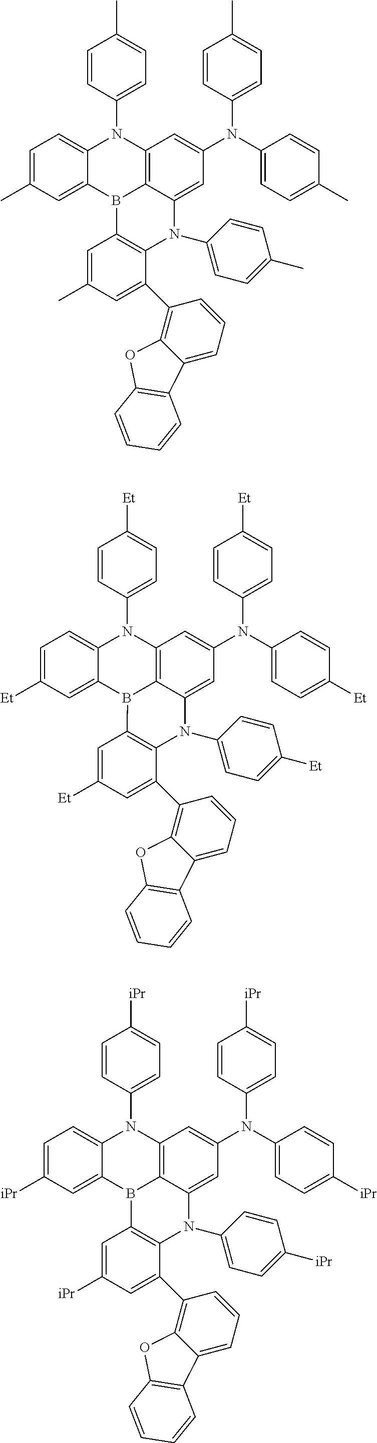

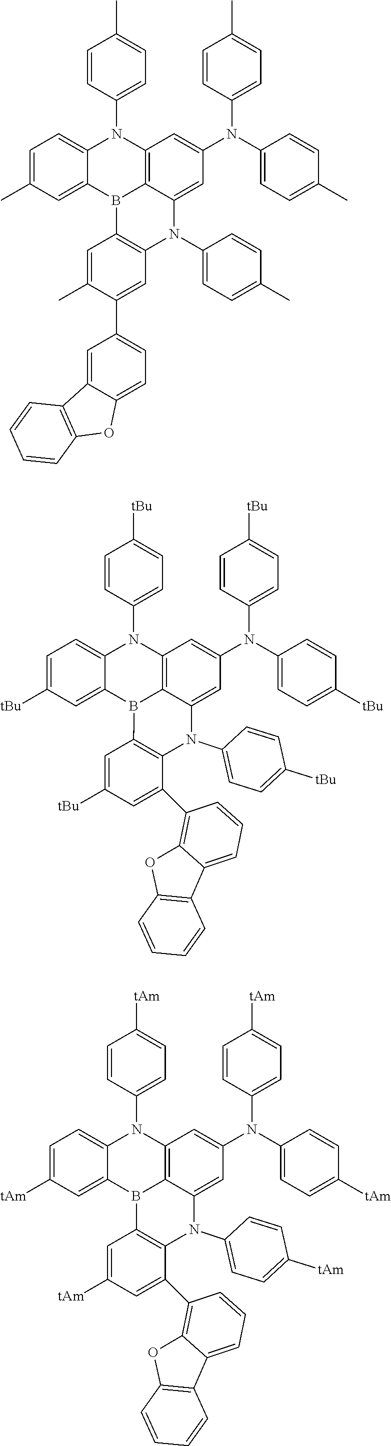

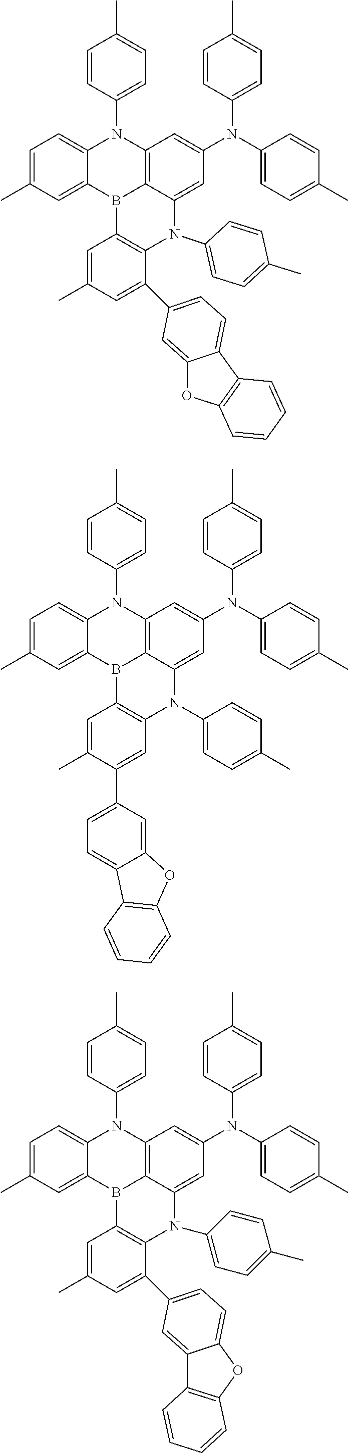

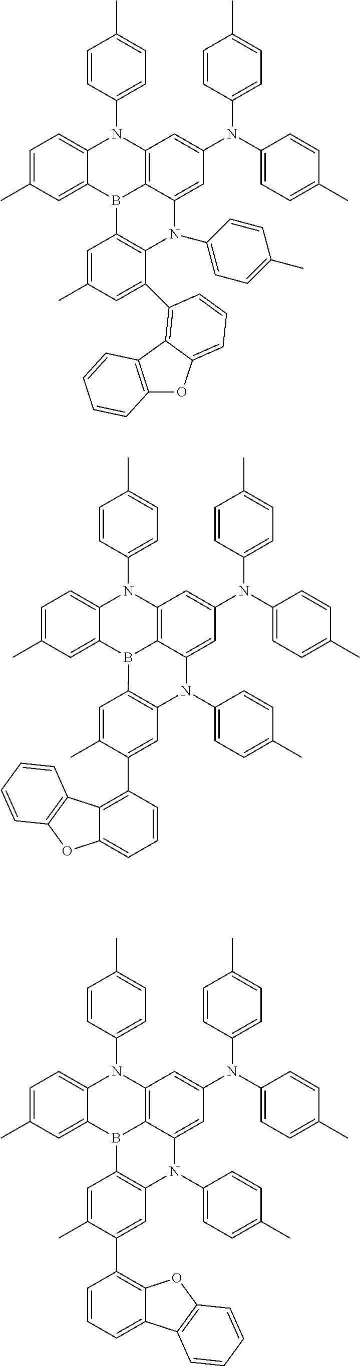

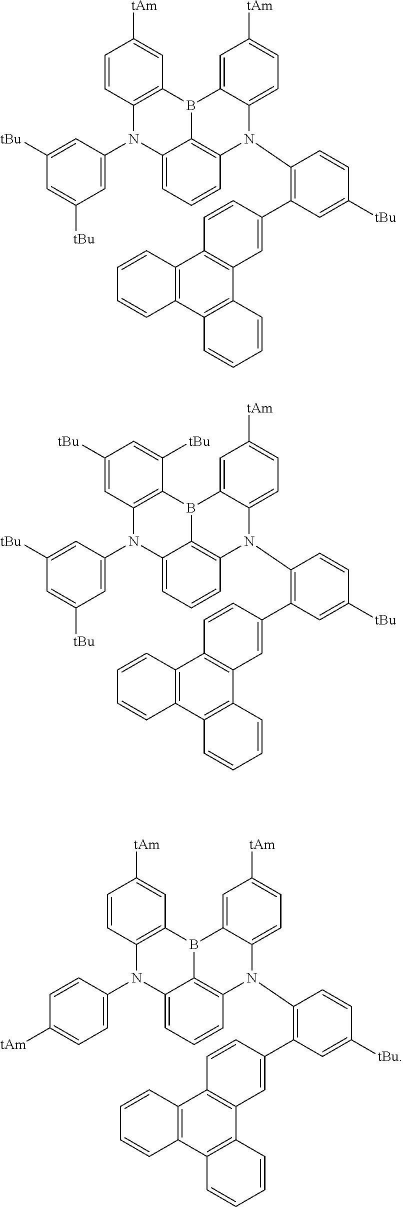

7. The organic compound of claim 1, wherein a six-membered aromatic ring or an aliphatic ring is formed between two adjacent R₁ groups.

8. The organic compound of claim 1, wherein a six-membered aromatic ring or an aliphatic ring is formed between two adjacent R₂ groups.

9. The organic compound of claim 1, wherein a six-membered aromatic ring or an aliphatic ring is formed between two adjacent R₃ groups.

10. The organic compound of claim 1, wherein a six-membered aromatic ring or an aliphatic ring is formed between two adjacent R₄ groups.

11. The organic compound of claim 1, wherein a six-membered aromatic ring or an aliphatic ring is formed between two adjacent R₅ groups.

12. A light-emitting element, comprising:
a pair of electrodes, comprising a first electrode and a second electrode; and
an organic functional layer located between the first electrode and the second electrode;
wherein materials of the organic functional layer comprise at least one organic compound, the organic compound is represented by Formula (1): 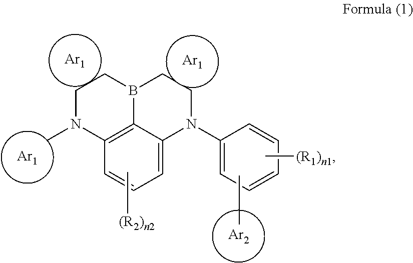
wherein each of Ar₁ groups is independently selected from structures represented by formula (A-1) to formula (A-5): 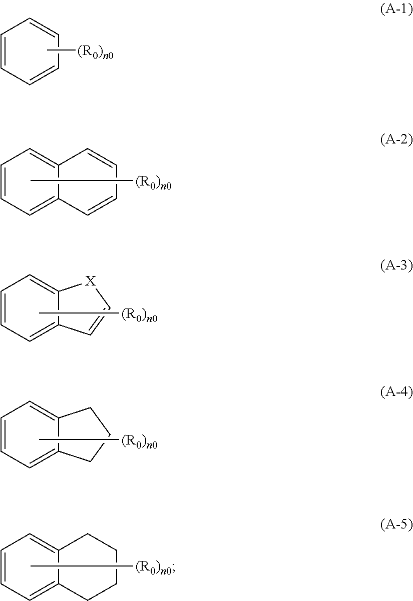
Ar₂ is selected from —H and structures represented by formula (B-1) to formula (B-4): 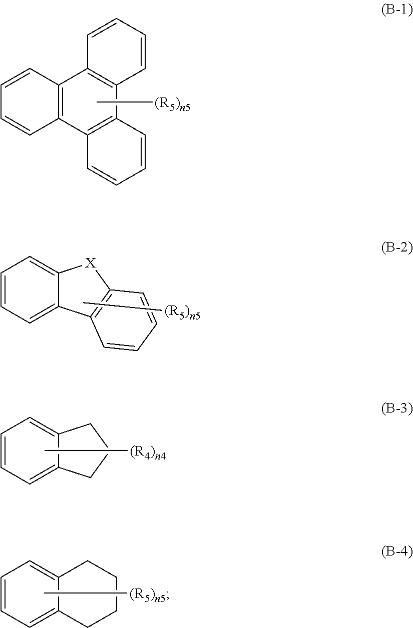
X is independently selected from O, S, N—CH₃, N-Ph, and C(CH₃)₂;
each of n₀, n₁, n₂, and n₅ is independently selected from 0 to 11;
each of R₀, R₁, R₂, and R₅ is independently selected from —H, -D, a C₁-C₂₀ linear alkyl group, a C₃-C₂₀ branched alkyl group, a substituted or unsubstituted aromatic group containing 6 to 30 ring atoms, and a substituted or unsubstituted heteroaromatic group containing 5 to 30 ring atoms; and
when n₀ is greater than or equal to 2, a ring is formed or no ring is formed between two adjacent R₀ groups; when n₁ is greater than or equal to 2, a ring is formed or no ring is formed between two adjacent R₁ groups; when n₂ is greater than or equal to 2, a ring is formed or no ring is formed between two adjacent R₂ groups; and when n₅ is greater than or equal to 2, a ring is formed or no ring is formed between two adjacent R₅ groups.

13. The light-emitting element of claim 12, wherein the organic functional layer comprises at least a light-emitting layer, the light-emitting layer comprises a host material and a guest material, the guest material is the organic compound, and the host material comprises a fused aromatic derivative or a heteroaromatic compound.

14. The light emitting element of claim 13, wherein the host material comprises at least one of an anthracene derivative, a pyrene derivative, a naphthalene derivative, a pentacene derivative, a phenanthrene compound, a fluoranthene compound, a carbazole derivative, a dibenzofuran derivative, a ladder type furan compound, and a pyrimidine derivative.

15. The light emitting element of claim 12, wherein the organic compound is represented by any one of formula (2-1) to formula (2-18): 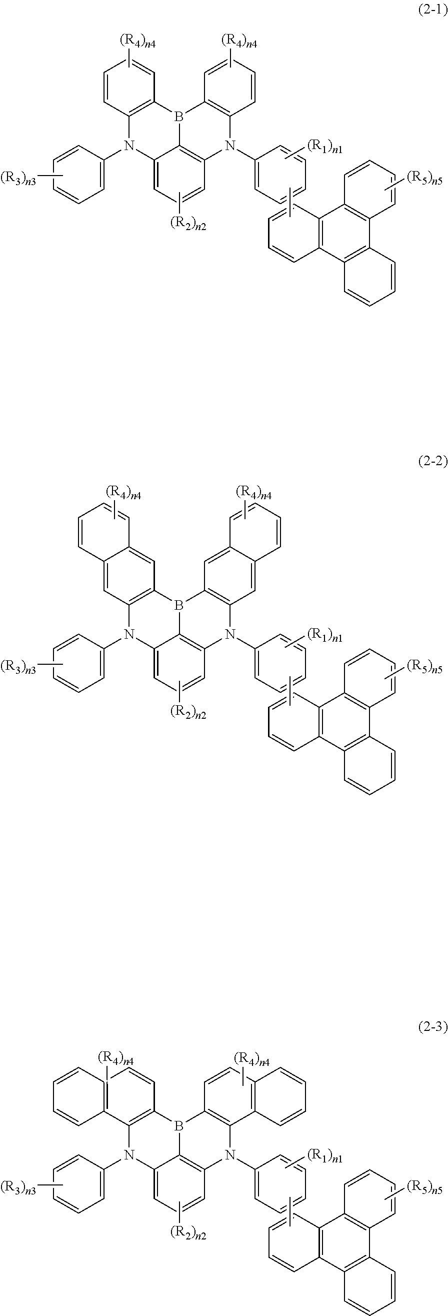 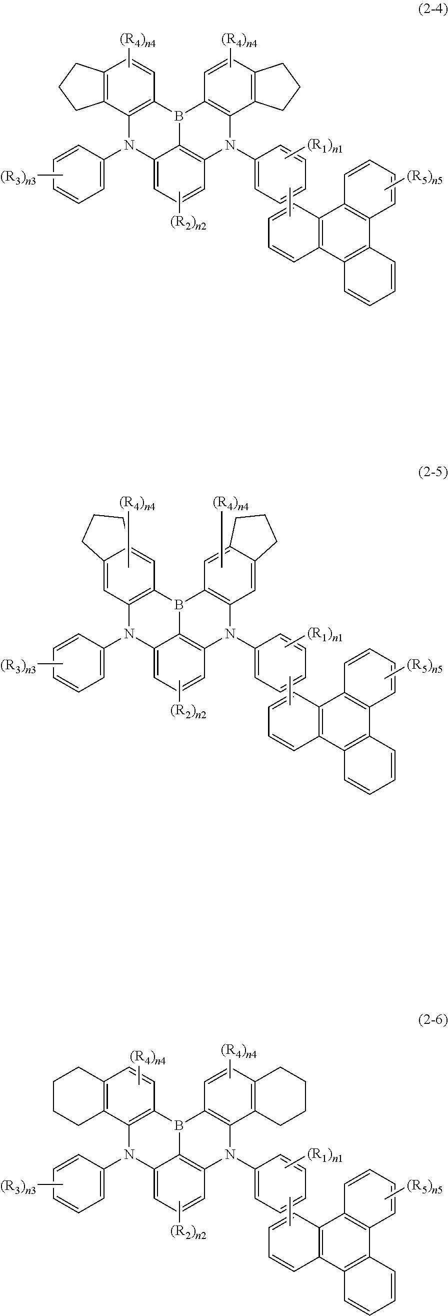 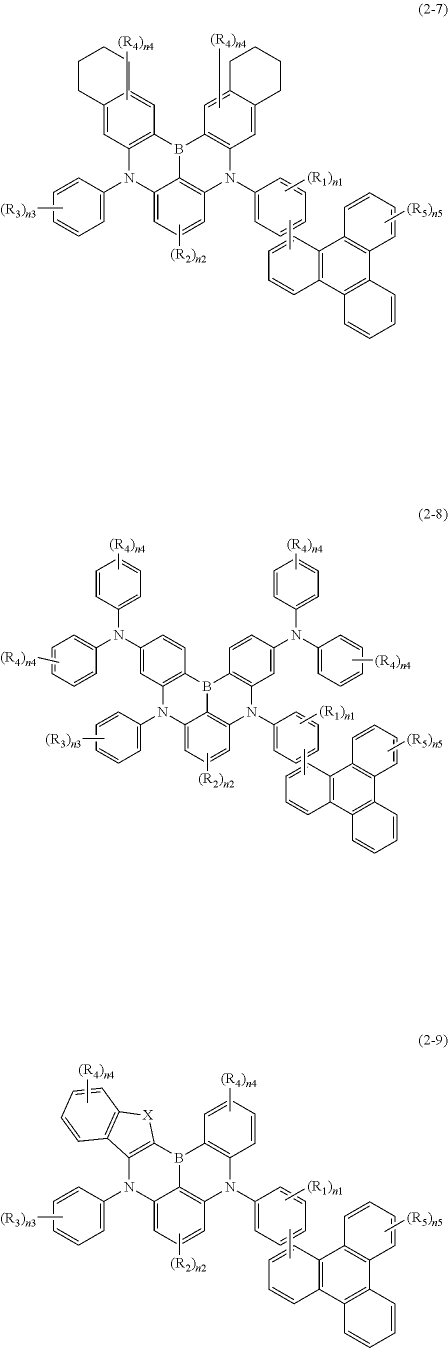 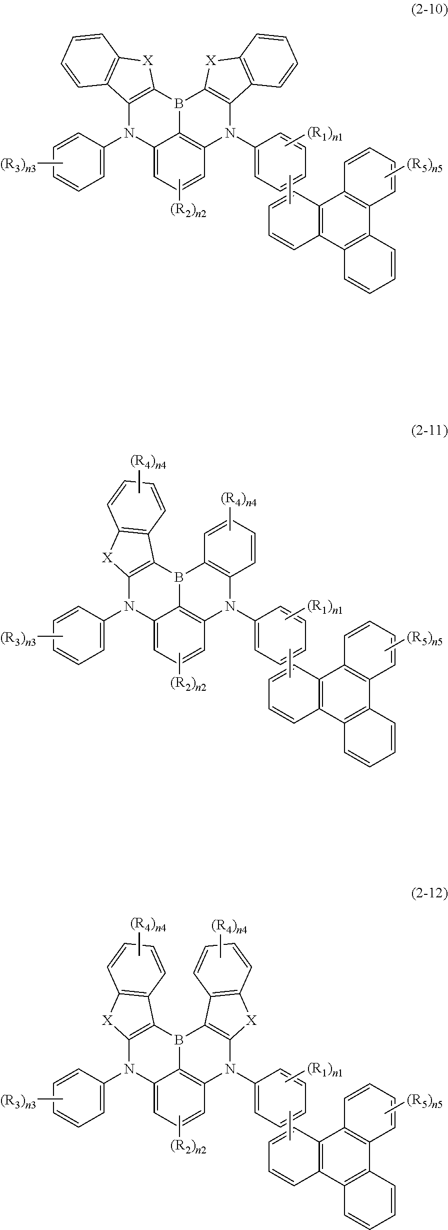 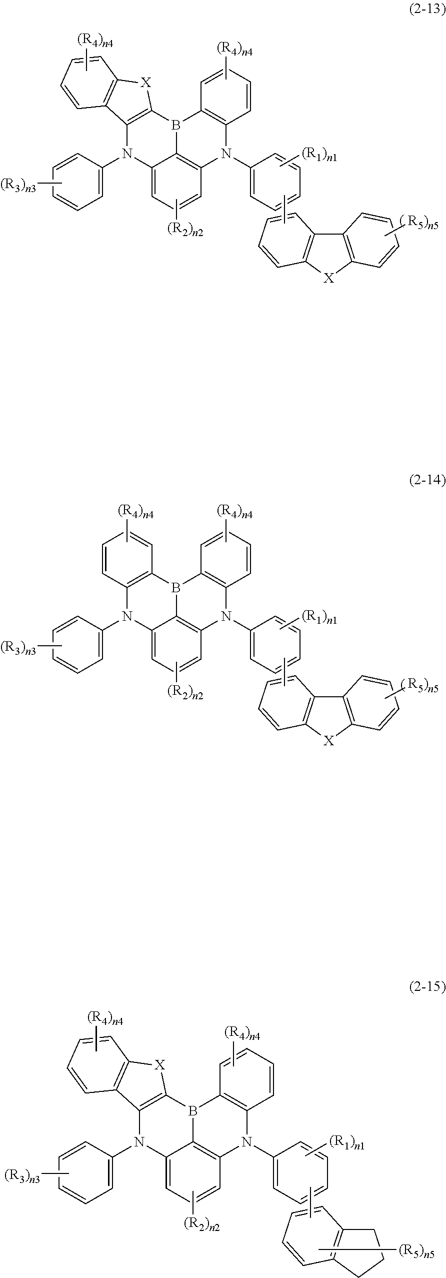 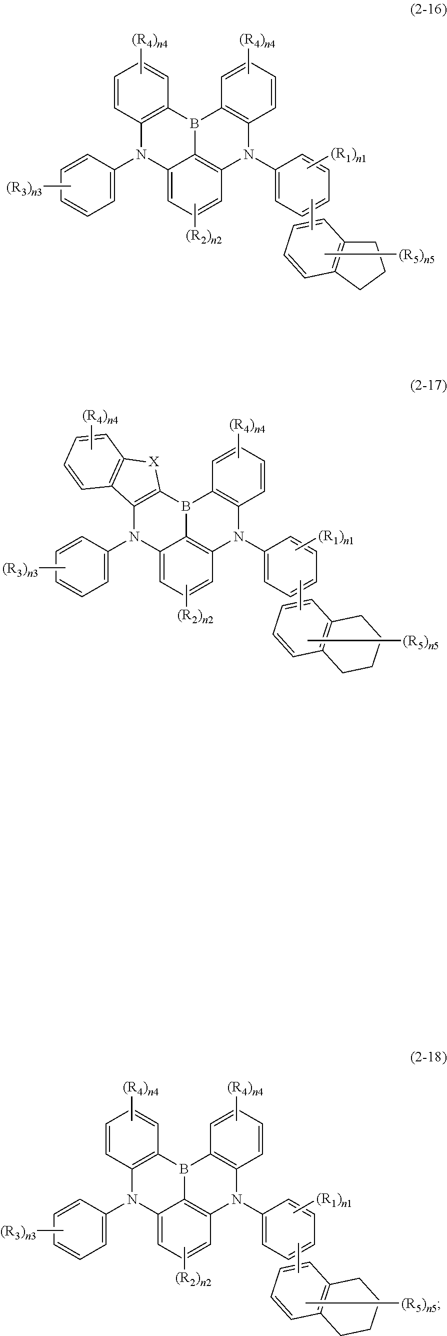
wherein each of R₃ and R₄ is independently selected from —H, -D, a C₁-C₂₀ linear alkyl group, a C₃-C₂₀ branched alkyl group, a substituted or unsubstituted aromatic group containing 6 to 30 ring atoms, and a substituted or unsubstituted heteroaromatic group containing 5 to 30 ring atoms;
each of n₃ and n₄ is independently selected from 0 to 11; and
when n₃ is greater than or equal to 2, a ring is formed or no ring is formed between two adjacent R₃ groups; and when n₄ is greater than or equal to 2, a ring is formed or no ring is formed between two adjacent R₄ groups.

16. The light-emitting element of claim 15, wherein each of R₁, R₂, R₃, R₄, and R₅ is independently selected from —H, -D, a C₁-C₁₀ linear alkyl group, and a C₃-C₁₀ branched alkyl group.

17. The light-emitting element of claim 16, wherein each of R₁, R₂, R₃, R₄, and R₅ is independently selected from —H, -D, a C₁-C₄ linear alkyl group, and a C₃-C₅ branched alkyl group.

18. The light-emitting element of claim 12, wherein a structure represented by the formula (A-3) is 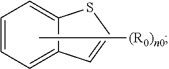
and
a structure represented by the formula (B-2) is

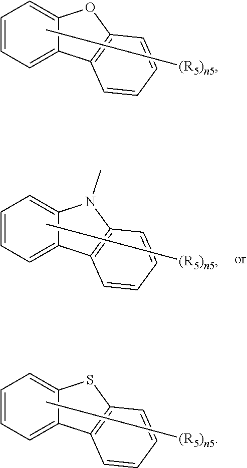

19. A display panel, comprising a light-emitting element, wherein the light-emitting element comprises:
a pair of electrodes, comprising a first electrode and a second electrode; and
an organic functional layer located between the first electrode and the second electrode;
wherein materials of the organic functional layer comprise at least one organic compound, the organic compound is represented by Formula (1): 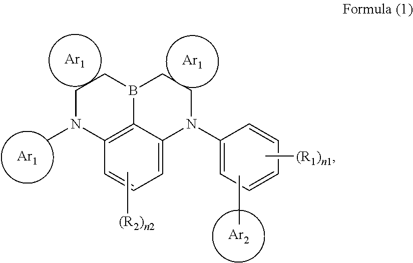
wherein each of Ar₁ groups is independently selected from structures represented by formula (A-1) to formula (A-5): 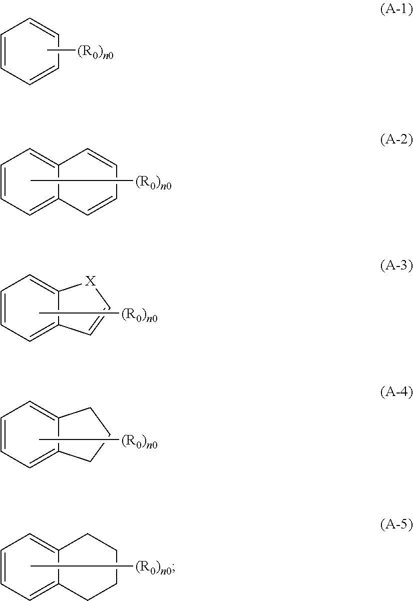
Ar₂ is selected from —H and structures represented by formula (B-1) to formula (B-4): 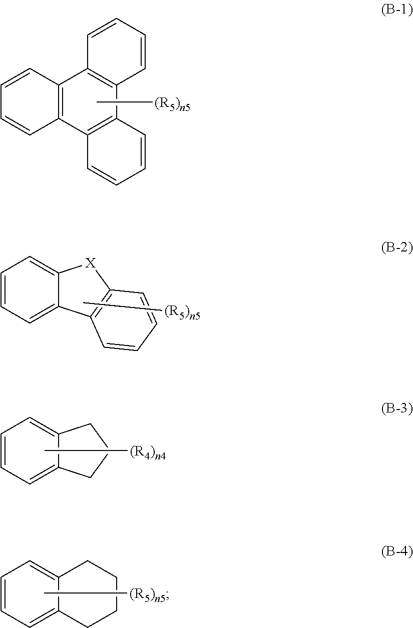
X is independently selected from O, S, N—CH₃, N-Ph, and C(CH₃)₂;
each of n₀, n₁, n₂, and n₅ is independently selected from 0 to 11;
each of R₀, R₁, R₂, and R₅ is independently selected from —H, -D, a C₁-C₂₀ linear alkyl group, a C₃-C₂₀ branched alkyl group, a substituted or unsubstituted aromatic group containing 6 to 30 ring atoms, and a substituted or unsubstituted heteroaromatic group containing 5 to 30 ring atoms; and
when n₀ is greater than or equal to 2, a ring is formed or no ring is formed between two adjacent R₀ groups; when n₁ is greater than or equal to 2, a ring is formed or no ring is formed between two adjacent R₁ groups; when n₂ is greater than or equal to 2, a ring is formed or no ring is formed between two adjacent R₂ groups; and when n₅ is greater than or equal to 2, a ring is formed or no ring is formed between two adjacent R₅ groups.

20. The display panel of claim 19, wherein each of R₁, R₂, R₃, R₄, and R₅ is independently selected from —H, -D, a C₁-C₁₀ linear alkyl group, and a C₃-C₁₀ branched alkyl group.
